(19) United States
(12) Patent Application Publication
(10) Pub. No.: US 2014/0299865 A1
(43) Pub. Date: Oct. 9, 2014

(54) ORGANIC ELECTROLUMINESCENCE ELEMENT AND MATERIAL FOR ORGANIC ELECTROLUMINESCENCE ELEMENT

(71) Applicants: Kazuki Nishimura, Sodegaura-shi (JP); Mitsuru Eida, Sodegaura-shi (JP); Mitsunori Ito, Sodegaura-shi (JP)

(72) Inventors: Kazuki Nishimura, Sodegaura-shi (JP); Mitsuru Eida, Sodegaura-shi (JP); Mitsunori Ito, Sodegaura-shi (JP)

(73) Assignee: IDEMITSU KOSAN CO., LTD., Tokyo (JP)

(21) Appl. No.: 14/353,128

(22) PCT Filed: Oct. 18, 2012
(86) PCT No.: PCT/JP2012/077011

§ 371 Date: Apr. 21, 2014

(30) Foreign Application Priority Data
Oct. 21, 2011 (JP) 2011-232020

(51) Int. Cl. H01L 51/00; H01L 51/50

(52) U.S. Cl. CPC H01L 51/0058; H01L 51/0072; H01L 51/0067; H01L 51/0094; H01L 51/0073; H01L 51/0074; H01L 51/0071; H01L 51/5028
USPC 257/40; 252/500

(57) ABSTRACT

An organic electroluminescence device includes an anode, a cathode and at least an emitting layer interposed between the anode and the cathode. The emitting layer contains a first host material, a second host material and a phosphorescent dopant material. The first host material is a compound represented by the following formula (1). The second host material is a compound represented by the following formula (3).

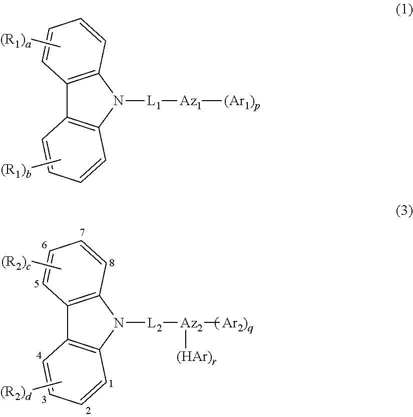

### TECHNICAL FIELD

The present invention relates to an organic electroluminescence device and an organic-electroluminescence-device material.

### BACKGROUND ART

When voltage is applied to an organic electroluminescence device (hereinafter, referred to as “organic EL device”), holes and electrons are injected into an emitting layer from an anode and a cathode, respectively. In the emitting layer, the injected holes and electrons are recombined with each other to generate excitons. Incidentally, according to the electron spin statistics theory, singlet excitons and triplet excitons are generated at a ratio of 25%:75%. An organic EL device classified into a fluorescent EL device by the emission principle uses emission from singlet excitons and thus the internal quantum efficiency thereof is believed to be not more than 25%. In contrast, an organic EL device classified into a phosphorescent EL device uses emission from triplet excitons and thus it is known that the internal quantum efficiency thereof can be enhanced to 100% as long as intersystem crossing from singlet excitons is efficiently performed.

Typically, an organic EL device has been appropriately designed in accordance with fluorescent mechanism or phosphorescent mechanism. In particular, it is known that a high performance of a phosphorescent organic EL device cannot be achieved by simply applying techniques for a fluorescent device thereto because of the emission properties thereof. The reasons are generally believed as follows.

Phosphorescence emission is emission using triplet excitons and thus requires a compound used for an emitting layer to have a large energy gap. This is because a value of the energy gap of a compound (hereinafter also referred to as singlet energy) is usually larger than a value of the triplet energy of the compound, the triplet energy herein meaning an energy difference between the lowest excited triplet state and the ground state.

In view of the above, in order to efficiently trap the triplet energy of a phosphorescent dopant material within the device, it is required that a host material having a triplet energy larger than that of the phosphorescent dopant material is used for an emitting layer. Further, it is also required that an electron transporting layer and a hole transporting layer are provided adjacent to the emitting layer and a compound having a triplet energy larger than that of the phosphorescent dopant material is used for the electron transporting layer and the hole transporting layer. As described above, when a typical device design concept is applied to a phosphorescent organic EL device, a compound having an energy gap larger than that of a compound usable for a fluorescent organic EL device is necessarily used for a phosphorescent organic EL device, which results in an increase in a drive voltage for the phosphorescent organic EL device as a whole.

A hydrocarbon-based compound, which is usable for a fluorescent device, is excellent in resistance to oxidation and reduction but has a small energy gap because of a widely formed n-electron cloud thereof. Therefore, the hydrocarbon-based compound is unlikely to be chosen for a phosphorescent organic EL device but an organic compound containing a hetero atom (e.g., oxygen and nitrogen) is chosen, so that a phosphorescent organic EL device has a short lifetime as compared with a fluorescent organic EL device.

Further, the exciton-relaxation rate of the triplet excitons of a phosphorescent dopant material is considerably low as compared with that of singlet excitons, which also has a large influence on the device performance. In other words, in the case of emission from singlet excitons, a rate of relaxation (resulting in emission) is high, so that the excitons are unlikely to disperse into layers near an emitting layer (e.g., a hole transporting layer and an electron transporting layer) and thus the emission is expected to be efficiently achieved. In contrast, in the case of emission from triplet excitons, a relaxation rate is low due to spin-forbidden transition, so that the excitons are likely to disperse into the nearby layers to cause thermal energy-deactivation (except a specific phosphorescent compound). In other words, control of an electron-hole recombination region is important for a phosphorescent organic EL device as compared with for a fluorescent organic EL device.

For the above reasons, in order to enhance the performance of a phosphorescent organic EL device to a high level, it is required to choose material and device design different from ones for a fluorescent organic EL device.

As a host material (phosphorescent host material) to be combined with such a phosphorescent dopant material, a carbazole derivative, an aromatic amine derivative, a quinolinol metal complex and the like are used according to disclosed techniques but none of them exhibits a sufficient luminous efficiency.

In connection with alternatives to such phosphorescent host materials, for instance, Patent Literatures 1 and 2 disclose techniques of using a carbazole-azine derivative having a carbazole skeleton and an azine skeleton as a host material and also disclose organic EL devices in which two host materials are used for an emitting layer.

In the organic EL devices as disclosed in Patent Literatures 1 and 2, the emitting layer contains the carbazole-azine derivative, a carbazole-amine derivative having an amine skeleton and a carbazole skeleton and a phosphorescent dopant material.

Patent Literature 3 discloses an organic EL device in which a carbazole-amine derivative and mcp with two carbazole rings bonded via a phenylene group are used as host materials.

Patent Literature 4 discloses an organic EL device using a carbazole derivative in which two carbazole rings are bonded via a biphenylene group and an amine derivative as host materials.

### CITATION LIST

### Patent Literatures

Patent Document 1: JP-A-2010-212676
Patent Document 2: JP-A-2010-206191
Patent Document 3: JP-A-2010-227462
Patent Document 4: JP-A-2007-251097

### SUMMARY OF THE INVENTION

### Problems to be Solved by the Invention

The organic EL devices as disclosed in Patent Literatures 1 to 4 each have an emitting layer containing a carbazole-based material in combination with an amine-based material but none of them exhibits a sufficient luminous efficiency.

An object of the invention is to provide an organic EL device with a sufficient luminous efficiency and an organic-EL-device material therefor.

### Means for Solving the Problems

According to an aspect of the invention, an organic electroluminescence device includes:

an anode; a cathode; and at least an emitting layer being provided between the anode and the cathode, the emitting layer comprising a first host material, a second host material and a phosphorescent dopant material, the first host material being a compound represented by the following formula (1), the second host material being a compound represented by the following formula (3).

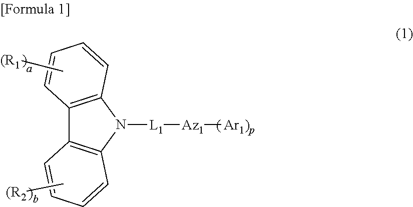

In the formula (1), R₁ are each independently a hydrogen atom, a halogen atom, a cyano group, a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted alkenyl group having 2 to 30 carbon atoms, a substituted or unsubstituted alkynyl group having 2 to 30 carbon atoms, a substituted or unsubstituted alkylsilyl group having 3 to 30 carbon atoms, a substituted or unsubstituted arylsilyl group having 6 to 30 ring carbon atoms, a substituted or unsubstituted alkoxy group having 1 to 30 carbon atoms, a substituted or unsubstituted aralkyl group having 6 to 30 ring carbon atoms, or a substituted or unsubstituted aryloxy group having 6 to 30 ring carbon atoms.

In the formula (1), a and b each represent 4 and plural R₁ are mutually the same or different.

According to the invention, the heterocyclic group includes a nitrogen-containing aromatic heterocyclic group.

In the formula (1), p is an integer of from 0 to 4.

In the formula (1), L₁ is a single bond or a linking group, the linking group being a substituted or unsubstituted aryl group having 6 to 30 ring carbon atoms, a substituted or unsubstituted heterocyclic group having 5 to 30 ring atoms, a cyclic hydrocarbon group having 5 to 30 ring carbon atoms, or a group provided by bonding the aryl group, the heterocyclic group and/or the cyclic hydrocarbon group.

Az₁ in the formula (1) is a group represented by the following formula (2).

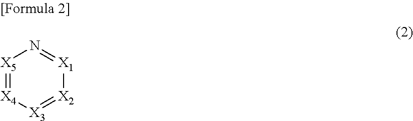

In the formula (2), any one of X₁ to X₅ is a carbon atom bonded to L₁.

In the formula (2), the other four of X₁ to X₅ that are not bonded to L₁ are each independently CR₁ or a nitrogen atom when p is 0.

When p is 1 to 4, p of X₁ to X₅ are each a carbon atom bonded to Ar₁ in the formula (1) and (4-p) of X₁ to X₅ are each independently CR₁ or a nitrogen atom. R₁ represents the same as R₁ in the formula (1).

CR₁ is a carbon atom (C) bonded with R₁.

Ar₁ in the formula (1) is a substituted or unsubstituted aryl group having 6 to 30 ring carbon atoms, a substituted or unsubstituted heterocyclic group having 5 to 30 ring carbon atoms, or a group provided by bonding the aryl group and the heterocyclic group.

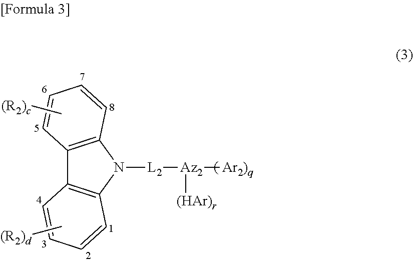

In the formula (3), R₂ are each independently a hydrogen atom, a halogen atom, a cyano group, a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted alkenyl group having 2 to 30 carbon atoms, a substituted or unsubstituted alkynyl group having 2 to 30 carbon atoms, a substituted or unsubstituted alkylsilyl group having 3 to 30 carbon atoms, a substituted or unsubstituted arylsilyl group having 6 to 30 ring carbon atoms, a substituted or unsubstituted alkoxy group having 1 to 30 carbon atoms, a substituted or unsubstituted aralkyl group having 6 to 30 ring carbon atoms, or a substituted or unsubstituted aryloxy group having 6 to 30 ring carbon atoms.

In the formula (3), c and d each independently an integer of 0 to 4 and plural R₂ are mutually the same or different.

In the formula (3), q is an integer of from 1 to 4.

In the formula (3), r is 0 or 1.

In the formula (3), 1≦q+r≦4.

In the formula (3), L₂ is a single bond or a linking group, the linking group being a substituted or unsubstituted aryl group having 6 to 30 ring carbon atoms, a substituted or unsubstituted heterocyclic group having 5 to 30 ring atoms, a cyclic hydrocarbon group having 5 to 30 ring carbon atoms, or a group provided by bonding the aryl group and the heterocyclic group.

In the formula (3), Ar₂ is a substituted or unsubstituted aryl group having 6 to 30 ring carbon atoms, a substituted or unsubstituted heterocyclic group having 5 to 30 ring carbon atoms, or a group provided by bonding the aryl group and the heterocyclic group.

In the formula (3), Az₂ is a group represented by the following formula (4).

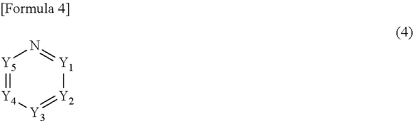

In the formula (4), any one of Y₁ to Y₅ is bonded to L₂.

In the formula (4), q of the other four of Y₁ to Y₅ that are not bonded to L₂ are each a carbon atom bonded to Ar₂, r of the other four of Y₁ to Y₅ are each a carbon atom bonded to HAr, and (4-q-r) of the other four of Y₁ to Y₅ are each independently CR₃ or a nitrogen atom. CR₃ is a carbon atom (C) bonded with R₃.

In the formula (4), R₃ represents the same as R₂ in the formula (3).

In the formula (4), HAr is represented by any one of the following formulae (5) to (7).

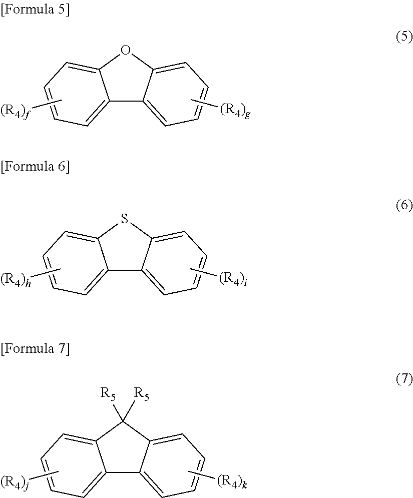

Each off and g in the formula (5) are each 4.

Each of h and i in the formula (6) is 4.

Each of j and k in the formula (7) is 4.

Plural R₄ in each of the formulae (5), (6) and (7) are mutually the same or different and at least one of the plural R₄ is a single bond to Az₂. R₄ in each of the formulae (5), (6) and (7) represents the same as R₂ in the formula (3).

Two R₅ in the formula (7) are mutually the same or different and each represent the same as R₂ in the formula (3).

R₂ is bonded to a carbazole ring in the formula (3), the carbazole ring being bonded to a moiety represented by the following formula (8).

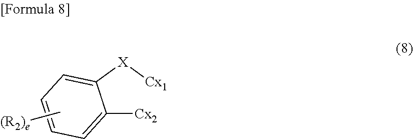

In the formula (8), Cx₁ and Cx₂ are any adjacent two of carbon atoms in 1- to 8-positions of the carbazole ring to which R₂ is bonded in the formula (3).

In the formula (8), X is an oxygen atom, a sulfur atom, NR₂ or C(R₂)₂. NR₂ is a nitrogen atom (N) bonded with one R₂ and C(R₂)₂ is a carbon atom (C) bonded with two R₂.

In the formula (8), e is 4.

In the formula (8), R₂ represents the same as R₂ in the formula (3).

In the organic electroluminescence device, the compound represented by the formula (1) as the first host material is preferably a compound represented by the following formula (9).

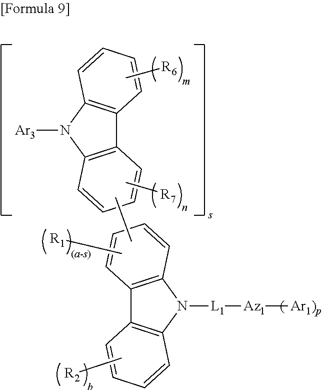

In the formula (9), s is an integer of from 1 to 4.

In the formula (9), R₆ and R₇ each represent the same as R₁ in the formula (1).

In the formula (9), m is 4 and plural R₆ are mutually the same or different.

In the formula (9), n is 3 and plural R₇ are mutually the same or different.

In the formula (9), Ar₁ represents the same as Ar₁ in the formula (1).

In the organic electroluminescence device, the compound represented by the formula (1) as the first host material is preferably a compound represented by the following formula (10).

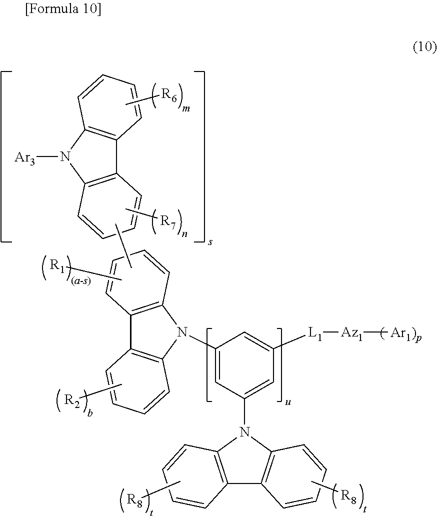

In the formula (10), R₆ and R₇ each represent the same as R₁ in the formula (1).

In the formula (10), m is 4 and plural R₆ are mutually the same or different.

In the formula (10), n is 3 and plural R₇ are mutually the same or different.

In the formula (10), Ar₃ represents the same as Ar₁ in the formula (1).

In the formula (10), s is 0 or 1, u is 0 or 1 and s and u satisfy a relation of s+u=1.

In the formula (10), R₈ represents the same as R₁ in the formula (1).

In the formula (10), t is 4 and plural R₈ are mutually the same or different.

According to another aspect of the invention, an organic-EL-device material contains a compound represented by the formula (1) and a compound represented by the formula (3).

In the organic-EL-device material, the compound represented by the formula (1) is preferably a compound represented by the formula (9).

In the organic-EL-device material, the compound represented by the formula (1) is preferably a compound represented by the formula (10).

The organic EL device according to the above aspect of the invention exhibits a sufficient luminous efficiency. Further, with the organic-EL-device material according to the above aspect of the invention, an organic EL device with a sufficient luminous efficiency can be provided.

### BRIEF DESCRIPTION OF DRAWINGS

FIG. 1 schematically shows an exemplary arrangement of an organic EL device according to a first exemplary embodiment of the invention.

FIG. 2 schematically shows an exemplary arrangement of an organic EL device according to a second exemplary embodiment of the invention.

FIG. 3 schematically shows an exemplary arrangement of an organic EL device according to a third exemplary embodiment of the invention.

### DESCRIPTION OF EMBODIMENTS

### First Exemplary Embodiment

Arrangement of Organic EL Device

Arrangements of an organic EL device according to the invention are described below.

Representative arrangement examples of an organic EL device are as follows:

(1) anode/emitting layer/cathode;

(2) anode/hole injecting layer/emitting layer/cathode;

(3) anode/emitting layer/electron injecting transporting layer/cathode;

(4) anode/hole injecting layer/emitting layer/electron injecting-transporting layer/cathode; and

(5) anode/hole injecting-transporting layer/emitting layer/electron injecting-transporting layer/cathode.

While the arrangement (5) is preferably used among the above, the arrangement of the invention is not limited to the above arrangements.

It should be noted that the aforementioned “emitting layer” is typically an organic layer in which a doping system is applied and a host material and a dopant material are contained. The host material typically promotes recombination of electrons and holes and transmits excited energy generated by the recombination to the dopant material. The dopant material is preferably a compound having a high quantum yield. The dopant material after receiving the excited energy from the host material exhibits a high luminescent performance.

The term “hole injecting/transporting layer (or hole injecting-transporting layer)” means “at least one of hole injecting layer and hole transporting layer”, while the term “electron injecting/transporting layer (or electron injecting-transporting layer)” means “at least one of electron injecting layer and electron transporting layer”. When the hole injecting layer and the hole transporting layer are provided, the hole injecting layer is preferably disposed closer to the anode. When the electron injecting layer and the electron transporting layer are provided, the electron injecting layer is preferably disposed closer to the cathode.

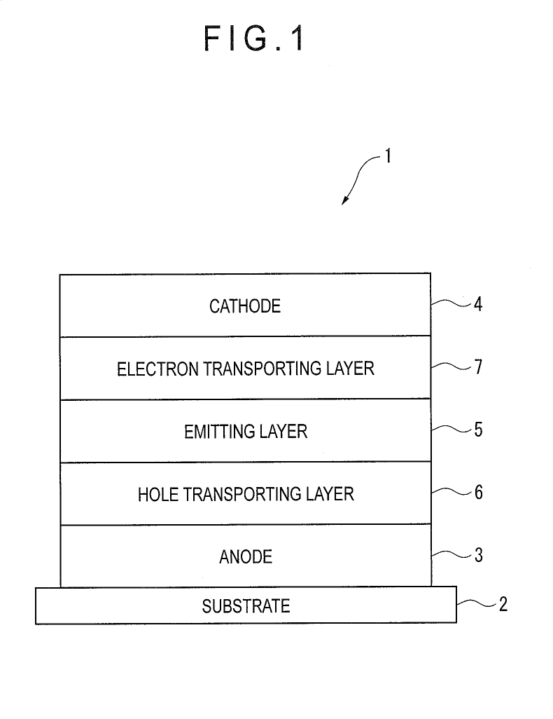

Next, an organic EL device 1 according to a first exemplary embodiment is shown in FIG. 1.

The organic EL device 1 includes a transparent substrate 2, an anode 3, a cathode 4, a hole transporting layer 6, an emitting layer 5 and an electron transporting layer 7.

The hole transporting layer 6, the emitting layer 5, the electron transporting layer 7 and the cathode 4 are sequentially laminated on the anode 3.

### Emitting Layer

The emitting layer 5 contains a first host material, a second host material and a phosphorescent dopant material.

The emitting layer 5 has a function for providing recombination of electrons and holes to emit light.

Preferably, the emitting layer 5 contains the first host material in an amount of from 10 mass % to 90 mass %, the second host material in an amount of from 10 mass % to 90 mass % and the phosphorescent dopant material in an amount of from 0.1 mass % to 30 mass % with the provision that the sum of the mass percentages of the materials is 100 mass %. Further preferably, the first host material is contained in an amount of from 40 mass % to 60 mass % and the second host material is contained in an amount of from 40 mass % to 60 mass %.

### First Host Material

The first host material used in the organic EL device according to the exemplary embodiment may be a compound represented by the following formula (1).

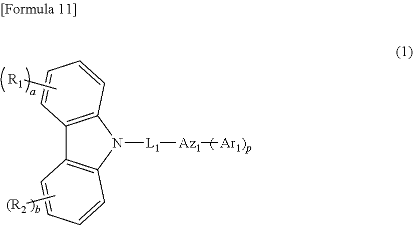

In the formula (1), R₁ are each independently a hydrogen atom, a halogen atom, a cyano group, a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted alkenyl group having 2 to 30 carbon atoms, a substituted or unsubstituted alkynyl group having 2 to 30 carbon atoms, a substituted or unsubstituted alkylsilyl group having 3 to 30 carbon atoms, a substituted or unsubstituted arylsilyl group having 6 to 30 ring carbon atoms, a substituted or unsubstituted alkoxy group having 1 to 30 carbon atoms, a substituted or unsubstituted aralkyl group having 6 to 30 ring carbon atoms, or a substituted or unsubstituted aryloxy group having 6 to 30 ring carbon atoms.

In the formula (1), a and b each represent 4 and plural R₁ are mutually the same or different.

Examples of the aryl group having 6 to 30 ring carbon atoms for R₁ in the formula (1) are: a phenyl group, 1-naphthyl group, 2-naphthyl group, 1-anthryl group, 2-anthryl group, 9-anthryl group, benzanthryl group, 1-phenanthryl group, 2-phenanthryl group, 3-phenanthryl group, 4-phenanthryl group, 9-phenanthryl group, naphthacenyl group, pyrenyl group, 1-chrysenyl group, 2-chrysenyl group, 3-chrysenyl group, 4-chrysenyl group, 5-chrysenyl group, 6-chrysenyl group, benzo[c]phenanthryl group, benzo[g]chrysenyl group, 1-triphenylenyl group, 2-triphenylenyl group, 3-triphenylenyl group, 4-triphenylenyl group, 1-fluorenyl group, 2-fluorenyl group, 3-fluorenyl group, 4-fluorenyl group, 9-fluorenyl group, benzofluorenyl group, dibenzofluorenyl group, 2-biphenylyl group, 3-biphenylyl group, 4-biphenylyl group, o-terphenyl group, m-terphenyl-4-yl group, m-terphenyl-3-yl group, m-terphenyl-2-yl group, p-terphenyl-4-yl group, p-terphenyl-3-yl group, p-terphenyl-2-yl group, m-quarterphenyl group, 3-fluoranthenyl group, 4-fluoranthenyl group, 8-fluoranthenyl group, 9-fluoranthenyl group, benzofluoranthenyl group, o-tolyl group, m-tolyl group, p-tolyl group, 2,3-xylyl group, 3,4-xylyl group, 2,5-xylyl group, mesityl group, o-cumenyl group, m-cumenyl group, p-cumenyl group, p-t-butylphenyl group, p-(2-phenylpropyl)phenyl group, 4′-methylbiphenylyl group and 4″-t-butyl-p-terphenyl-4-yl group.

The aryl group in the formula (1) preferably has 6 to 20 ring carbon atoms, more preferably 6 to 12 ring carbon atoms. Among the above examples of the aryl group, a phenyl group, biphenyl group, naphthyl group, phenanthryl group, terphenyl group and fluorenyl group are particularly preferable. In the 1-fluorenyl group, 2-fluorenyl group, 3-fluorenyl group and 4-fluorenyl group, it is preferable that a carbon atom in the 9-position is substituted with a substituted or unsubstituted alkyl group having 1 to 30 carbon atoms for the formula (1).

Examples of the heterocyclic group having 5 to 30 ring atoms in the formula (1) are a pyrroryl group, pyrazinyl group, pyridinyl group, indolyl group, isoindolyl group, imidazolyl group, furyl group, benzofuranyl group, isobenzofuranyl group, dibenzofuranyl group, dibenzothiophenyl group, quinolyl group, isoquinolyl group, quinoxalinyl group, carbazolyl group, phenantridinyl group, acridinyl group, phenanthrolinyl group, phenazinyl group, phenothiazinyl group, phenoxazinyl group, oxazolyl group, oxadiazolyl group, furazanyl group, thienyl group, benzothiophenyl group and a group formed from a pyridine ring, pyrazine ring, pyrimidine ring, pyridazine ring, triazine ring, indol ring, quinoline ring, acridine ring, pirrolidine ring, dioxane ring, piperidine ring, morpholine ring, piperadine ring, carbazole ring, furan ring, thiophene ring, oxazole ring, oxadiazole ring, benzoxazole ring, thiazole ring, thiadiazole ring, benzothiazole ring, triazole ring, imidazole ring, benzimidazole ring, pyrane ring and dibenzofuran ring.

Further, specific examples are a 1-pyrroryl group, 2-pyrroryl group, 3-pyrroryl group, pyrazinyl group, 2-pyridinyl group, 2-pyrimidinyl group, 4-pyrimidinyl group, 5-pyrimidinyl group, 6-pyrimidinyl group, 1,2,3-triazine-4-yl group, 1,2,4-triazine-3-yl group, 1,3,5-triazine-2-yl group, 1-imidazolyl group, 2-imidazolyl group, 1-pyrazolyl group, 1-indolidinyl group, 2-indolidinyl group, 3-indolidinyl group, 5-indolidinyl group, 6-indolidinyl group, 7-indolidinyl group, 8-indolidinyl group, 2-imidazopyridinyl group, 3-imidazopyridinyl group, 5-imidazopyridinyl group, 6-imidazopyridinyl group, 7-imidazopyridinyl group, 8-imidazopyridinyl group, 3-pyridinyl group, 4-pyridinyl group, 1-indolyl group, 2-indolyl group, 3-indolyl group, 4-indolyl group, 5-indolyl group, 6-indolyl group, 7-indolyl group, 1-isoindolyl group, 2-isoindolyl group, 3-isoindolyl group, 4-isoindolyl group, 5-isoindolyl group, 6-isoindolyl group, 7-isoindolyl group, 2-furyl group, 3-furyl group, 2-benzofuranyl group, 3-benzofuranyl group, 4-benzofuranyl group, 5-benzofuranyl group, 6-benzofuranyl group, 7-benzofuranyl group, 1-isobenzofuranyl group, 3-isobenzofuranyl group, 4-isobenzofuranyl group, 5-isobenzofuranyl group, 6-isobenzofuranyl group, 7-isobenzofuranyl group, 2-quinolyl group, 3-quinolyl group, 4-quinolyl group, 5-quinolyl group, 6-quinolyl group, 7-quinolyl group, 8-quinolyl group, 1-isoquinolyl group, 3-isoquinolyl group, 4-isoquinolyl group, 5-isoquinolyl group, 6-isoquinolyl group, 7-isoquinolyl group, 8-isoquinolyl group, 2-quinoxalinyl group, 5-quinoxalinyl group, 6-quinoxalinyl group, 1-carbazolyl group, 2-carbazolyl group, 3-carbazolyl group, 4-carbazolyl group, 9-carbazolyl group, azacarbazolyl-1-yl group, azacarbazolyl-2-yl group, azacarbazolyl-3-yl group, azacarbazolyl-4-yl group, azacarbazolyl-5-yl group, azacarbazolyl-6-yl group, azacarbazolyl-7-yl group, azacarbazolyl-8-yl group, azacarbazolyl-9-yl group, 1-phenanthrydinyl group, 2-phenanthrydinyl group, 3-phenanthrydinyl group, 4-phenanthrydinyl group, 6-phenanthrydinyl group, 7-phenanthrydinyl group, 8-phenanthrydinyl group, 9-phenanthrydinyl group, 10-phenanthrydinyl group, 1-acridinyl group, 2-acridinyl group, 3-acridinyl group, 4-acridinyl group, 9-acridinyl group, 1,7-phenanthroline-2-yl group, 1,7-phenanthroline-3-yl group, 1,7-phenanthroline-4-yl group, 1,7-phenanthroline-5-yl group, 1,7-phenanthroline-6-yl group, 1,7-phenanthroline-8-yl group, 1,7-phenanthroline-9-yl group, 1,7-phenanthroline-10-yl group, 1,8-phenanthroline-2-yl group, 1,8-phenanthroline-3-yl group, 1,8-phenanthroline-4-yl group, 1,8-phenanthroline-5-yl group, 1,8-phenanthroline-6-yl group, 1,8-phenanthroline-7-yl group, 1,8-phenanthroline-9-yl group, 1,8-phenanthroline-10-yl group, 1,9-phenanthroline-2-yl group, 1,9-phenanthroline-3-yl group, 1,9-phenanthroline-4-yl group, 1,9-phenanthroline-5-yl group, 1,9-phenanthroline-6-yl group, 1,9-phenanthroline-7-yl group, 1,9-phenanthroline-8-yl group, 1,9-phenanthroline-10-yl group, 1,10-phenanthroline-2-yl group, 1,10-phenanthroline-3-yl group, 1,10-phenanthroline-4-yl group, 1,10-phenanthroline-5-yl group, 2,9-phenanthroline-1-yl group, 2,9-phenanthroline-3-yl group, 2,9-phenanthroline-4-yl group, 2,9-phenanthroline-5-yl group, 2,9-phenanthroline-6-yl group, 2,9-phenanthroline-7-yl group, 2,9-phenanthroline-8-yl group, 2,9-phenanthroline-10-yl group, 2,8-phenanthroline-1-yl group, 2,8-phenanthroline-3-yl group, 2,8-phenanthroline-4-yl group, 2,8-phenanthroline-5-yl group, 2,8-phenanthroline-6-yl group, 2,8-phenanthroline-7-yl group, 2,8-phenanthroline-9-yl group, 2,8-phenanthroline-10-yl group, 2,7-phenanthroline-1-yl group, 2,7-phenanthroline-3-yl group, 2,7-phenanthroline-4-yl group, 2,7-phenanthroline-5-yl group, 2,7-phenanthroline-6-yl group, 2,7-phenanthroline-8-yl group, 2,7-phenanthroline-9-yl group, 2,7-phenanthroline-10-yl group, 1-phenazinyl group, 2-phenazinyl group, 1-phenothiazinyl group, 2-phenothiazinyl group, 3-phenothiazinyl group, 4-phenothiazinyl group, 10-phenothiazinyl group, 1-phenoxazinyl group, 2-phenoxazinyl group, 3-phenoxazinyl group, 4-phenoxazinyl group, 10-phenoxazinyl group, 2-oxazolyl group, 4-oxazolyl group, 5-oxazolyl group, 2-oxadiazolyl group, 5-oxadiazolyl group, 3-furazanyl group, 2-thienyl group, 3-thienyl group, 2-methylpyrrole-1-yl group, 2-methylpyrrole-3-yl group, 2-methylpyrrole-4-yl group, 2-methylpyrrole-5-yl group, 3-methylpyrrole-1-yl group, 3-methylpyrrole-2-yl group, 3-methylpyrrole-4-yl group, 3-methylpyrrole-5-yl group, 2-t-butylpyrrole-4-yl group, 342-phenylpropyl)pyrrole-1-yl group, 2-methyl-1-indolyl group, 4-methyl-1-indolyl group, 2-methyl-3-indolyl group, 4-methyl-3-indolyl group, 2-t-butyl-1-indolyl group, 4-t-butyl-1-indolyl group, 2-t-butyl-3-indolyl group, 4-t-butyl-3-indolyl group, 1-dibenzofuranyl group, 2-dibenzofuranyl group, 3-dibenzofuranyl group, 4-dibenzofuranyl group, 1-dibenzothiophenyl group, 2-dibenzothiophenyl group, 3-dibenzothiophenyl group, 4-dibenzothiophenyl group, 1-silafluorenyl group, 2-silafluorenyl group, 3-silafluorenyl group, 4-silafluorenyl group, 1-germafluorenyl group, 2-germafluorenyl group, 3-germafluorenyl group and 4-germafluorenyl group.

The number of the ring atoms of the heterocyclic group in the formula (1) is preferably 5 to 20, more preferably 5 to 14. Among the above examples of the heterocyclic group, a 1-dibenzofuranyl group, 2-dibenzofuranyl group, 3-dibenzofuranyl group, 4-dibenzofuranyl group, 1-dibenzothiophenyl group, 2-dibenzothiophenyl group, 3-dibenzothiophenyl group, 4-dibenzothiophenyl group, 1-carbazolyl group, 2-carbazolyl group, 3-carbazolyl group, 4-carbazolyl group and 9-carbazolyl group are preferable. In a 1-carbazolyl group, 2-carbazolyl group, 3-carbazolyl group and 4-carbazolyl group, it is preferable that a nitrogen atom in the 9-position is substituted with the substituted or unsubstituted aryl group having 6 to 30 ring carbon atoms or the substituted or unsubstituted heterocyclic group having 5 to 30 ring atoms for the formula (1).

The alkyl group having 1 to 30 carbon atoms for R₁ in the formula (1) may be linear, branched or cyclic. Examples of the linear or branched alkyl group are a methyl group, ethyl group, propyl group, isopropyl group, n-butyl group, s-butyl group, isobutyl group, t-butyl group, n-pentyl group, n-hexyl group, n-heptyl group, n-octyl group, n-nonyl group, n-decyl group, n-undecyl group, n-dodecyl group, n-tridecyl group, n-tetradecyl group, n-pentadecyl group, n-hexadecyl group, n-heptadecyl group, n-octadecyl group, neo-pentyl group, 1-methylpentyl group, 2-methylpentyl group, 1-pentylhexyl group, 1-butylpentyl group, 1-heptyloctyl group, 3-methylpentyl group, hydroxymethyl group, 1-hydroxyethyl group, 2-hydroxyethyl group, 2-hydroxyisobutyl group, 1,2-dihydroroxyethyl group, 1,3-dihydroxyisopropyl group, 2,3-dihydroxy-t-butyl group, 1,2,3-trihydroxypropyl group, chloromethyl group, 1-chloroethyl group, 2-chloroethyl group, 2-chloroisobutyl group, 1,2-dichloroethyl group, 1,3-dichloroisopropyl group, 2,3-dichloro-t-butyl group, 1,2,3-trichloropropyl group, bromomethyl group, 1-bromoethyl group, 2-bromoethyl group, 2-bromoisobutyl group, 1,2-dibromoethyl group, 1,3-dibromoisopropyl group, 2,3-dibromo-t-butyl group, 1,2,3-tribromopropyl group, iodomethyl group, 1-iodoethyl group, 2-iodoethyl group, 2-iodoisobutyl group, 1,2-diiodoethyl group, 1,3-diiodoisopropyl group, 2,3-diiodo-t-butyl group, 1,2,3-triiodopropyl group, aminomethyl group, 1-aminoethyl group, 2-aminoethyl group, 2-aminoisobutyl group, 1,2-diaminoethyl group, 1,3-diaminoisopropyl group, 2,3-diamino-t-butyl group, 1,2,3-triaminopropyl group, cyanomethyl group, 1-cyanoethyl group, 2-cyanoethyl group, 2-cyanoisobutyl group, 1,2-dicyanoethyl group, 1,3-dicyanoisopropyl group, 2,3-dicyano-t-butyl group, 1,2,3-tricyanopropyl group, nitromethyl group, 1-nitroethyl group, 2-nitroethyl group, 1,2-dinitroethyl group, 2,3-dinitro-t-butyl group and 1,2,3-trinitropropyl group.

Examples of the cyclic alkyl group (i.e., cycloalkyl group) include a cyclopropyl group, cyclobutyl group, cyclopentyl group, cyclohexyl group, 4-methylcyclohexyl group, 1-adamantyl group, 2-adamantyl group, 1-norbornyl group and 2-norbornyl group.

The number of the carbon atoms of the linear or branched alkyl group for R₁ in the formula (1) is preferably 1 to 10, more preferably 1 to 6. Among the above examples of the linear or branched alkyl group, a methyl group, ethyl group, propyl group, isopropyl group, n-butyl group, s-butyl group, isobutyl group, t-butyl group, n-pentyl group and n-hexyl group are preferable.

The number of the ring carbon atoms of the cycloalkyl group for R₁ in the formula (1) is preferably 3 to 10, more preferably 5 to 8. Among the above examples of the cycloalkyl group, a cyclopentyl group and a cyclohexyl group are preferable.

An example of a halogenated alkyl group obtained by substituting an alkyl group with a halogen atom is one obtained by substituting the above alkyl group having 1 to 30 carbon atoms with one or more halogen group(s). Specific examples of the halogenated alkyl group are a fluoromethyl group, difluoromethyl group, trifluoromethyl group, fluoroethyl group and trifluoromethylmethyl group.

The alkenyl group having 2 to 30 carbon atoms for R₁ in the formula (1) may be linear, branched or cyclic and examples thereof are vinyl, propenyl, butenyl, oleyl, eicosapentaenyl, docosahexaenyl, styryl, 2,2-diphenylvinyl, 1,2,2-triphenylvinyl and 2-phenyl-2-propenyl. Among the above alkenyl groups, a vinyl group is preferable.

The alkynyl group having 2 to 30 carbon atoms for R₁ in the formula (1) may be linear, branched or cyclic and examples thereof are ethynyl, propynyl and 2-phenylethynyl. Among the above alkenyl groups, an ethynyl group is preferable.

Examples of the alkylsilyl group having 3 to 30 carbon atoms for R₁ in the formula (1) are a trialkylsilyl group having an exemplary alkyl group listed for the above alkyl group having 1 to 30 carbon atoms. Specific examples of the alkylsilyl group are a trimethylsilyl group, triethylsilyl group, tri-n-butylsilyl group, tri-n-octylsilyl group, triisobutylsilyl group, dimethylethylsilyl group, dimethylisopropylsilyl group, dimethyl-n-propylsilyl group, dimethyl-n-butylsilyl group, dimethyl-t-butylsilyl group, diethylisopropylsilyl group, vinyldimethylsilyl group, propyldimethylsilyl group and triisopropylsilyl group. The three alkyl groups may be mutually the same or different.

Examples of the arylsilyl group having 6 to 30 ring carbon atoms for R₁ in the formula (1) are a dialkylarylsilyl group, alkyldiarylsilyl group and triarylsilyl group.

An example of the dialkylarylsilyl group is a dialkylarylsilyl group having two of the exemplary alkyl groups listed for the above alkyl group having 1 to 30 carbon atoms and one of the above aryl groups having 6 to 30 ring carbon atoms. The number of the carbon atoms of the dialkylarylsilyl group is preferably 8 to 30. The two alkyl groups may be mutually the same or different.

An example of the alkyldiarylsilyl group is an alkyldiarylsilyl group having one of the exemplary alkyl groups listed for the above alkyl group having 1 to 30 carbon atoms and two of the above aryl groups having 6 to 30 ring carbon atoms. The number of the carbon atoms of the alkyldiarylsilyl group is preferably 13 to 30. The two aryl groups may be mutually the same or different.

An example of the triarylsilyl group is a triarylsilyl group having three of the above aryl groups having 6 to 30 ring carbon atoms. The number of the carbon atoms of the triarylsilyl group is preferably 18 to 30. The three aryl groups may be mutually the same or different.

The alkoxy group having 1 to 30 carbon atoms for R₁ in the formula (1) is represented by —OY. An example of Y is the above alkyl group having 1 to 30 carbon atoms. Examples of the alkoxy group are a methoxy group, ethoxy group, propoxy group, butoxy group, pentyloxy group and hexyloxy group.

An example of a halogenated alkoxy group obtained by substituting an alkoxy group with a halogen atom is one obtained by substituting the above alkoxy group having 1 to 30 carbon atoms with one or more halogen group(s).

The aralkyl group having 6 to 30 ring carbon atoms for R₁ in the formula (1) is represented by —Y—Z. An example of Y is an alkylene group related to the above alkyl group having 1 to 30 carbon atoms. Examples of Z are the same as those of the above aryl group having 6 to 30 ring carbon atoms. The aralkyl group is preferably an aralkyl group having 7 to 30 carbon atoms, in which an aryl part has 6 to 30 carbon atoms, preferably 6 to 20 carbon atoms, more preferably 6 to 12 carbon atoms, while an alkyl part has 1 to 30 carbon atoms, preferably 1 to 20 carbon atoms, more preferably 1 to 10 carbon atoms, further more preferably 1 to 6 carbon atoms. Examples of the aralkyl group are a benzyl group, 2-phenylpropane-2-yl group, 1-phenylethyl group, 2-phenylethyl group, 1-phenylisopropyl group, 2-phenylisopropyl group, phenyl-t-butyl group, alpha-naphthylmethyl group, 1-alpha-naphthylethyl group, 2-alpha-naphthylethyl group, 1-alpha-naphthylisopropyl group, 2-alpha-naphthylisopropyl group, beta-naphthylmethyl group, 1-beta-naphthylethyl group, 2-beta-naphthylethyl group, 1-beta-naphthylisopropyl group, 2-beta-naphthylisopropyl group, 1-pyrrorylmethyl group, 2-(1-pyrroryl)ethyl group, p-methylbenzyl group, m-methylbenzyl group, o-methylbenzyl group, p-chlorobenzyl group, m-chlorobenzyl group, o-chlorobenzyl group, p-bromobenzyl group, m-bromobenzyl group, o-bromobenzyl group, p-iodobenzyl group, m-iodobenzyl group, o-iodobenzyl group, p-hydroxybenzyl group, m-hydroxybenzyl group, o-hydroxybenzyl group, p-aminobenzyl group, m-aminobenzyl group, o-aminobenzyl group, p-nitrobenzyl group, m-nitrobenzyl group, o-nitrobenzyl group, p-cyanobenzyl group, m-cyanobenzyl group, o-cyanobenzyl group, 1-hydroxy-2-phenylisopropyl group and 1-chloro-2-phenylisopropyl group.

The aryloxy group having 6 to 30 ring carbon atoms for R₁ in the formula (1) is represented by —OZ. Examples of Z are the above aryl group having 6 to 30 ring carbon atoms and later-described monocyclic group and fused ring group. An example of the aryloxy group is a phenoxy group.

Examples of the halogen atom for R₁ in the formula (1) are fluorine, chlorine, bromine and iodine, among which a fluorine atom is preferable.

According to the invention, “ring carbon atoms (carbon atoms forming a ring)” means carbon atoms forming a saturated ring, unsaturated ring or aromatic ring. “Ring atoms (atoms forming a ring)” means carbon atoms and hetero atoms forming a hetero ring including a saturated ring, unsaturated ring and aromatic ring.

When the expression “substituted or unsubstituted” is used, examples of the intended substituent include an aryl group, heterocyclic group, alkyl group (e.g., a linear or branched alkyl group, cycloalkyl group and halogenated alkyl group), alkenyl group, alkynyl group, alkylsilyl group, arylsilyl group, alkoxy group, halogenated alkoxy group, aralkyl group, aryloxy group, halogen atom, deuterium atom and cyano group as described above and further include a hydroxy group, nitro group and carboxy group. Among the above examples of the substituent, an aryl group, heterocyclic group, alkyl group, halogen atom, alkylsilyl group, arylsilyl group, cyano group and deuterium atom are preferable and specific preferable examples of these exemplary substituents are further preferable. These substituents may be further substituted with any of the substituents.

Similarly, when the expression “substituted or unsubstituted” is used in relation to later-described compounds and moieties thereof, the intended substituent is the same as described above.

According to the invention, a hydrogen atom includes isotopes with different neutron numbers (i.e., protium, deuterium and tritium).

In the formula (1), p is an integer of from 0 to 4.

L₁ in the formula (1) is a single bond or a linking group, the linking group being a substituted or unsubstituted aryl group having 6 to 30 ring carbon atoms, a substituted or unsubstituted heterocyclic group having 5 to 30 ring atoms, a cyclic hydrocarbon group having 5 to 30 ring carbon atoms, or a group provided by bonding the aryl group, the heterocyclic group and/or the cyclic hydrocarbon group.

When L₁ is a linking group, an example of the aryl group having 6 to 30 ring carbon atoms is a divalent group derived from the aryl group having 6 to 30 ring carbon atoms for R₁ in the formula (1).

When L₁ is a linking group, an example of the heterocyclic group having 5 to 30 ring atoms is a divalent group derived from the heterocyclic group having 5 to 30 ring atoms for R₁ in the formula (1).

When L₁ is a linking group, an example of the cyclic hydrocarbon group having 5 to 30 ring atoms is a divalent group derived from the cyclic alkyl group (i.e., cycloalkyl group) for R₁ in the formula (1), examples of which are a cyclopentylene group, cyclohexylene group and cycloheptylene group.

When L₁ is a linking group, examples of L₁ also include groups formed by mutually bonding the above exemplary linking groups (i.e., the aryl group, the heterocyclic group and the cyclic hydrocarbon group) and the bonded linking groups may be mutually the same or different.

Az₁ in the formula (1) is a group represented by the following formula (2).

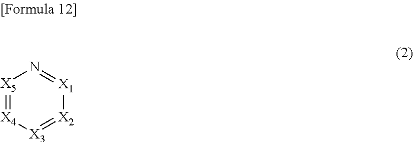

In the formula (2), any one of X₁ to X₅ is a carbon atom bonded to L₁.

In the formula (2), the other four of X₁ to X₅ that are not bonded to L₁ are each independently CR₁ or a nitrogen atom when p is 0.

When p is 1 to 4, p of X₁ to X₅ are each a carbon atom bonded to Ar₁ and (4-p) of X₁ to X₅ are each independently CR₁ or a nitrogen atom. R₁ represents the same as R₁ in the formula (1).

CR₁ is a carbon atom (C) bonded with R₁.

Ar₁ in the formula (1) is a substituted or unsubstituted aryl group having 6 to 30 ring carbon atoms, a substituted or unsubstituted heterocyclic group having 5 to 30 ring carbon atoms, or a group provided by bonding the aryl group and the heterocyclic group.

The aryl group having 6 to 30 ring carbon atoms and the heterocyclic group having 5 to 30 ring atoms for Ar₁ are the same as described above for R₁ in the formula (1).

Examples of Ar₁ also include groups formed by bonding the aryl group and the heterocyclic group mentioned here and the bonded groups may be the same or different.

The compound represented by the formula (1) as the first host material is preferably a compound represented by the following formula (9).

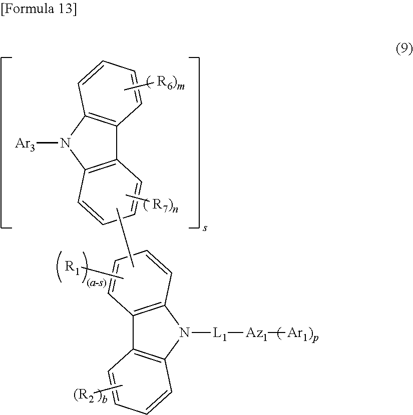

In the formula (9), s is an integer of from 1 to 4.

In the formula (9), R₆ and R₇ each represent the same as R₁ in the formula (1).

In the formula (9), m is 4 and plural R₆ are mutually the same or different.

In the formula (9), n is 3 and plural R₇ are mutually the same or different.

In the formula (9), Ar₃ represents the same as Ar₁ in the formula (1).

The compound represented by the formula (1) as the first host material is preferably a compound represented by the following formula (10).

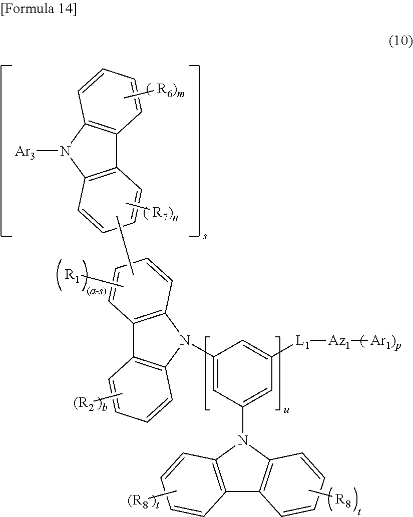

In the formula (10), R₆ and R₇ each represent the same as R₁ in the formula (1).

In the formula (10), m is 4 and plural R₆ are mutually the same or different.

In the formula (10), n is 3 and plural R₇ are mutually the same or different.

In the formula (10), Ar₃ represents the same as Ar₁ in the formula (1).

In the formula (10), s is 0 or 1, u is 0 or 1 and s and u satisfy a relation of s+u=1.

In the formula (10), R₈ represents the same as R₁ in the formula (1).

In the formula (10), t is 4 and plural R₈ are mutually the same or different.

Examples of the compounds represented by the formulae (1), (9) and (10) are compounds represented by the following formulae. It should be noted that these exemplary compound structures are not intended to limit the scope of the invention.

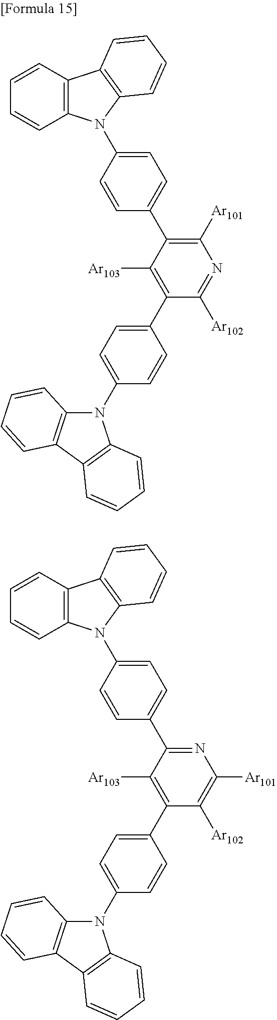

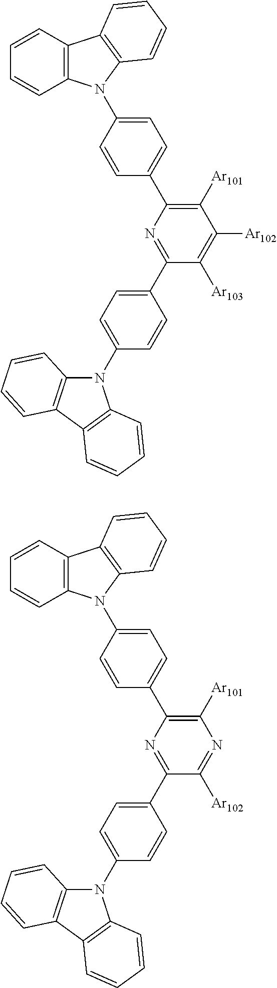

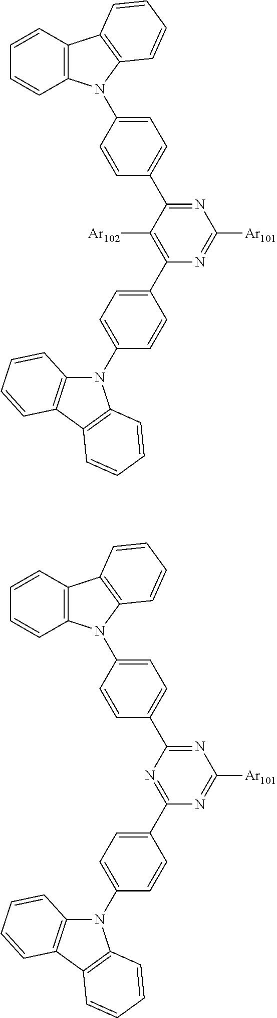

In the above formulae, Ar₁₀₁ to Ar₁₀₃ each represent the same as R₁ in the formula (1).

Further, specific examples of the compounds represented by the formulae (1), (9) and (10) are compounds shown below. It should be noted that these exemplary compound structures are not intended to limit the scope of the invention.

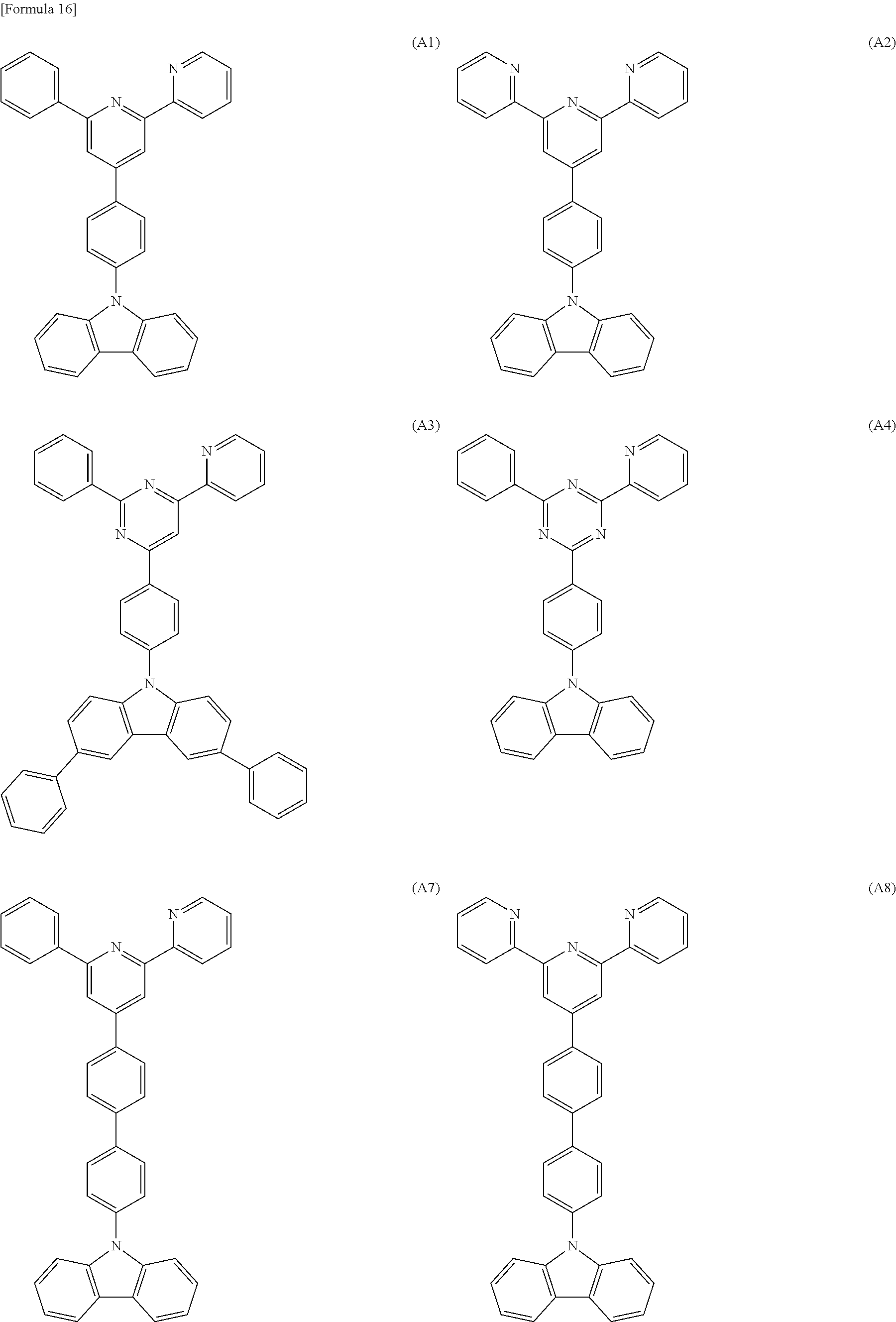 [SMILES: c1ccc(-c2cc(-c3ccc(-n4c5ccccc5c5ccccc54)cc3)cc(-c3ccccn3)n2)cc1 ; c1ccc(-c2cc(-c3ccc(-n4c5ccccc5c5ccccc54)cc3)cc(-c3ccccn3)n2)nc1 ; c1ccc(-c2ccc3c(c2)c2cc(-c4ccccc4)ccc2n3-c2ccc(-c3cc(-c4ccccn4)nc(-c4ccccc4)n3)cc2)cc1 ; c1ccc(-c2nc(-c3ccc(-n4c5ccccc5c5ccccc54)cc3)nc(-c3ccccn3)n2)cc1 ; c1ccc(-c2cc(-c3ccc(-c4ccc(-n5c6ccccc6c6ccccc65)cc4)cc3)cc(-c3ccccn3)n2)cc1 ; c1ccc(-c2cc(-c3ccc(-c4ccc(-n5c6ccccc6c6ccccc65)cc4)cc3)cc(-c3ccccn3)n2)nc1]

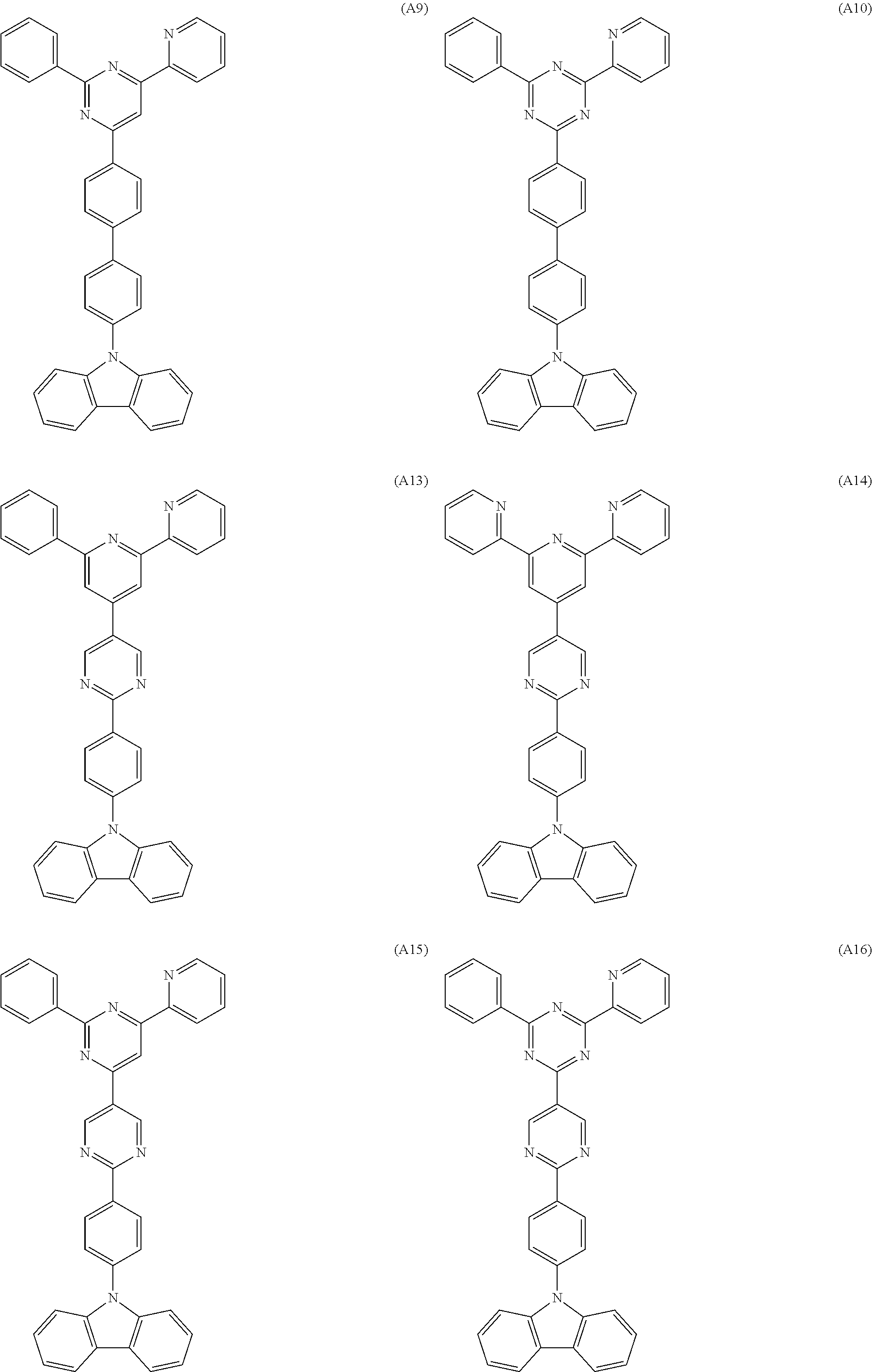 [SMILES: c1ccc(-c2nc(-c3ccc(-c4ccc(-n5c6ccccc6c6ccccc65)cc4)cc3)cc(-c3ccccn3)n2)cc1 ; c1ccc(-c2nc(-c3ccc(-c4ccc(-n5c6ccccc6c6ccccc65)cc4)cc3)nc(-c3ccccn3)n2)cc1 ; c1ccc(-c2cc(-c3cnc(-c4ccc(-n5c6ccccc6c6ccccc65)cc4)nc3)cc(-c3ccccn3)n2)cc1 ; c1ccc(-c2cc(-c3cnc(-c4ccc(-n5c6ccccc6c6ccccc65)cc4)nc3)cc(-c3ccccn3)n2)nc1 ; c1ccc(-c2nc(-c3cnc(-c4ccc(-n5c6ccccc6c6ccccc65)cc4)nc3)cc(-c3ccccn3)n2)cc1 ; c1ccc(-c2nc(-c3cnc(-c4ccc(-n5c6ccccc6c6ccccc65)cc4)nc3)nc(-c3ccccn3)n2)cc1]

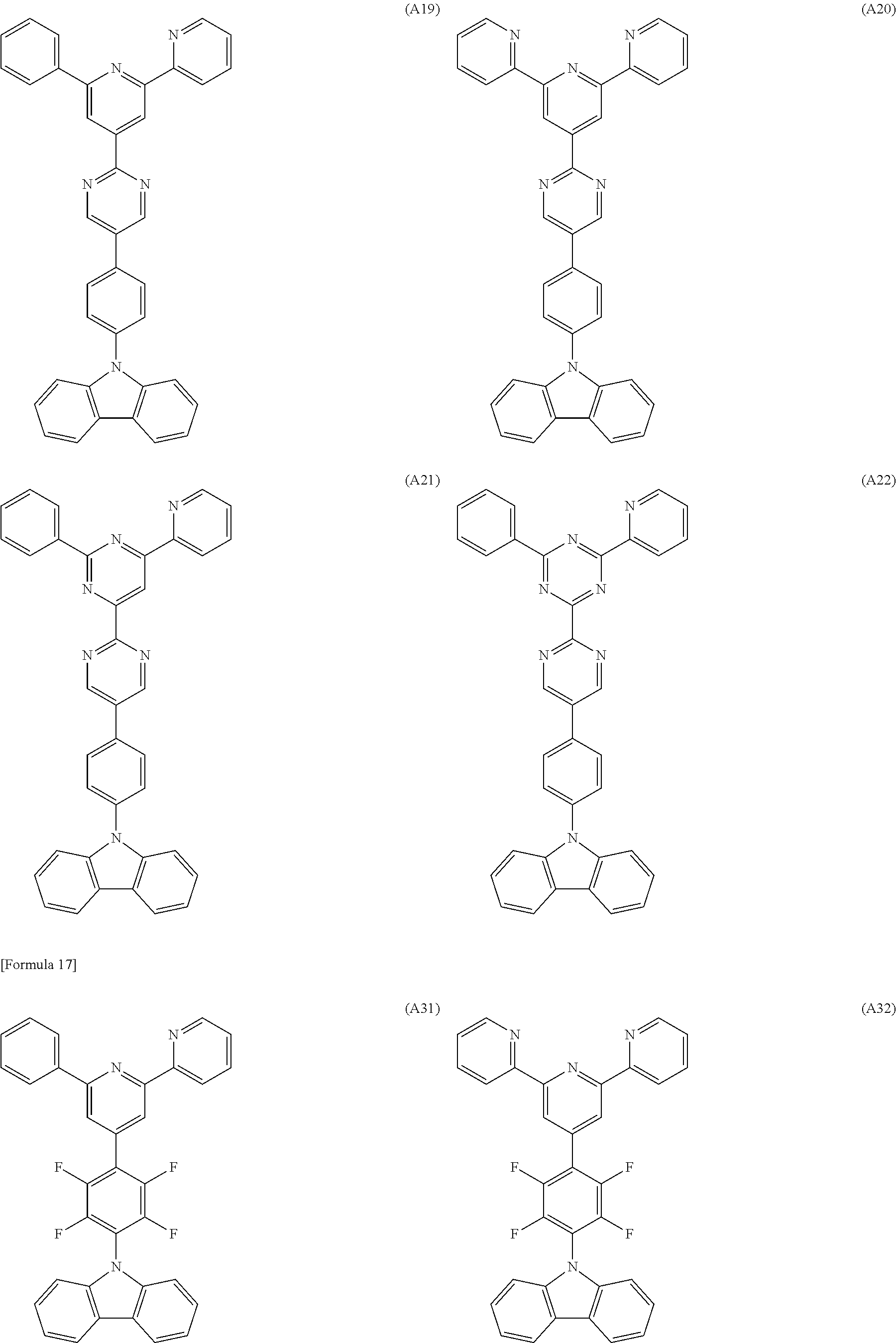 [SMILES: c1ccc(-c2cc(-c3ncc(-c4ccc(-n5c6ccccc6c6ccccc65)cc4)cn3)cc(-c3ccccn3)n2)cc1 ; c1ccc(-c2cc(-c3ncc(-c4ccc(-n5c6ccccc6c6ccccc65)cc4)cn3)cc(-c3ccccn3)n2)nc1 ; c1ccc(-c2nc(-c3ccccn3)cc(-c3ncc(-c4ccc(-n5c6ccccc6c6ccccc65)cc4)cn3)n2)cc1 ; c1ccc(-c2nc(-c3ccccn3)nc(-c3ncc(-c4ccc(-n5c6ccccc6c6ccccc65)cc4)cn3)n2)cc1 ; Fc1c(F)c(-n2c3ccccc3c3ccccc32)c(F)c(F)c1-c1cc(-c2ccccc2)nc(-c2ccccn2)c1 ; Fc1c(F)c(-n2c3ccccc3c3ccccc32)c(F)c(F)c1-c1cc(-c2ccccn2)nc(-c2ccccn2)c1]

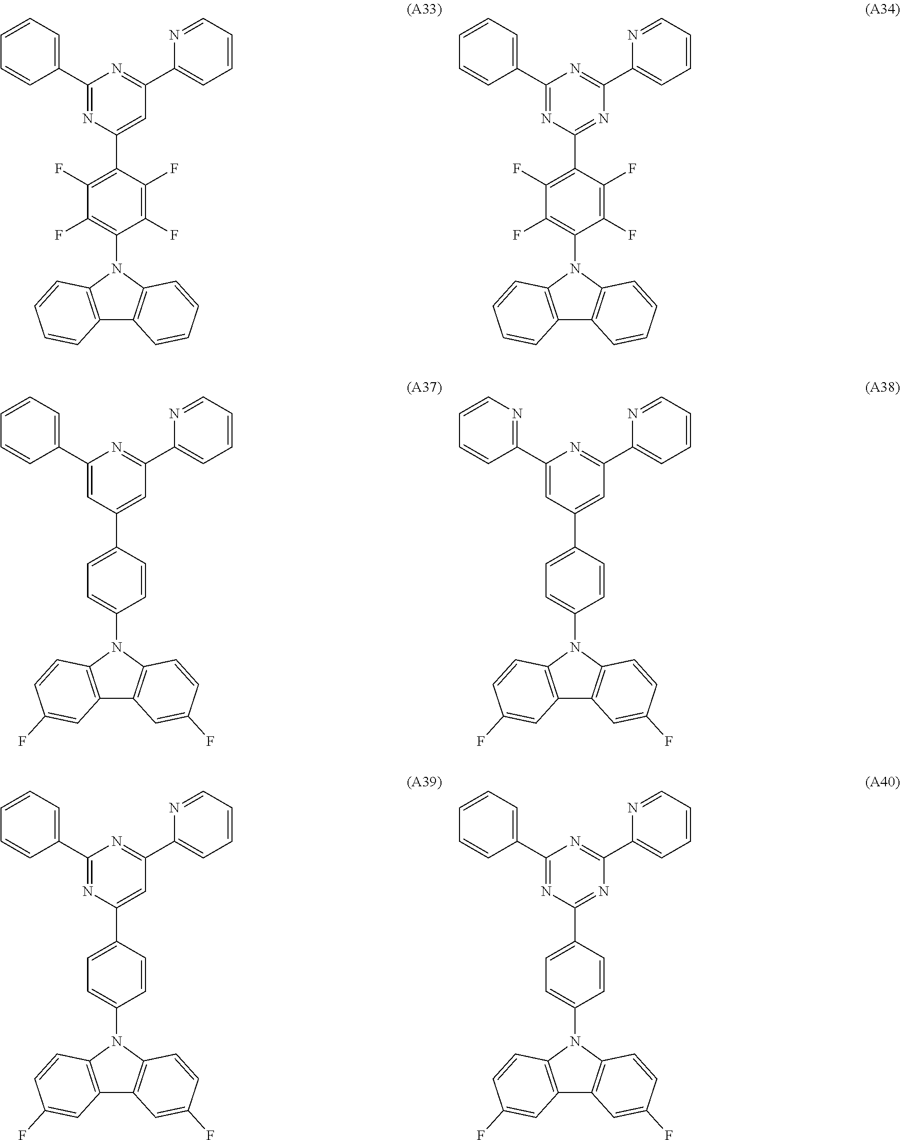 [SMILES: Fc1c(F)c(-n2c3ccccc3c3ccccc32)c(F)c(F)c1-c1cc(-c2ccccn2)nc(-c2ccccc2)n1 ; Fc1c(F)c(-n2c3ccccc3c3ccccc32)c(F)c(F)c1-c1nc(-c2ccccc2)nc(-c2ccccn2)n1 ; Fc1ccc2c(c1)c1cc(F)ccc1n2-c1ccc(-c2cc(-c3ccccc3)nc(-c3ccccn3)c2)cc1 ; Fc1ccc2c(c1)c1cc(F)ccc1n2-c1ccc(-c2cc(-c3ccccn3)nc(-c3ccccn3)c2)cc1 ; Fc1ccc2c(c1)c1cc(F)ccc1n2-c1ccc(-c2cc(-c3ccccn3)nc(-c3ccccc3)n2)cc1 ; Fc1ccc2c(c1)c1cc(F)ccc1n2-c1ccc(-c2nc(-c3ccccc3)nc(-c3ccccn3)n2)cc1]

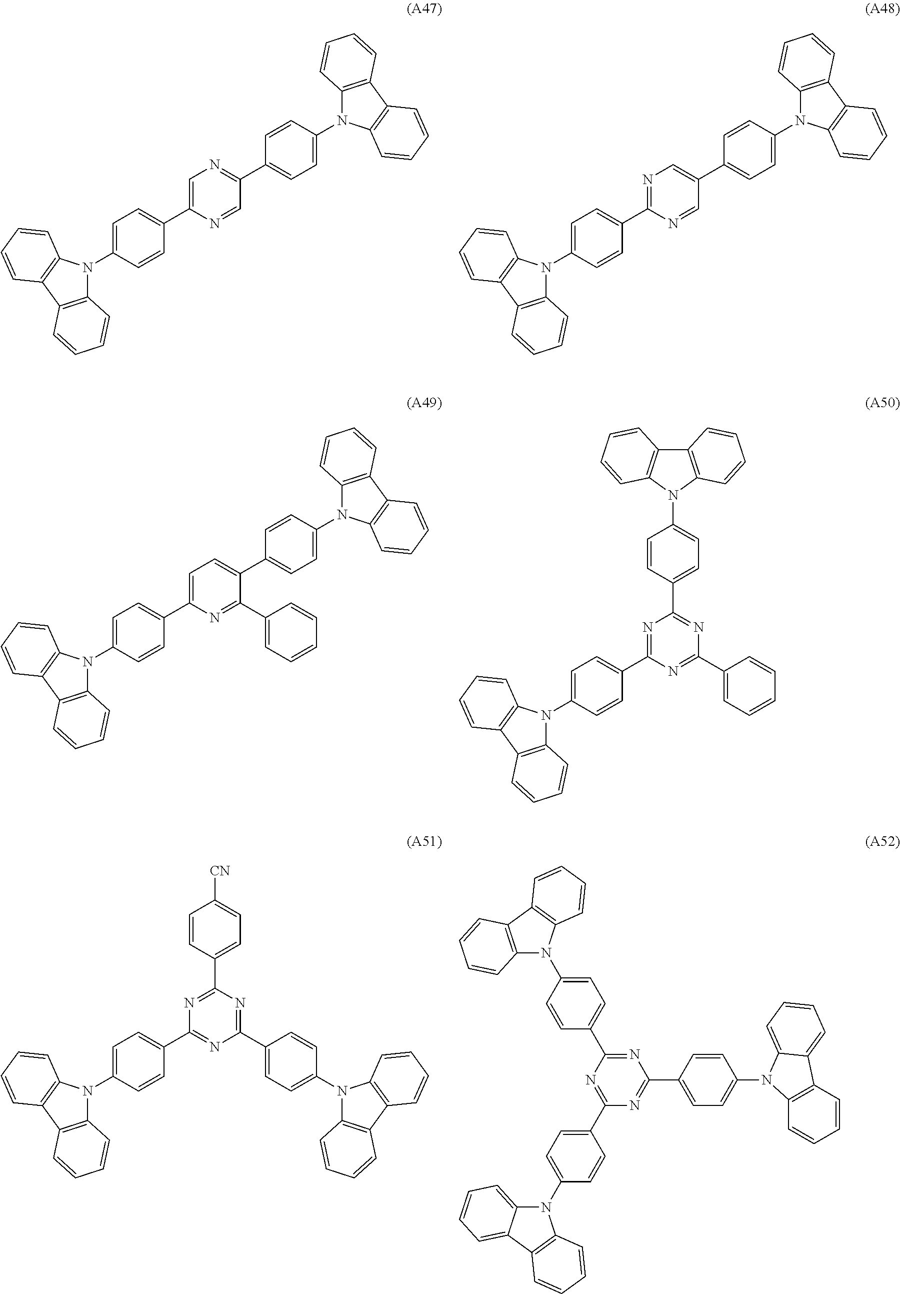

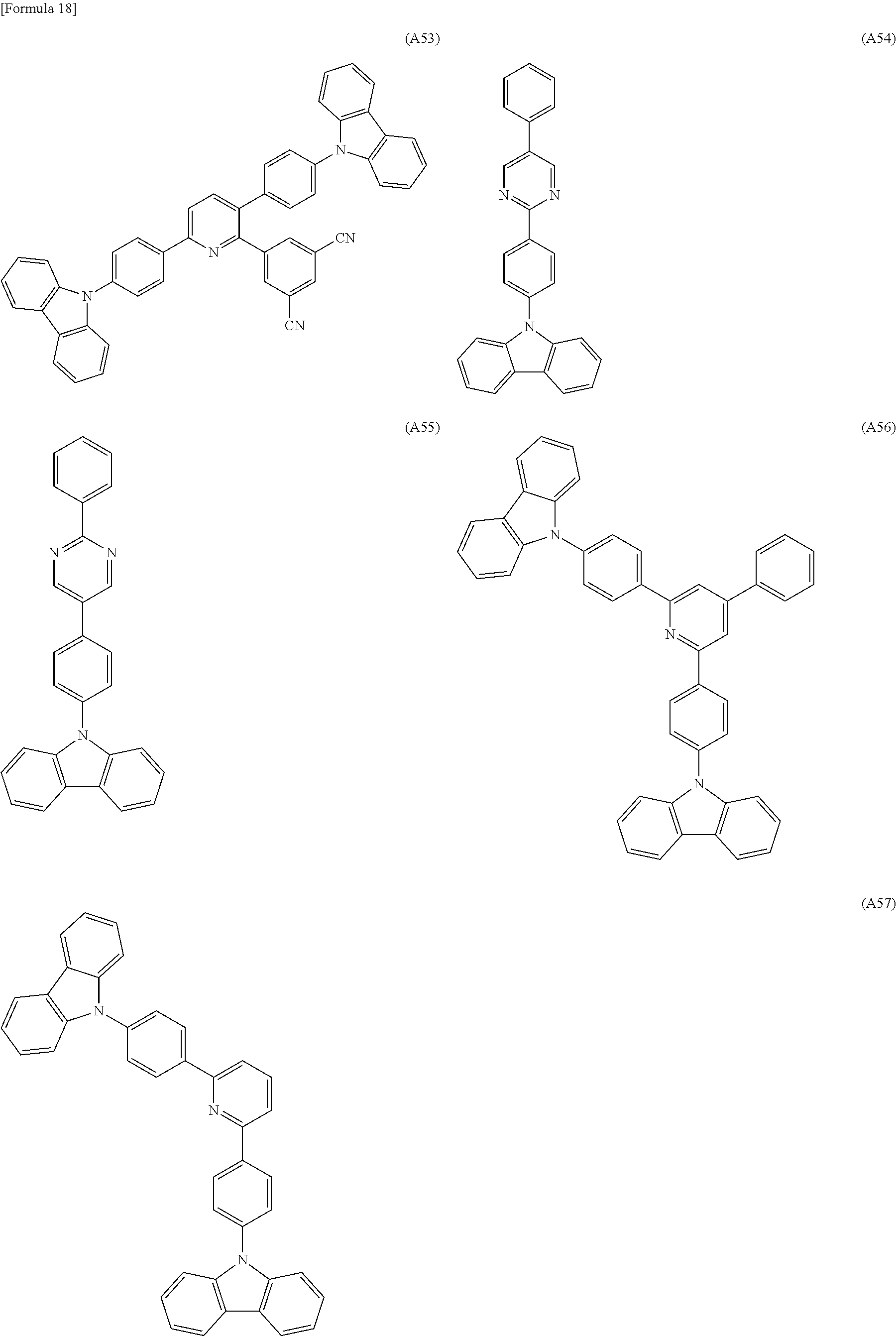 [SMILES: N#Cc1cc(C#N)cc(-c2nc(-c3ccc(-n4c5ccccc5c5ccccc54)cc3)ccc2-c2ccc(-n3c4ccccc4c4ccccc43)cc2)c1 ; c1ccc(-c2cnc(-c3ccc(-n4c5ccccc5c5ccccc54)cc3)nc2)cc1 ; c1ccc(-c2ncc(-c3ccc(-n4c5ccccc5c5ccccc54)cc3)cn2)cc1 ; c1ccc(-c2cc(-c3ccc(-n4c5ccccc5c5ccccc54)cc3)nc(-c3ccc(-n4c5ccccc5c5ccccc54)cc3)c2)cc1 ; c1cc(-c2ccc(-n3c4ccccc4c4ccccc43)cc2)nc(-c2ccc(-n3c4ccccc4c4ccccc43)cc2)c1]

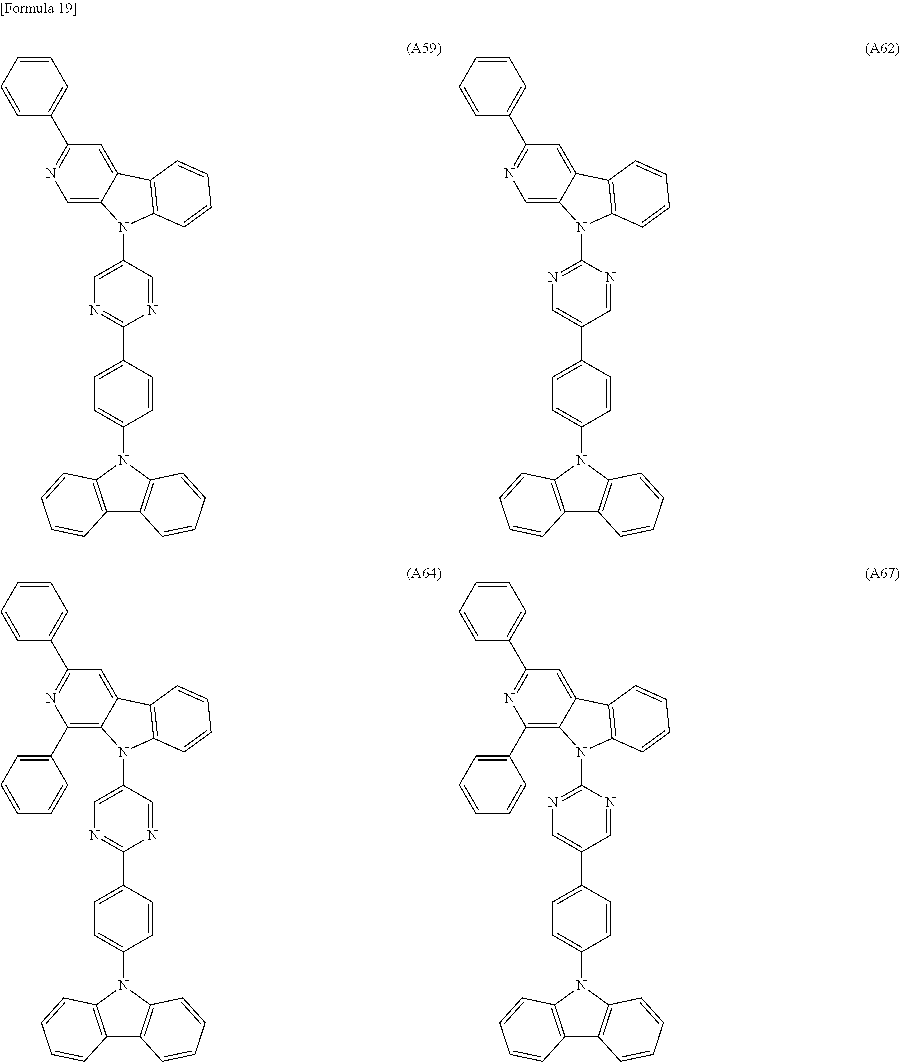 [SMILES: c1ccc(-c2cc3c4ccccc4n(-c4cnc(-c5ccc(-n6c7ccccc7c7ccccc76)cc5)nc4)c3cn2)cc1 ; c1ccc(-c2cc3c4ccccc4n(-c4ncc(-c5ccc(-n6c7ccccc7c7ccccc76)cc5)cn4)c3cn2)cc1 ; c1ccc(-c2cc3c4ccccc4n(-c4cnc(-c5ccc(-n6c7ccccc7c7ccccc76)cc5)nc4)c3c(-c3ccccc3)n2)cc1 ; c1ccc(-c2cc3c4ccccc4n(-c4ncc(-c5ccc(-n6c7ccccc7c7ccccc76)cc5)cn4)c3c(-c3ccccc3)n2)cc1]

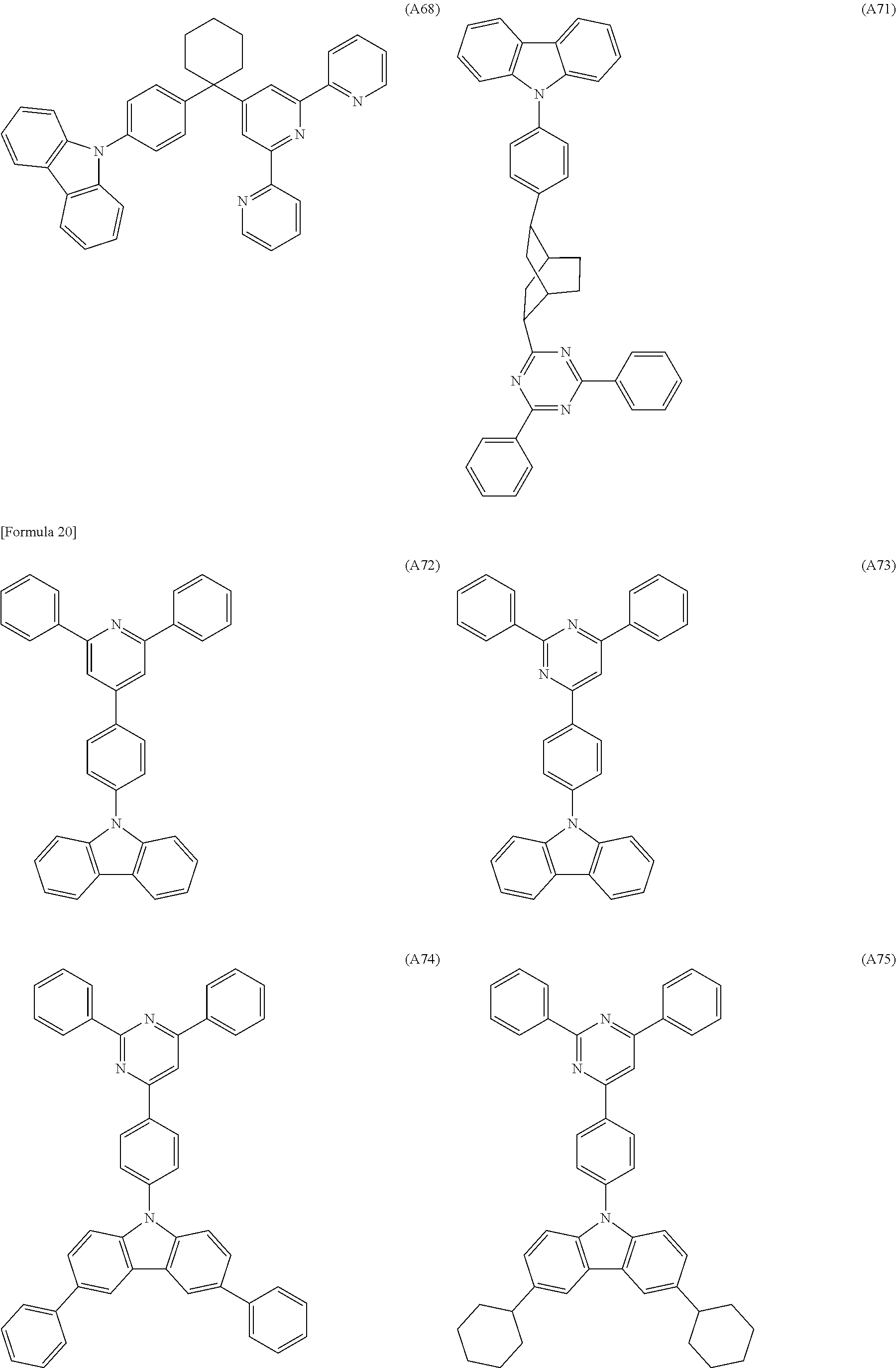 [SMILES: c1ccc(-c2cc(C3(c4ccc(-n5c6ccccc6c6ccccc65)cc4)CCCCC3)cc(-c3ccccn3)n2)nc1 ; c1ccc(-c2nc(-c3ccccc3)nc(C3CC4CCC3CC4c3ccc(-n4c5ccccc5c5ccccc54)cc3)n2)cc1 ; c1ccc(-c2cc(-c3ccc(-n4c5ccccc5c5ccccc54)cc3)cc(-c3ccccc3)n2)cc1 ; c1ccc(-c2cc(-c3ccc(-n4c5ccccc5c5ccccc54)cc3)nc(-c3ccccc3)n2)cc1 ; c1ccc(-c2ccc3c(c2)c2cc(-c4ccccc4)ccc2n3-c2ccc(-c3cc(-c4ccccc4)nc(-c4ccccc4)n3)cc2)cc1 ; c1ccc(-c2cc(-c3ccc(-n4c5ccc(C6CCCCC6)cc5c5cc(C6CCCCC6)ccc54)cc3)nc(-c3ccccc3)n2)cc1]

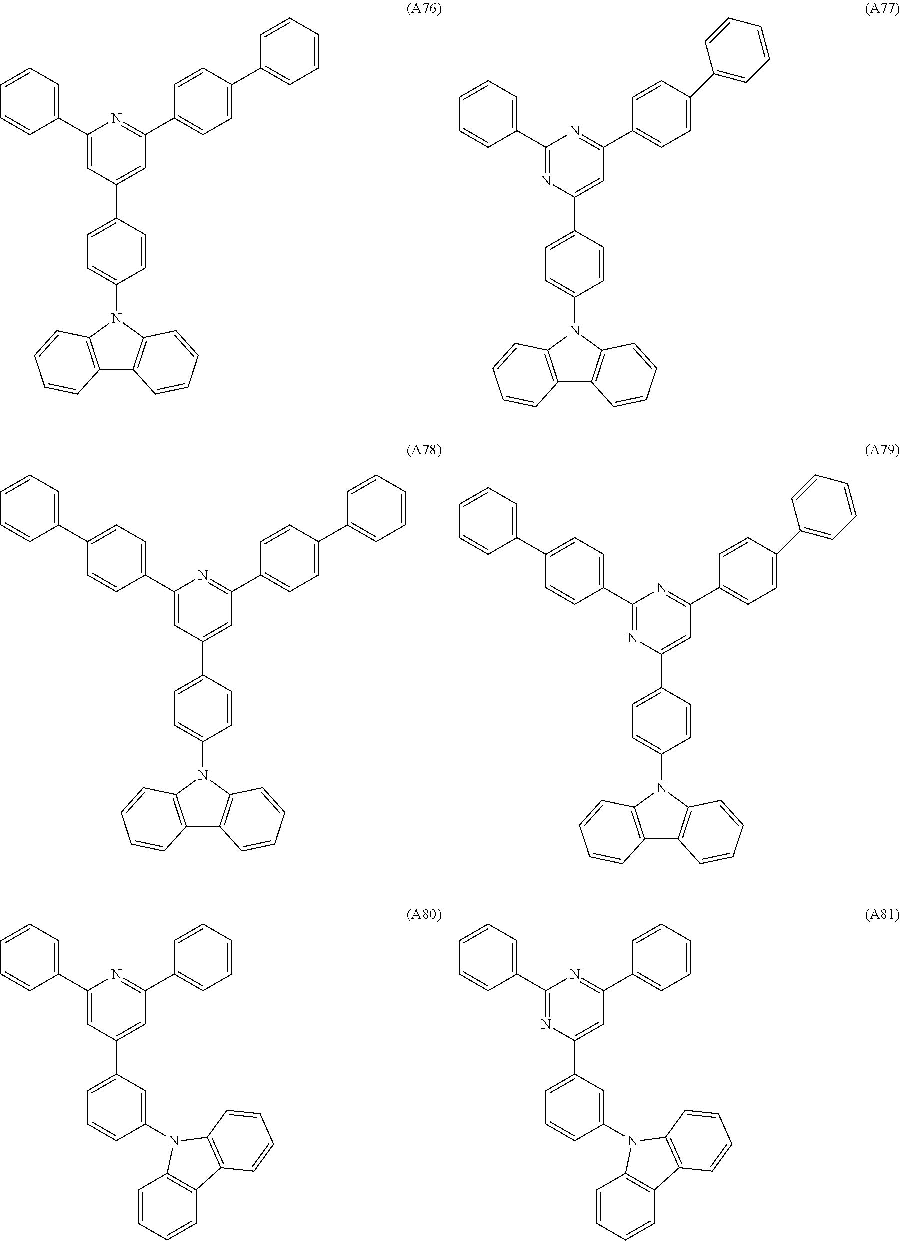 [SMILES: c1ccc(-c2ccc(-c3cc(-c4ccc(-n5c6ccccc6c6ccccc65)cc4)cc(-c4ccccc4)n3)cc2)cc1 ; c1ccc(-c2ccc(-c3cc(-c4ccc(-n5c6ccccc6c6ccccc65)cc4)nc(-c4ccccc4)n3)cc2)cc1 ; c1ccc(-c2ccc(-c3cc(-c4ccc(-n5c6ccccc6c6ccccc65)cc4)cc(-c4ccc(-c5ccccc5)cc4)n3)cc2)cc1 ; c1ccc(-c2ccc(-c3cc(-c4ccc(-n5c6ccccc6c6ccccc65)cc4)nc(-c4ccc(-c5ccccc5)cc4)n3)cc2)cc1 ; c1ccc(-c2cc(-c3cccc(-n4c5ccccc5c5ccccc54)c3)cc(-c3ccccc3)n2)cc1 ; c1ccc(-c2cc(-c3cccc(-n4c5ccccc5c5ccccc54)c3)nc(-c3ccccc3)n2)cc1]

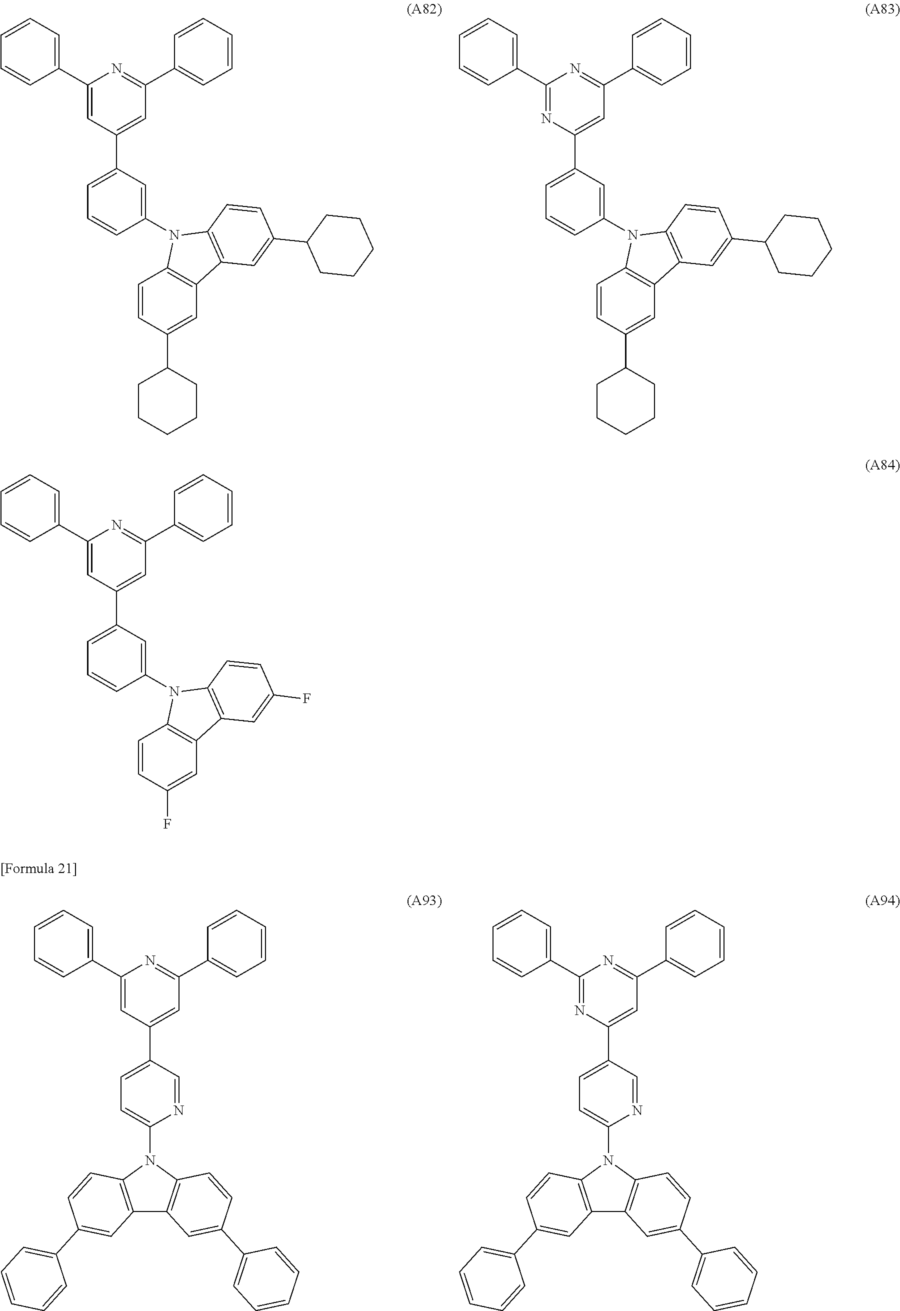 [SMILES: c1ccc(-c2cc(-c3cccc(-n4c5ccc(C6CCCCC6)cc5c5cc(C6CCCCC6)ccc54)c3)cc(-c3ccccc3)n2)cc1 ; c1ccc(-c2cc(-c3cccc(-n4c5ccc(C6CCCCC6)cc5c5cc(C6CCCCC6)ccc54)c3)nc(-c3ccccc3)n2)cc1 ; Fc1ccc2c(c1)c1cc(F)ccc1n2-c1cccc(-c2cc(-c3ccccc3)nc(-c3ccccc3)c2)c1 ; c1ccc(-c2ccc3c(c2)c2cc(-c4ccccc4)ccc2n3-c2ccc(-c3cc(-c4ccccc4)nc(-c4ccccc4)c3)cn2)cc1 ; c1ccc(-c2ccc3c(c2)c2cc(-c4ccccc4)ccc2n3-c2ccc(-c3cc(-c4ccccc4)nc(-c4ccccc4)n3)cn2)cc1]

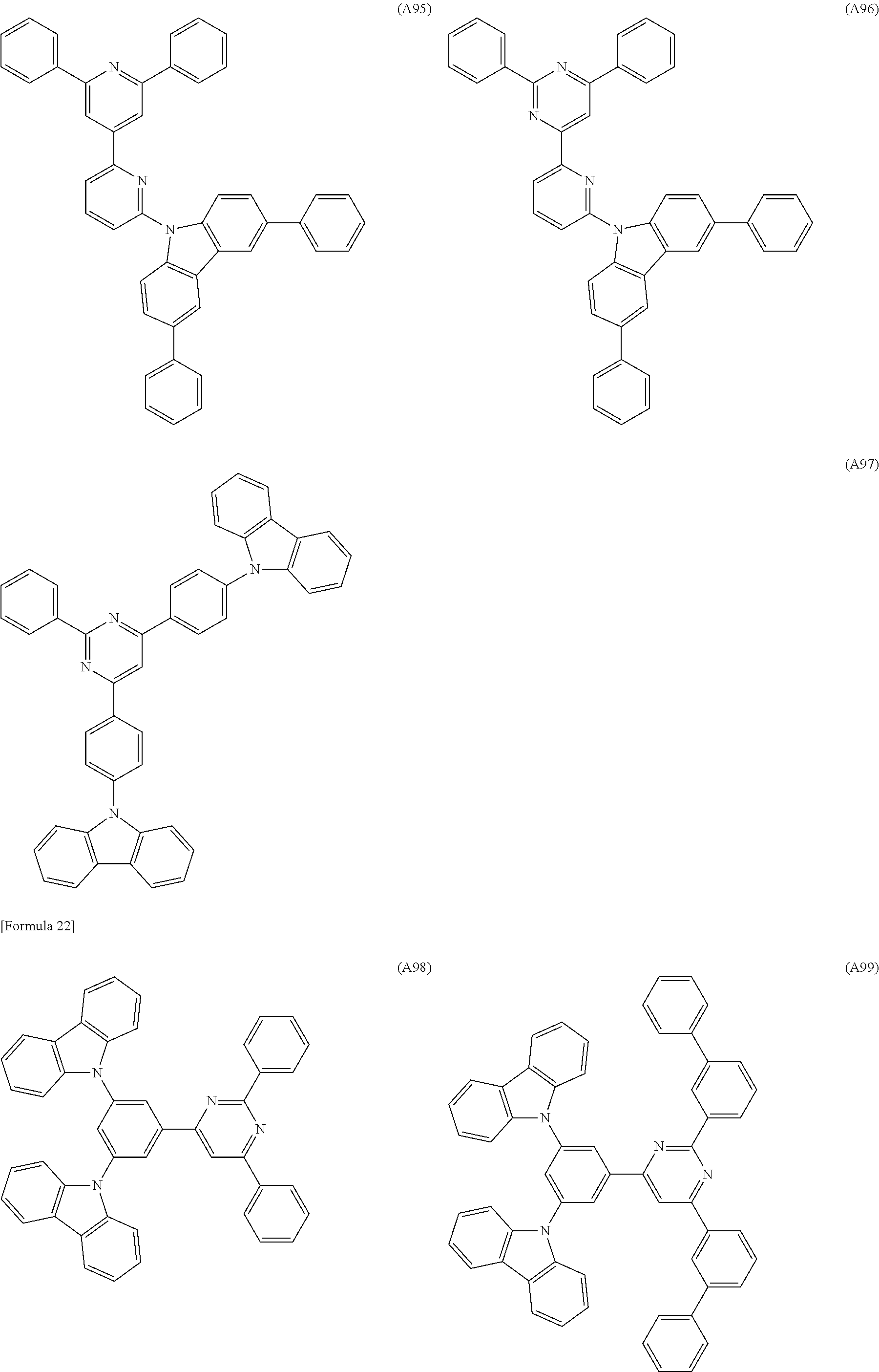 [SMILES: c1ccc(-c2ccc3c(c2)c2cc(-c4ccccc4)ccc2n3-c2cccc(-c3cc(-c4ccccc4)nc(-c4ccccc4)c3)n2)cc1 ; c1ccc(-c2ccc3c(c2)c2cc(-c4ccccc4)ccc2n3-c2cccc(-c3cc(-c4ccccc4)nc(-c4ccccc4)n3)n2)cc1 ; c1ccc(-c2nc(-c3ccc(-n4c5ccccc5c5ccccc54)cc3)cc(-c3ccc(-n4c5ccccc5c5ccccc54)cc3)n2)cc1 ; c1ccc(-c2cc(-c3cc(-n4c5ccccc5c5ccccc54)cc(-n4c5ccccc5c5ccccc54)c3)nc(-c3ccccc3)n2)cc1 ; c1ccc(-c2cccc(-c3cc(-c4cc(-n5c6ccccc6c6ccccc65)cc(-n5c6ccccc6c6ccccc65)c4)nc(-c4cccc(-c5ccccc5)c4)n3)c2)cc1]

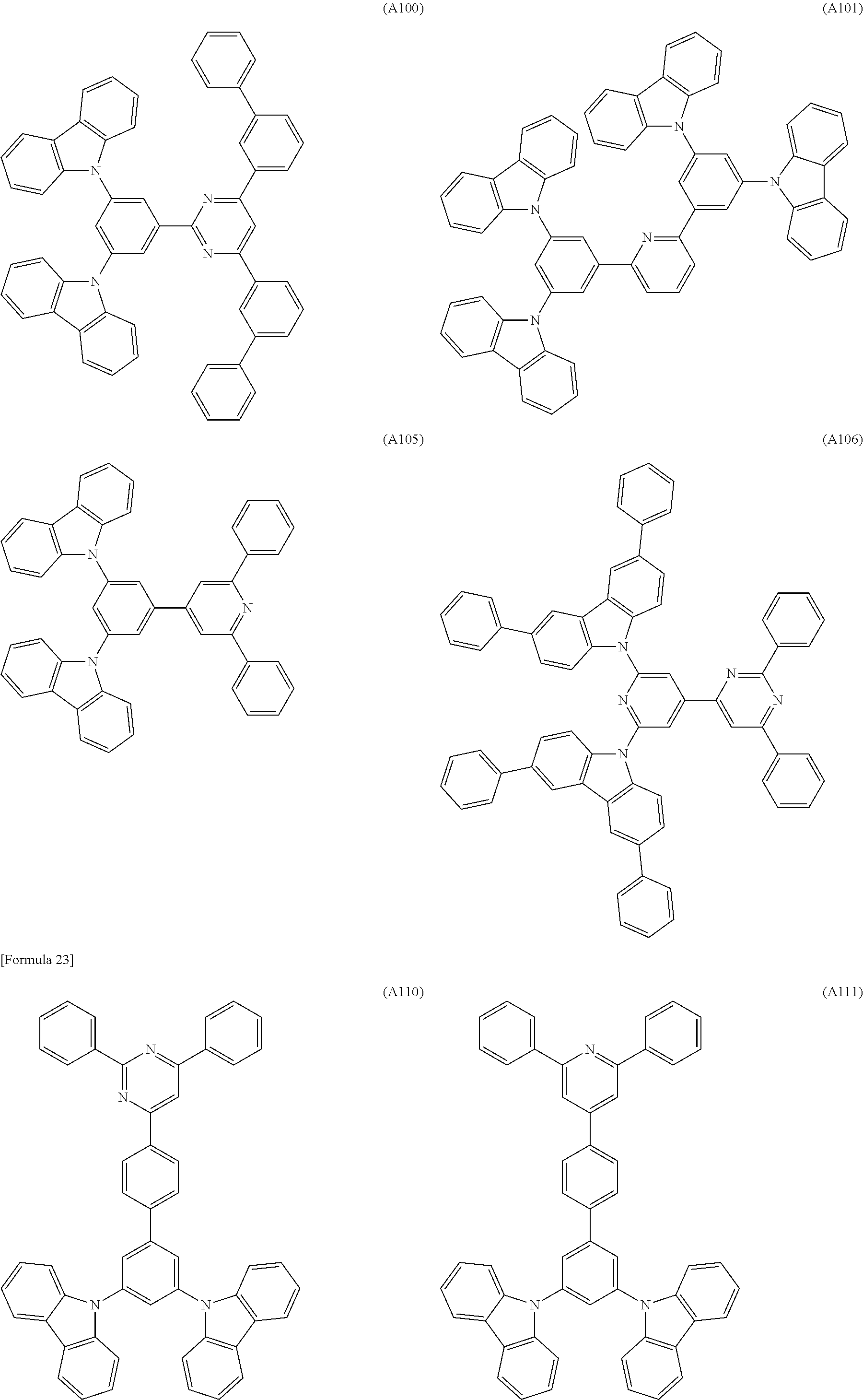

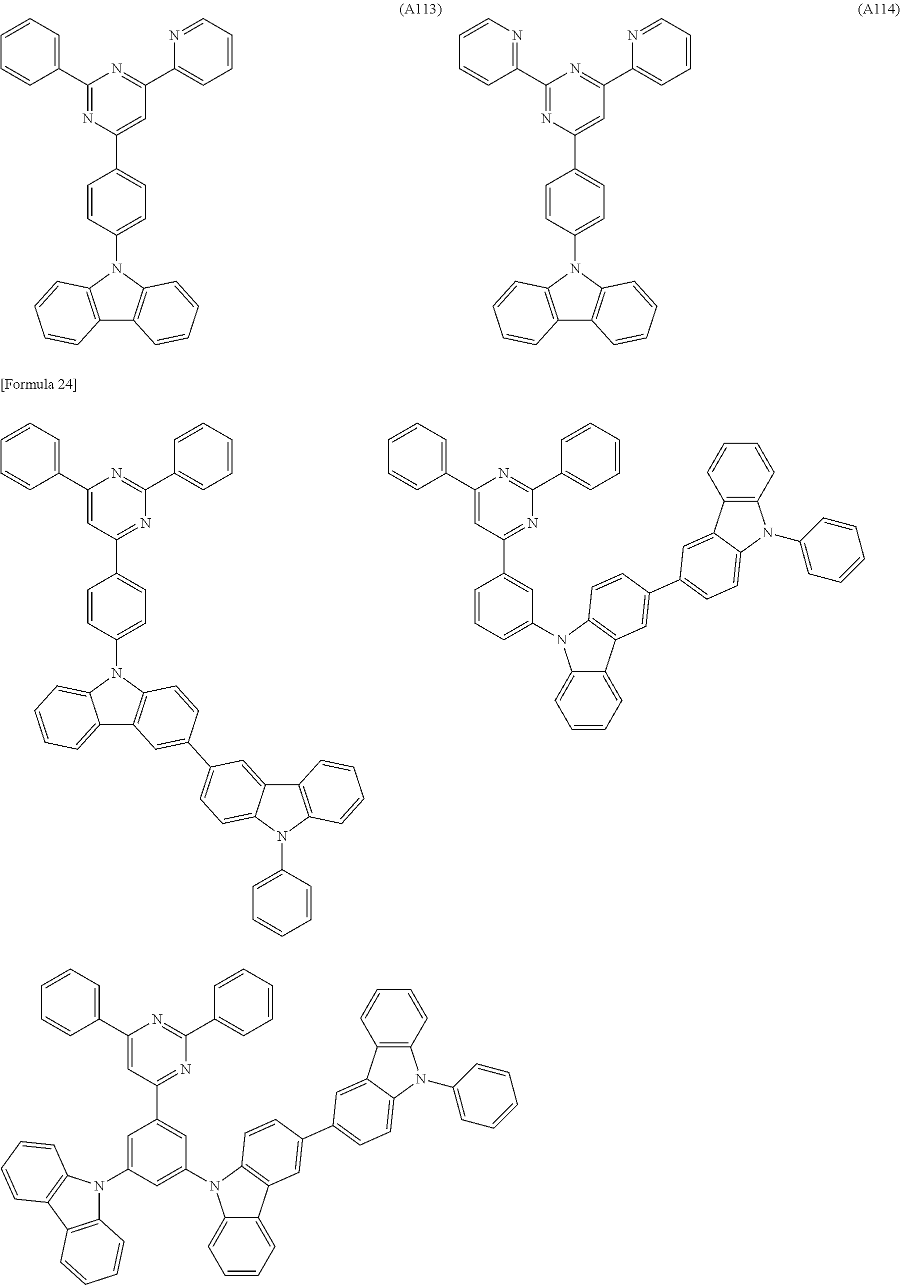 [SMILES: c1ccc(-c2nc(-c3ccc(-n4c5ccccc5c5ccccc54)cc3)cc(-c3ccccn3)n2)cc1 ; c1ccc(-c2cc(-c3ccc(-n4c5ccccc5c5ccccc54)cc3)nc(-c3ccccn3)n2)nc1 ; c1ccc(-c2cc(-c3ccc(-n4c5ccccc5c5cc(-c6ccc7c(c6)c6ccccc6n7-c6ccccc6)ccc54)cc3)nc(-c3ccccc3)n2)cc1 ; c1ccc(-c2cc(-c3cccc(-n4c5ccccc5c5cc(-c6ccc7c(c6)c6ccccc6n7-c6ccccc6)ccc54)c3)nc(-c3ccccc3)n2)cc1 ; c1ccc(-c2cc(-c3cc(-n4c5ccccc5c5ccccc54)cc(-n4c5ccccc5c5cc(-c6ccc7c(c6)c6ccccc6n7-c6ccccc6)ccc54)c3)nc(-c3ccccc3)n2)cc1]

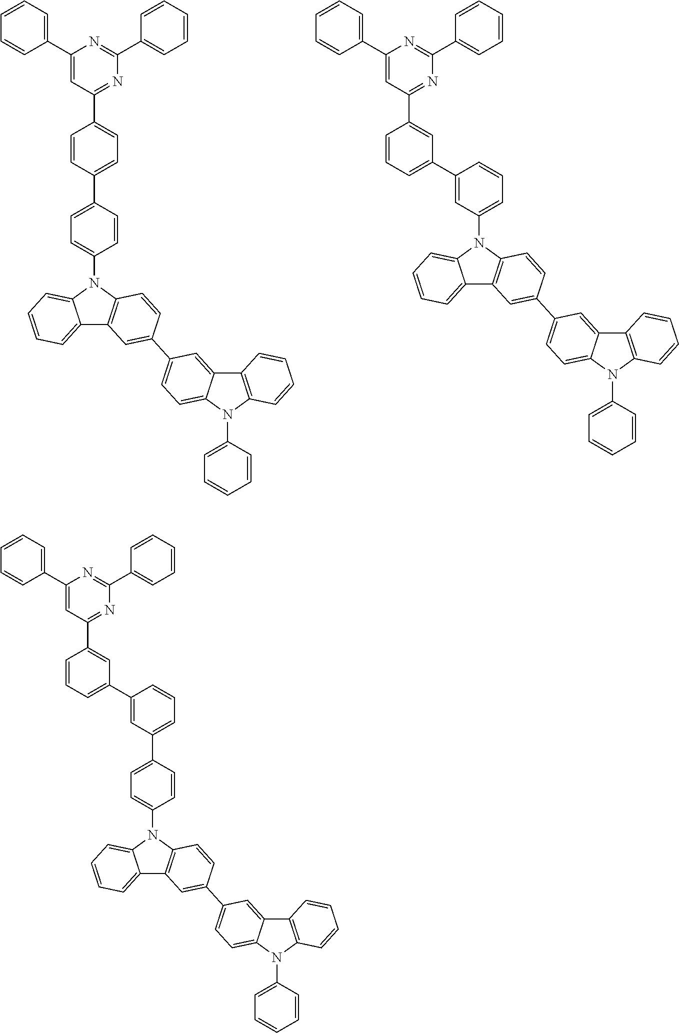 [SMILES: c1ccc(-c2cc(-c3ccc(-c4ccc(-n5c6ccccc6c6cc(-c7ccc8c(c7)c7ccccc7n8-c7ccccc7)ccc65)cc4)cc3)nc(-c3ccccc3)n2)cc1 ; c1ccc(-c2cc(-c3cccc(-c4cccc(-n5c6ccccc6c6cc(-c7ccc8c(c7)c7ccccc7n8-c7ccccc7)ccc65)c4)c3)nc(-c3ccccc3)n2)cc1 ; c1ccc(-c2cc(-c3cccc(-c4cccc(-c5ccc(-n6c7ccccc7c7cc(-c8ccc9c(c8)c8ccccc8n9-c8ccccc8)ccc76)cc5)c4)c3)nc(-c3ccccc3)n2)cc1]

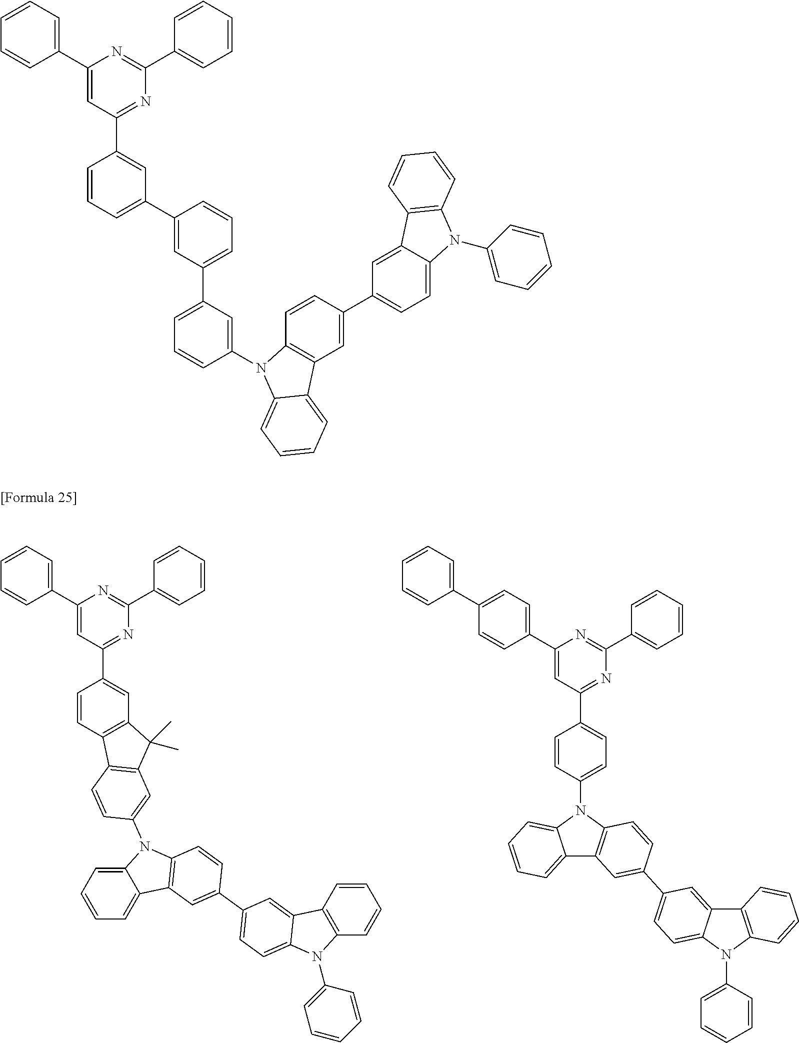 [SMILES: c1ccc(-c2cc(-c3cccc(-c4cccc(-c5cccc(-n6c7ccccc7c7cc(-c8ccc9c(c8)c8ccccc8n9-c8ccccc8)ccc76)c5)c4)c3)nc(-c3ccccc3)n2)cc1 ; CC1(C)c2cc(-c3cc(-c4ccccc4)nc(-c4ccccc4)n3)ccc2-c2ccc(-n3c4ccccc4c4cc(-c5ccc6c(c5)c5ccccc5n6-c5ccccc5)ccc43)cc21 ; c1ccc(-c2ccc(-c3cc(-c4ccc(-n5c6ccccc6c6cc(-c7ccc8c(c7)c7ccccc7n8-c7ccccc7)ccc65)cc4)nc(-c4ccccc4)n3)cc2)cc1]

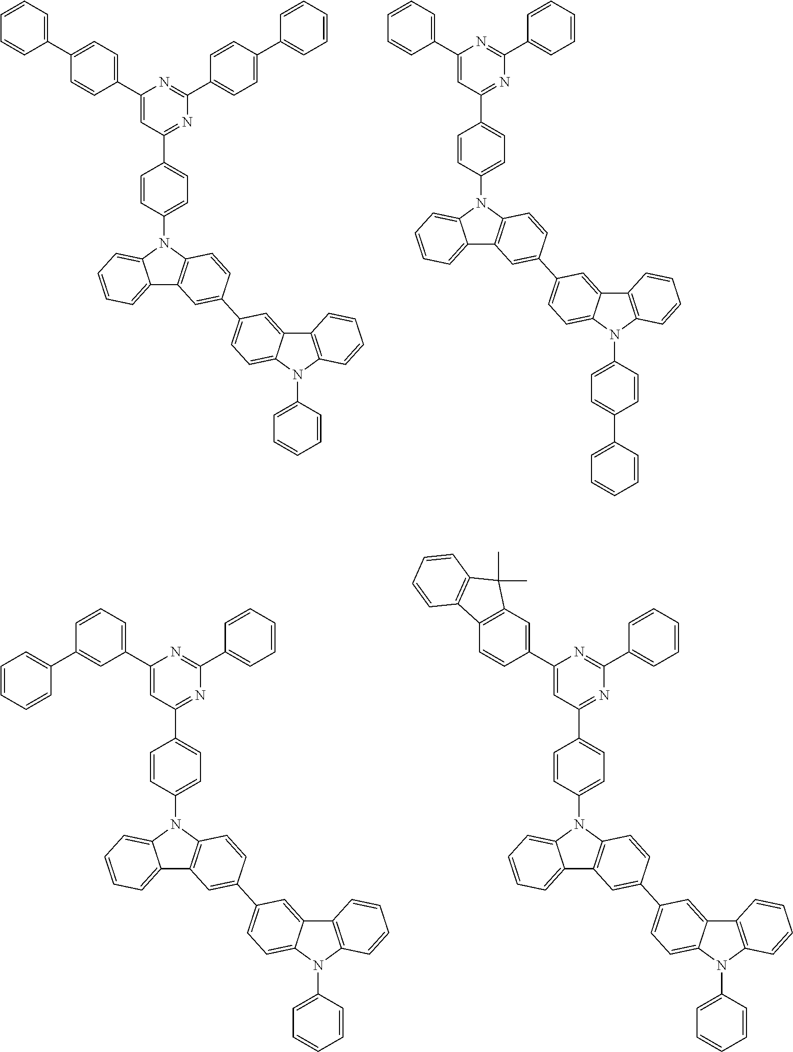 [SMILES: c1ccc(-c2ccc(-c3cc(-c4ccc(-n5c6ccccc6c6cc(-c7ccc8c(c7)c7ccccc7n8-c7ccccc7)ccc65)cc4)nc(-c4ccc(-c5ccccc5)cc4)n3)cc2)cc1 ; c1ccc(-c2ccc(-n3c4ccccc4c4cc(-c5ccc6c(c5)c5ccccc5n6-c5ccc(-c6cc(-c7ccccc7)nc(-c7ccccc7)n6)cc5)ccc43)cc2)cc1 ; c1ccc(-c2cccc(-c3cc(-c4ccc(-n5c6ccccc6c6cc(-c7ccc8c(c7)c7ccccc7n8-c7ccccc7)ccc65)cc4)nc(-c4ccccc4)n3)c2)cc1 ; CC1(C)c2ccccc2-c2ccc(-c3cc(-c4ccc(-n5c6ccccc6c6cc(-c7ccc8c(c7)c7ccccc7n8-c7ccccc7)ccc65)cc4)nc(-c4ccccc4)n3)cc21]

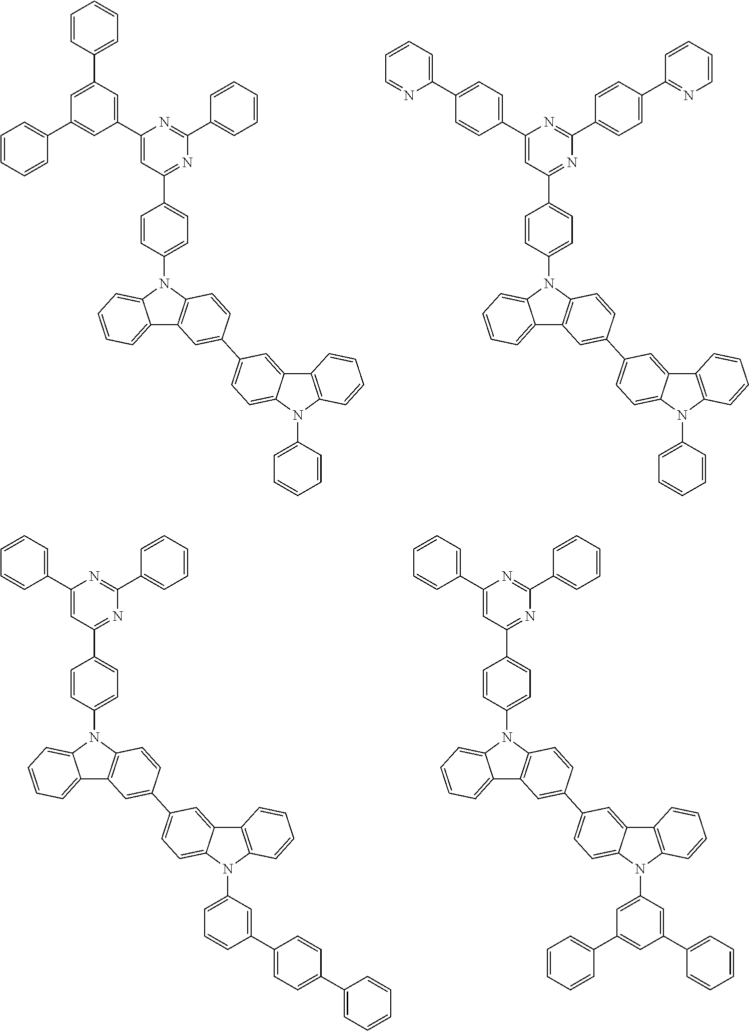 [SMILES: c1ccc(-c2cc(-c3ccccc3)cc(-c3cc(-c4ccc(-n5c6ccccc6c6cc(-c7ccc8c(c7)c7ccccc7n8-c7ccccc7)ccc65)cc4)nc(-c4ccccc4)n3)c2)cc1 ; c1ccc(-n2c3ccccc3c3cc(-c4ccc5c(c4)c4ccccc4n5-c4ccc(-c5cc(-c6ccc(-c7ccccn7)cc6)nc(-c6ccc(-c7ccccn7)cc6)n5)cc4)ccc32)cc1 ; c1ccc(-c2ccc(-c3cccc(-n4c5ccccc5c5cc(-c6ccc7c(c6)c6ccccc6n7-c6ccc(-c7cc(-c8ccccc8)nc(-c8ccccc8)n7)cc6)ccc54)c3)cc2)cc1 ; c1ccc(-c2cc(-c3ccccc3)cc(-n3c4ccccc4c4cc(-c5ccc6c(c5)c5ccccc5n6-c5ccc(-c6cc(-c7ccccc7)nc(-c7ccccc7)n6)cc5)ccc43)c2)cc1]

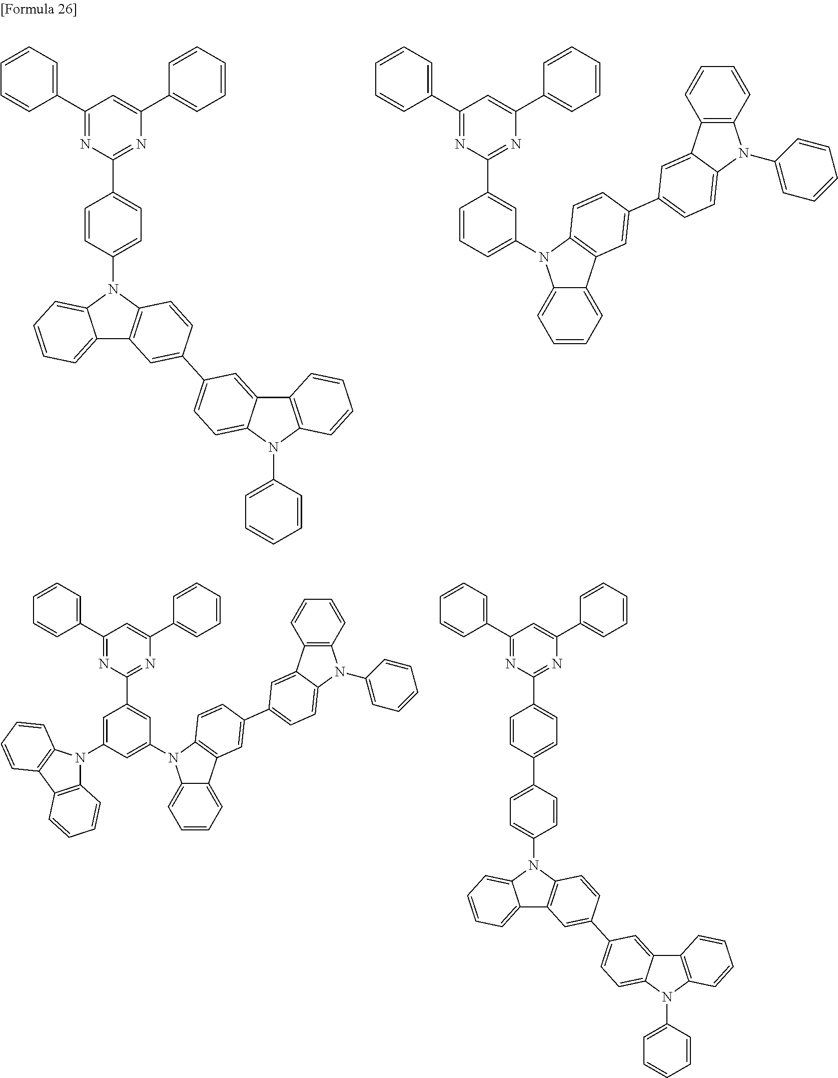 [SMILES: c1ccc(-c2cc(-c3ccccc3)nc(-c3ccc(-n4c5ccccc5c5cc(-c6ccc7c(c6)c6ccccc6n7-c6ccccc6)ccc54)cc3)n2)cc1 ; c1ccc(-c2cc(-c3ccccc3)nc(-c3cccc(-n4c5ccccc5c5cc(-c6ccc7c(c6)c6ccccc6n7-c6ccccc6)ccc54)c3)n2)cc1 ; c1ccc(-c2cc(-c3ccccc3)nc(-c3cc(-n4c5ccccc5c5ccccc54)cc(-n4c5ccccc5c5cc(-c6ccc7c(c6)c6ccccc6n7-c6ccccc6)ccc54)c3)n2)cc1 ; c1ccc(-c2cc(-c3ccccc3)nc(-c3ccc(-c4ccc(-n5c6ccccc6c6cc(-c7ccc8c(c7)c7ccccc7n8-c7ccccc7)ccc65)cc4)cc3)n2)cc1]

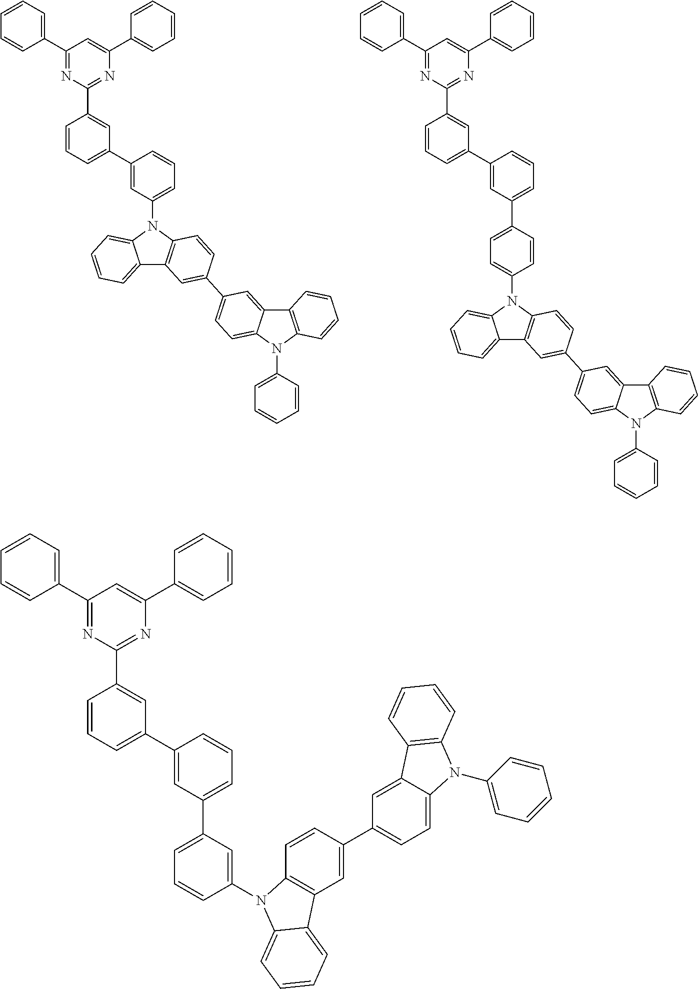 [SMILES: c1ccc(-c2cc(-c3ccccc3)nc(-c3cccc(-c4cccc(-n5c6ccccc6c6cc(-c7ccc8c(c7)c7ccccc7n8-c7ccccc7)ccc65)c4)c3)n2)cc1 ; c1ccc(-c2cc(-c3ccccc3)nc(-c3cccc(-c4cccc(-c5ccc(-n6c7ccccc7c7cc(-c8ccc9c(c8)c8ccccc8n9-c8ccccc8)ccc76)cc5)c4)c3)n2)cc1 ; c1ccc(-c2cc(-c3ccccc3)nc(-c3cccc(-c4cccc(-c5cccc(-n6c7ccccc7c7cc(-c8ccc9c(c8)c8ccccc8n9-c8ccccc8)ccc76)c5)c4)c3)n2)cc1]

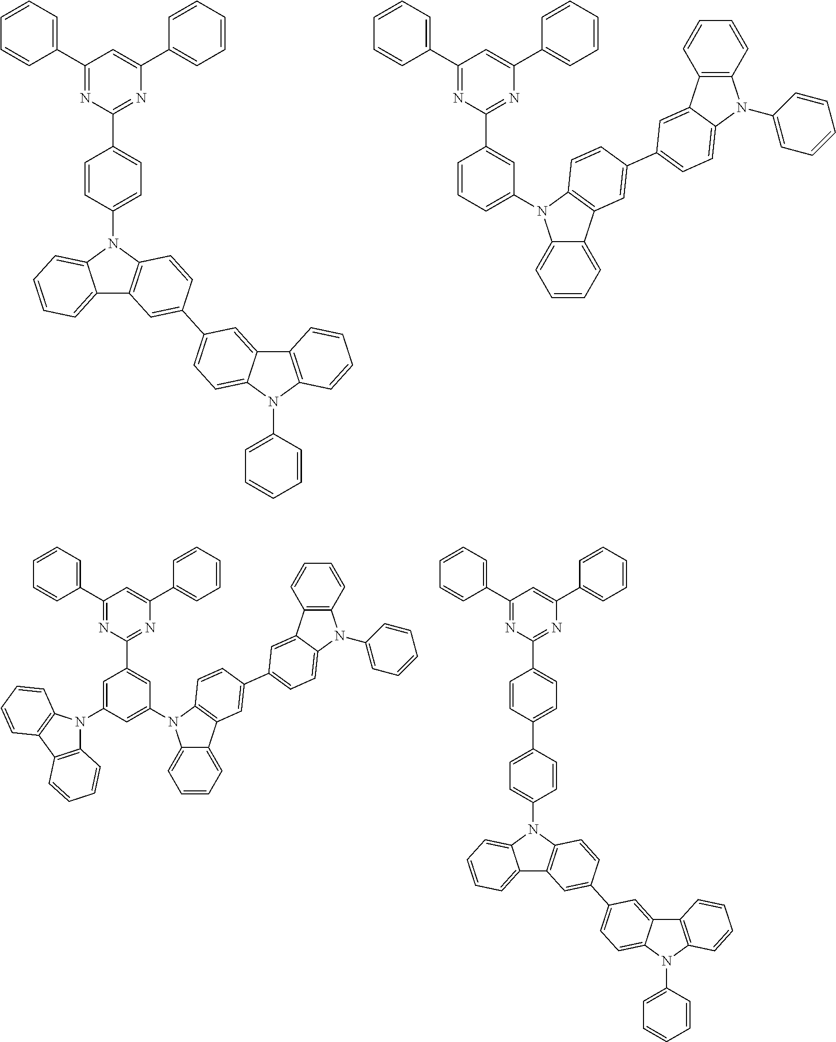 [SMILES: c1ccc(-c2cc(-c3ccccc3)nc(-c3ccc(-n4c5ccccc5c5cc(-c6ccc7c(c6)c6ccccc6n7-c6ccccc6)ccc54)cc3)n2)cc1 ; c1ccc(-c2cc(-c3ccccc3)nc(-c3cccc(-n4c5ccccc5c5cc(-c6ccc7c(c6)c6ccccc6n7-c6ccccc6)ccc54)c3)n2)cc1 ; c1ccc(-c2cc(-c3ccccc3)nc(-c3cc(-n4c5ccccc5c5ccccc54)cc(-n4c5ccccc5c5cc(-c6ccc7c(c6)c6ccccc6n7-c6ccccc6)ccc54)c3)n2)cc1 ; c1ccc(-c2cc(-c3ccccc3)nc(-c3ccc(-c4ccc(-n5c6ccccc6c6cc(-c7ccc8c(c7)c7ccccc7n8-c7ccccc7)ccc65)cc4)cc3)n2)cc1]

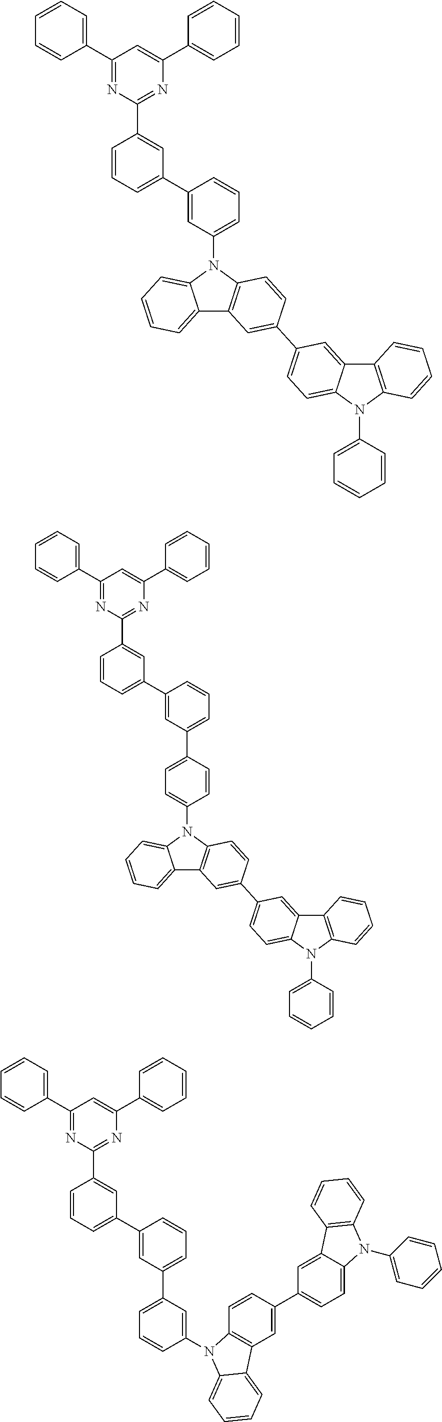 [SMILES: c1ccc(-c2cc(-c3ccccc3)nc(-c3cccc(-c4cccc(-n5c6ccccc6c6cc(-c7ccc8c(c7)c7ccccc7n8-c7ccccc7)ccc65)c4)c3)n2)cc1 ; c1ccc(-c2cc(-c3ccccc3)nc(-c3cccc(-c4cccc(-c5ccc(-n6c7ccccc7c7cc(-c8ccc9c(c8)c8ccccc8n9-c8ccccc8)ccc76)cc5)c4)c3)n2)cc1 ; c1ccc(-c2cc(-c3ccccc3)nc(-c3cccc(-c4cccc(-c5cccc(-n6c7ccccc7c7cc(-c8ccc9c(c8)c8ccccc8n9-c8ccccc8)ccc76)c5)c4)c3)n2)cc1]

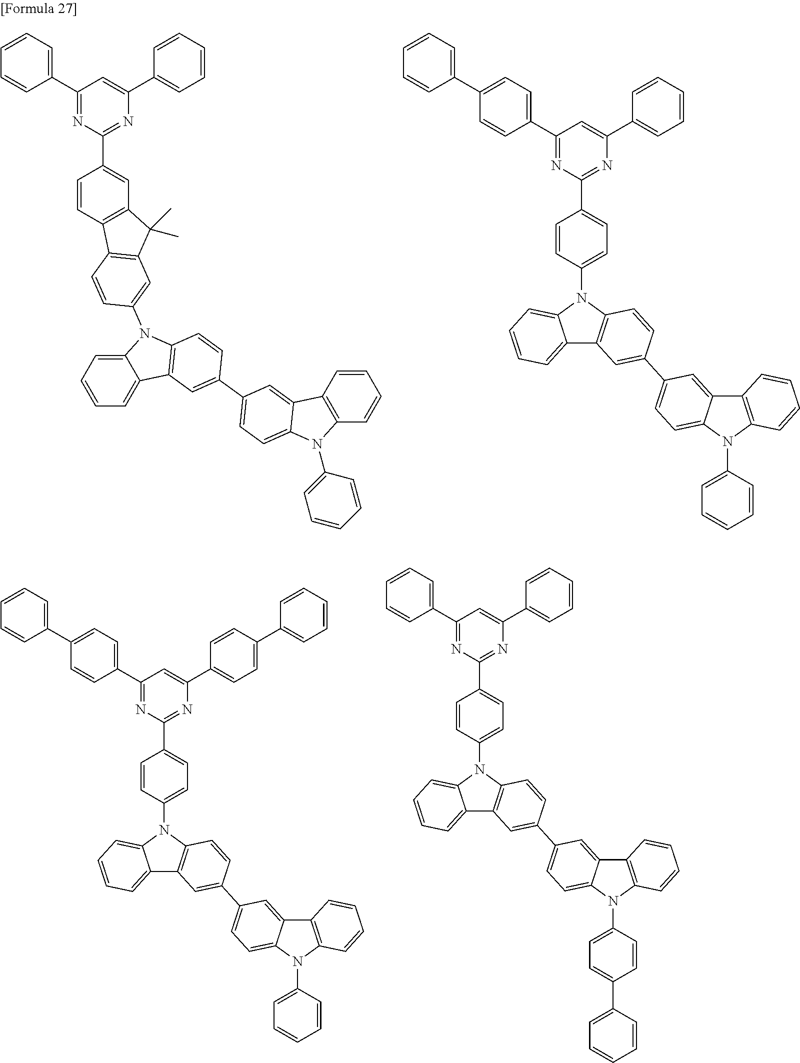 [SMILES: CC1(C)c2cc(-c3nc(-c4ccccc4)cc(-c4ccccc4)n3)ccc2-c2ccc(-n3c4ccccc4c4cc(-c5ccc6c(c5)c5ccccc5n6-c5ccccc5)ccc43)cc21 ; c1ccc(-c2ccc(-c3cc(-c4ccccc4)nc(-c4ccc(-n5c6ccccc6c6cc(-c7ccc8c(c7)c7ccccc7n8-c7ccccc7)ccc65)cc4)n3)cc2)cc1 ; c1ccc(-c2ccc(-c3cc(-c4ccc(-c5ccccc5)cc4)nc(-c4ccc(-n5c6ccccc6c6cc(-c7ccc8c(c7)c7ccccc7n8-c7ccccc7)ccc65)cc4)n3)cc2)cc1 ; c1ccc(-c2ccc(-n3c4ccccc4c4cc(-c5ccc6c(c5)c5ccccc5n6-c5ccc(-c6nc(-c7ccccc7)cc(-c7ccccc7)n6)cc5)ccc43)cc2)cc1]

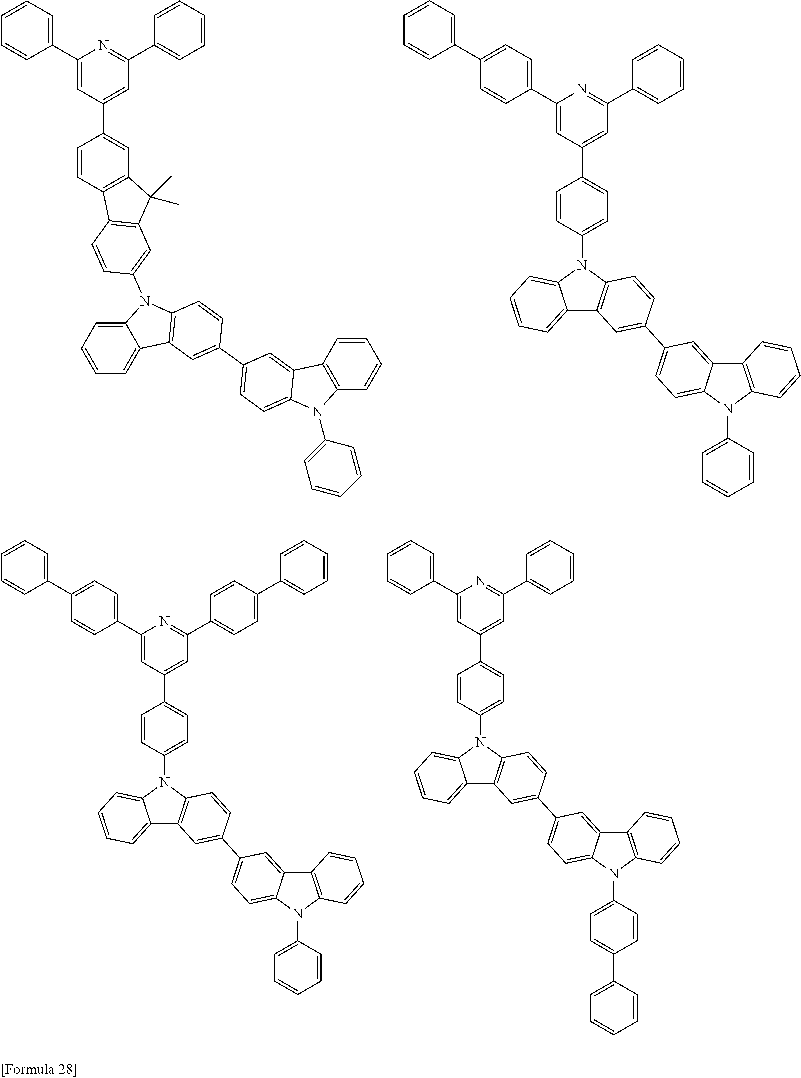 [SMILES: CC1(C)c2cc(-c3cc(-c4ccccc4)nc(-c4ccccc4)c3)ccc2-c2ccc(-n3c4ccccc4c4cc(-c5ccc6c(c5)c5ccccc5n6-c5ccccc5)ccc43)cc21 ; c1ccc(-c2ccc(-c3cc(-c4ccc(-n5c6ccccc6c6cc(-c7ccc8c(c7)c7ccccc7n8-c7ccccc7)ccc65)cc4)cc(-c4ccccc4)n3)cc2)cc1 ; c1ccc(-c2ccc(-c3cc(-c4ccc(-n5c6ccccc6c6cc(-c7ccc8c(c7)c7ccccc7n8-c7ccccc7)ccc65)cc4)cc(-c4ccc(-c5ccccc5)cc4)n3)cc2)cc1 ; c1ccc(-c2ccc(-n3c4ccccc4c4cc(-c5ccc6c(c5)c5ccccc5n6-c5ccc(-c6cc(-c7ccccc7)nc(-c7ccccc7)c6)cc5)ccc43)cc2)cc1]

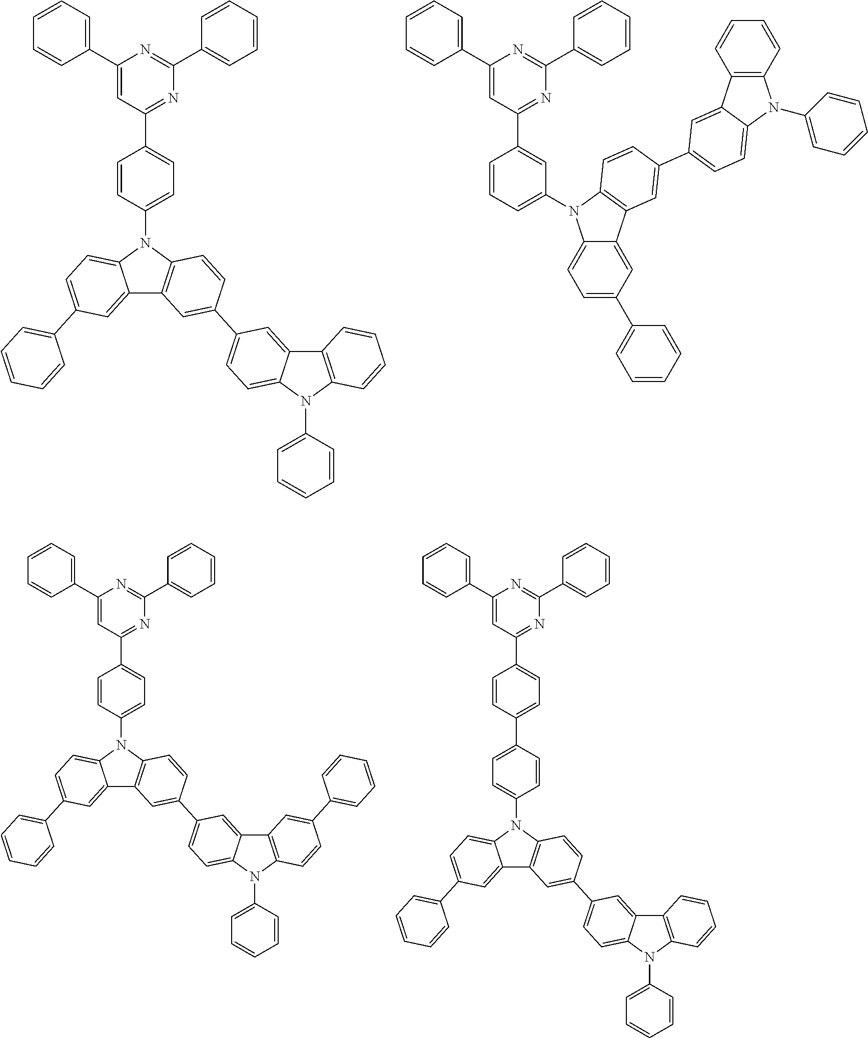 [SMILES: c1ccc(-c2ccc3c(c2)c2cc(-c4ccc5c(c4)c4ccccc4n5-c4ccccc4)ccc2n3-c2ccc(-c3cc(-c4ccccc4)nc(-c4ccccc4)n3)cc2)cc1 ; c1ccc(-c2ccc3c(c2)c2cc(-c4ccc5c(c4)c4ccccc4n5-c4ccccc4)ccc2n3-c2cccc(-c3cc(-c4ccccc4)nc(-c4ccccc4)n3)c2)cc1 ; c1ccc(-c2ccc3c(c2)c2cc(-c4ccc5c(c4)c4cc(-c6ccccc6)ccc4n5-c4ccc(-c5cc(-c6ccccc6)nc(-c6ccccc6)n5)cc4)ccc2n3-c2ccccc2)cc1 ; c1ccc(-c2ccc3c(c2)c2cc(-c4ccc5c(c4)c4ccccc4n5-c4ccccc4)ccc2n3-c2ccc(-c3ccc(-c4cc(-c5ccccc5)nc(-c5ccccc5)n4)cc3)cc2)cc1]

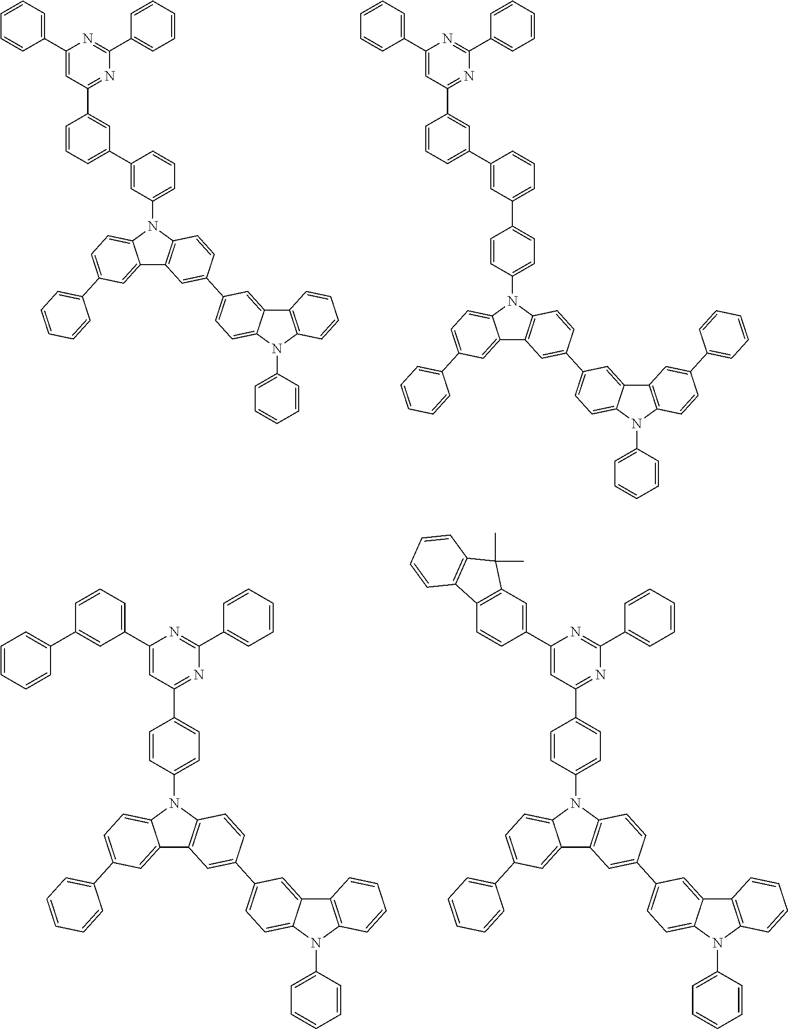

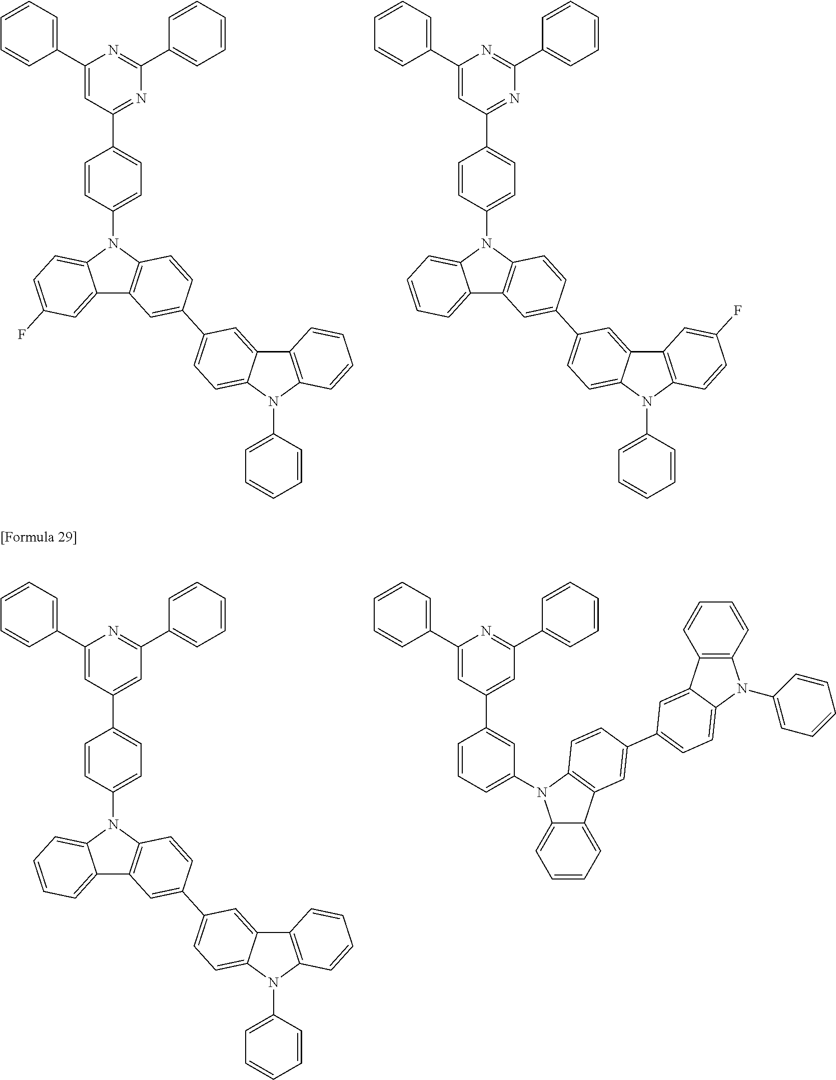 [SMILES: Fc1ccc2c(c1)c1cc(-c3ccc4c(c3)c3ccccc3n4-c3ccccc3)ccc1n2-c1ccc(-c2cc(-c3ccccc3)nc(-c3ccccc3)n2)cc1 ; Fc1ccc2c(c1)c1cc(-c3ccc4c(c3)c3ccccc3n4-c3ccc(-c4cc(-c5ccccc5)nc(-c5ccccc5)n4)cc3)ccc1n2-c1ccccc1 ; c1ccc(-c2cc(-c3ccc(-n4c5ccccc5c5cc(-c6ccc7c(c6)c6ccccc6n7-c6ccccc6)ccc54)cc3)cc(-c3ccccc3)n2)cc1 ; c1ccc(-c2cc(-c3cccc(-n4c5ccccc5c5cc(-c6ccc7c(c6)c6ccccc6n7-c6ccccc6)ccc54)c3)cc(-c3ccccc3)n2)cc1]

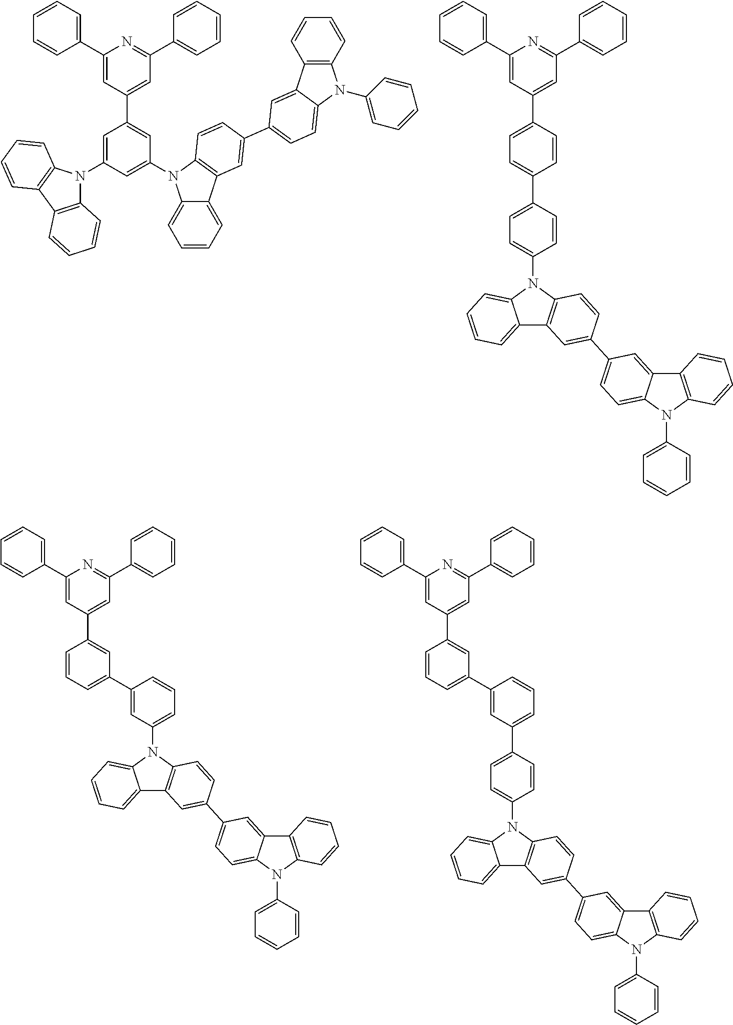 [SMILES: c1ccc(-c2cc(-c3cc(-n4c5ccccc5c5ccccc54)cc(-n4c5ccccc5c5cc(-c6ccc7c(c6)c6ccccc6n7-c6ccccc6)ccc54)c3)cc(-c3ccccc3)n2)cc1 ; c1ccc(-c2cc(-c3ccc(-c4ccc(-n5c6ccccc6c6cc(-c7ccc8c(c7)c7ccccc7n8-c7ccccc7)ccc65)cc4)cc3)cc(-c3ccccc3)n2)cc1 ; c1ccc(-c2cc(-c3cccc(-c4cccc(-n5c6ccccc6c6cc(-c7ccc8c(c7)c7ccccc7n8-c7ccccc7)ccc65)c4)c3)cc(-c3ccccc3)n2)cc1 ; c1ccc(-c2cc(-c3cccc(-c4cccc(-c5ccc(-n6c7ccccc7c7cc(-c8ccc9c(c8)c8ccccc8n9-c8ccccc8)ccc76)cc5)c4)c3)cc(-c3ccccc3)n2)cc1]

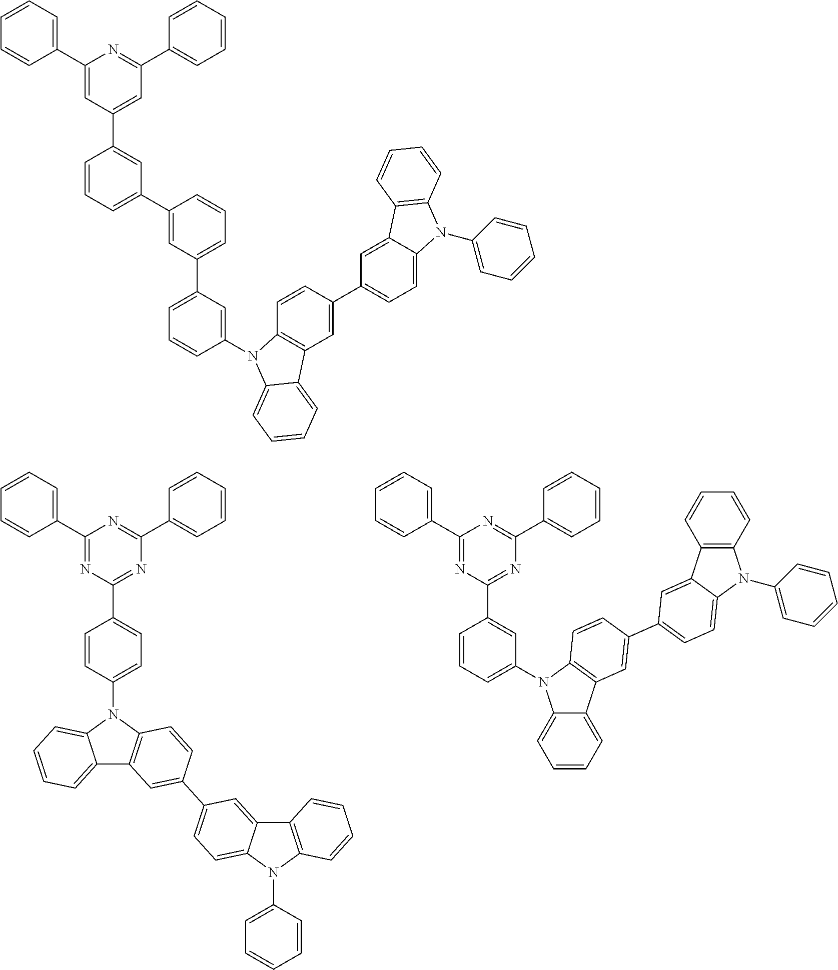 [SMILES: c1ccc(-c2cc(-c3cccc(-c4cccc(-c5cccc(-n6c7ccccc7c7cc(-c8ccc9c(c8)c8ccccc8n9-c8ccccc8)ccc76)c5)c4)c3)cc(-c3ccccc3)n2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1]

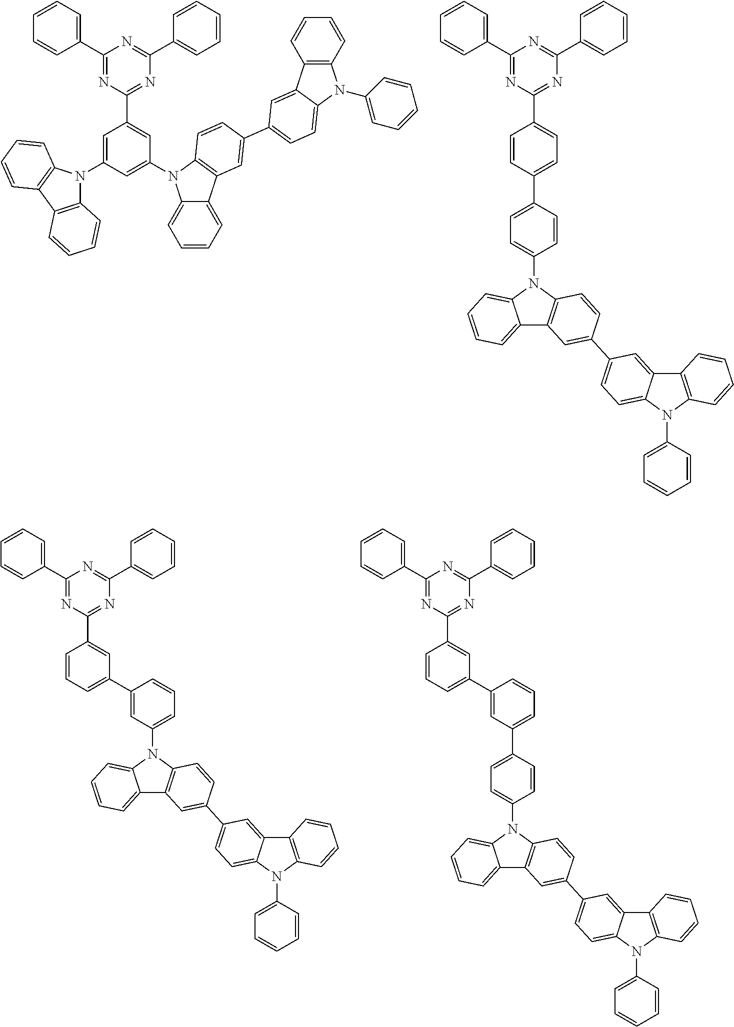 [SMILES: c1ccc(-c2nc(-c3ccccc3)nc(-c3cc(-n4c5ccccc5c5ccccc54)cc(-n4c5ccccc5c5cc(-c6ccc7c(c6)c6ccccc6n7-c6ccccc6)ccc54)c3)n2)cc1 ; c1ccc(-c2nc(-c3ccccc3)nc(-c3ccc(-c4ccc(-n5c6ccccc6c6cc(-c7ccc8c(c7)c7ccccc7n8-c7ccccc7)ccc65)cc4)cc3)n2)cc1 ; c1ccc(-c2nc(-c3ccccc3)nc(-c3cccc(-c4cccc(-n5c6ccccc6c6cc(-c7ccc8c(c7)c7ccccc7n8-c7ccccc7)ccc65)c4)c3)n2)cc1 ; c1ccc(-c2nc(-c3ccccc3)nc(-c3cccc(-c4cccc(-c5ccc(-n6c7ccccc7c7cc(-c8ccc9c(c8)c8ccccc8n9-c8ccccc8)ccc76)cc5)c4)c3)n2)cc1]

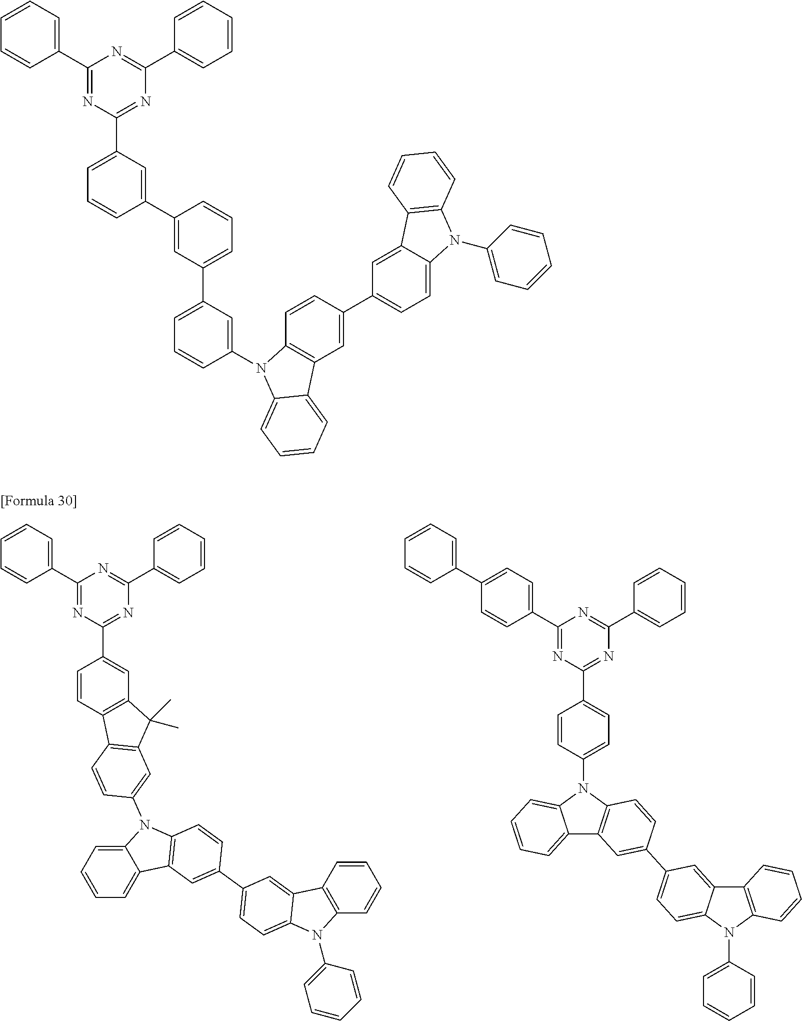 [SMILES: c1ccc(-c2nc(-c3ccccc3)nc(-c3cccc(-c4cccc(-c5cccc(-n6c7ccccc7c7cc(-c8ccc9c(c8)c8ccccc8n9-c8ccccc8)ccc76)c5)c4)c3)n2)cc1 ; CC1(C)c2cc(-c3nc(-c4ccccc4)nc(-c4ccccc4)n3)ccc2-c2ccc(-n3c4ccccc4c4cc(-c5ccc6c(c5)c5ccccc5n6-c5ccccc5)ccc43)cc21 ; c1ccc(-c2ccc(-c3nc(-c4ccccc4)nc(-c4ccc(-n5c6ccccc6c6cc(-c7ccc8c(c7)c7ccccc7n8-c7ccccc7)ccc65)cc4)n3)cc2)cc1]

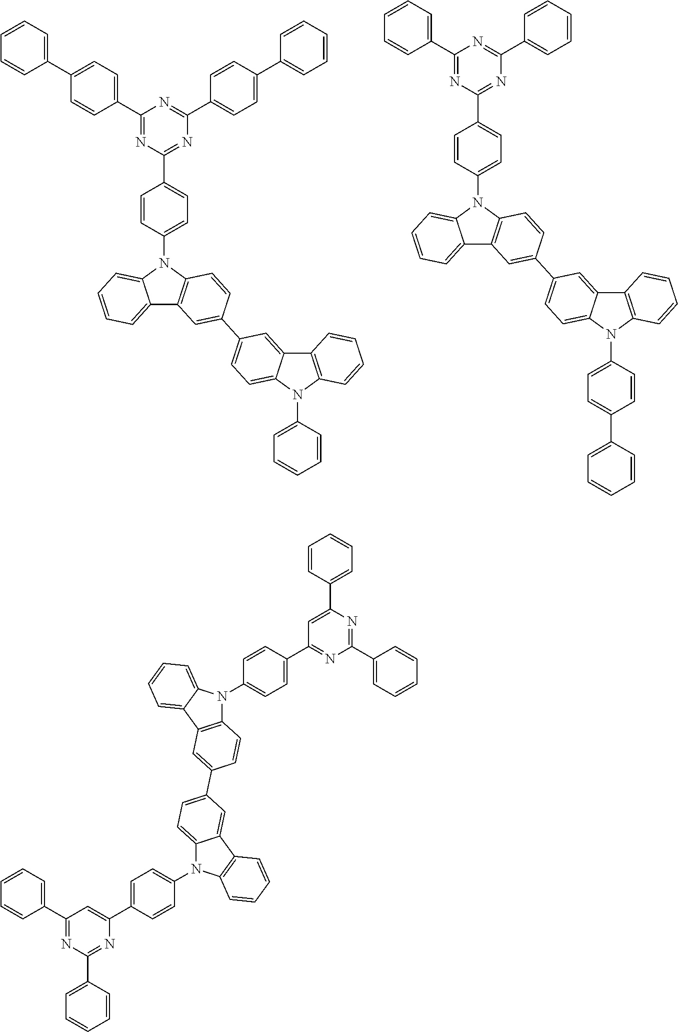 [SMILES: c1ccc(-c2ccc(-c3nc(-c4ccc(-c5ccccc5)cc4)nc(-c4ccc(-n5c6ccccc6c6cc(-c7ccc8c(c7)c7ccccc7n8-c7ccccc7)ccc65)cc4)n3)cc2)cc1 ; c1ccc(-c2ccc(-n3c4ccccc4c4cc(-c5ccc6c(c5)c5ccccc5n6-c5ccc(-c6nc(-c7ccccc7)nc(-c7ccccc7)n6)cc5)ccc43)cc2)cc1 ; c1ccc(-c2cc(-c3ccc(-n4c5ccccc5c5cc(-c6ccc7c(c6)c6ccccc6n7-c6ccc(-c7cc(-c8ccccc8)nc(-c8ccccc8)n7)cc6)ccc54)cc3)nc(-c3ccccc3)n2)cc1]

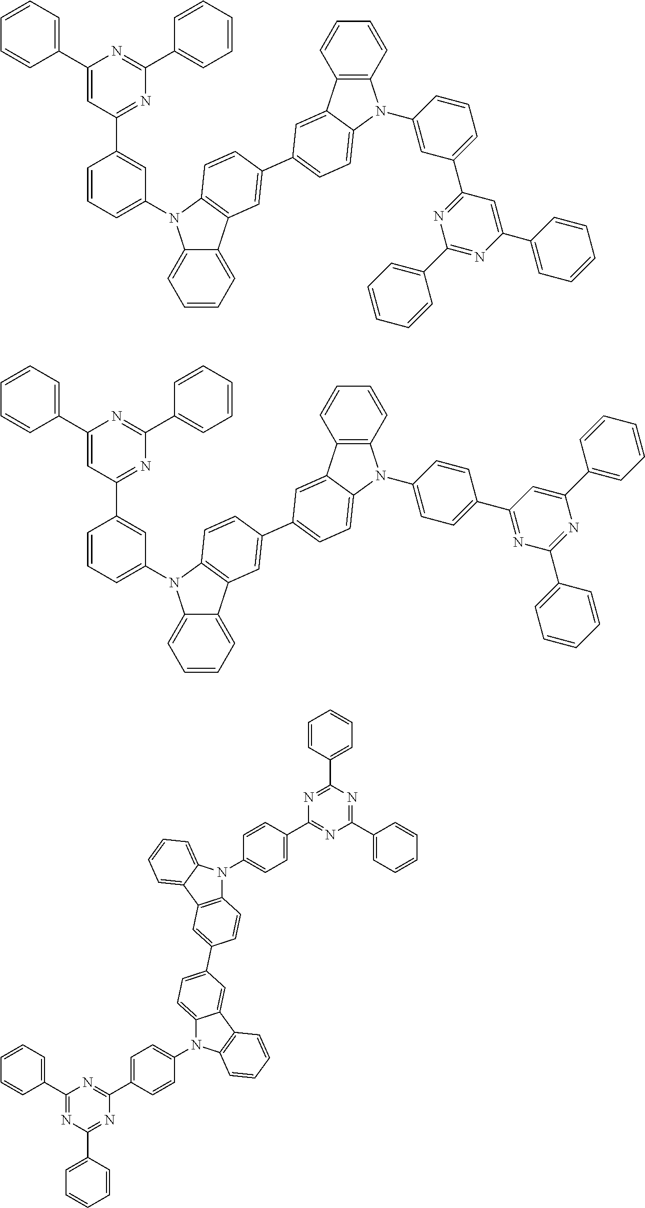 [SMILES: c1ccc(-c2cc(-c3cccc(-n4c5ccccc5c5cc(-c6ccc7c(c6)c6ccccc6n7-c6cccc(-c7cc(-c8ccccc8)nc(-c8ccccc8)n7)c6)ccc54)c3)nc(-c3ccccc3)n2)cc1 ; c1ccc(-c2cc(-c3ccc(-n4c5ccccc5c5cc(-c6ccc7c(c6)c6ccccc6n7-c6cccc(-c7cc(-c8ccccc8)nc(-c8ccccc8)n7)c6)ccc54)cc3)nc(-c3ccccc3)n2)cc1 ; c1ccc(-c2nc(-c3ccccc3)nc(-c3ccc(-n4c5ccccc5c5cc(-c6ccc7c(c6)c6ccccc6n7-c6ccc(-c7nc(-c8ccccc8)nc(-c8ccccc8)n7)cc6)ccc54)cc3)n2)cc1]

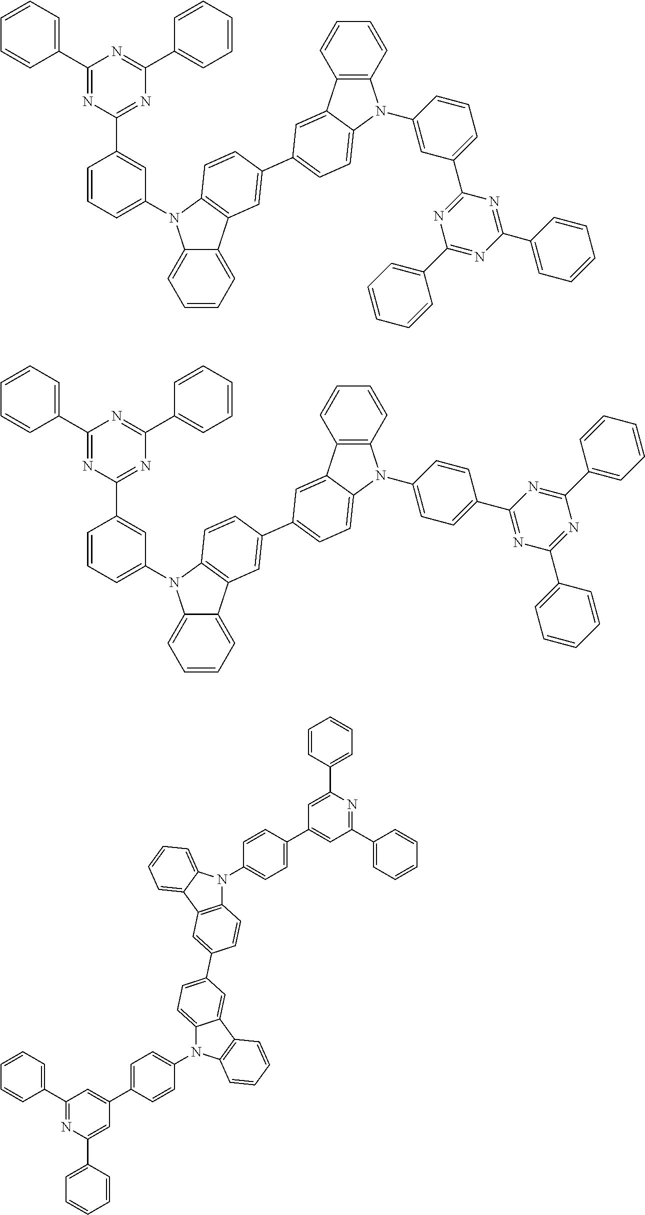 [SMILES: c1ccc(-c2nc(-c3ccccc3)nc(-c3cccc(-n4c5ccccc5c5cc(-c6ccc7c(c6)c6ccccc6n7-c6cccc(-c7nc(-c8ccccc8)nc(-c8ccccc8)n7)c6)ccc54)c3)n2)cc1 ; c1ccc(-c2nc(-c3ccccc3)nc(-c3ccc(-n4c5ccccc5c5cc(-c6ccc7c(c6)c6ccccc6n7-c6cccc(-c7nc(-c8ccccc8)nc(-c8ccccc8)n7)c6)ccc54)cc3)n2)cc1 ; c1ccc(-c2cc(-c3ccc(-n4c5ccccc5c5cc(-c6ccc7c(c6)c6ccccc6n7-c6ccc(-c7cc(-c8ccccc8)nc(-c8ccccc8)c7)cc6)ccc54)cc3)cc(-c3ccccc3)n2)cc1]

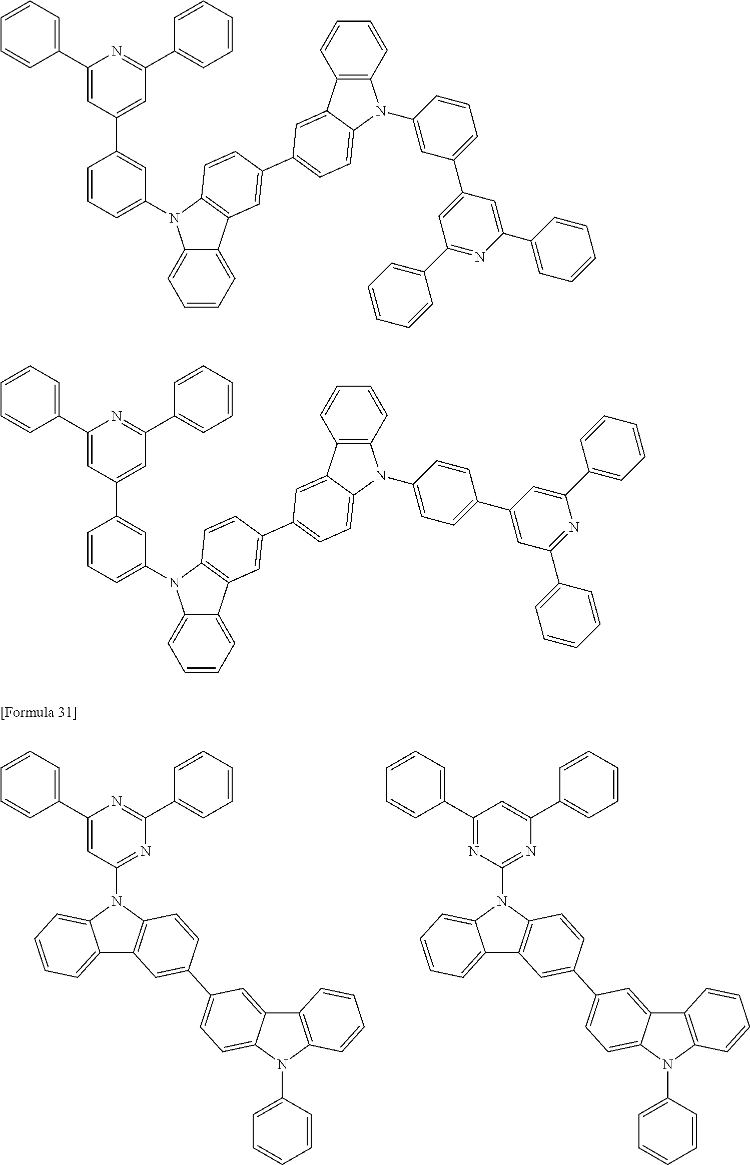 [SMILES: c1ccc(-c2cc(-c3cccc(-n4c5ccccc5c5cc(-c6ccc7c(c6)c6ccccc6n7-c6cccc(-c7cc(-c8ccccc8)nc(-c8ccccc8)c7)c6)ccc54)c3)cc(-c3ccccc3)n2)cc1 ; c1ccc(-c2cc(-c3ccc(-n4c5ccccc5c5cc(-c6ccc7c(c6)c6ccccc6n7-c6cccc(-c7cc(-c8ccccc8)nc(-c8ccccc8)c7)c6)ccc54)cc3)cc(-c3ccccc3)n2)cc1 ; c1ccc(-c2cc(-n3c4ccccc4c4cc(-c5ccc6c(c5)c5ccccc5n6-c5ccccc5)ccc43)nc(-c3ccccc3)n2)cc1 ; c1ccc(-c2cc(-c3ccccc3)nc(-n3c4ccccc4c4cc(-c5ccc6c(c5)c5ccccc5n6-c5ccccc5)ccc43)n2)cc1]

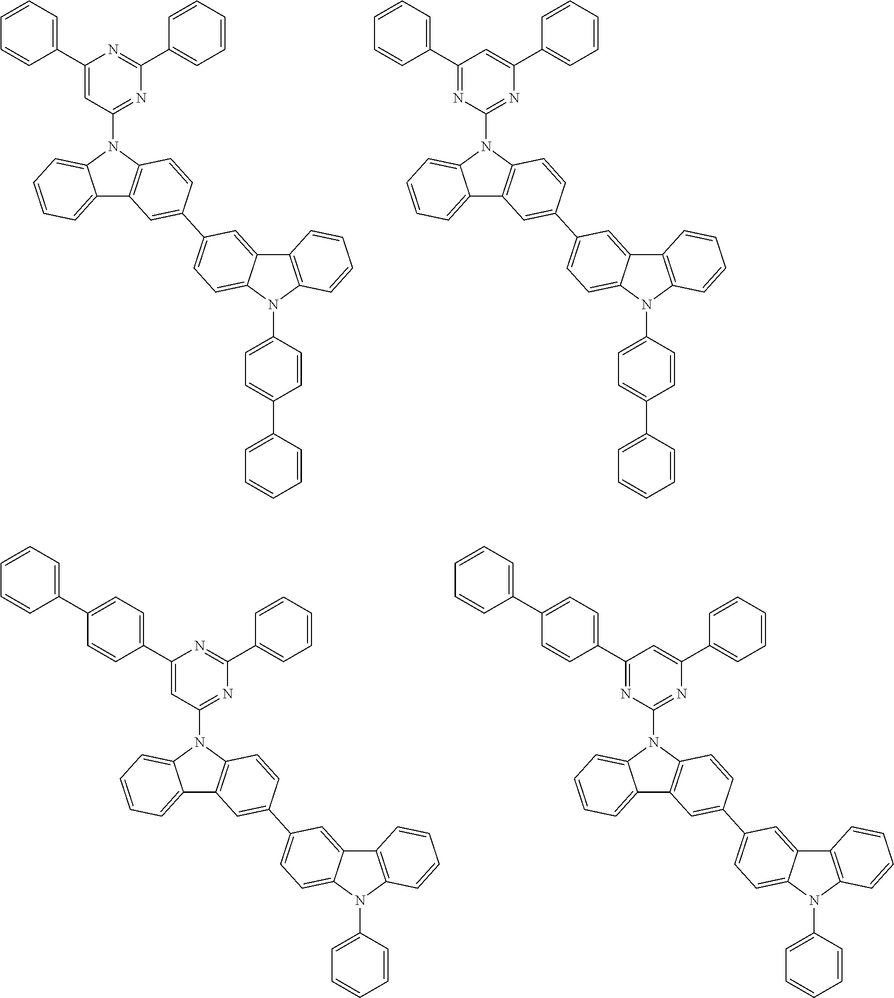 [SMILES: c1ccc(-c2ccc(-n3c4ccccc4c4cc(-c5ccc6c(c5)c5ccccc5n6-c5cc(-c6ccccc6)nc(-c6ccccc6)n5)ccc43)cc2)cc1 ; c1ccc(-c2ccc(-n3c4ccccc4c4cc(-c5ccc6c(c5)c5ccccc5n6-c5nc(-c6ccccc6)cc(-c6ccccc6)n5)ccc43)cc2)cc1 ; c1ccc(-c2ccc(-c3cc(-n4c5ccccc5c5cc(-c6ccc7c(c6)c6ccccc6n7-c6ccccc6)ccc54)nc(-c4ccccc4)n3)cc2)cc1 ; c1ccc(-c2ccc(-c3cc(-c4ccccc4)nc(-n4c5ccccc5c5cc(-c6ccc7c(c6)c6ccccc6n7-c6ccccc6)ccc54)n3)cc2)cc1]

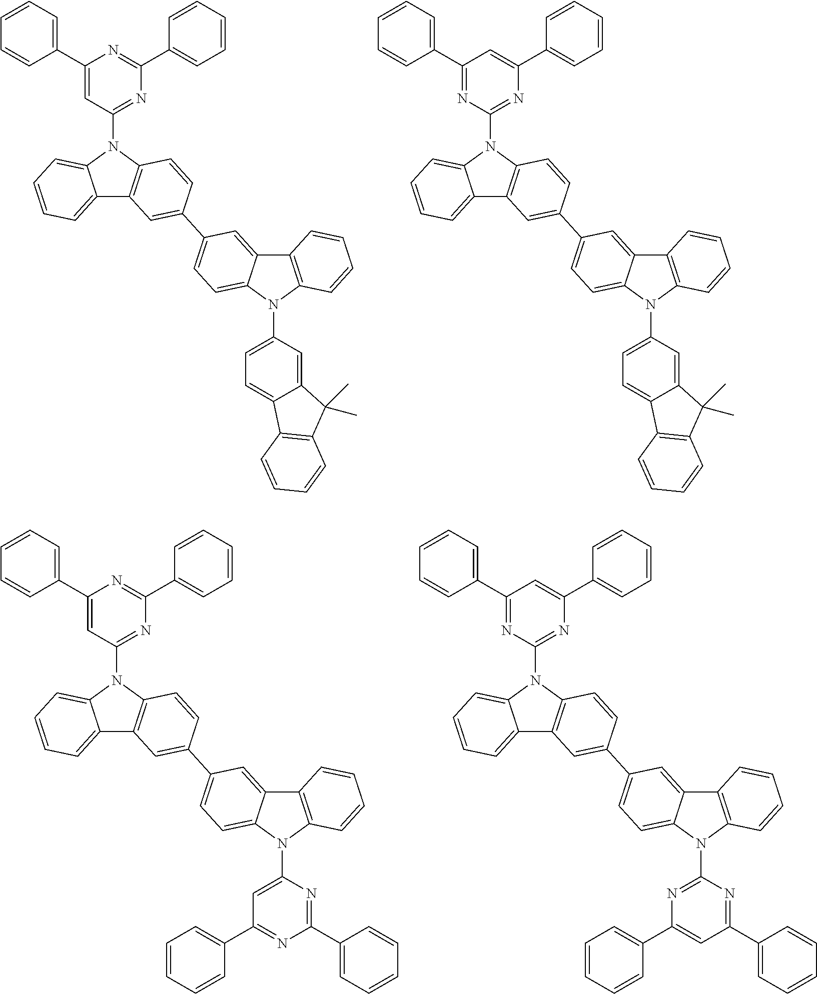 [SMILES: CC1(C)c2ccccc2-c2ccc(-n3c4ccccc4c4cc(-c5ccc6c(c5)c5ccccc5n6-c5cc(-c6ccccc6)nc(-c6ccccc6)n5)ccc43)cc21 ; CC1(C)c2ccccc2-c2ccc(-n3c4ccccc4c4cc(-c5ccc6c(c5)c5ccccc5n6-c5nc(-c6ccccc6)cc(-c6ccccc6)n5)ccc43)cc21 ; c1ccc(-c2cc(-n3c4ccccc4c4cc(-c5ccc6c(c5)c5ccccc5n6-c5cc(-c6ccccc6)nc(-c6ccccc6)n5)ccc43)nc(-c3ccccc3)n2)cc1 ; c1ccc(-c2cc(-c3ccccc3)nc(-n3c4ccccc4c4cc(-c5ccc6c(c5)c5ccccc5n6-c5nc(-c6ccccc6)cc(-c6ccccc6)n5)ccc43)n2)cc1]

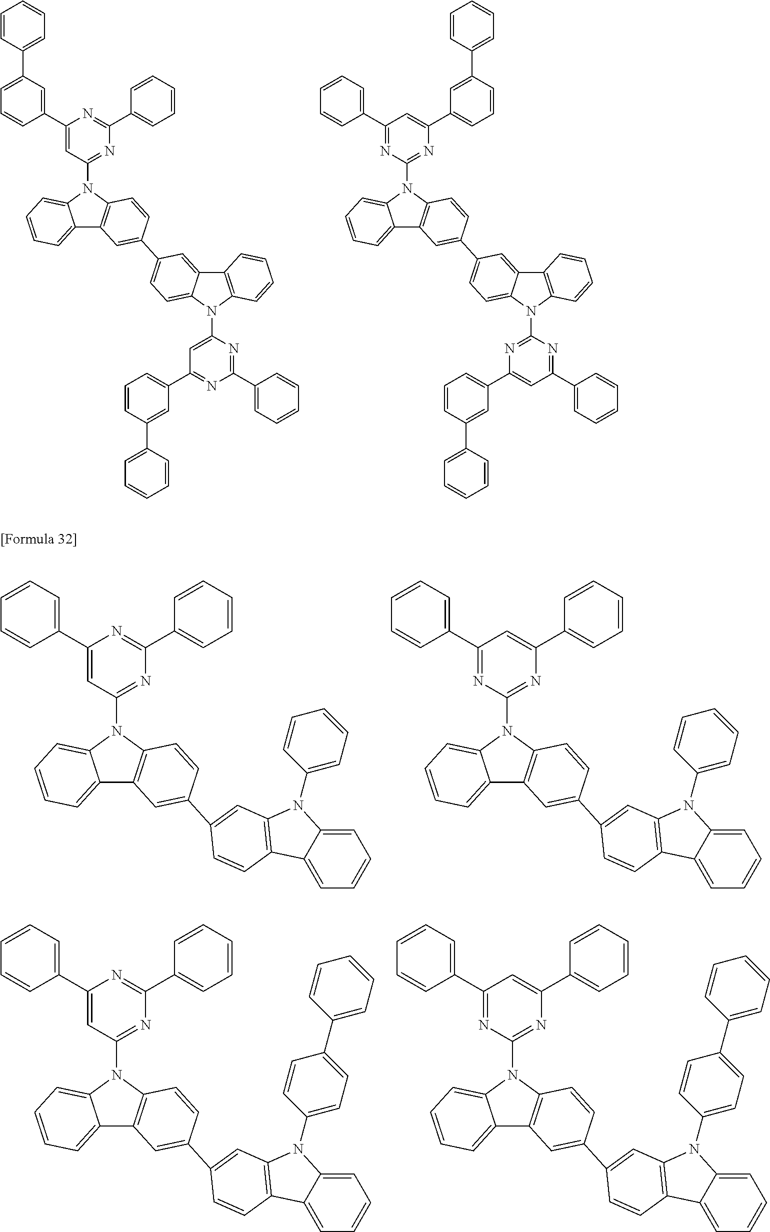

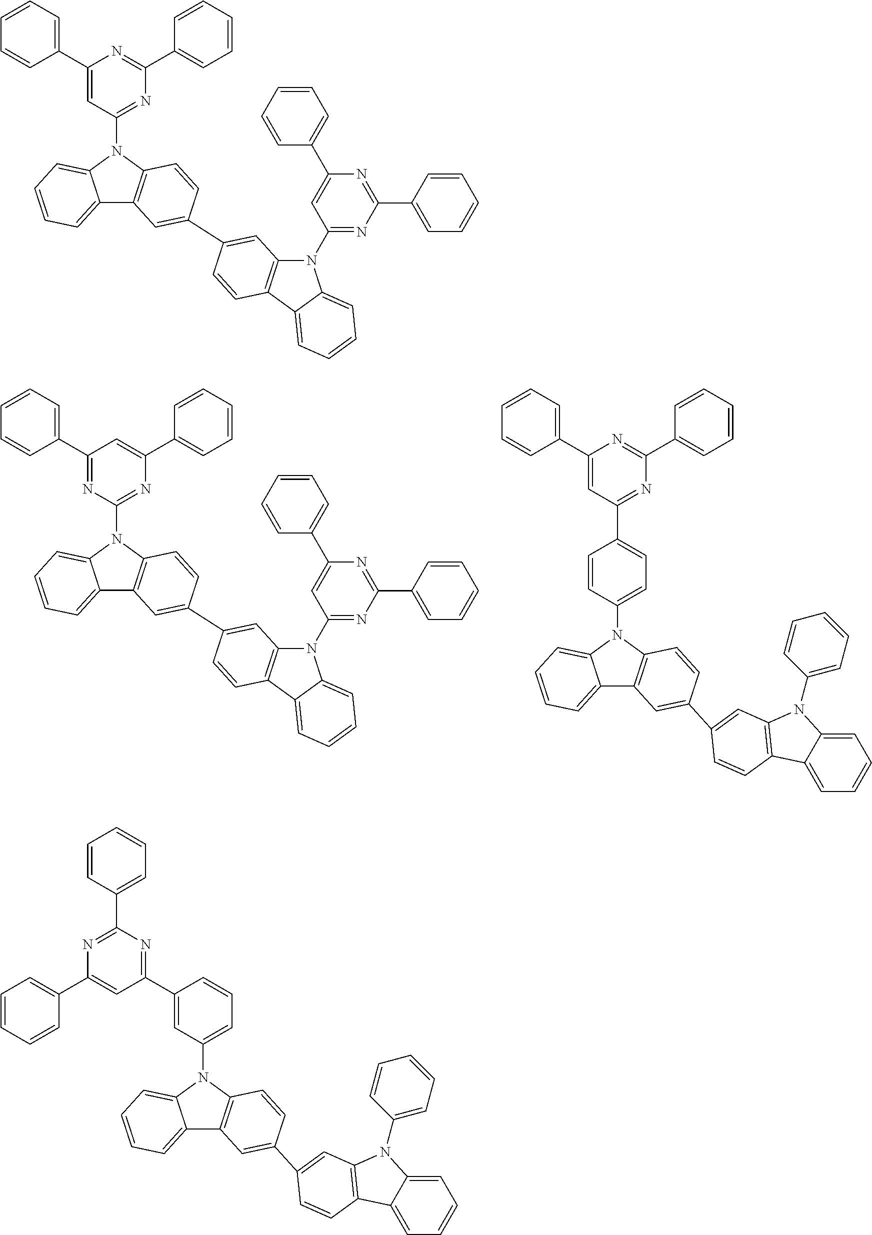 [SMILES: c1ccc(-c2cc(-n3c4ccccc4c4cc(-c5ccc6c7ccccc7n(-c7cc(-c8ccccc8)nc(-c8ccccc8)n7)c6c5)ccc43)nc(-c3ccccc3)n2)cc1 ; c1ccc(-c2cc(-n3c4ccccc4c4ccc(-c5ccc6c(c5)c5ccccc5n6-c5nc(-c6ccccc6)cc(-c6ccccc6)n5)cc43)nc(-c3ccccc3)n2)cc1 ; c1ccc(-c2cc(-c3ccc(-n4c5ccccc5c5cc(-c6ccc7c8ccccc8n(-c8ccccc8)c7c6)ccc54)cc3)nc(-c3ccccc3)n2)cc1 ; c1ccc(-c2cc(-c3cccc(-n4c5ccccc5c5cc(-c6ccc7c8ccccc8n(-c8ccccc8)c7c6)ccc54)c3)nc(-c3ccccc3)n2)cc1]

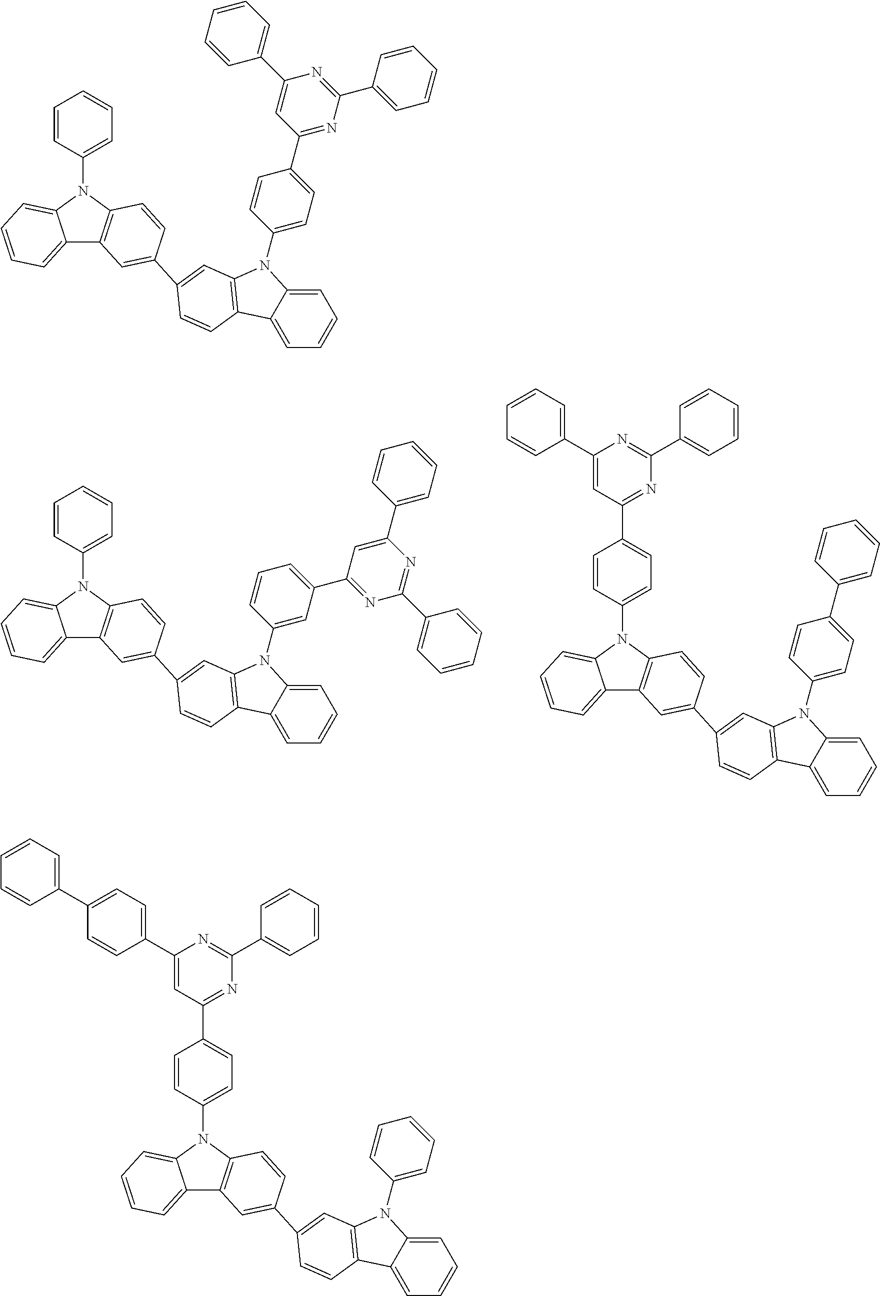 [SMILES: c1ccc(-c2cc(-c3ccc(-n4c5ccccc5c5ccc(-c6ccc7c(c6)c6ccccc6n7-c6ccccc6)cc54)cc3)nc(-c3ccccc3)n2)cc1 ; c1ccc(-c2cc(-c3cccc(-n4c5ccccc5c5ccc(-c6ccc7c(c6)c6ccccc6n7-c6ccccc6)cc54)c3)nc(-c3ccccc3)n2)cc1 ; c1ccc(-c2ccc(-n3c4ccccc4c4ccc(-c5ccc6c(c5)c5ccccc5n6-c5ccc(-c6cc(-c7ccccc7)nc(-c7ccccc7)n6)cc5)cc43)cc2)cc1 ; c1ccc(-c2ccc(-c3cc(-c4ccc(-n5c6ccccc6c6cc(-c7ccc8c9ccccc9n(-c9ccccc9)c8c7)ccc65)cc4)nc(-c4ccccc4)n3)cc2)cc1]

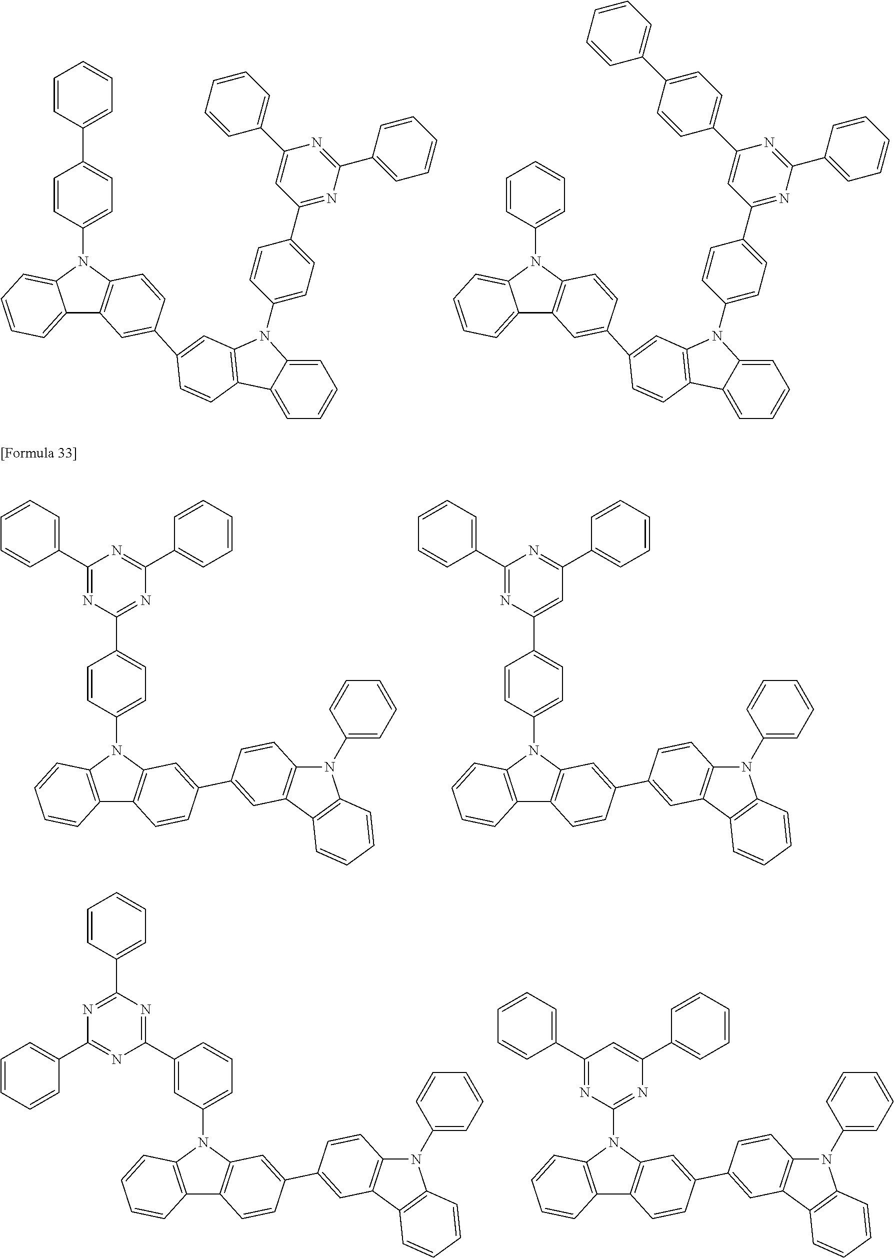

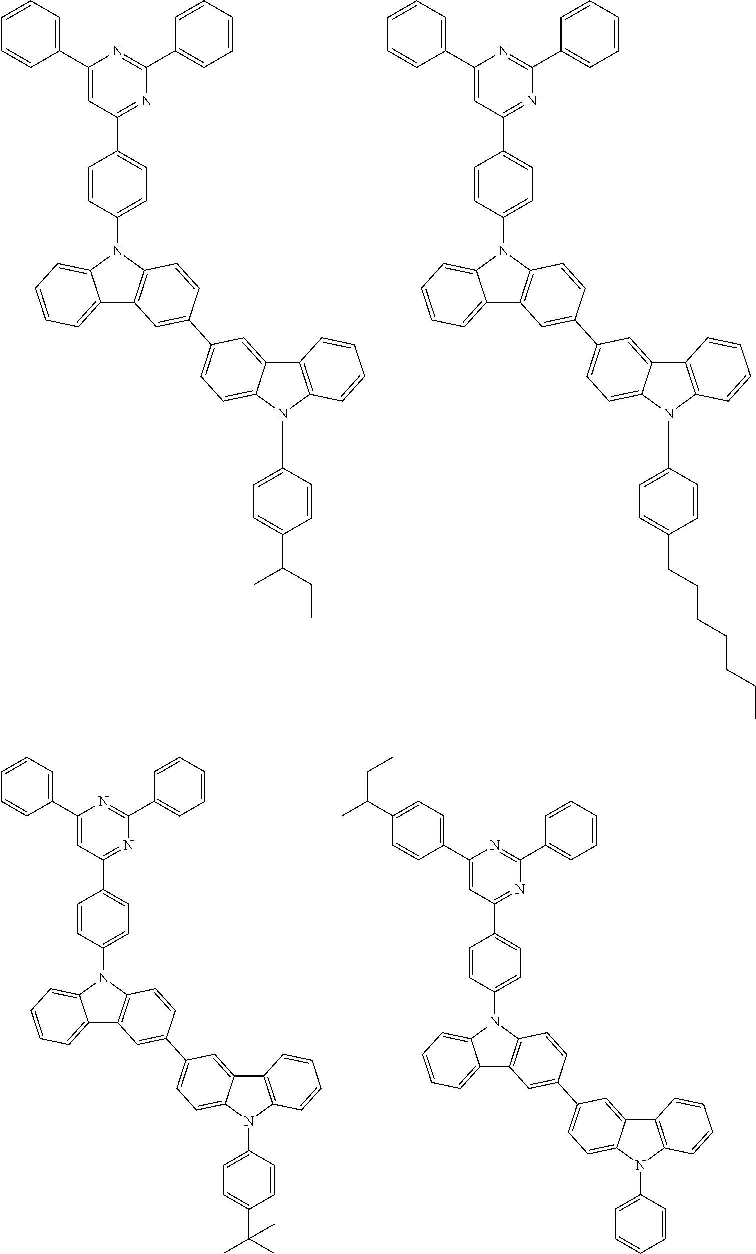 [SMILES: CCC(C)c1ccc(-n2c3ccccc3c3cc(-c4ccc5c(c4)c4ccccc4n5-c4ccc(-c5cc(-c6ccccc6)nc(-c6ccccc6)n5)cc4)ccc32)cc1 ; CCCCCCCc1ccc(-n2c3ccccc3c3cc(-c4ccc5c(c4)c4ccccc4n5-c4ccc(-c5cc(-c6ccccc6)nc(-c6ccccc6)n5)cc4)ccc32)cc1 ; CC(C)(C)c1ccc(-n2c3ccccc3c3cc(-c4ccc5c(c4)c4ccccc4n5-c4ccc(-c5cc(-c6ccccc6)nc(-c6ccccc6)n5)cc4)ccc32)cc1 ; CCC(C)c1ccc(-c2cc(-c3ccc(-n4c5ccccc5c5cc(-c6ccc7c(c6)c6ccccc6n7-c6ccccc6)ccc54)cc3)nc(-c3ccccc3)n2)cc1]

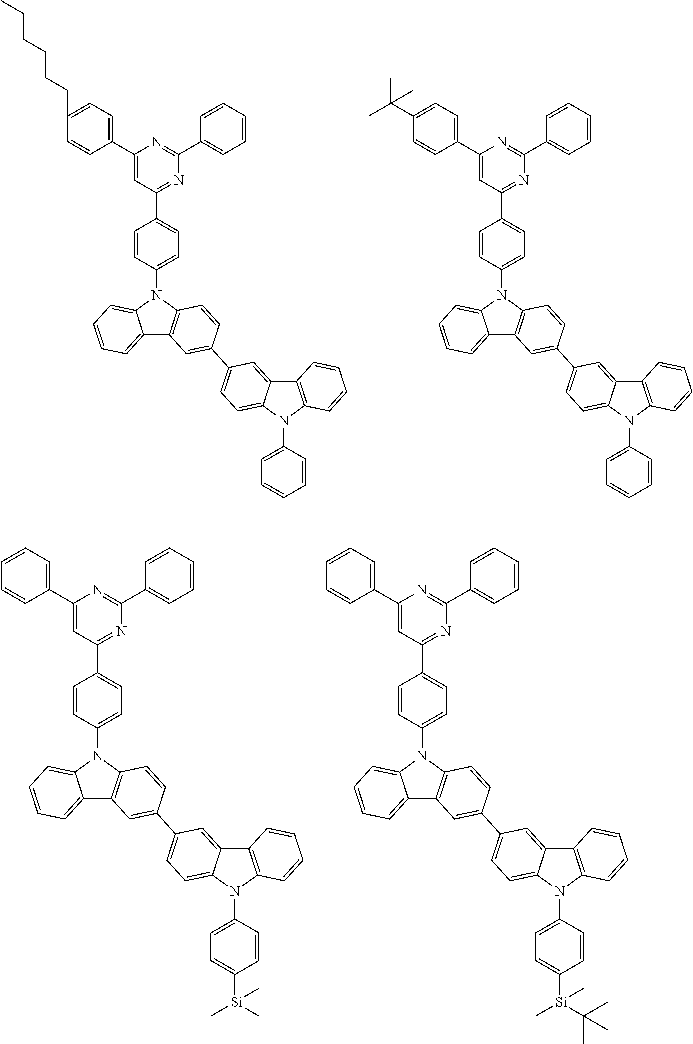 [SMILES: CCCCCCc1ccc(-c2cc(-c3ccc(-n4c5ccccc5c5cc(-c6ccc7c(c6)c6ccccc6n7-c6ccccc6)ccc54)cc3)nc(-c3ccccc3)n2)cc1 ; CC(C)(C)c1ccc(-c2cc(-c3ccc(-n4c5ccccc5c5cc(-c6ccc7c(c6)c6ccccc6n7-c6ccccc6)ccc54)cc3)nc(-c3ccccc3)n2)cc1 ; C[Si](C)(C)c1ccc(-n2c3ccccc3c3cc(-c4ccc5c(c4)c4ccccc4n5-c4ccc(-c5cc(-c6ccccc6)nc(-c6ccccc6)n5)cc4)ccc32)cc1 ; CC(C)(C)[Si](C)(C)c1ccc(-n2c3ccccc3c3cc(-c4ccc5c(c4)c4ccccc4n5-c4ccc(-c5cc(-c6ccccc6)nc(-c6ccccc6)n5)cc4)ccc32)cc1]

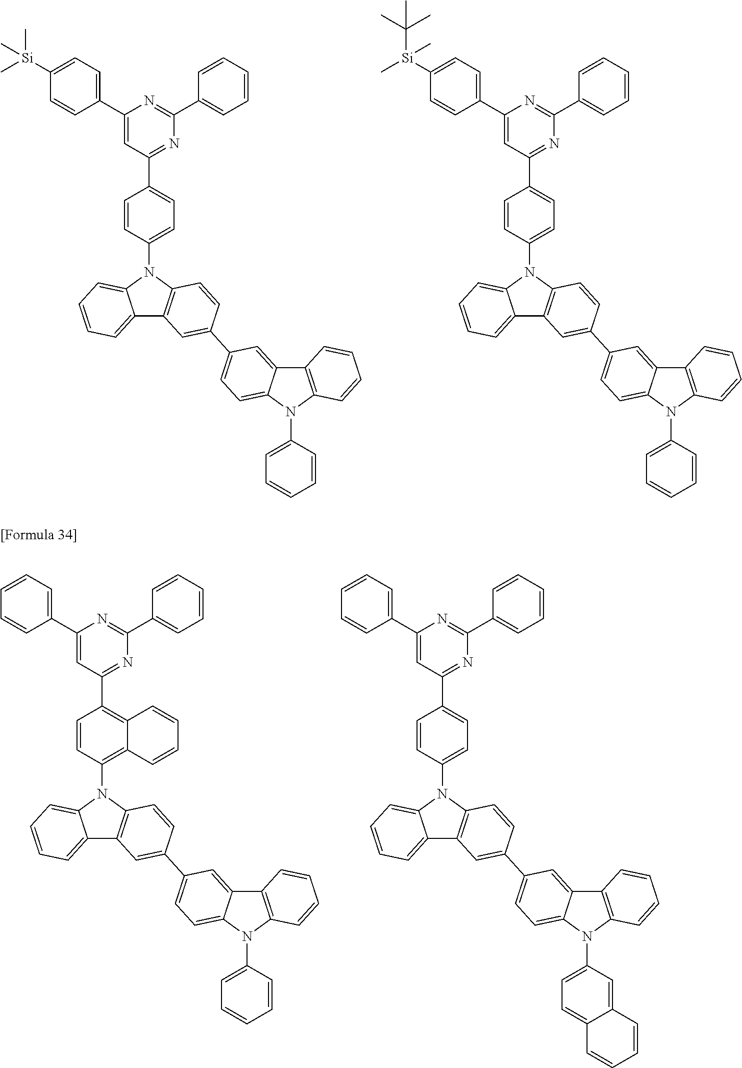 [SMILES: C[Si](C)(C)c1ccc(-c2cc(-c3ccc(-n4c5ccccc5c5cc(-c6ccc7c(c6)c6ccccc6n7-c6ccccc6)ccc54)cc3)nc(-c3ccccc3)n2)cc1 ; CC(C)(C)[Si](C)(C)c1ccc(-c2cc(-c3ccc(-n4c5ccccc5c5cc(-c6ccc7c(c6)c6ccccc6n7-c6ccccc6)ccc54)cc3)nc(-c3ccccc3)n2)cc1 ; c1ccc(-c2cc(-c3ccc(-n4c5ccccc5c5cc(-c6ccc7c(c6)c6ccccc6n7-c6ccccc6)ccc54)c4ccccc34)nc(-c3ccccc3)n2)cc1 ; c1ccc(-c2cc(-c3ccc(-n4c5ccccc5c5cc(-c6ccc7c(c6)c6ccccc6n7-c6ccc7ccccc7c6)ccc54)cc3)nc(-c3ccccc3)n2)cc1]

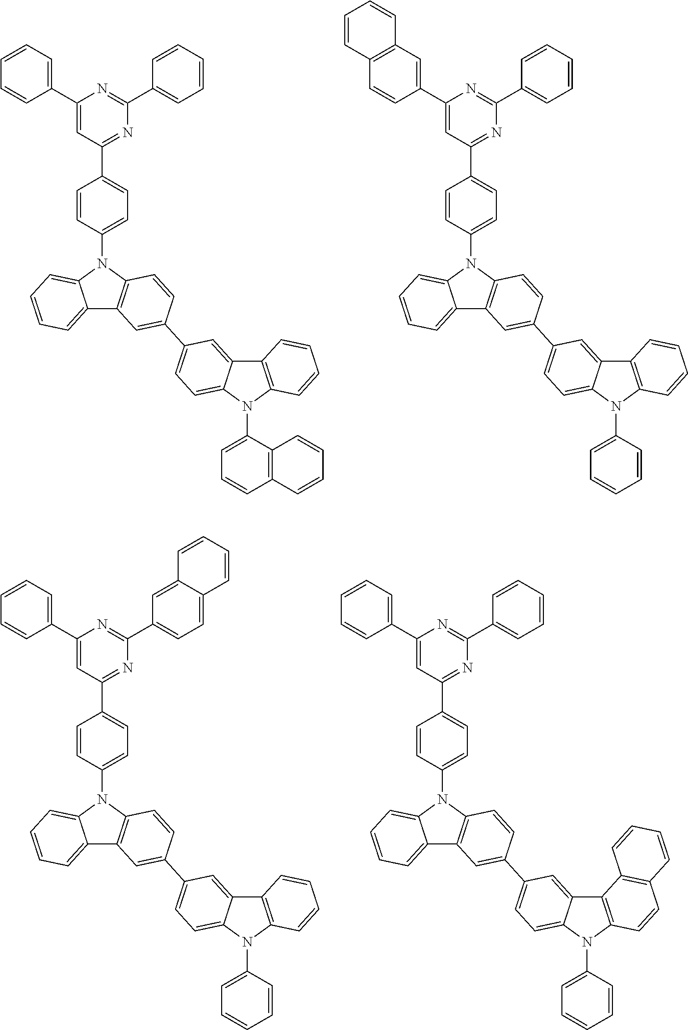 [SMILES: c1ccc(-c2cc(-c3ccc(-n4c5ccccc5c5cc(-c6ccc7c(c6)c6ccccc6n7-c6cccc7ccccc67)ccc54)cc3)nc(-c3ccccc3)n2)cc1 ; c1ccc(-c2nc(-c3ccc(-n4c5ccccc5c5cc(-c6ccc7c(c6)c6ccccc6n7-c6ccccc6)ccc54)cc3)cc(-c3ccc4ccccc4c3)n2)cc1 ; c1ccc(-c2cc(-c3ccc(-n4c5ccccc5c5cc(-c6ccc7c(c6)c6ccccc6n7-c6ccccc6)ccc54)cc3)nc(-c3ccc4ccccc4c3)n2)cc1 ; c1ccc(-c2cc(-c3ccc(-n4c5ccccc5c5cc(-c6ccc7c(c6)c6c8ccccc8ccc6n7-c6ccccc6)ccc54)cc3)nc(-c3ccccc3)n2)cc1]

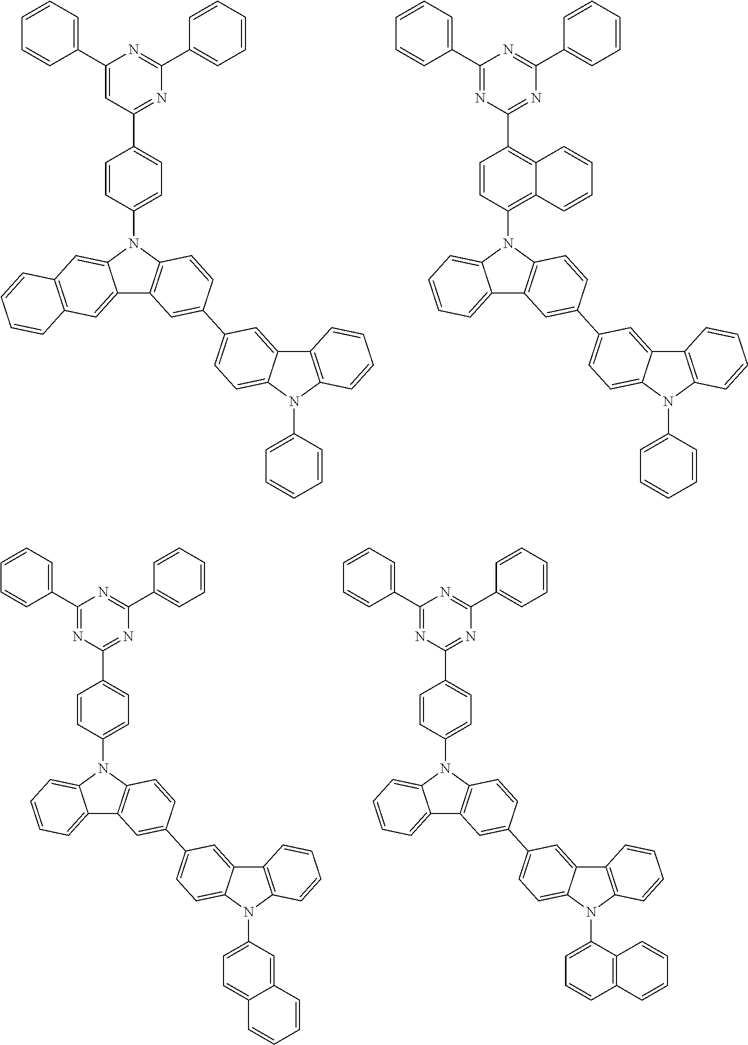 [SMILES: c1ccc(-c2cc(-c3ccc(-n4c5ccc(-c6ccc7c(c6)c6ccccc6n7-c6ccccc6)cc5c5cc6ccccc6cc54)cc3)nc(-c3ccccc3)n2)cc1 ; c1ccc(-c2nc(-c3ccccc3)nc(-c3ccc(-n4c5ccccc5c5cc(-c6ccc7c(c6)c6ccccc6n7-c6ccccc6)ccc54)c4ccccc34)n2)cc1 ; c1ccc(-c2nc(-c3ccccc3)nc(-c3ccc(-n4c5ccccc5c5cc(-c6ccc7c(c6)c6ccccc6n7-c6ccc7ccccc7c6)ccc54)cc3)n2)cc1 ; c1ccc(-c2nc(-c3ccccc3)nc(-c3ccc(-n4c5ccccc5c5cc(-c6ccc7c(c6)c6ccccc6n7-c6cccc7ccccc67)ccc54)cc3)n2)cc1]

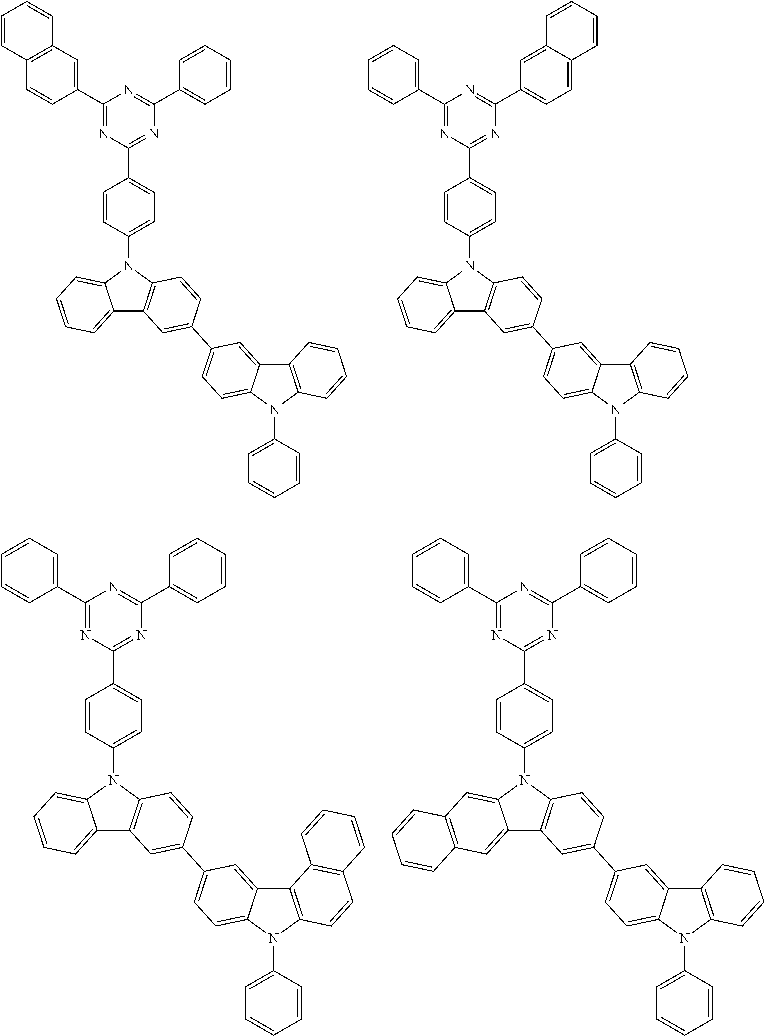

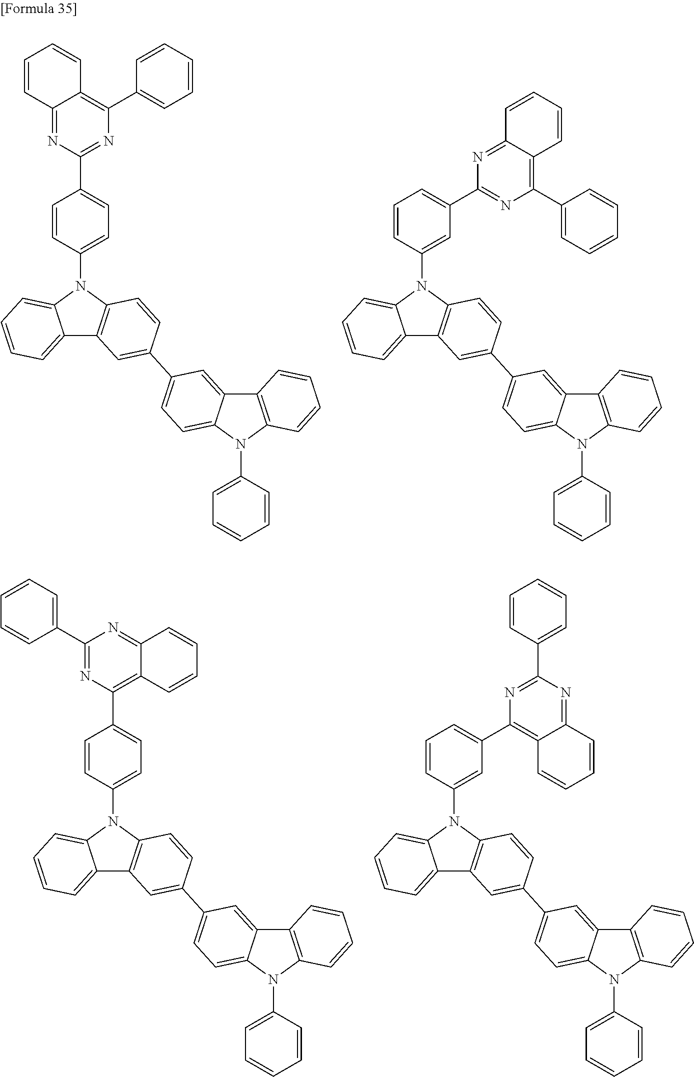 [SMILES: c1ccc(-c2nc(-c3ccc(-n4c5ccccc5c5cc(-c6ccc7c(c6)c6ccccc6n7-c6ccccc6)ccc54)cc3)nc3ccccc23)cc1 ; c1ccc(-c2nc(-c3cccc(-n4c5ccccc5c5cc(-c6ccc7c(c6)c6ccccc6n7-c6ccccc6)ccc54)c3)nc3ccccc23)cc1 ; c1ccc(-c2nc(-c3ccc(-n4c5ccccc5c5cc(-c6ccc7c(c6)c6ccccc6n7-c6ccccc6)ccc54)cc3)c3ccccc3n2)cc1 ; c1ccc(-c2nc(-c3cccc(-n4c5ccccc5c5cc(-c6ccc7c(c6)c6ccccc6n7-c6ccccc6)ccc54)c3)c3ccccc3n2)cc1]

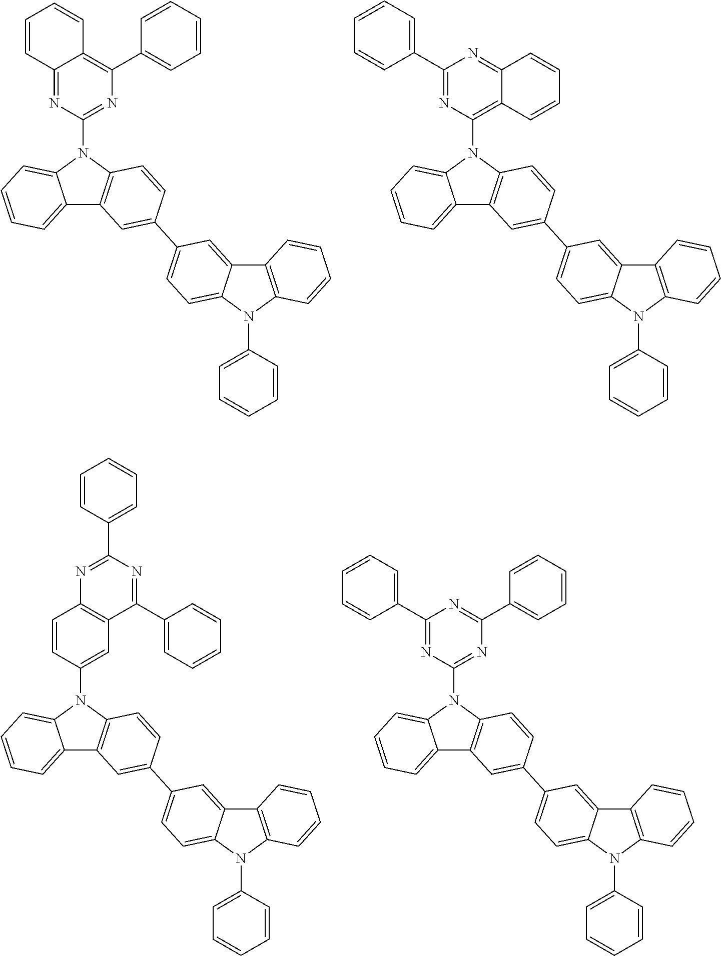 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-c2nc(-n3c4ccccc4c4cc(-c5ccc6c(c5)c5ccccc5n6-c5ccccc5)ccc43)c3ccccc3n2)cc1 ; c1ccc(-c2nc(-c3ccccc3)c3cc(-n4c5ccccc5c5cc(-c6ccc7c(c6)c6ccccc6n7-c6ccccc6)ccc54)ccc3n2)cc1 ; c1ccc(-c2nc(-c3ccccc3)nc(-n3c4ccccc4c4cc(-c5ccc6c(c5)c5ccccc5n6-c5ccccc5)ccc43)n2)cc1]

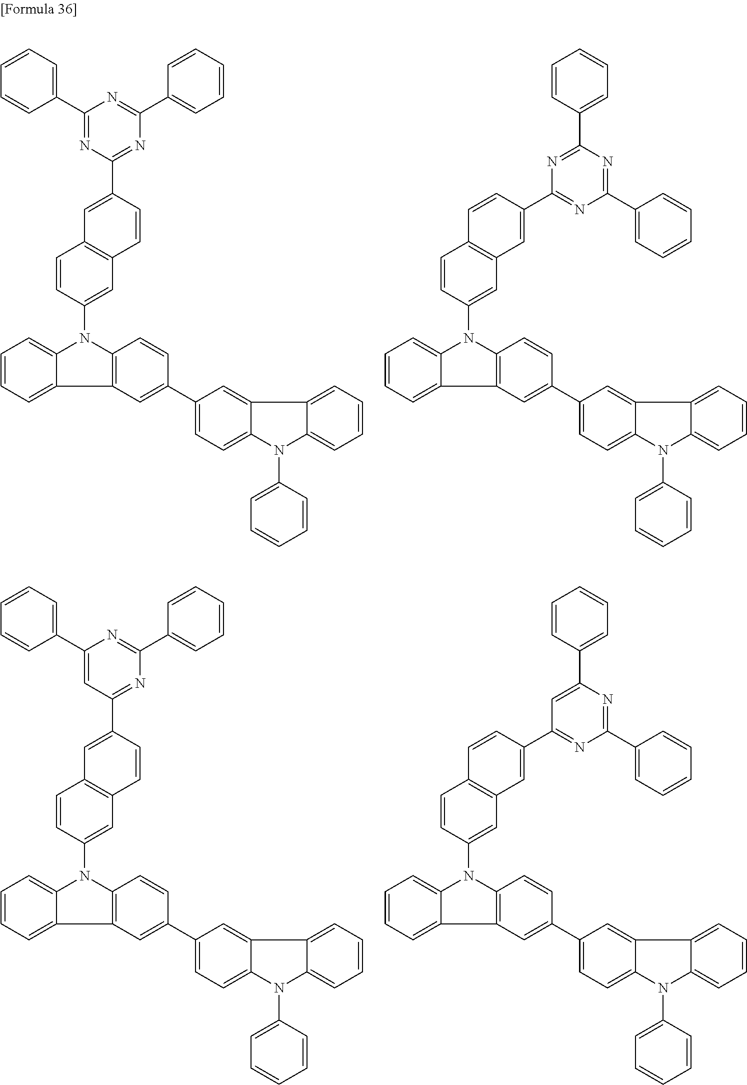

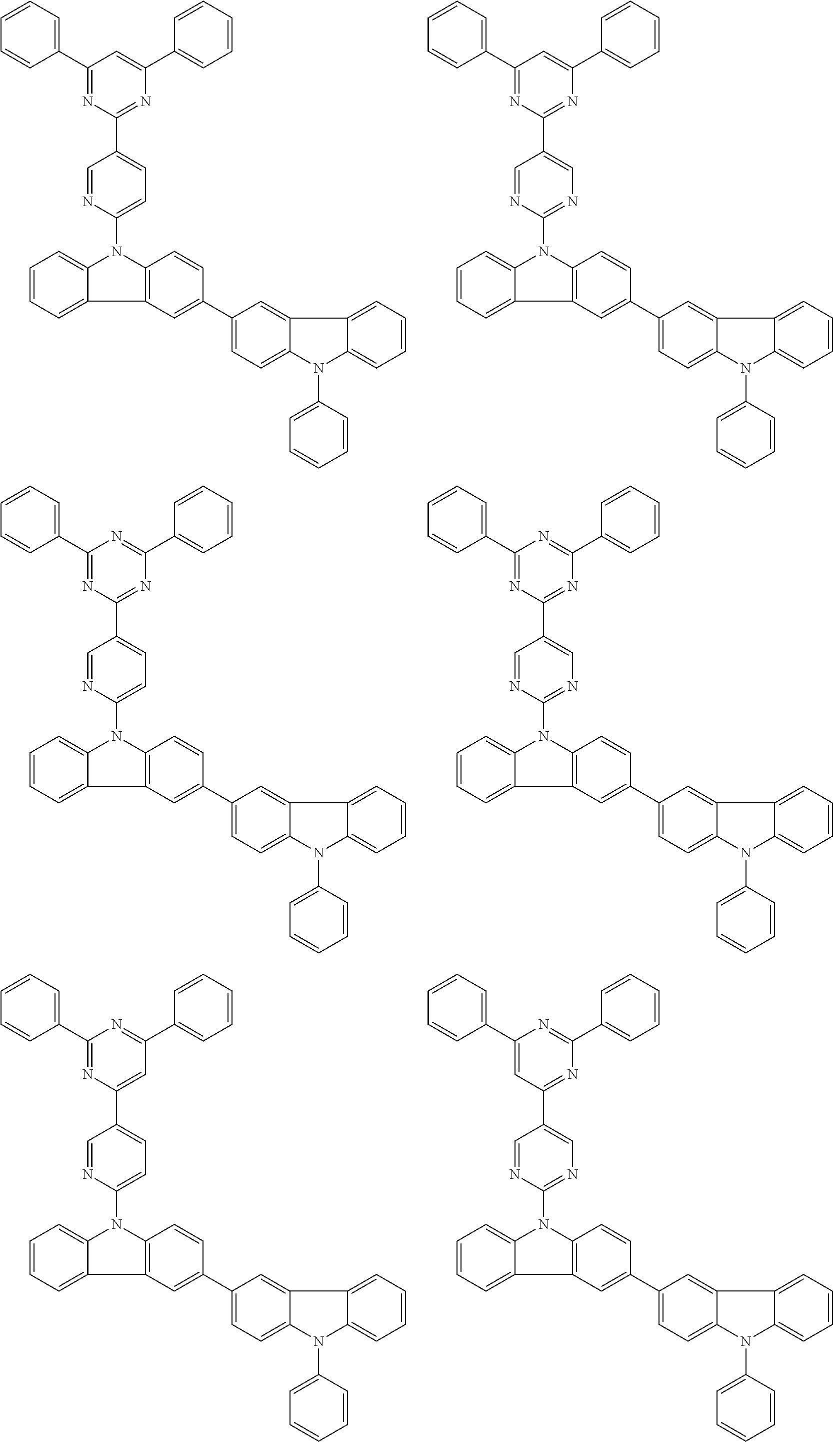

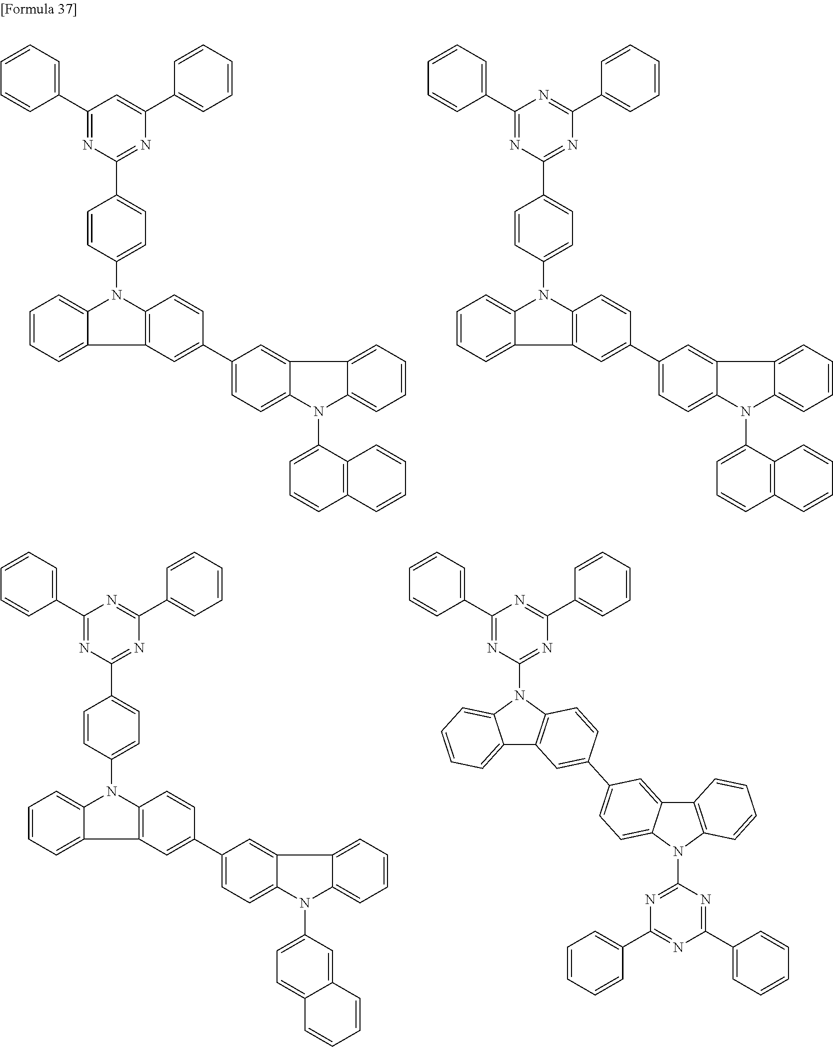 [SMILES: c1ccc(-c2cc(-c3ccccc3)nc(-c3ccc(-n4c5ccccc5c5cc(-c6ccc7c(c6)c6ccccc6n7-c6cccc7ccccc67)ccc54)cc3)n2)cc1 ; c1ccc(-c2nc(-c3ccccc3)nc(-c3ccc(-n4c5ccccc5c5cc(-c6ccc7c(c6)c6ccccc6n7-c6cccc7ccccc67)ccc54)cc3)n2)cc1 ; c1ccc(-c2nc(-c3ccccc3)nc(-c3ccc(-n4c5ccccc5c5cc(-c6ccc7c(c6)c6ccccc6n7-c6ccc7ccccc7c6)ccc54)cc3)n2)cc1 ; c1ccc(-c2nc(-c3ccccc3)nc(-n3c4ccccc4c4cc(-c5ccc6c(c5)c5ccccc5n6-c5nc(-c6ccccc6)nc(-c6ccccc6)n5)ccc43)n2)cc1]

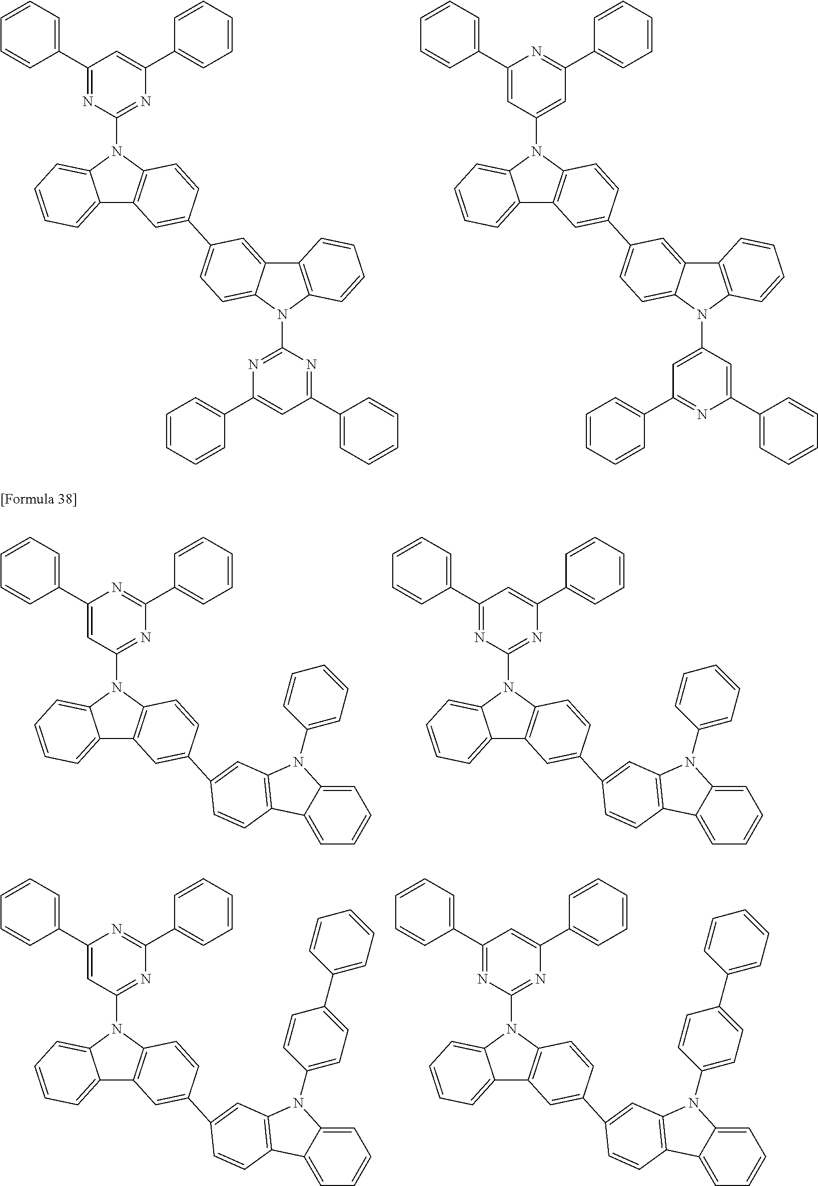

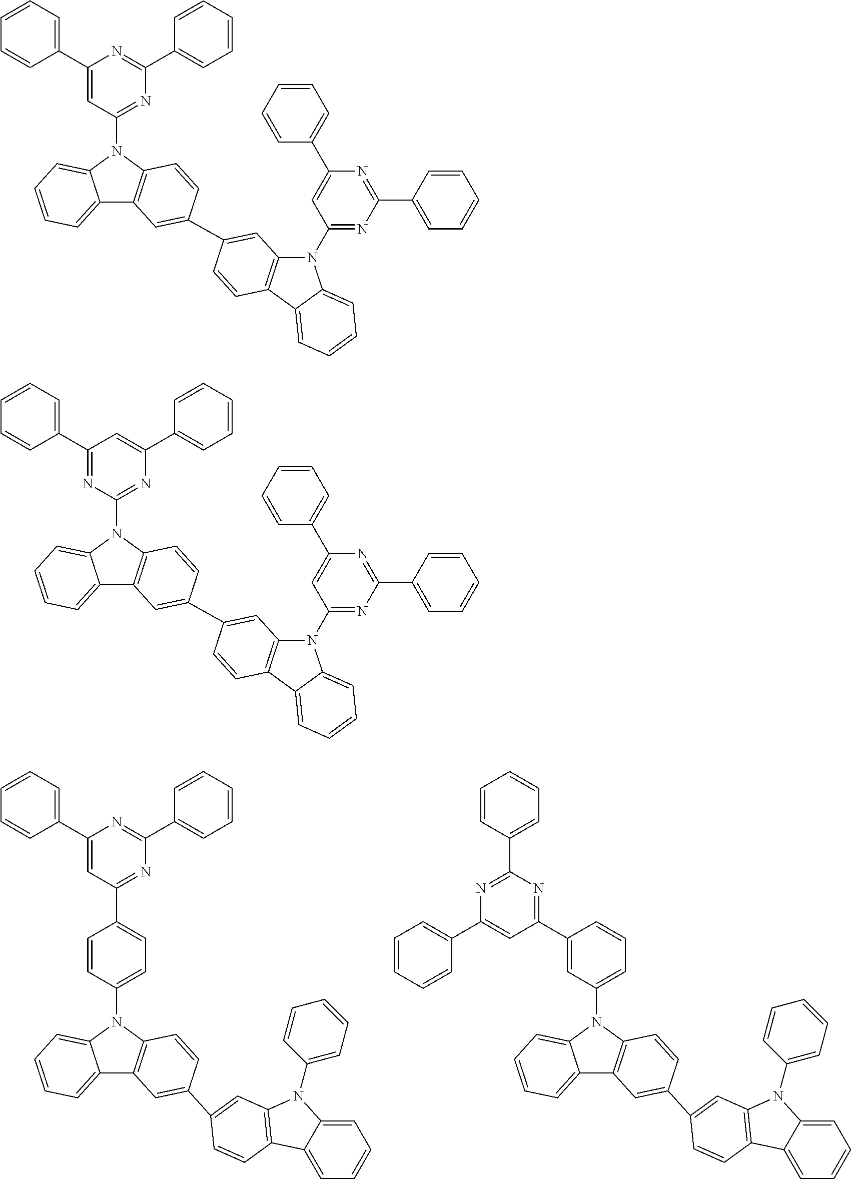 [SMILES: c1ccc(-c2cc(-n3c4ccccc4c4cc(-c5ccc6c7ccccc7n(-c7cc(-c8ccccc8)nc(-c8ccccc8)n7)c6c5)ccc43)nc(-c3ccccc3)n2)cc1 ; c1ccc(-c2cc(-n3c4ccccc4c4ccc(-c5ccc6c(c5)c5ccccc5n6-c5nc(-c6ccccc6)cc(-c6ccccc6)n5)cc43)nc(-c3ccccc3)n2)cc1 ; c1ccc(-c2cc(-c3ccc(-n4c5ccccc5c5cc(-c6ccc7c8ccccc8n(-c8ccccc8)c7c6)ccc54)cc3)nc(-c3ccccc3)n2)cc1 ; c1ccc(-c2cc(-c3cccc(-n4c5ccccc5c5cc(-c6ccc7c8ccccc8n(-c8ccccc8)c7c6)ccc54)c3)nc(-c3ccccc3)n2)cc1]

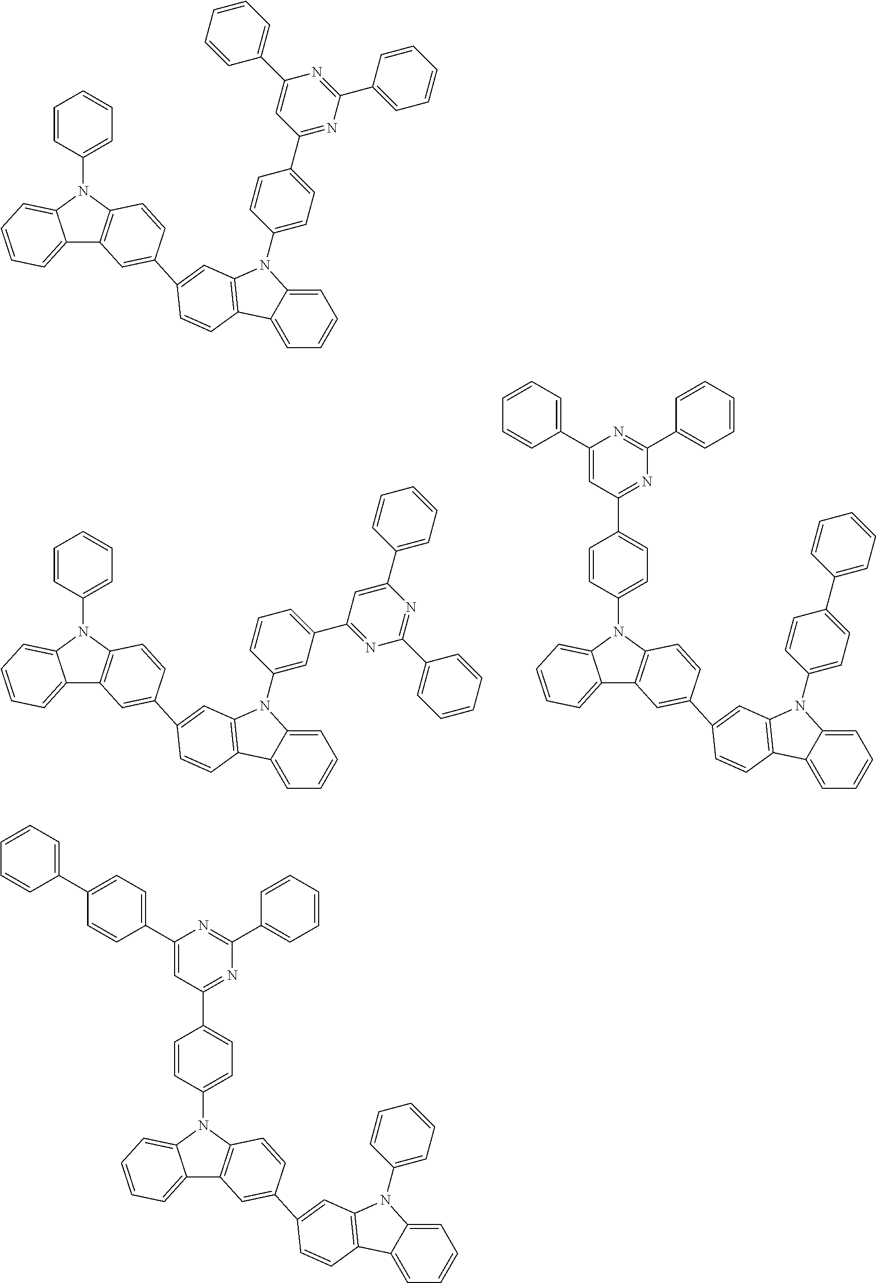 [SMILES: c1ccc(-c2cc(-c3ccc(-n4c5ccccc5c5ccc(-c6ccc7c(c6)c6ccccc6n7-c6ccccc6)cc54)cc3)nc(-c3ccccc3)n2)cc1 ; c1ccc(-c2cc(-c3cccc(-n4c5ccccc5c5ccc(-c6ccc7c(c6)c6ccccc6n7-c6ccccc6)cc54)c3)nc(-c3ccccc3)n2)cc1 ; c1ccc(-c2ccc(-n3c4ccccc4c4ccc(-c5ccc6c(c5)c5ccccc5n6-c5ccc(-c6cc(-c7ccccc7)nc(-c7ccccc7)n6)cc5)cc43)cc2)cc1 ; c1ccc(-c2ccc(-c3cc(-c4ccc(-n5c6ccccc6c6cc(-c7ccc8c9ccccc9n(-c9ccccc9)c8c7)ccc65)cc4)nc(-c4ccccc4)n3)cc2)cc1]

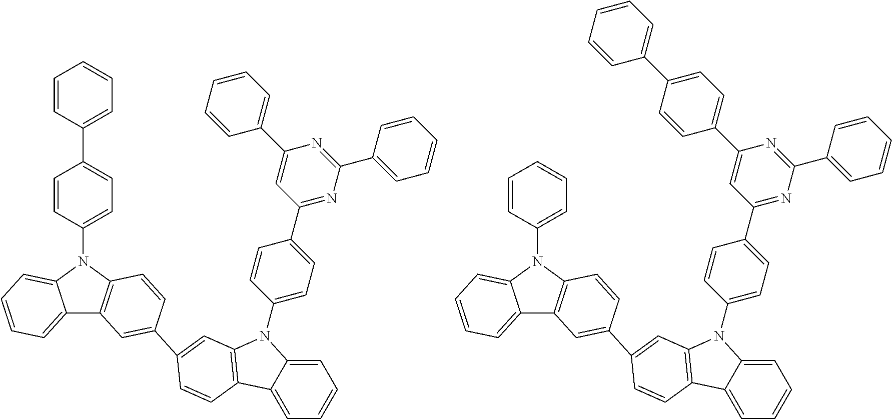 [SMILES: c1ccc(-c2ccc(-n3c4ccccc4c4cc(-c5ccc6c7ccccc7n(-c7ccc(-c8cc(-c9ccccc9)nc(-c9ccccc9)n8)cc7)c6c5)ccc43)cc2)cc1 ; c1ccc(-c2ccc(-c3cc(-c4ccc(-n5c6ccccc6c6ccc(-c7ccc8c(c7)c7ccccc7n8-c7ccccc7)cc65)cc4)nc(-c4ccccc4)n3)cc2)cc1]

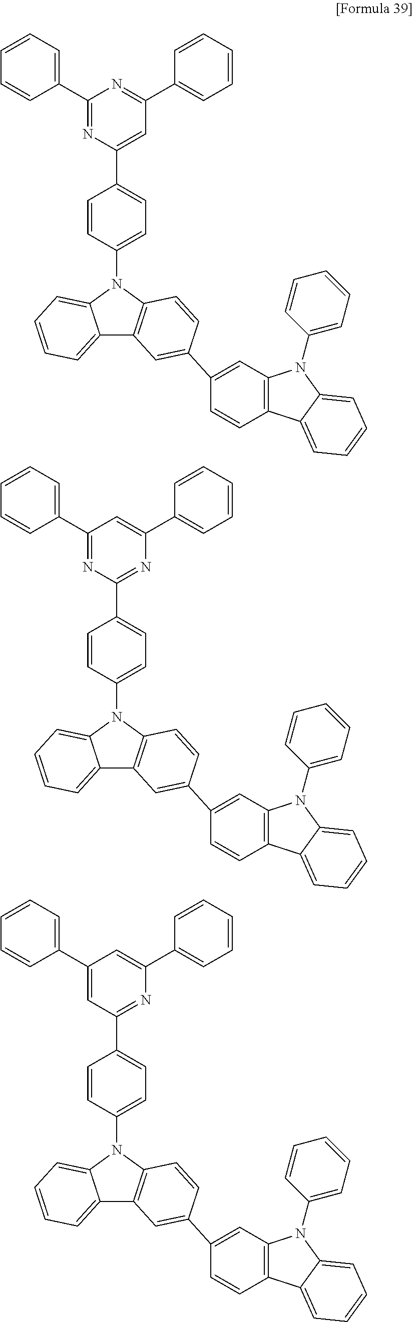 [SMILES: c1ccc(-c2cc(-c3ccc(-n4c5ccccc5c5cc(-c6ccc7c8ccccc8n(-c8ccccc8)c7c6)ccc54)cc3)nc(-c3ccccc3)n2)cc1 ; c1ccc(-c2cc(-c3ccccc3)nc(-c3ccc(-n4c5ccccc5c5cc(-c6ccc7c8ccccc8n(-c8ccccc8)c7c6)ccc54)cc3)n2)cc1 ; c1ccc(-c2cc(-c3ccccc3)nc(-c3ccc(-n4c5ccccc5c5cc(-c6ccc7c8ccccc8n(-c8ccccc8)c7c6)ccc54)cc3)c2)cc1]

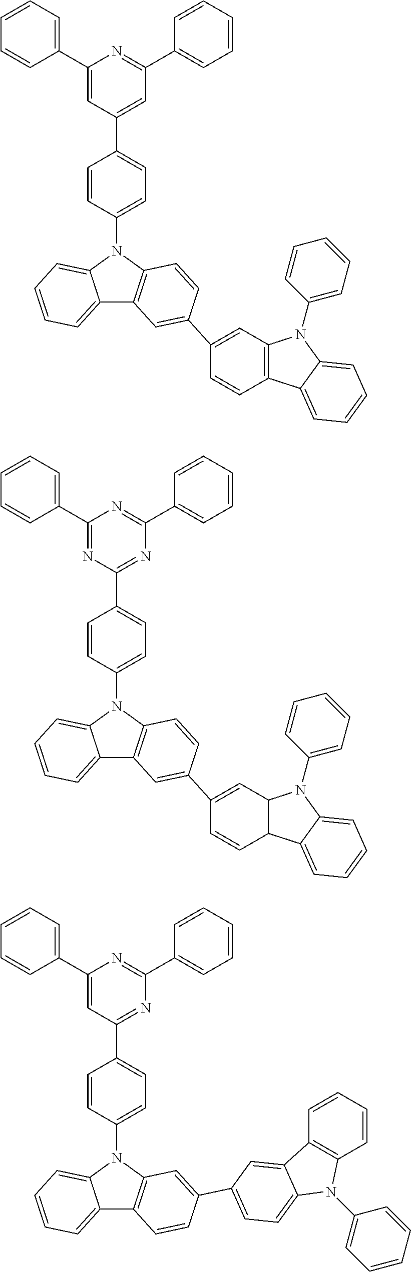 [SMILES: c1ccc(-c2cc(-c3ccc(-n4c5ccccc5c5cc(-c6ccc7c8ccccc8n(-c8ccccc8)c7c6)ccc54)cc3)cc(-c3ccccc3)n2)cc1 ; C1=CC2c3ccccc3N(c3ccccc3)C2C=C1c1ccc2c(c1)c1ccccc1n2-c1ccc(-c2nc(-c3ccccc3)nc(-c3ccccc3)n2)cc1 ; c1ccc(-c2cc(-c3ccc(-n4c5ccccc5c5ccc(-c6ccc7c(c6)c6ccccc6n7-c6ccccc6)cc54)cc3)nc(-c3ccccc3)n2)cc1]

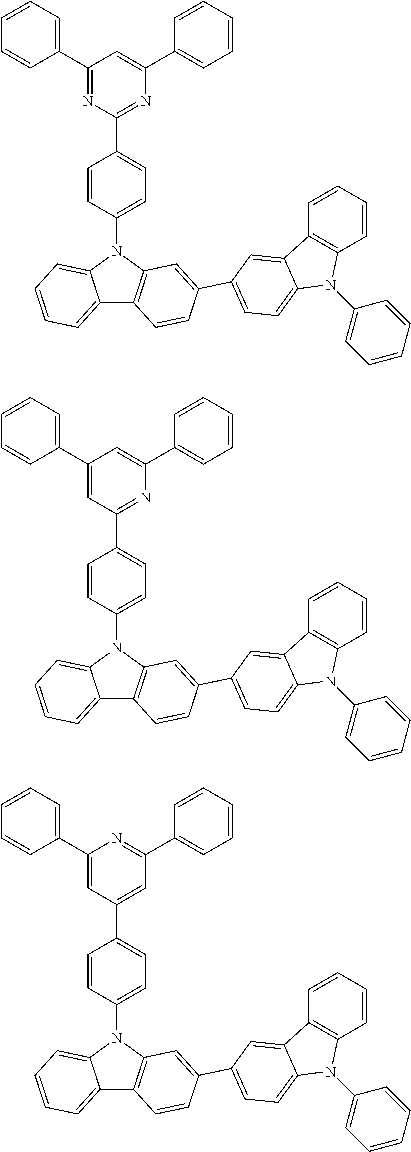 [SMILES: c1ccc(-c2cc(-c3ccccc3)nc(-c3ccc(-n4c5ccccc5c5ccc(-c6ccc7c(c6)c6ccccc6n7-c6ccccc6)cc54)cc3)n2)cc1 ; c1ccc(-c2cc(-c3ccccc3)nc(-c3ccc(-n4c5ccccc5c5ccc(-c6ccc7c(c6)c6ccccc6n7-c6ccccc6)cc54)cc3)c2)cc1 ; c1ccc(-c2cc(-c3ccc(-n4c5ccccc5c5ccc(-c6ccc7c(c6)c6ccccc6n7-c6ccccc6)cc54)cc3)cc(-c3ccccc3)n2)cc1]

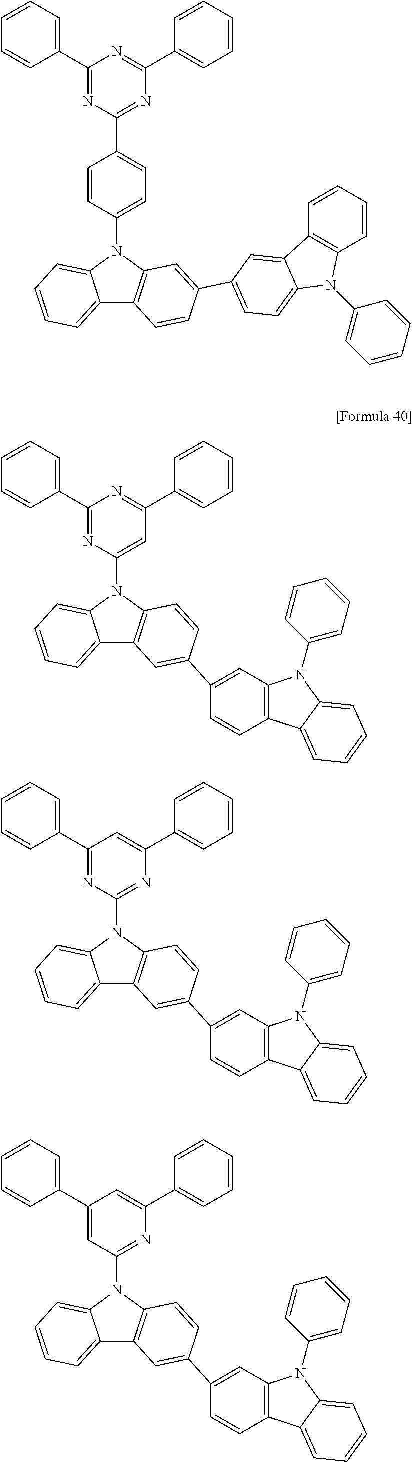 [SMILES: c1ccc(-c2nc(-c3ccccc3)nc(-c3ccc(-n4c5ccccc5c5ccc(-c6ccc7c(c6)c6ccccc6n7-c6ccccc6)cc54)cc3)n2)cc1 ; c1ccc(-c2cc(-n3c4ccccc4c4cc(-c5ccc6c7ccccc7n(-c7ccccc7)c6c5)ccc43)nc(-c3ccccc3)n2)cc1 ; c1ccc(-c2cc(-c3ccccc3)nc(-n3c4ccccc4c4cc(-c5ccc6c7ccccc7n(-c7ccccc7)c6c5)ccc43)n2)cc1 ; c1ccc(-c2cc(-c3ccccc3)nc(-n3c4ccccc4c4cc(-c5ccc6c7ccccc7n(-c7ccccc7)c6c5)ccc43)c2)cc1]

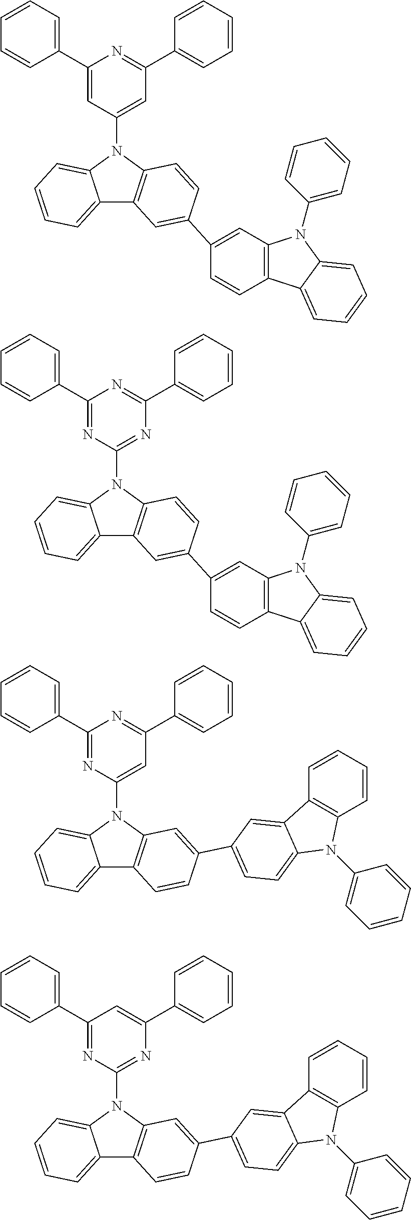 [SMILES: c1ccc(-c2cc(-n3c4ccccc4c4cc(-c5ccc6c7ccccc7n(-c7ccccc7)c6c5)ccc43)cc(-c3ccccc3)n2)cc1 ; c1ccc(-c2nc(-c3ccccc3)nc(-n3c4ccccc4c4cc(-c5ccc6c7ccccc7n(-c7ccccc7)c6c5)ccc43)n2)cc1 ; c1ccc(-c2cc(-n3c4ccccc4c4ccc(-c5ccc6c(c5)c5ccccc5n6-c5ccccc5)cc43)nc(-c3ccccc3)n2)cc1 ; c1ccc(-c2cc(-c3ccccc3)nc(-n3c4ccccc4c4ccc(-c5ccc6c(c5)c5ccccc5n6-c5ccccc5)cc43)n2)cc1]

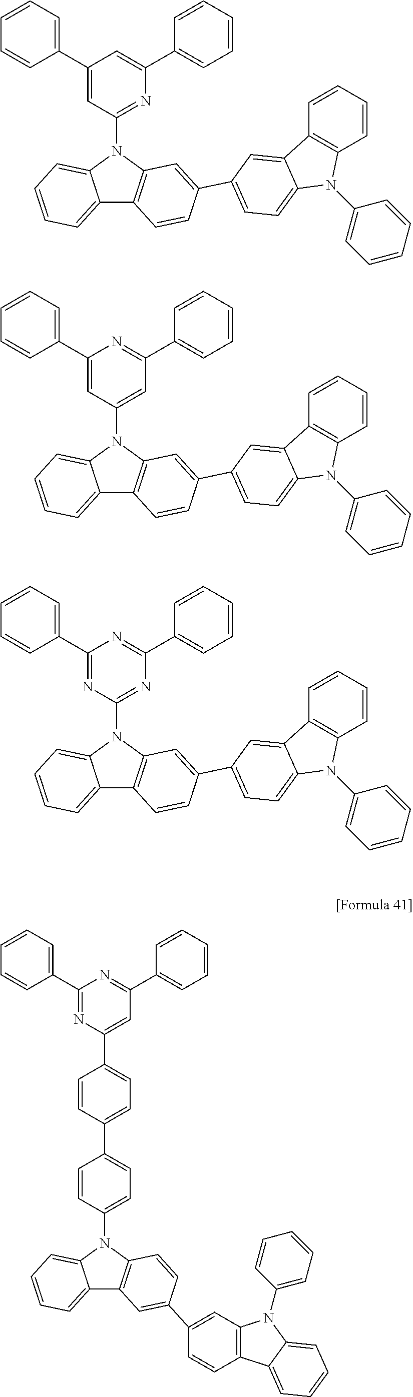 [SMILES: c1ccc(-c2cc(-c3ccccc3)nc(-n3c4ccccc4c4ccc(-c5ccc6c(c5)c5ccccc5n6-c5ccccc5)cc43)c2)cc1 ; c1ccc(-c2cc(-n3c4ccccc4c4ccc(-c5ccc6c(c5)c5ccccc5n6-c5ccccc5)cc43)cc(-c3ccccc3)n2)cc1 ; c1ccc(-c2nc(-c3ccccc3)nc(-n3c4ccccc4c4ccc(-c5ccc6c(c5)c5ccccc5n6-c5ccccc5)cc43)n2)cc1 ; c1ccc(-c2cc(-c3ccc(-c4ccc(-n5c6ccccc6c6cc(-c7ccc8c9ccccc9n(-c9ccccc9)c8c7)ccc65)cc4)cc3)nc(-c3ccccc3)n2)cc1]

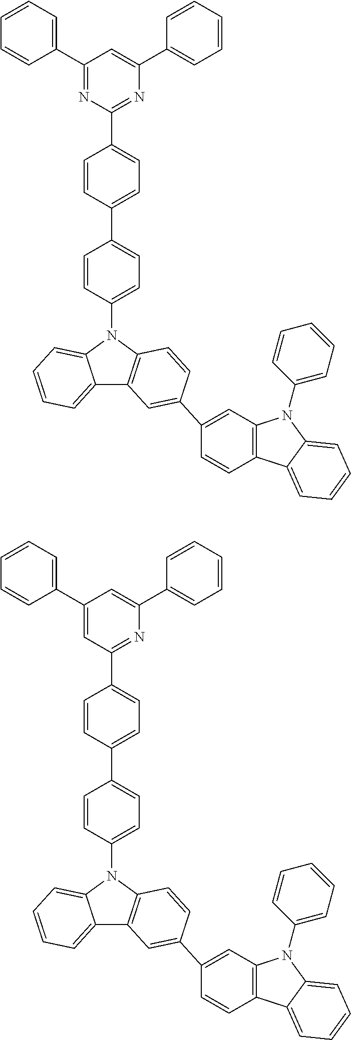 [SMILES: c1ccc(-c2cc(-c3ccccc3)nc(-c3ccc(-c4ccc(-n5c6ccccc6c6cc(-c7ccc8c9ccccc9n(-c9ccccc9)c8c7)ccc65)cc4)cc3)n2)cc1 ; c1ccc(-c2cc(-c3ccccc3)nc(-c3ccc(-c4ccc(-n5c6ccccc6c6cc(-c7ccc8c9ccccc9n(-c9ccccc9)c8c7)ccc65)cc4)cc3)c2)cc1]

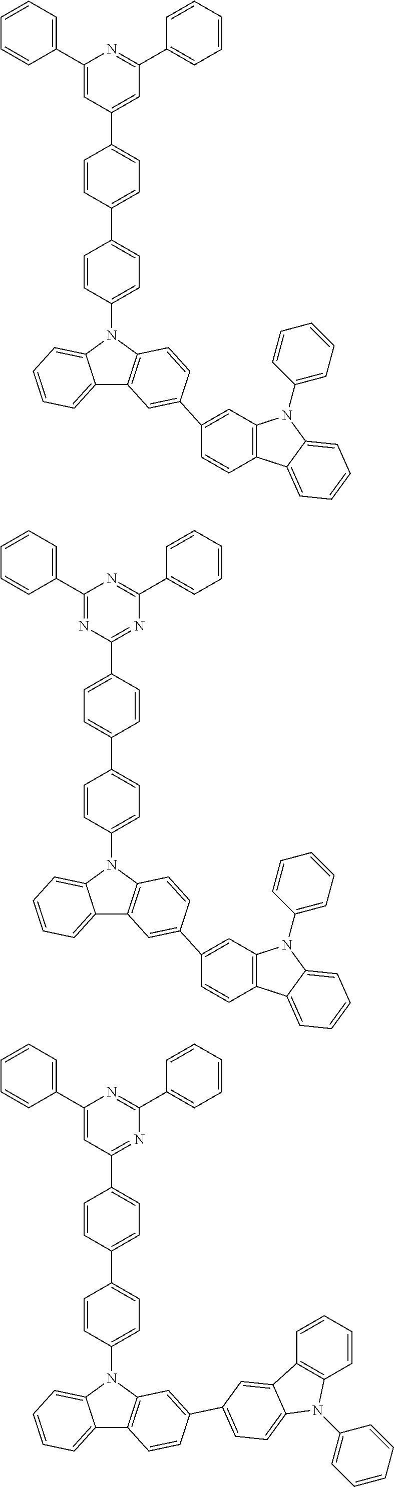 [SMILES: c1ccc(-c2cc(-c3ccc(-c4ccc(-n5c6ccccc6c6cc(-c7ccc8c9ccccc9n(-c9ccccc9)c8c7)ccc65)cc4)cc3)cc(-c3ccccc3)n2)cc1 ; c1ccc(-c2nc(-c3ccccc3)nc(-c3ccc(-c4ccc(-n5c6ccccc6c6cc(-c7ccc8c9ccccc9n(-c9ccccc9)c8c7)ccc65)cc4)cc3)n2)cc1 ; c1ccc(-c2cc(-c3ccc(-c4ccc(-n5c6ccccc6c6ccc(-c7ccc8c(c7)c7ccccc7n8-c7ccccc7)cc65)cc4)cc3)nc(-c3ccccc3)n2)cc1]

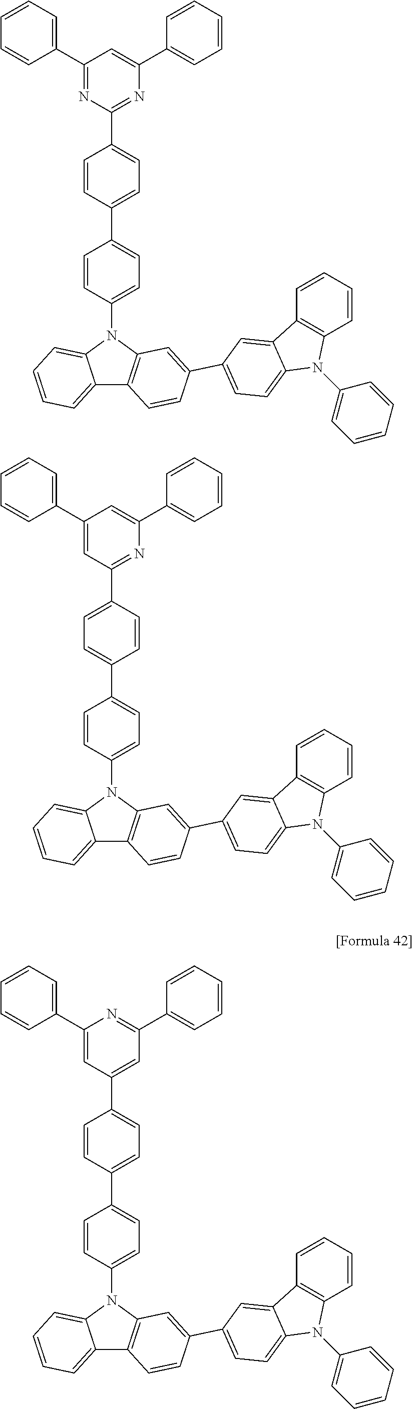 [SMILES: c1ccc(-c2cc(-c3ccccc3)nc(-c3ccc(-c4ccc(-n5c6ccccc6c6ccc(-c7ccc8c(c7)c7ccccc7n8-c7ccccc7)cc65)cc4)cc3)n2)cc1 ; c1ccc(-c2cc(-c3ccccc3)nc(-c3ccc(-c4ccc(-n5c6ccccc6c6ccc(-c7ccc8c(c7)c7ccccc7n8-c7ccccc7)cc65)cc4)cc3)c2)cc1 ; c1ccc(-c2cc(-c3ccc(-c4ccc(-n5c6ccccc6c6ccc(-c7ccc8c(c7)c7ccccc7n8-c7ccccc7)cc65)cc4)cc3)cc(-c3ccccc3)n2)cc1]

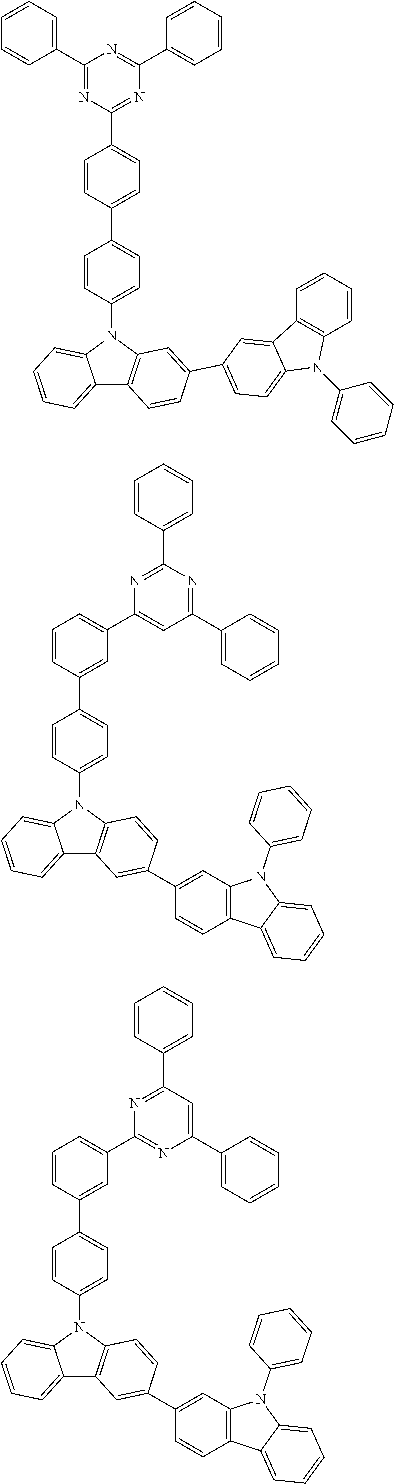 [SMILES: c1ccc(-c2nc(-c3ccccc3)nc(-c3ccc(-c4ccc(-n5c6ccccc6c6ccc(-c7ccc8c(c7)c7ccccc7n8-c7ccccc7)cc65)cc4)cc3)n2)cc1 ; c1ccc(-c2cc(-c3cccc(-c4ccc(-n5c6ccccc6c6cc(-c7ccc8c9ccccc9n(-c9ccccc9)c8c7)ccc65)cc4)c3)nc(-c3ccccc3)n2)cc1 ; c1ccc(-c2cc(-c3ccccc3)nc(-c3cccc(-c4ccc(-n5c6ccccc6c6cc(-c7ccc8c9ccccc9n(-c9ccccc9)c8c7)ccc65)cc4)c3)n2)cc1]

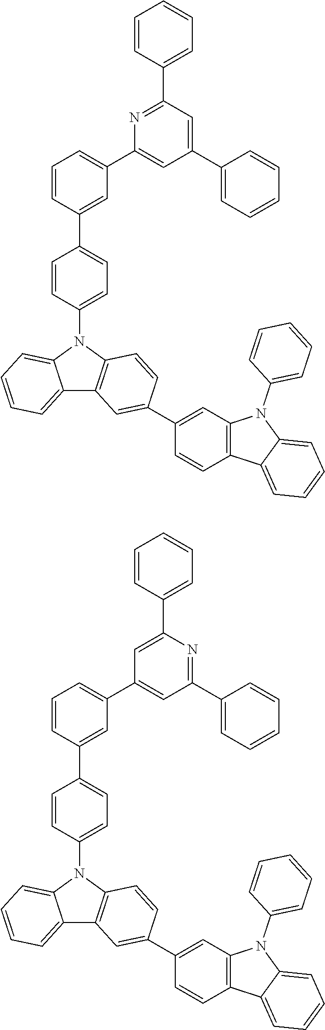 [SMILES: c1ccc(-c2cc(-c3ccccc3)nc(-c3cccc(-c4ccc(-n5c6ccccc6c6cc(-c7ccc8c9ccccc9n(-c9ccccc9)c8c7)ccc65)cc4)c3)c2)cc1 ; c1ccc(-c2cc(-c3cccc(-c4ccc(-n5c6ccccc6c6cc(-c7ccc8c9ccccc9n(-c9ccccc9)c8c7)ccc65)cc4)c3)cc(-c3ccccc3)n2)cc1]

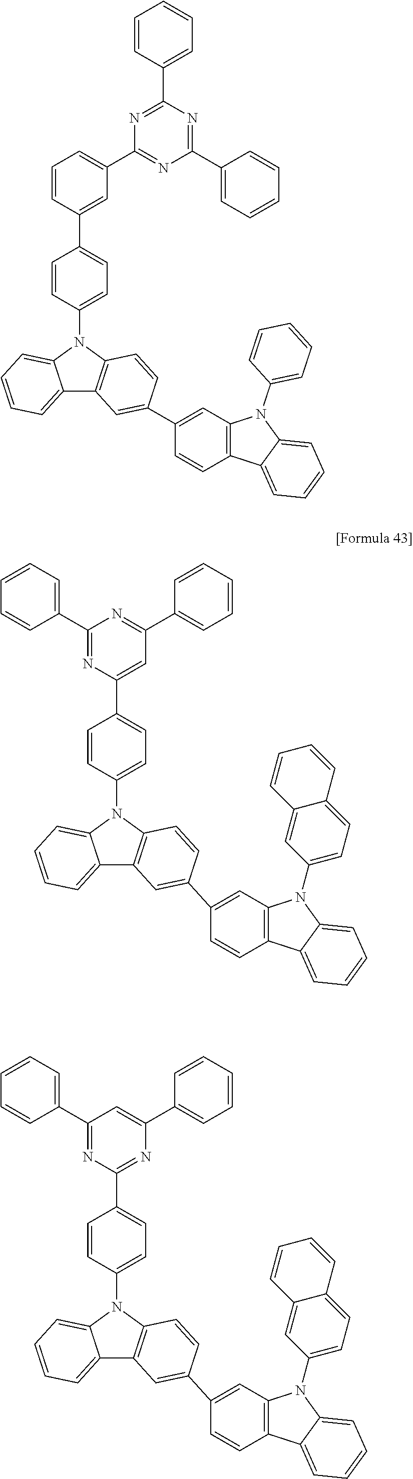 [SMILES: c1ccc(-c2nc(-c3ccccc3)nc(-c3cccc(-c4ccc(-n5c6ccccc6c6cc(-c7ccc8c9ccccc9n(-c9ccccc9)c8c7)ccc65)cc4)c3)n2)cc1 ; c1ccc(-c2cc(-c3ccc(-n4c5ccccc5c5cc(-c6ccc7c8ccccc8n(-c8ccc9ccccc9c8)c7c6)ccc54)cc3)nc(-c3ccccc3)n2)cc1 ; c1ccc(-c2cc(-c3ccccc3)nc(-c3ccc(-n4c5ccccc5c5cc(-c6ccc7c8ccccc8n(-c8ccc9ccccc9c8)c7c6)ccc54)cc3)n2)cc1]

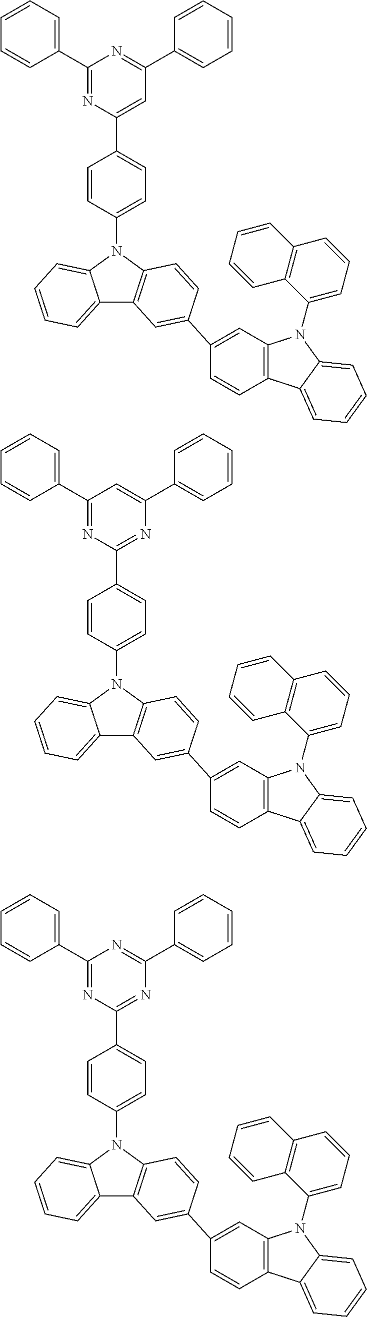 [SMILES: c1ccc(-c2cc(-c3ccc(-n4c5ccccc5c5cc(-c6ccc7c8ccccc8n(-c8cccc9ccccc89)c7c6)ccc54)cc3)nc(-c3ccccc3)n2)cc1 ; c1ccc(-c2cc(-c3ccccc3)nc(-c3ccc(-n4c5ccccc5c5cc(-c6ccc7c8ccccc8n(-c8cccc9ccccc89)c7c6)ccc54)cc3)n2)cc1 ; c1ccc(-c2nc(-c3ccccc3)nc(-c3ccc(-n4c5ccccc5c5cc(-c6ccc7c8ccccc8n(-c8cccc9ccccc89)c7c6)ccc54)cc3)n2)cc1]

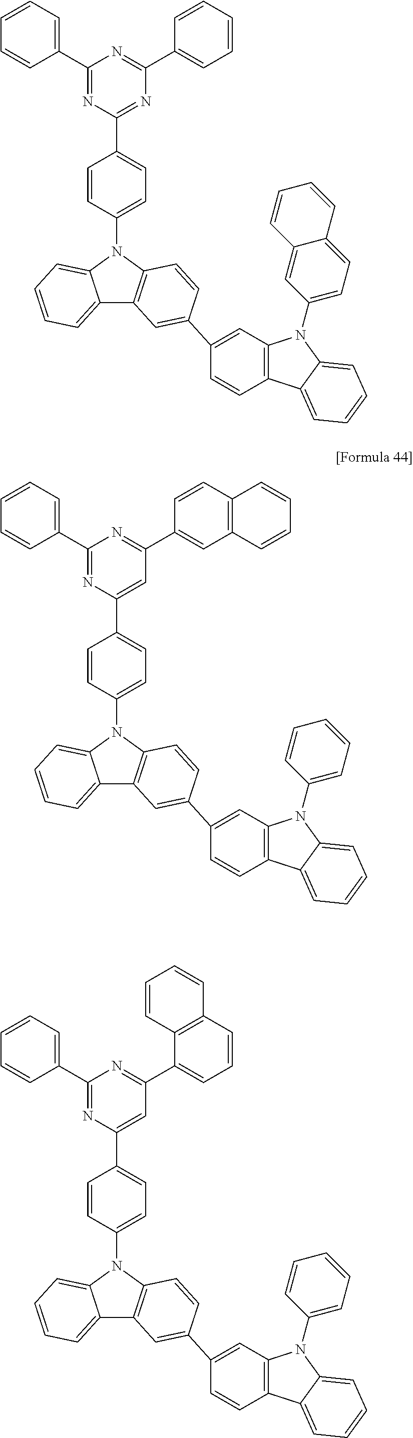 [SMILES: c1ccc(-c2nc(-c3ccccc3)nc(-c3ccc(-n4c5ccccc5c5cc(-c6ccc7c8ccccc8n(-c8ccc9ccccc9c8)c7c6)ccc54)cc3)n2)cc1 ; c1ccc(-c2nc(-c3ccc(-n4c5ccccc5c5cc(-c6ccc7c8ccccc8n(-c8ccccc8)c7c6)ccc54)cc3)cc(-c3ccc4ccccc4c3)n2)cc1 ; c1ccc(-c2nc(-c3ccc(-n4c5ccccc5c5cc(-c6ccc7c8ccccc8n(-c8ccccc8)c7c6)ccc54)cc3)cc(-c3cccc4ccccc34)n2)cc1]

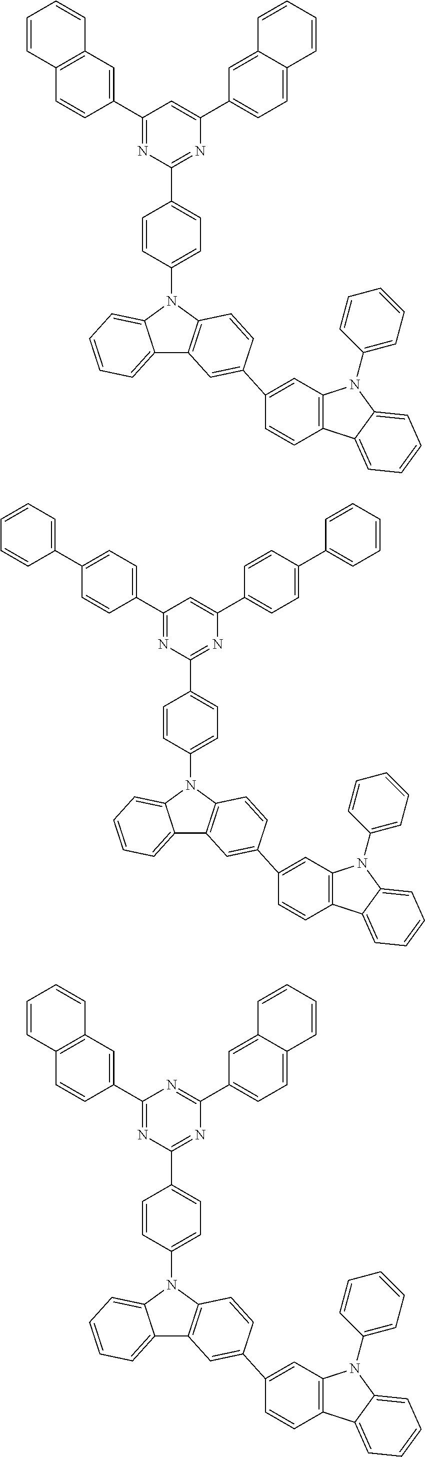

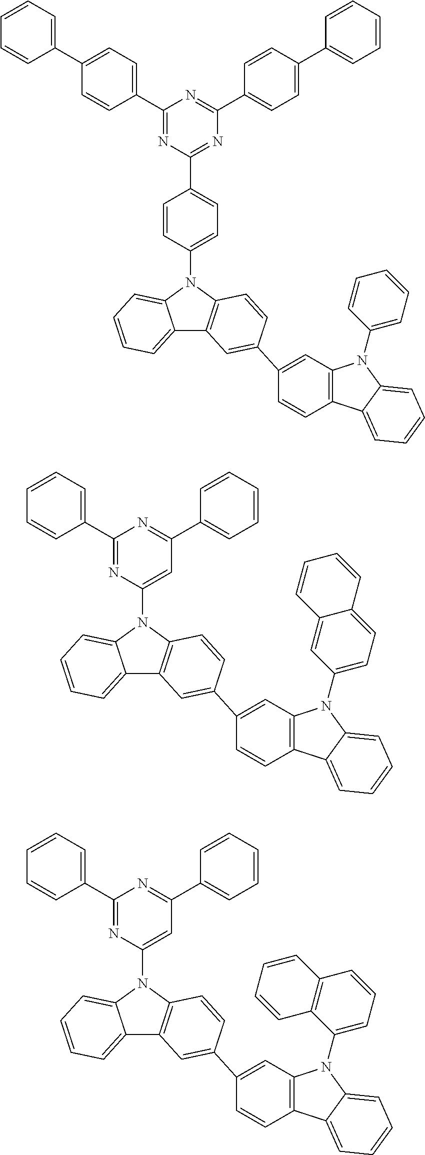 [SMILES: c1ccc(-c2ccc(-c3nc(-c4ccc(-c5ccccc5)cc4)nc(-c4ccc(-n5c6ccccc6c6cc(-c7ccc8c9ccccc9n(-c9ccccc9)c8c7)ccc65)cc4)n3)cc2)cc1 ; c1ccc(-c2cc(-n3c4ccccc4c4cc(-c5ccc6c7ccccc7n(-c7ccc8ccccc8c7)c6c5)ccc43)nc(-c3ccccc3)n2)cc1 ; c1ccc(-c2cc(-n3c4ccccc4c4cc(-c5ccc6c7ccccc7n(-c7cccc8ccccc78)c6c5)ccc43)nc(-c3ccccc3)n2)cc1]

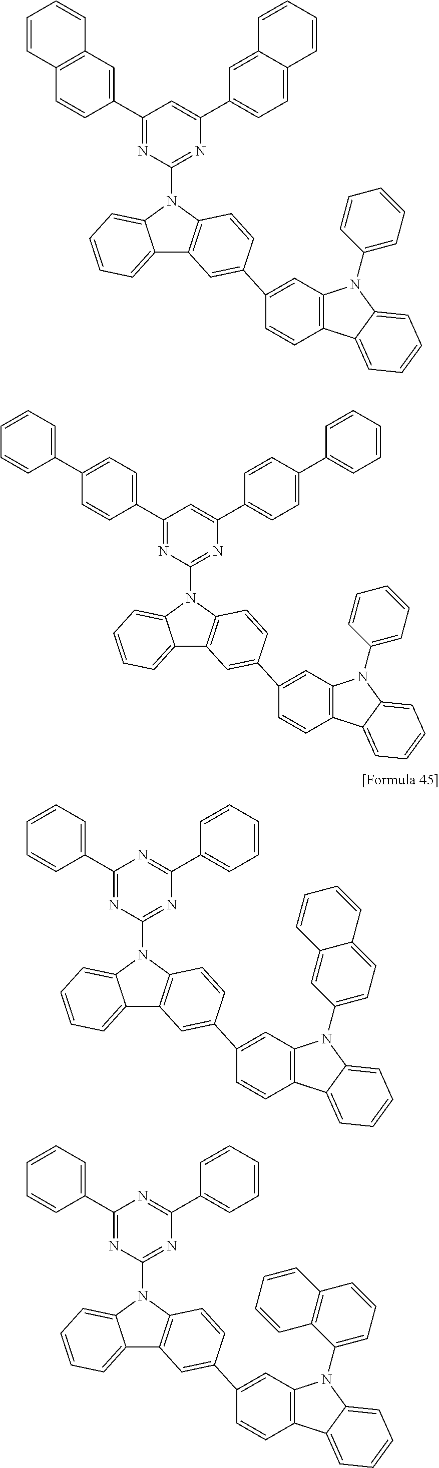

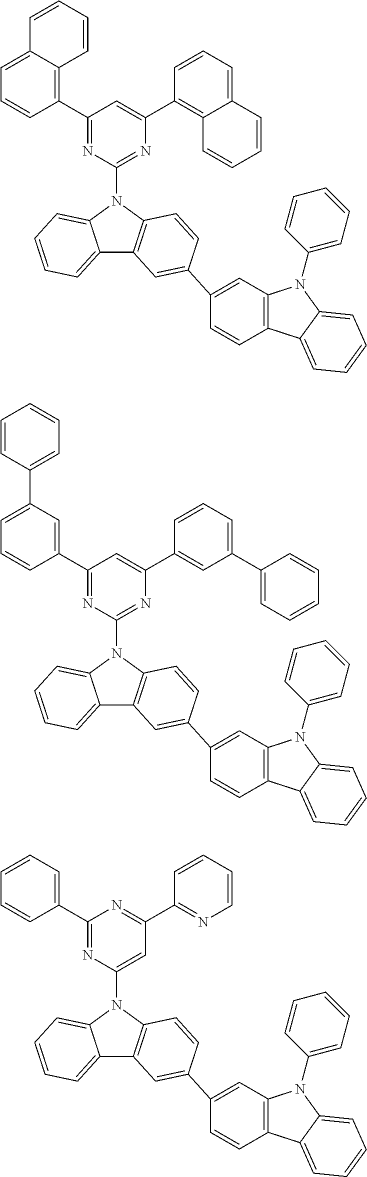 [SMILES: c1ccc(-n2c3ccccc3c3ccc(-c4ccc5c(c4)c4ccccc4n5-c4nc(-c5cccc6ccccc56)cc(-c5cccc6ccccc56)n4)cc32)cc1 ; c1ccc(-c2cccc(-c3cc(-c4cccc(-c5ccccc5)c4)nc(-n4c5ccccc5c5cc(-c6ccc7c8ccccc8n(-c8ccccc8)c7c6)ccc54)n3)c2)cc1 ; c1ccc(-c2nc(-c3ccccn3)cc(-n3c4ccccc4c4cc(-c5ccc6c7ccccc7n(-c7ccccc7)c6c5)ccc43)n2)cc1]

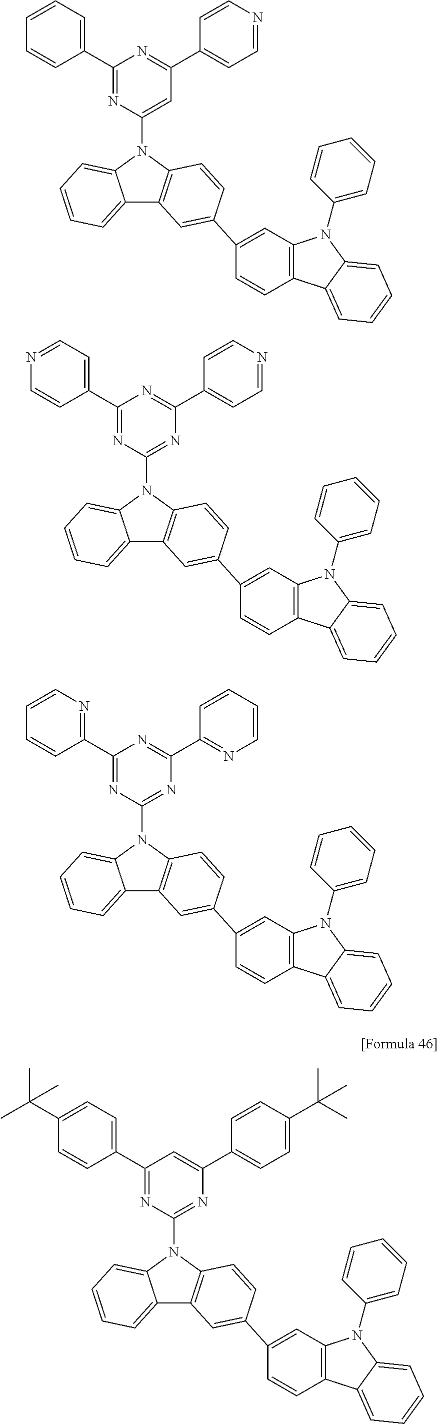 [SMILES: c1ccc(-c2nc(-c3ccncc3)cc(-n3c4ccccc4c4cc(-c5ccc6c7ccccc7n(-c7ccccc7)c6c5)ccc43)n2)cc1 ; c1ccc(-n2c3ccccc3c3ccc(-c4ccc5c(c4)c4ccccc4n5-c4nc(-c5ccncc5)nc(-c5ccncc5)n4)cc32)cc1 ; c1ccc(-n2c3ccccc3c3ccc(-c4ccc5c(c4)c4ccccc4n5-c4nc(-c5ccccn5)nc(-c5ccccn5)n4)cc32)cc1 ; CC(C)(C)c1ccc(-c2cc(-c3ccc(C(C)(C)C)cc3)nc(-n3c4ccccc4c4cc(-c5ccc6c7ccccc7n(-c7ccccc7)c6c5)ccc43)n2)cc1]

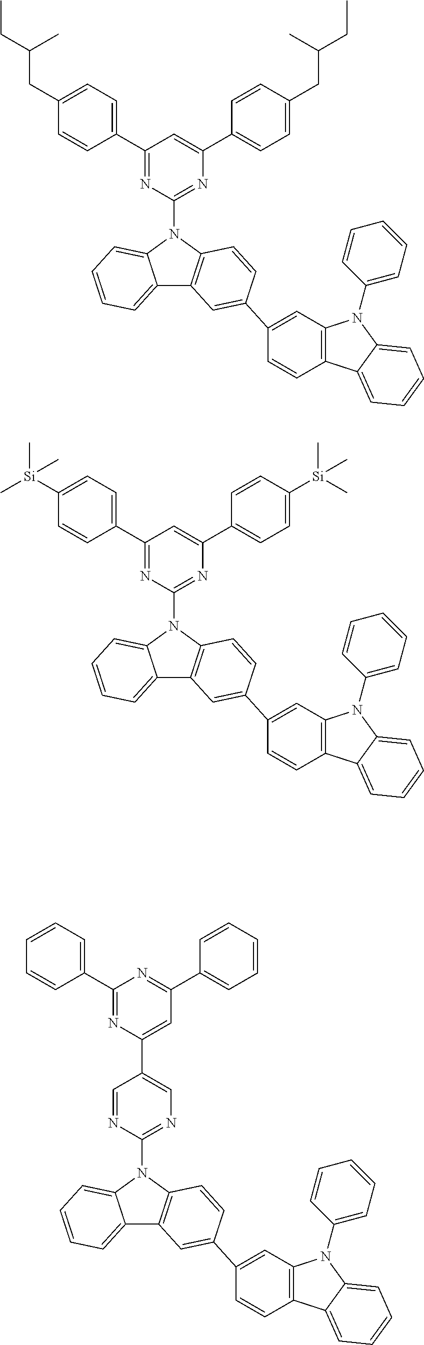 [SMILES: CCC(C)Cc1ccc(-c2cc(-c3ccc(CC(C)CC)cc3)nc(-n3c4ccccc4c4cc(-c5ccc6c7ccccc7n(-c7ccccc7)c6c5)ccc43)n2)cc1 ; C[Si](C)(C)c1ccc(-c2cc(-c3ccc([Si](C)(C)C)cc3)nc(-n3c4ccccc4c4cc(-c5ccc6c7ccccc7n(-c7ccccc7)c6c5)ccc43)n2)cc1 ; c1ccc(-c2cc(-c3cnc(-n4c5ccccc5c5cc(-c6ccc7c8ccccc8n(-c8ccccc8)c7c6)ccc54)nc3)nc(-c3ccccc3)n2)cc1]

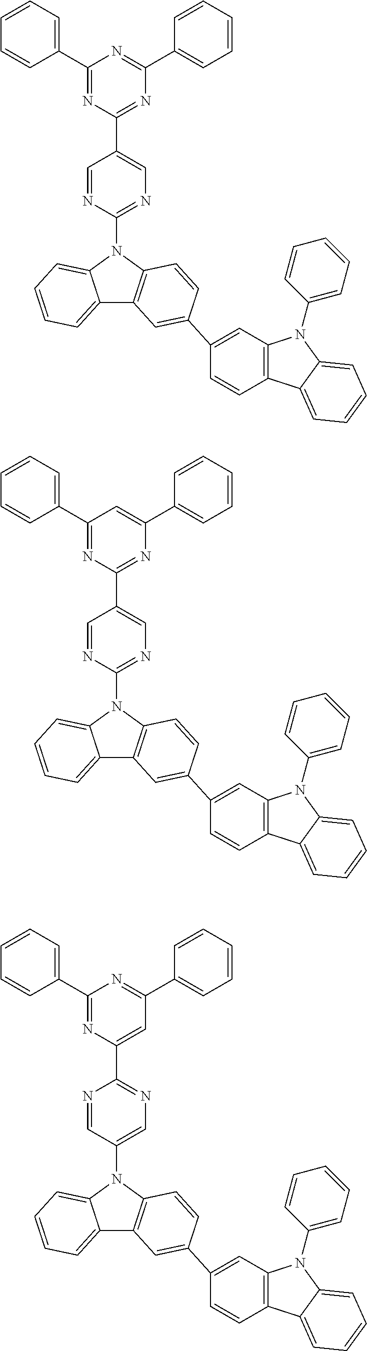 [SMILES: c1ccc(-c2nc(-c3ccccc3)nc(-c3cnc(-n4c5ccccc5c5cc(-c6ccc7c8ccccc8n(-c8ccccc8)c7c6)ccc54)nc3)n2)cc1 ; c1ccc(-c2cc(-c3ccccc3)nc(-c3cnc(-n4c5ccccc5c5cc(-c6ccc7c8ccccc8n(-c8ccccc8)c7c6)ccc54)nc3)n2)cc1 ; c1ccc(-c2cc(-c3ncc(-n4c5ccccc5c5cc(-c6ccc7c8ccccc8n(-c8ccccc8)c7c6)ccc54)cn3)nc(-c3ccccc3)n2)cc1]

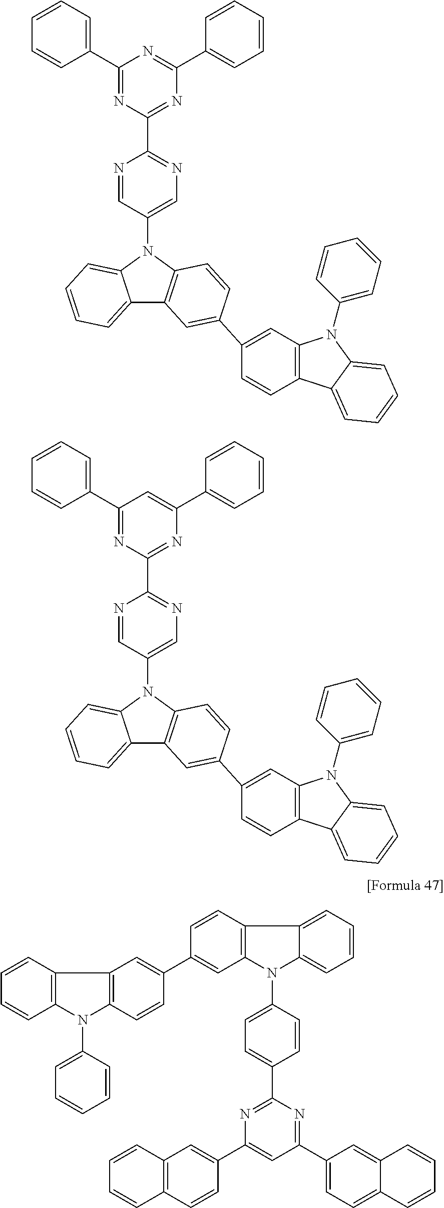 [SMILES: c1ccc(-c2nc(-c3ccccc3)nc(-c3ncc(-n4c5ccccc5c5cc(-c6ccc7c8ccccc8n(-c8ccccc8)c7c6)ccc54)cn3)n2)cc1 ; c1ccc(-c2cc(-c3ccccc3)nc(-c3ncc(-n4c5ccccc5c5cc(-c6ccc7c8ccccc8n(-c8ccccc8)c7c6)ccc54)cn3)n2)cc1 ; c1ccc(-n2c3ccccc3c3cc(-c4ccc5c6ccccc6n(-c6ccc(-c7nc(-c8ccc9ccccc9c8)cc(-c8ccc9ccccc9c8)n7)cc6)c5c4)ccc32)cc1]

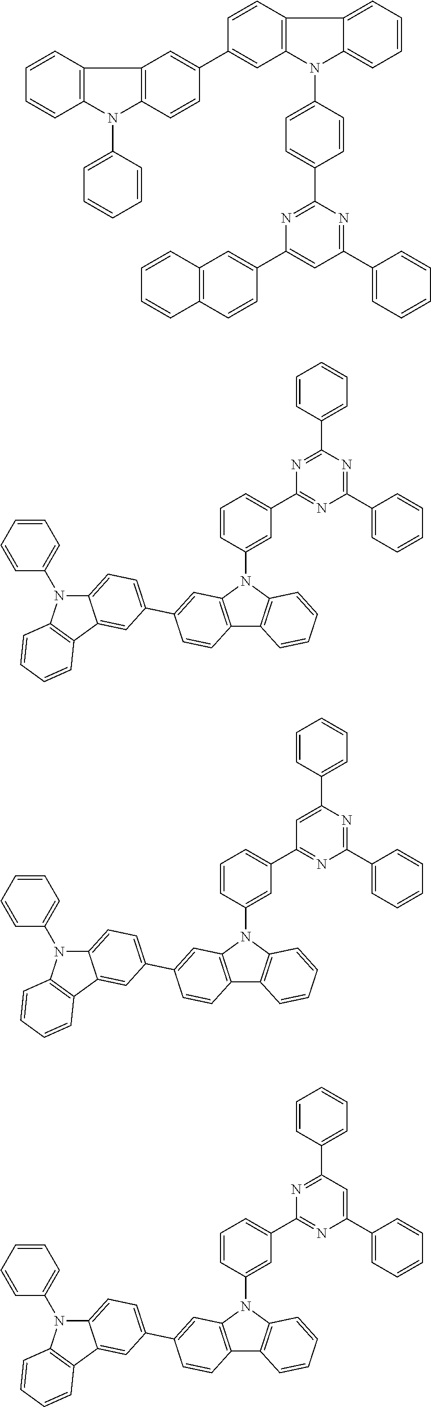 [SMILES: c1ccc(-c2cc(-c3ccc4ccccc4c3)nc(-c3ccc(-n4c5ccccc5c5ccc(-c6ccc7c(c6)c6ccccc6n7-c6ccccc6)cc54)cc3)n2)cc1 ; c1ccc(-c2nc(-c3ccccc3)nc(-c3cccc(-n4c5ccccc5c5ccc(-c6ccc7c(c6)c6ccccc6n7-c6ccccc6)cc54)c3)n2)cc1 ; c1ccc(-c2cc(-c3cccc(-n4c5ccccc5c5ccc(-c6ccc7c(c6)c6ccccc6n7-c6ccccc6)cc54)c3)nc(-c3ccccc3)n2)cc1 ; c1ccc(-c2cc(-c3ccccc3)nc(-c3cccc(-n4c5ccccc5c5ccc(-c6ccc7c(c6)c6ccccc6n7-c6ccccc6)cc54)c3)n2)cc1]

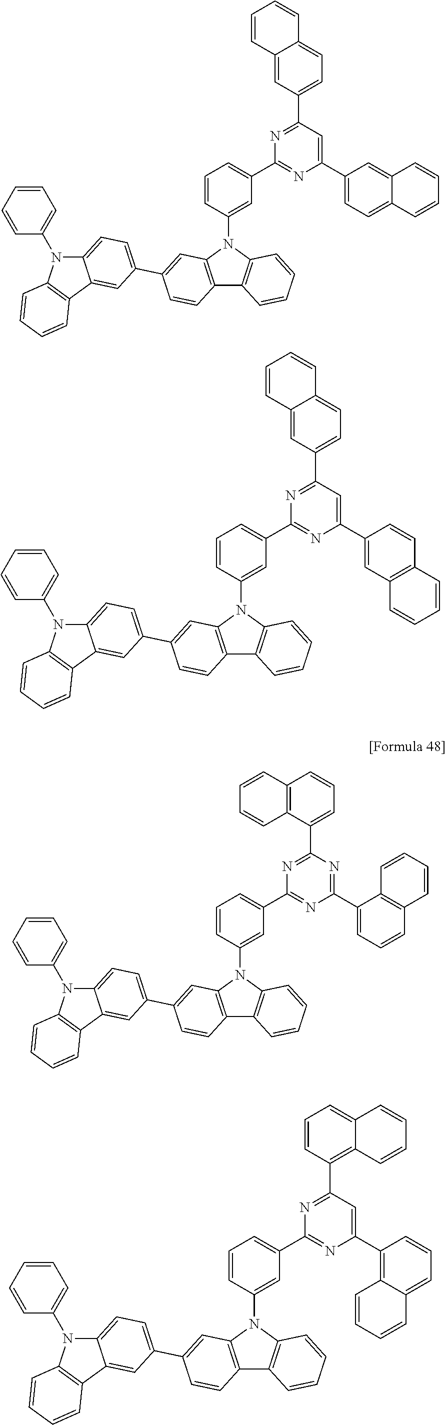 [SMILES: c1ccc(-n2c3ccccc3c3cc(-c4ccc5c6ccccc6n(-c6cccc(-c7nc(-c8ccc9ccccc9c8)cc(-c8ccc9ccccc9c8)n7)c6)c5c4)ccc32)cc1 ; c1ccc(-n2c3ccccc3c3cc(-c4ccc5c6ccccc6n(-c6cccc(-c7nc(-c8ccc9ccccc9c8)cc(-c8ccc9ccccc9c8)n7)c6)c5c4)ccc32)cc1 ; c1ccc(-n2c3ccccc3c3cc(-c4ccc5c6ccccc6n(-c6cccc(-c7nc(-c8cccc9ccccc89)nc(-c8cccc9ccccc89)n7)c6)c5c4)ccc32)cc1 ; c1ccc(-n2c3ccccc3c3cc(-c4ccc5c6ccccc6n(-c6cccc(-c7nc(-c8cccc9ccccc89)cc(-c8cccc9ccccc89)n7)c6)c5c4)ccc32)cc1]

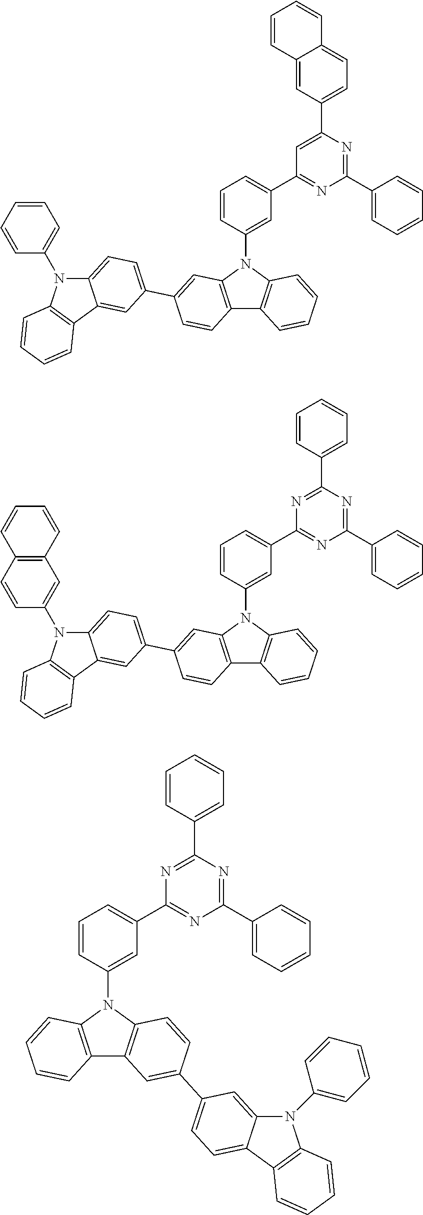 [SMILES: c1ccc(-c2nc(-c3cccc(-n4c5ccccc5c5ccc(-c6ccc7c(c6)c6ccccc6n7-c6ccccc6)cc54)c3)cc(-c3ccc4ccccc4c3)n2)cc1 ; c1ccc(-c2nc(-c3ccccc3)nc(-c3cccc(-n4c5ccccc5c5ccc(-c6ccc7c(c6)c6ccccc6n7-c6ccc7ccccc7c6)cc54)c3)n2)cc1 ; c1ccc(-c2nc(-c3ccccc3)nc(-c3cccc(-n4c5ccccc5c5cc(-c6ccc7c8ccccc8n(-c8ccccc8)c7c6)ccc54)c3)n2)cc1]

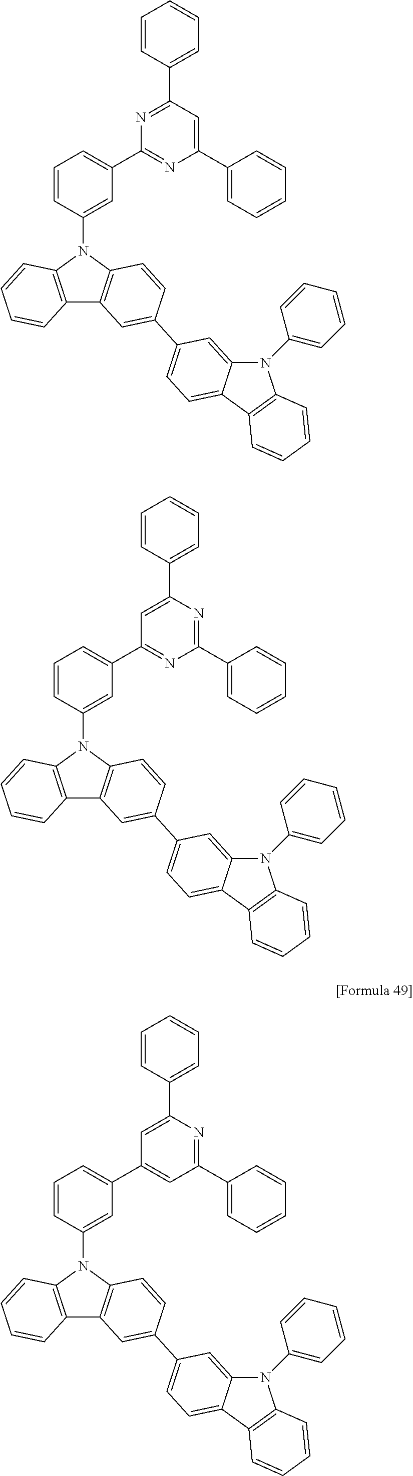 [SMILES: c1ccc(-c2cc(-c3ccccc3)nc(-c3cccc(-n4c5ccccc5c5cc(-c6ccc7c8ccccc8n(-c8ccccc8)c7c6)ccc54)c3)n2)cc1 ; c1ccc(-c2cc(-c3cccc(-n4c5ccccc5c5cc(-c6ccc7c8ccccc8n(-c8ccccc8)c7c6)ccc54)c3)nc(-c3ccccc3)n2)cc1 ; c1ccc(-c2cc(-c3cccc(-n4c5ccccc5c5cc(-c6ccc7c8ccccc8n(-c8ccccc8)c7c6)ccc54)c3)cc(-c3ccccc3)n2)cc1]

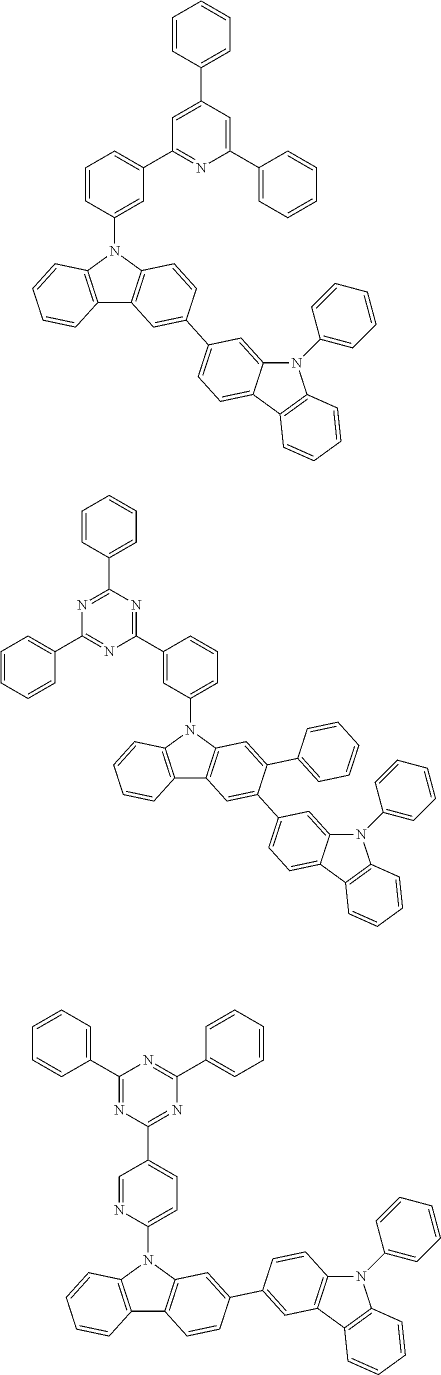 [SMILES: c1ccc(-c2cc(-c3ccccc3)nc(-c3cccc(-n4c5ccccc5c5cc(-c6ccc7c8ccccc8n(-c8ccccc8)c7c6)ccc54)c3)c2)cc1 ; c1ccc(-c2nc(-c3ccccc3)nc(-c3cccc(-n4c5ccccc5c5cc(-c6ccc7c8ccccc8n(-c8ccccc8)c7c6)c(-c6ccccc6)cc54)c3)n2)cc1 ; c1ccc(-c2nc(-c3ccccc3)nc(-c3ccc(-n4c5ccccc5c5ccc(-c6ccc7c(c6)c6ccccc6n7-c6ccccc6)cc54)nc3)n2)cc1]

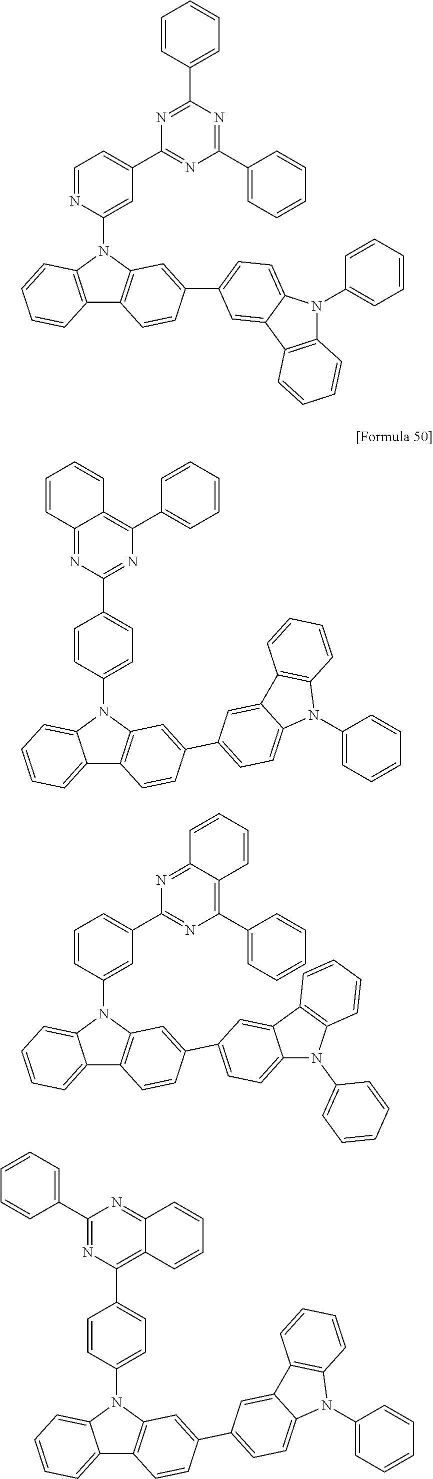 [SMILES: c1ccc(-c2nc(-c3ccccc3)nc(-c3ccnc(-n4c5ccccc5c5ccc(-c6ccc7c(c6)c6ccccc6n7-c6ccccc6)cc54)c3)n2)cc1 ; c1ccc(-c2nc(-c3ccc(-n4c5ccccc5c5ccc(-c6ccc7c(c6)c6ccccc6n7-c6ccccc6)cc54)cc3)nc3ccccc23)cc1 ; c1ccc(-c2nc(-c3cccc(-n4c5ccccc5c5ccc(-c6ccc7c(c6)c6ccccc6n7-c6ccccc6)cc54)c3)nc3ccccc23)cc1 ; c1ccc(-c2nc(-c3ccc(-n4c5ccccc5c5ccc(-c6ccc7c(c6)c6ccccc6n7-c6ccccc6)cc54)cc3)c3ccccc3n2)cc1]

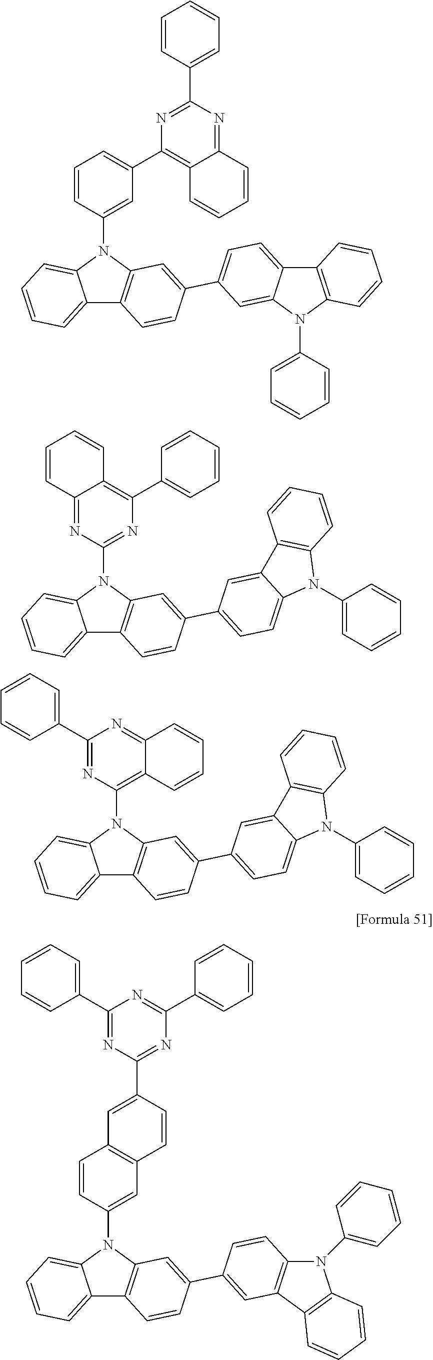

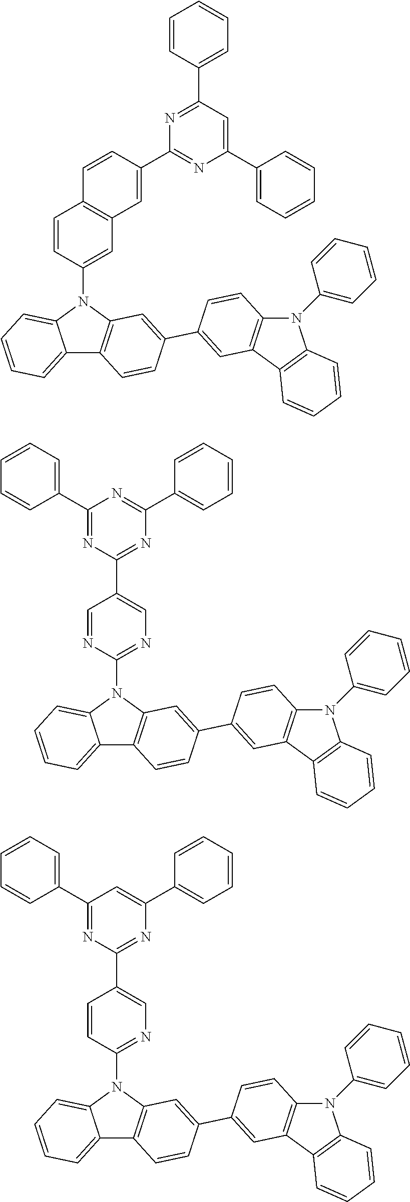 [SMILES: c1ccc(-c2cc(-c3ccccc3)nc(-c3ccc4ccc(-n5c6ccccc6c6ccc(-c7ccc8c(c7)c7ccccc7n8-c7ccccc7)cc65)cc4c3)n2)cc1 ; c1ccc(-c2nc(-c3ccccc3)nc(-c3cnc(-n4c5ccccc5c5ccc(-c6ccc7c(c6)c6ccccc6n7-c6ccccc6)cc54)nc3)n2)cc1 ; c1ccc(-c2cc(-c3ccccc3)nc(-c3ccc(-n4c5ccccc5c5ccc(-c6ccc7c(c6)c6ccccc6n7-c6ccccc6)cc54)nc3)n2)cc1]

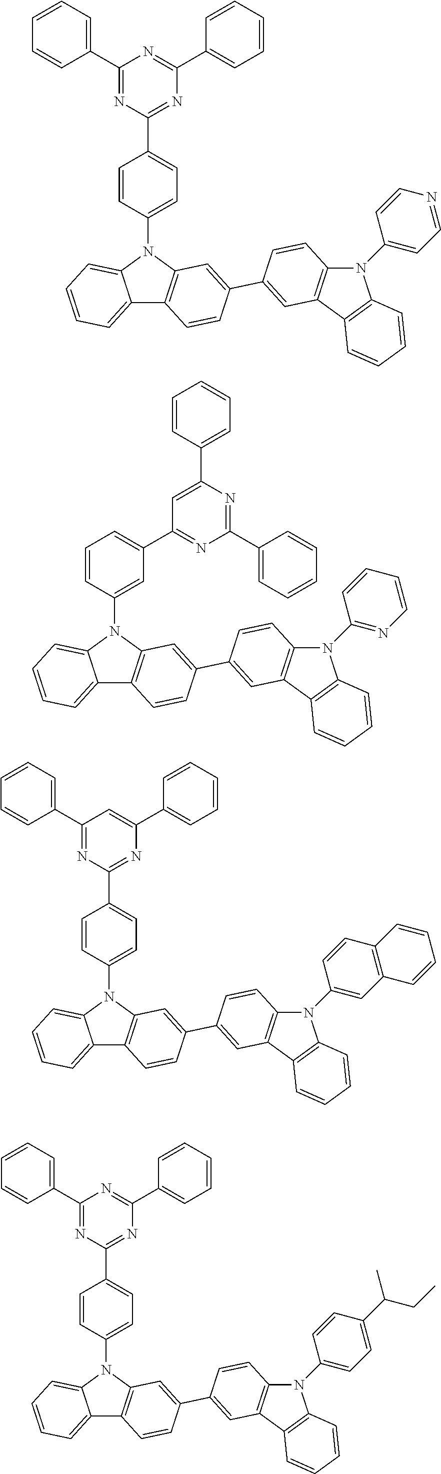 [SMILES: c1ccc(-c2nc(-c3ccccc3)nc(-c3ccc(-n4c5ccccc5c5ccc(-c6ccc7c(c6)c6ccccc6n7-c6ccncc6)cc54)cc3)n2)cc1 ; c1ccc(-c2cc(-c3cccc(-n4c5ccccc5c5ccc(-c6ccc7c(c6)c6ccccc6n7-c6ccccn6)cc54)c3)nc(-c3ccccc3)n2)cc1 ; c1ccc(-c2cc(-c3ccccc3)nc(-c3ccc(-n4c5ccccc5c5ccc(-c6ccc7c(c6)c6ccccc6n7-c6ccc7ccccc7c6)cc54)cc3)n2)cc1 ; CCC(C)c1ccc(-n2c3ccccc3c3cc(-c4ccc5c6ccccc6n(-c6ccc(-c7nc(-c8ccccc8)nc(-c8ccccc8)n7)cc6)c5c4)ccc32)cc1]

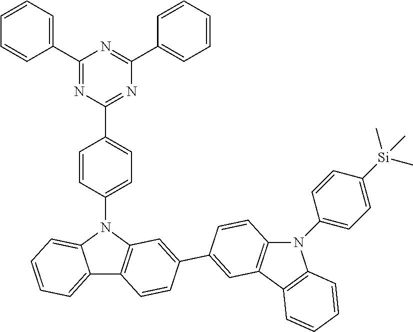 [SMILES: C[Si](C)(C)c1ccc(-n2c3ccccc3c3cc(-c4ccc5c6ccccc6n(-c6ccc(-c7nc(-c8ccccc8)nc(-c8ccccc8)n7)cc6)c5c4)ccc32)cc1]

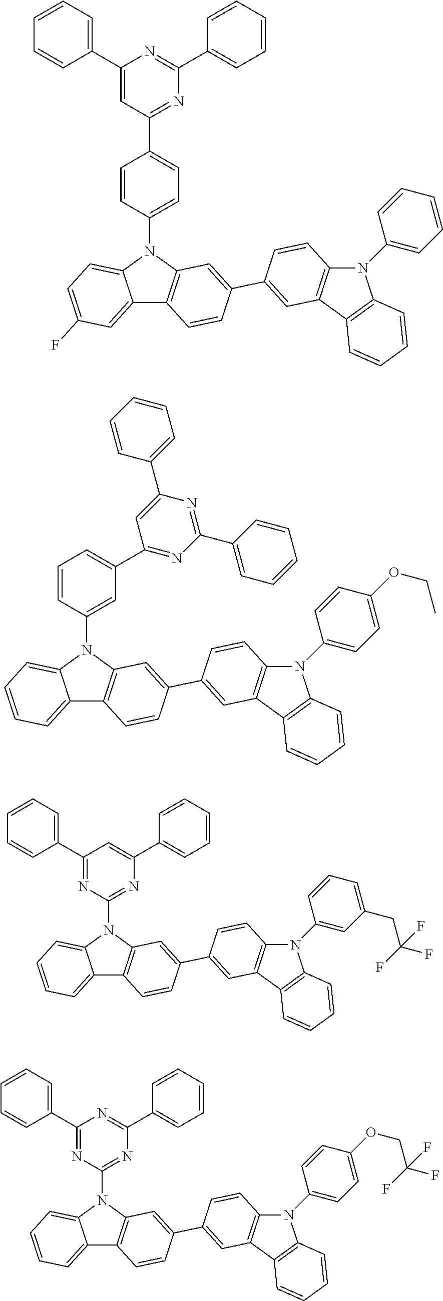 [SMILES: Fc1ccc2c(c1)c1ccc(-c3ccc4c(c3)c3ccccc3n4-c3ccccc3)cc1n2-c1ccc(-c2cc(-c3ccccc3)nc(-c3ccccc3)n2)cc1 ; CCOc1ccc(-n2c3ccccc3c3cc(-c4ccc5c6ccccc6n(-c6cccc(-c7cc(-c8ccccc8)nc(-c8ccccc8)n7)c6)c5c4)ccc32)cc1 ; FC(F)(F)Cc1cccc(-n2c3ccccc3c3cc(-c4ccc5c6ccccc6n(-c6nc(-c7ccccc7)cc(-c7ccccc7)n6)c5c4)ccc32)c1 ; FC(F)(F)COc1ccc(-n2c3ccccc3c3cc(-c4ccc5c6ccccc6n(-c6nc(-c7ccccc7)nc(-c7ccccc7)n6)c5c4)ccc32)cc1]

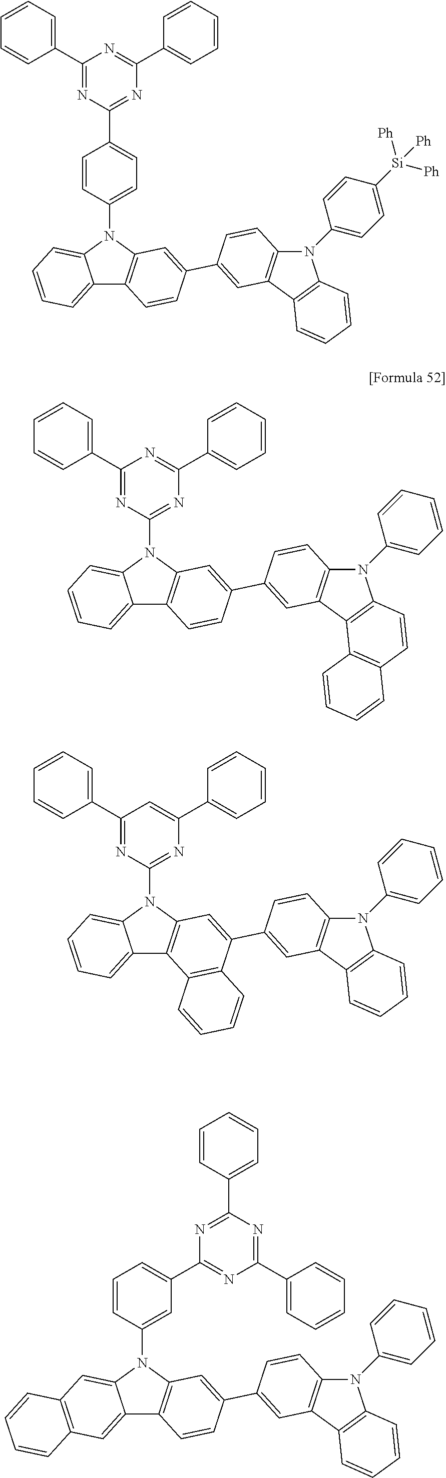 [SMILES: c1ccc(-c2nc(-c3ccccc3)nc(-c3ccc(-n4c5ccccc5c5ccc(-c6ccc7c(c6)c6ccccc6n7-c6ccc([Si](c7ccccc7)(c7ccccc7)c7ccccc7)cc6)cc54)cc3)n2)cc1 ; c1ccc(-c2nc(-c3ccccc3)nc(-n3c4ccccc4c4ccc(-c5ccc6c(c5)c5c7ccccc7ccc5n6-c5ccccc5)cc43)n2)cc1 ; c1ccc(-c2cc(-c3ccccc3)nc(-n3c4ccccc4c4c5ccccc5c(-c5ccc6c(c5)c5ccccc5n6-c5ccccc5)cc43)n2)cc1 ; c1ccc(-c2nc(-c3ccccc3)nc(-c3cccc(-n4c5cc(-c6ccc7c(c6)c6ccccc6n7-c6ccccc6)ccc5c5cc6ccccc6cc54)c3)n2)cc1]

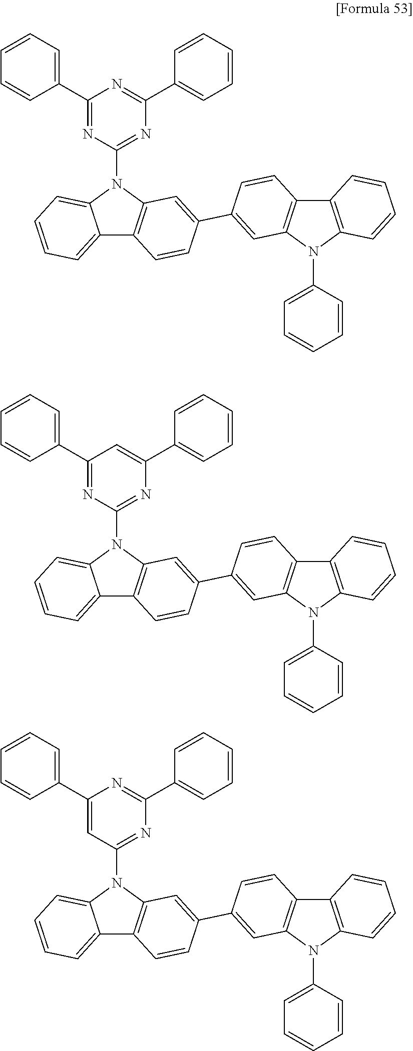 [SMILES: c1ccc(-c2nc(-c3ccccc3)nc(-n3c4ccccc4c4ccc(-c5ccc6c7ccccc7n(-c7ccccc7)c6c5)cc43)n2)cc1 ; c1ccc(-c2cc(-c3ccccc3)nc(-n3c4ccccc4c4ccc(-c5ccc6c7ccccc7n(-c7ccccc7)c6c5)cc43)n2)cc1 ; c1ccc(-c2cc(-n3c4ccccc4c4ccc(-c5ccc6c7ccccc7n(-c7ccccc7)c6c5)cc43)nc(-c3ccccc3)n2)cc1]

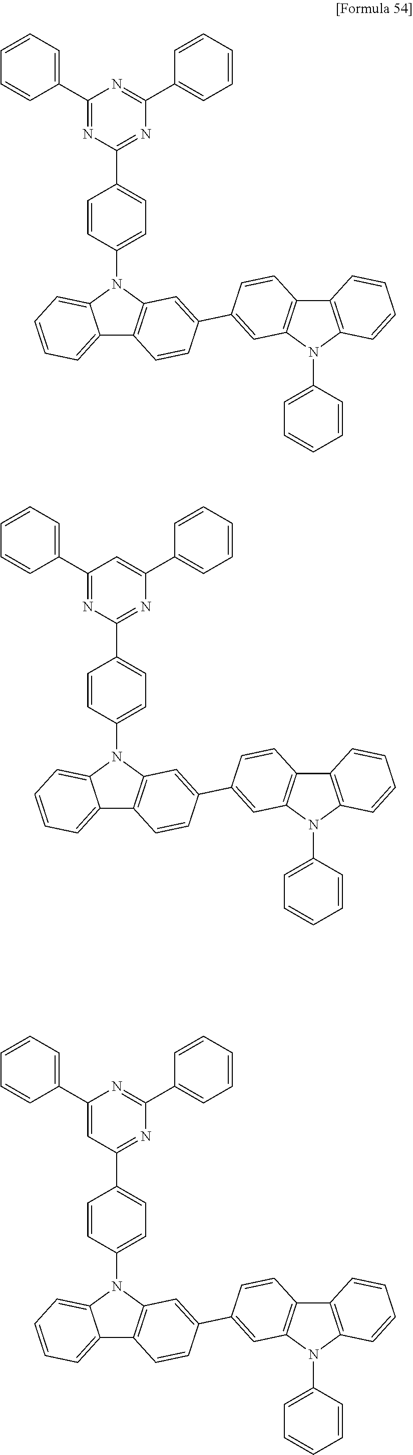 [SMILES: c1ccc(-c2nc(-c3ccccc3)nc(-c3ccc(-n4c5ccccc5c5ccc(-c6ccc7c8ccccc8n(-c8ccccc8)c7c6)cc54)cc3)n2)cc1 ; c1ccc(-c2cc(-c3ccccc3)nc(-c3ccc(-n4c5ccccc5c5ccc(-c6ccc7c8ccccc8n(-c8ccccc8)c7c6)cc54)cc3)n2)cc1 ; c1ccc(-c2cc(-c3ccc(-n4c5ccccc5c5ccc(-c6ccc7c8ccccc8n(-c8ccccc8)c7c6)cc54)cc3)nc(-c3ccccc3)n2)cc1]

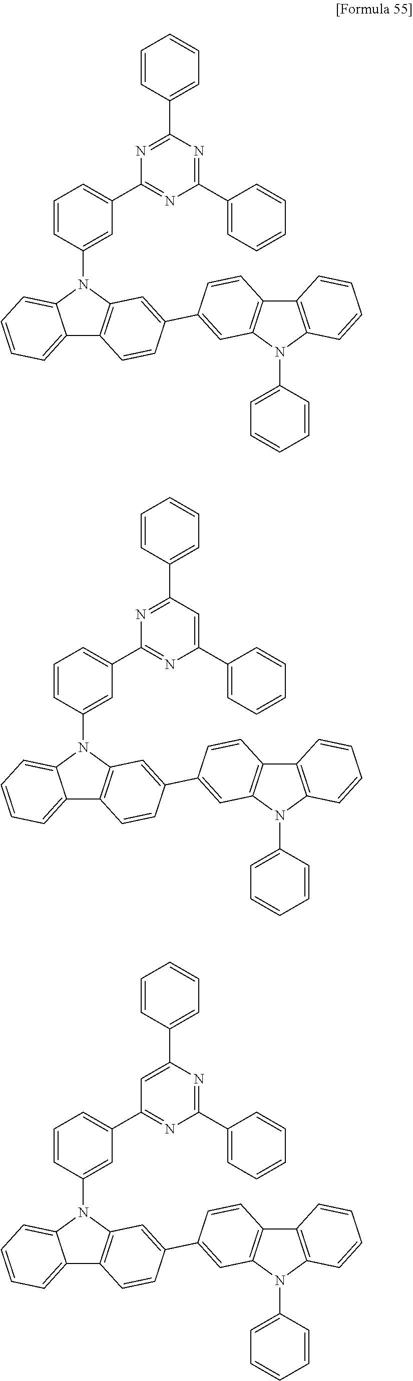 [SMILES: c1ccc(-c2nc(-c3ccccc3)nc(-c3cccc(-n4c5ccccc5c5ccc(-c6ccc7c8ccccc8n(-c8ccccc8)c7c6)cc54)c3)n2)cc1 ; c1ccc(-c2cc(-c3ccccc3)nc(-c3cccc(-n4c5ccccc5c5ccc(-c6ccc7c8ccccc8n(-c8ccccc8)c7c6)cc54)c3)n2)cc1 ; c1ccc(-c2cc(-c3cccc(-n4c5ccccc5c5ccc(-c6ccc7c8ccccc8n(-c8ccccc8)c7c6)cc54)c3)nc(-c3ccccc3)n2)cc1]

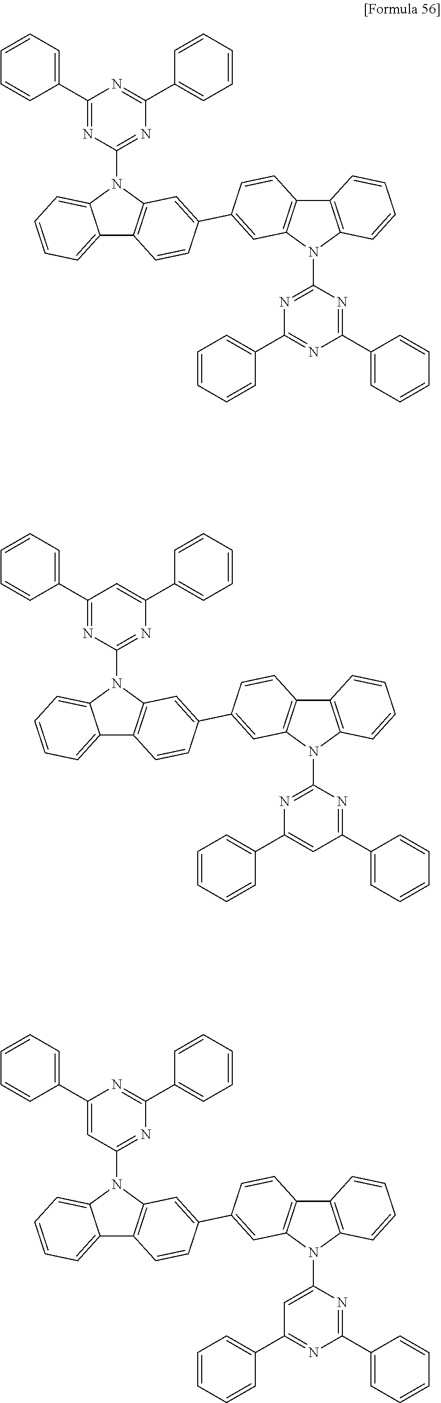 [SMILES: c1ccc(-c2nc(-c3ccccc3)nc(-n3c4ccccc4c4ccc(-c5ccc6c7ccccc7n(-c7nc(-c8ccccc8)nc(-c8ccccc8)n7)c6c5)cc43)n2)cc1 ; c1ccc(-c2cc(-c3ccccc3)nc(-n3c4ccccc4c4ccc(-c5ccc6c7ccccc7n(-c7nc(-c8ccccc8)cc(-c8ccccc8)n7)c6c5)cc43)n2)cc1 ; c1ccc(-c2cc(-n3c4ccccc4c4ccc(-c5ccc6c7ccccc7n(-c7cc(-c8ccccc8)nc(-c8ccccc8)n7)c6c5)cc43)nc(-c3ccccc3)n2)cc1]

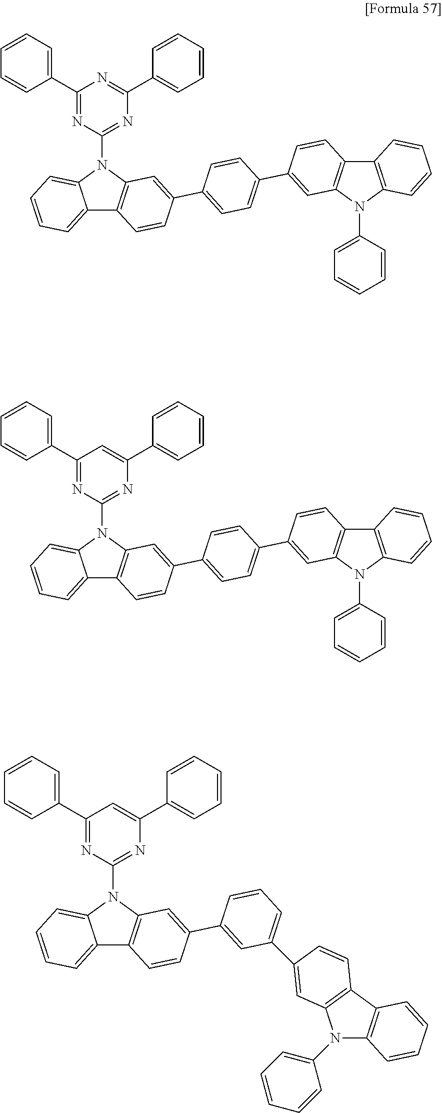 [SMILES: c1ccc(-c2nc(-c3ccccc3)nc(-n3c4ccccc4c4ccc(-c5ccc(-c6ccc7c8ccccc8n(-c8ccccc8)c7c6)cc5)cc43)n2)cc1 ; c1ccc(-c2cc(-c3ccccc3)nc(-n3c4ccccc4c4ccc(-c5ccc(-c6ccc7c8ccccc8n(-c8ccccc8)c7c6)cc5)cc43)n2)cc1 ; c1ccc(-c2cc(-c3ccccc3)nc(-n3c4ccccc4c4ccc(-c5cccc(-c6ccc7c8ccccc8n(-c8ccccc8)c7c6)c5)cc43)n2)cc1]

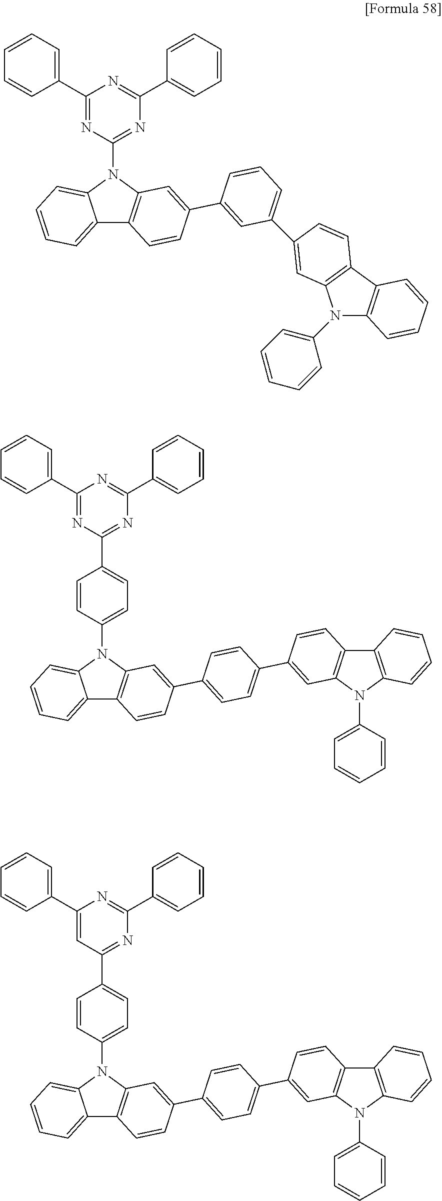 [SMILES: c1ccc(-c2nc(-c3ccccc3)nc(-n3c4ccccc4c4ccc(-c5cccc(-c6ccc7c8ccccc8n(-c8ccccc8)c7c6)c5)cc43)n2)cc1 ; c1ccc(-c2nc(-c3ccccc3)nc(-c3ccc(-n4c5ccccc5c5ccc(-c6ccc(-c7ccc8c9ccccc9n(-c9ccccc9)c8c7)cc6)cc54)cc3)n2)cc1 ; c1ccc(-c2cc(-c3ccc(-n4c5ccccc5c5ccc(-c6ccc(-c7ccc8c9ccccc9n(-c9ccccc9)c8c7)cc6)cc54)cc3)nc(-c3ccccc3)n2)cc1]

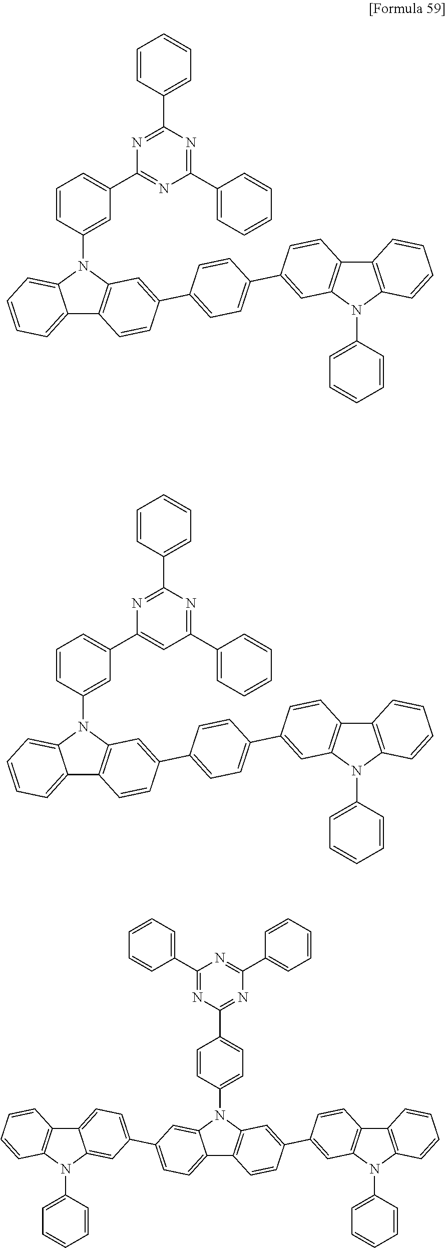 [SMILES: c1ccc(-c2nc(-c3ccccc3)nc(-c3cccc(-n4c5ccccc5c5ccc(-c6ccc(-c7ccc8c9ccccc9n(-c9ccccc9)c8c7)cc6)cc54)c3)n2)cc1 ; c1ccc(-c2cc(-c3cccc(-n4c5ccccc5c5ccc(-c6ccc(-c7ccc8c9ccccc9n(-c9ccccc9)c8c7)cc6)cc54)c3)nc(-c3ccccc3)n2)cc1 ; c1ccc(-c2nc(-c3ccccc3)nc(-c3ccc(-n4c5cc(-c6ccc7c8ccccc8n(-c8ccccc8)c7c6)ccc5c5ccc(-c6ccc7c8ccccc8n(-c8ccccc8)c7c6)cc54)cc3)n2)cc1]

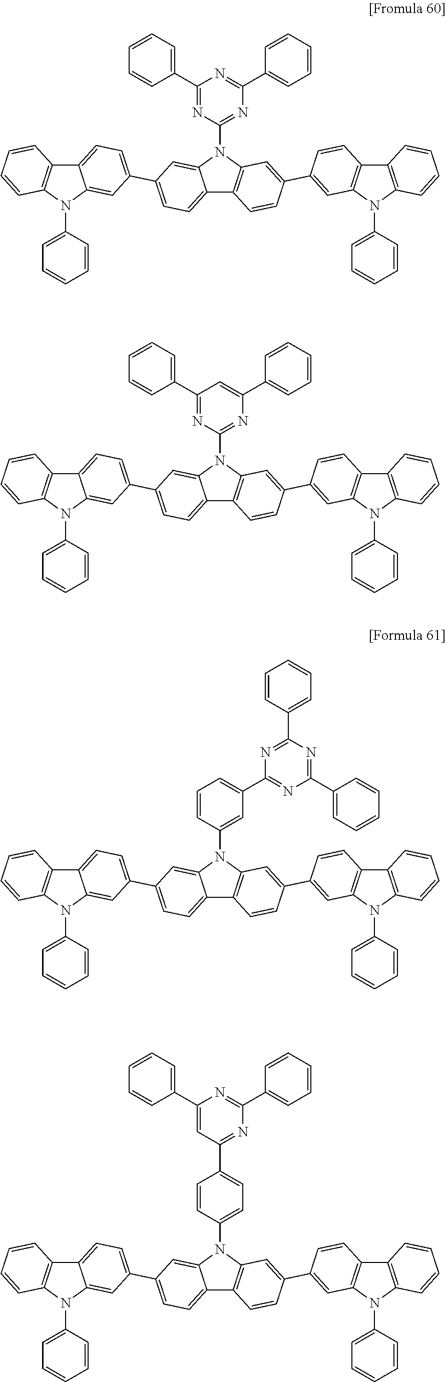

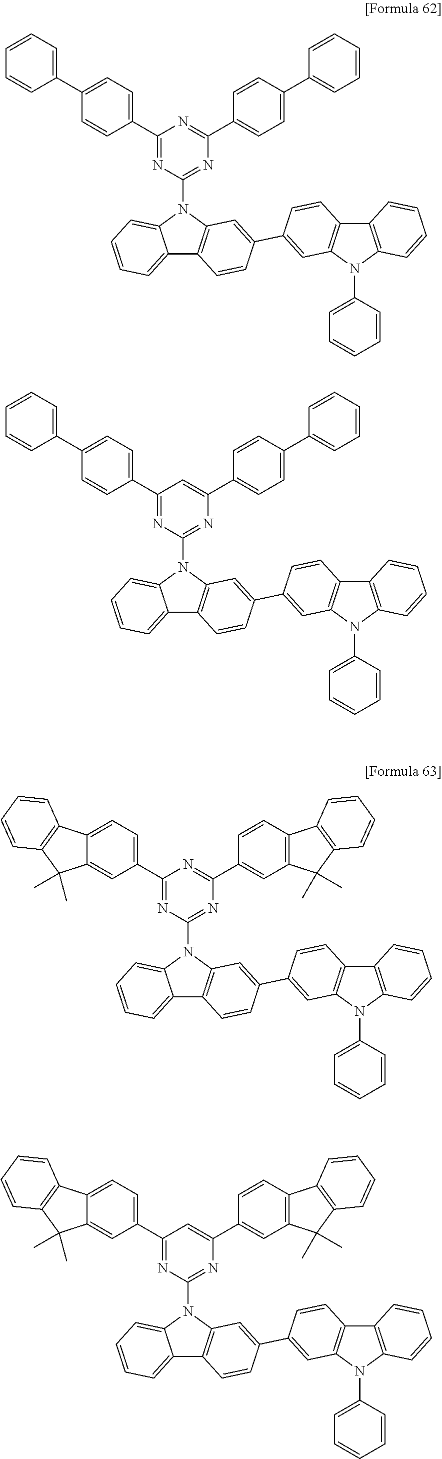 [SMILES: c1ccc(-c2ccc(-c3nc(-c4ccc(-c5ccccc5)cc4)nc(-n4c5ccccc5c5ccc(-c6ccc7c8ccccc8n(-c8ccccc8)c7c6)cc54)n3)cc2)cc1 ; c1ccc(-c2ccc(-c3cc(-c4ccc(-c5ccccc5)cc4)nc(-n4c5ccccc5c5ccc(-c6ccc7c8ccccc8n(-c8ccccc8)c7c6)cc54)n3)cc2)cc1 ; CC1(C)c2ccccc2-c2ccc(-c3nc(-c4ccc5c(c4)C(C)(C)c4ccccc4-5)nc(-n4c5ccccc5c5ccc(-c6ccc7c8ccccc8n(-c8ccccc8)c7c6)cc54)n3)cc21 ; CC1(C)c2ccccc2-c2ccc(-c3cc(-c4ccc5c(c4)C(C)(C)c4ccccc4-5)nc(-n4c5ccccc5c5ccc(-c6ccc7c8ccccc8n(-c8ccccc8)c7c6)cc54)n3)cc21]

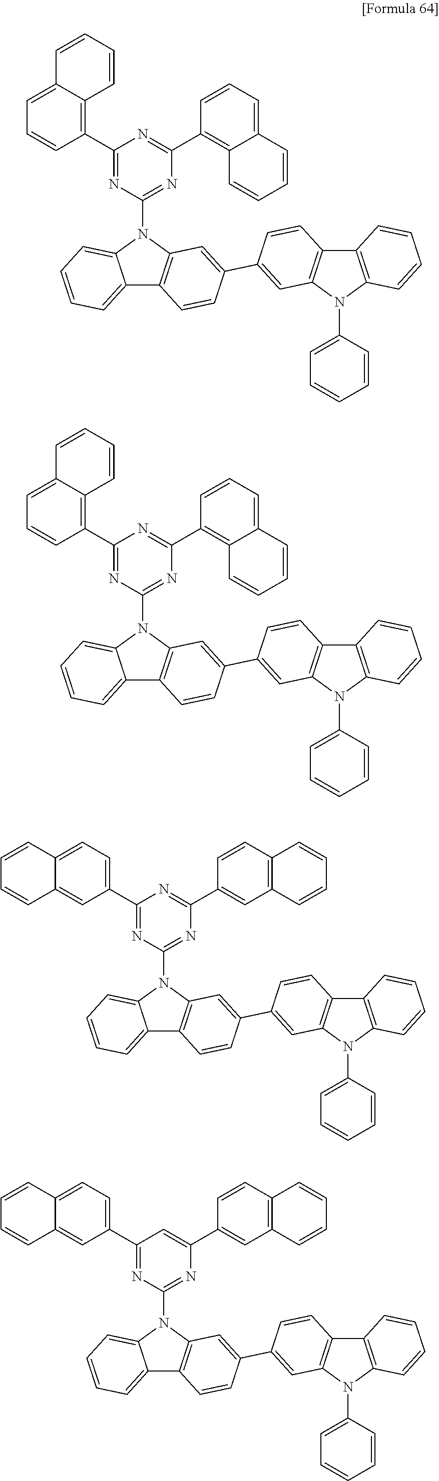 [SMILES: c1ccc(-n2c3ccccc3c3ccc(-c4ccc5c6ccccc6n(-c6nc(-c7cccc8ccccc78)nc(-c7cccc8ccccc78)n6)c5c4)cc32)cc1 ; c1ccc(-n2c3ccccc3c3ccc(-c4ccc5c6ccccc6n(-c6nc(-c7cccc8ccccc78)nc(-c7cccc8ccccc78)n6)c5c4)cc32)cc1 ; c1ccc(-n2c3ccccc3c3ccc(-c4ccc5c6ccccc6n(-c6nc(-c7ccc8ccccc8c7)nc(-c7ccc8ccccc8c7)n6)c5c4)cc32)cc1 ; c1ccc(-n2c3ccccc3c3ccc(-c4ccc5c6ccccc6n(-c6nc(-c7ccc8ccccc8c7)cc(-c7ccc8ccccc8c7)n6)c5c4)cc32)cc1]

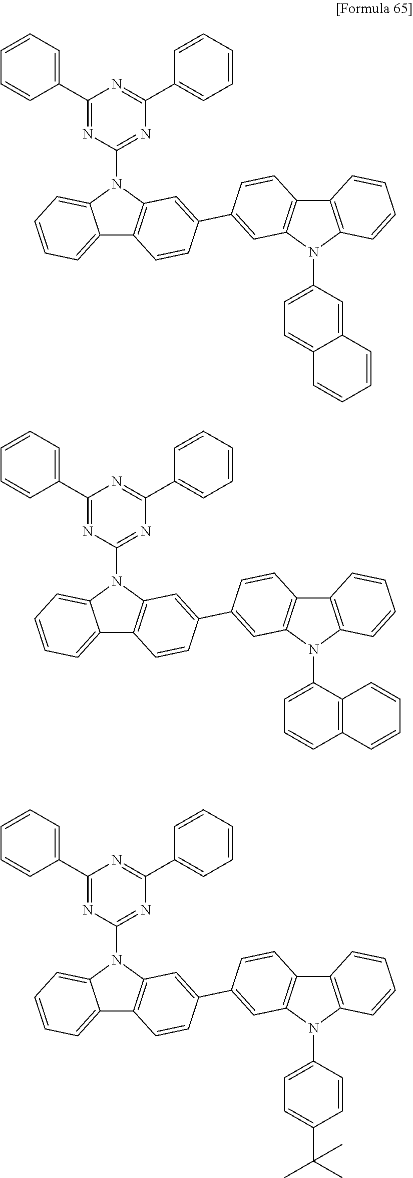 [SMILES: c1ccc(-c2nc(-c3ccccc3)nc(-n3c4ccccc4c4ccc(-c5ccc6c7ccccc7n(-c7ccc8ccccc8c7)c6c5)cc43)n2)cc1 ; c1ccc(-c2nc(-c3ccccc3)nc(-n3c4ccccc4c4ccc(-c5ccc6c7ccccc7n(-c7cccc8ccccc78)c6c5)cc43)n2)cc1 ; CC(C)(C)c1ccc(-n2c3ccccc3c3ccc(-c4ccc5c6ccccc6n(-c6nc(-c7ccccc7)nc(-c7ccccc7)n6)c5c4)cc32)cc1]

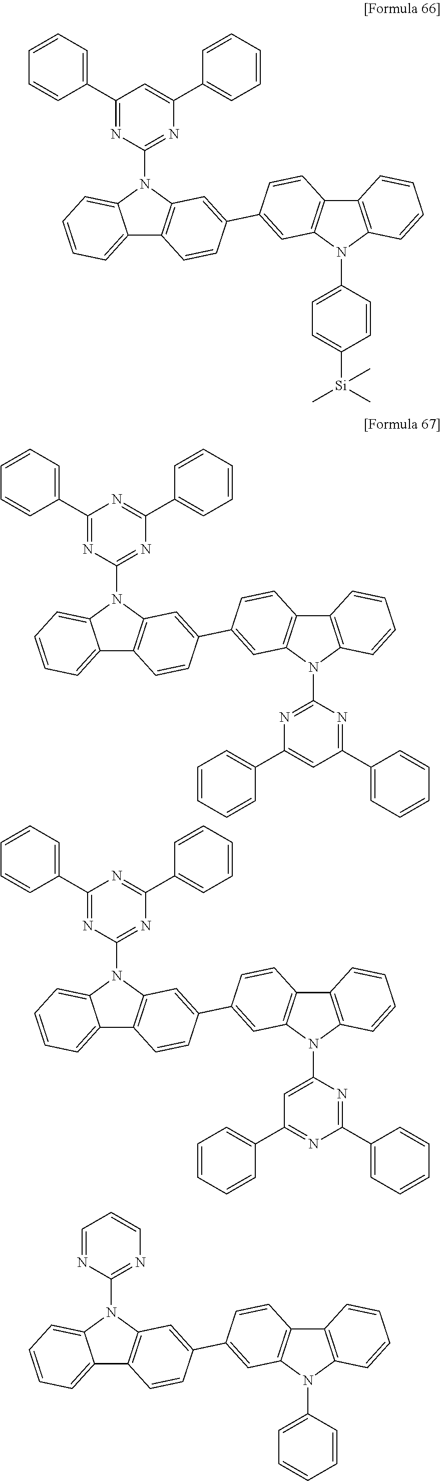

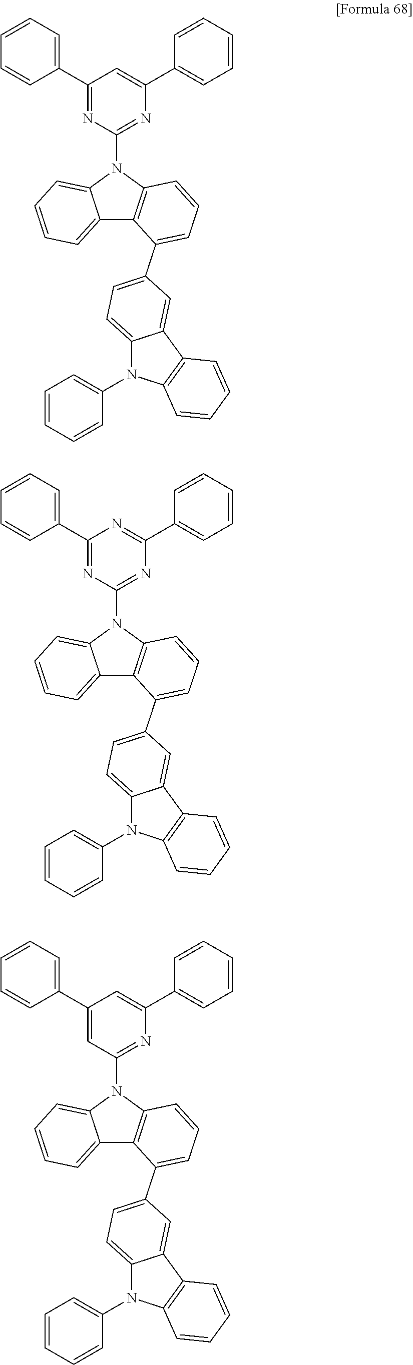 [SMILES: c1ccc(-c2cc(-c3ccccc3)nc(-n3c4ccccc4c4c(-c5ccc6c(c5)c5ccccc5n6-c5ccccc5)cccc43)n2)cc1 ; c1ccc(-c2nc(-c3ccccc3)nc(-n3c4ccccc4c4c(-c5ccc6c(c5)c5ccccc5n6-c5ccccc5)cccc43)n2)cc1 ; c1ccc(-c2cc(-c3ccccc3)nc(-n3c4ccccc4c4c(-c5ccc6c(c5)c5ccccc5n6-c5ccccc5)cccc43)c2)cc1]

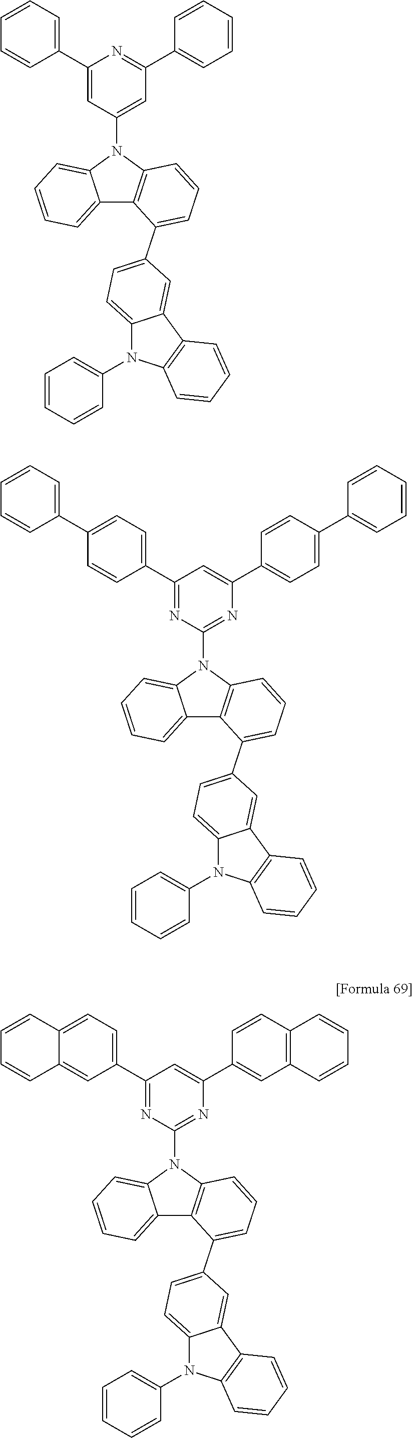 [SMILES: c1ccc(-c2cc(-n3c4ccccc4c4c(-c5ccc6c(c5)c5ccccc5n6-c5ccccc5)cccc43)cc(-c3ccccc3)n2)cc1 ; c1ccc(-c2ccc(-c3cc(-c4ccc(-c5ccccc5)cc4)nc(-n4c5ccccc5c5c(-c6ccc7c(c6)c6ccccc6n7-c6ccccc6)cccc54)n3)cc2)cc1 ; c1ccc(-n2c3ccccc3c3cc(-c4cccc5c4c4ccccc4n5-c4nc(-c5ccc6ccccc6c5)cc(-c5ccc6ccccc6c5)n4)ccc32)cc1]

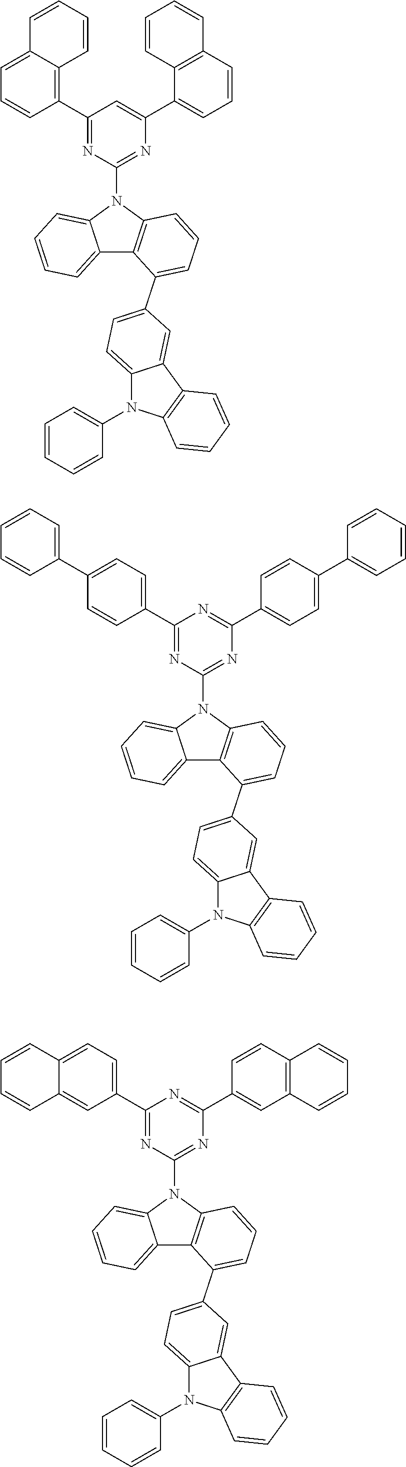 [SMILES: c1ccc(-n2c3ccccc3c3cc(-c4cccc5c4c4ccccc4n5-c4nc(-c5cccc6ccccc56)cc(-c5cccc6ccccc56)n4)ccc32)cc1 ; c1ccc(-c2ccc(-c3nc(-c4ccc(-c5ccccc5)cc4)nc(-n4c5ccccc5c5c(-c6ccc7c(c6)c6ccccc6n7-c6ccccc6)cccc54)n3)cc2)cc1 ; c1ccc(-n2c3ccccc3c3cc(-c4cccc5c4c4ccccc4n5-c4nc(-c5ccc6ccccc6c5)nc(-c5ccc6ccccc6c5)n4)ccc32)cc1]

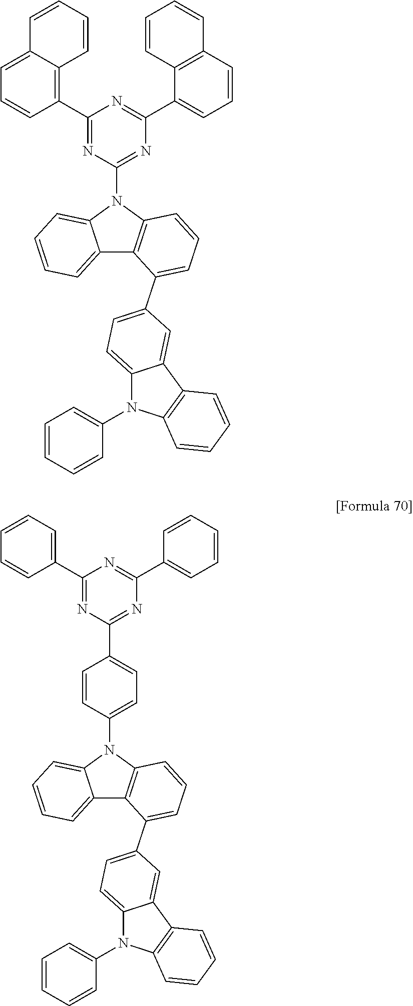 [SMILES: c1ccc(-n2c3ccccc3c3cc(-c4cccc5c4c4ccccc4n5-c4nc(-c5cccc6ccccc56)nc(-c5cccc6ccccc56)n4)ccc32)cc1 ; c1ccc(-c2nc(-c3ccccc3)nc(-c3ccc(-n4c5ccccc5c5c(-c6ccc7c(c6)c6ccccc6n7-c6ccccc6)cccc54)cc3)n2)cc1]

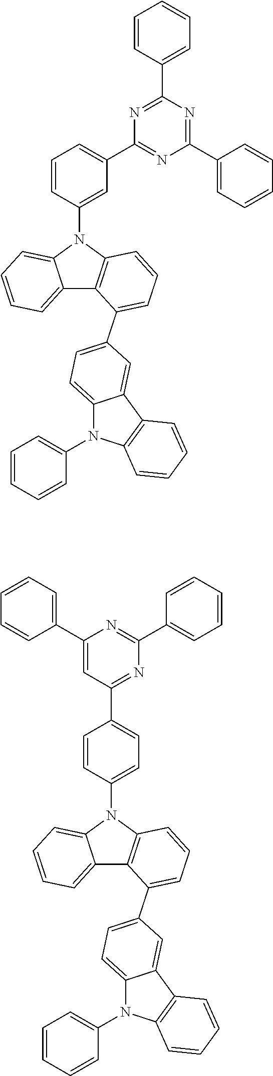 [SMILES: c1ccc(-c2nc(-c3ccccc3)nc(-c3cccc(-n4c5ccccc5c5c(-c6ccc7c(c6)c6ccccc6n7-c6ccccc6)cccc54)c3)n2)cc1 ; c1ccc(-c2cc(-c3ccc(-n4c5ccccc5c5c(-c6ccc7c(c6)c6ccccc6n7-c6ccccc6)cccc54)cc3)nc(-c3ccccc3)n2)cc1]

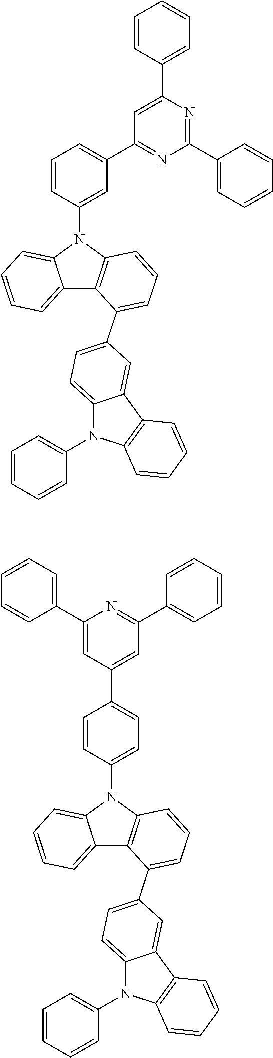 [SMILES: c1ccc(-c2cc(-c3cccc(-n4c5ccccc5c5c(-c6ccc7c(c6)c6ccccc6n7-c6ccccc6)cccc54)c3)nc(-c3ccccc3)n2)cc1 ; c1ccc(-c2cc(-c3ccc(-n4c5ccccc5c5c(-c6ccc7c(c6)c6ccccc6n7-c6ccccc6)cccc54)cc3)cc(-c3ccccc3)n2)cc1]

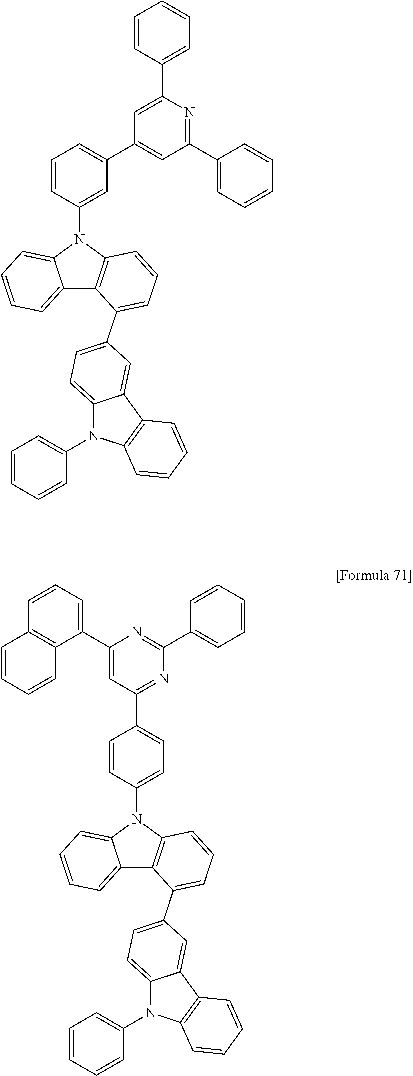 [SMILES: c1ccc(-c2cc(-c3cccc(-n4c5ccccc5c5c(-c6ccc7c(c6)c6ccccc6n7-c6ccccc6)cccc54)c3)cc(-c3ccccc3)n2)cc1 ; c1ccc(-c2nc(-c3ccc(-n4c5ccccc5c5c(-c6ccc7c(c6)c6ccccc6n7-c6ccccc6)cccc54)cc3)cc(-c3cccc4ccccc34)n2)cc1]

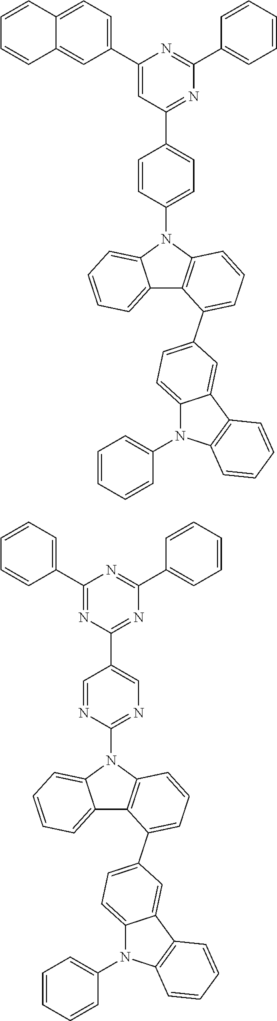 [SMILES: c1ccc(-c2nc(-c3ccc(-n4c5ccccc5c5c(-c6ccc7c(c6)c6ccccc6n7-c6ccccc6)cccc54)cc3)cc(-c3ccc4ccccc4c3)n2)cc1 ; c1ccc(-c2nc(-c3ccccc3)nc(-c3cnc(-n4c5ccccc5c5c(-c6ccc7c(c6)c6ccccc6n7-c6ccccc6)cccc54)nc3)n2)cc1]

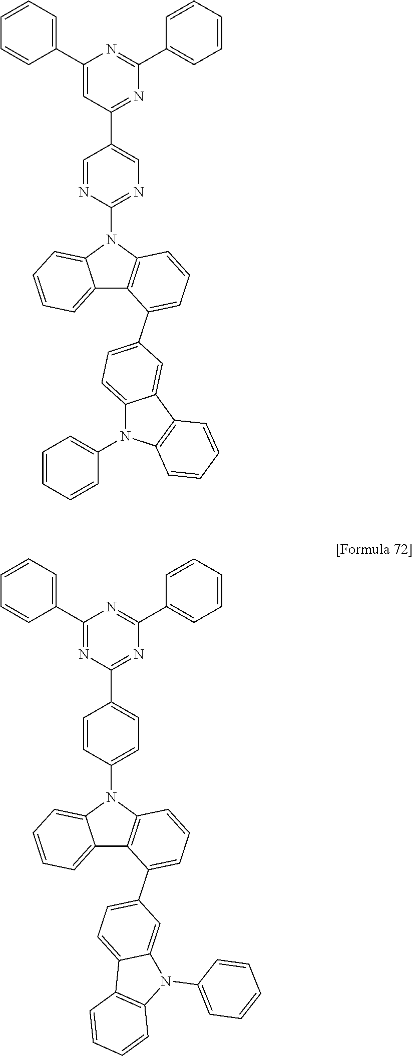 [SMILES: c1ccc(-c2cc(-c3cnc(-n4c5ccccc5c5c(-c6ccc7c(c6)c6ccccc6n7-c6ccccc6)cccc54)nc3)nc(-c3ccccc3)n2)cc1 ; c1ccc(-c2nc(-c3ccccc3)nc(-c3ccc(-n4c5ccccc5c5c(-c6ccc7c8ccccc8n(-c8ccccc8)c7c6)cccc54)cc3)n2)cc1]

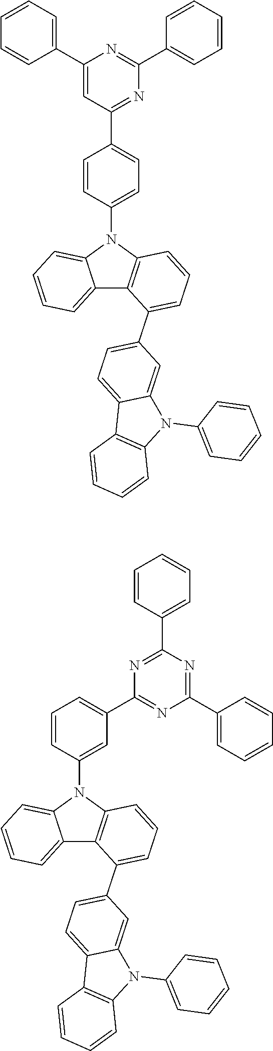 [SMILES: c1ccc(-c2cc(-c3ccc(-n4c5ccccc5c5c(-c6ccc7c8ccccc8n(-c8ccccc8)c7c6)cccc54)cc3)nc(-c3ccccc3)n2)cc1 ; c1ccc(-c2nc(-c3ccccc3)nc(-c3cccc(-n4c5ccccc5c5c(-c6ccc7c8ccccc8n(-c8ccccc8)c7c6)cccc54)c3)n2)cc1]

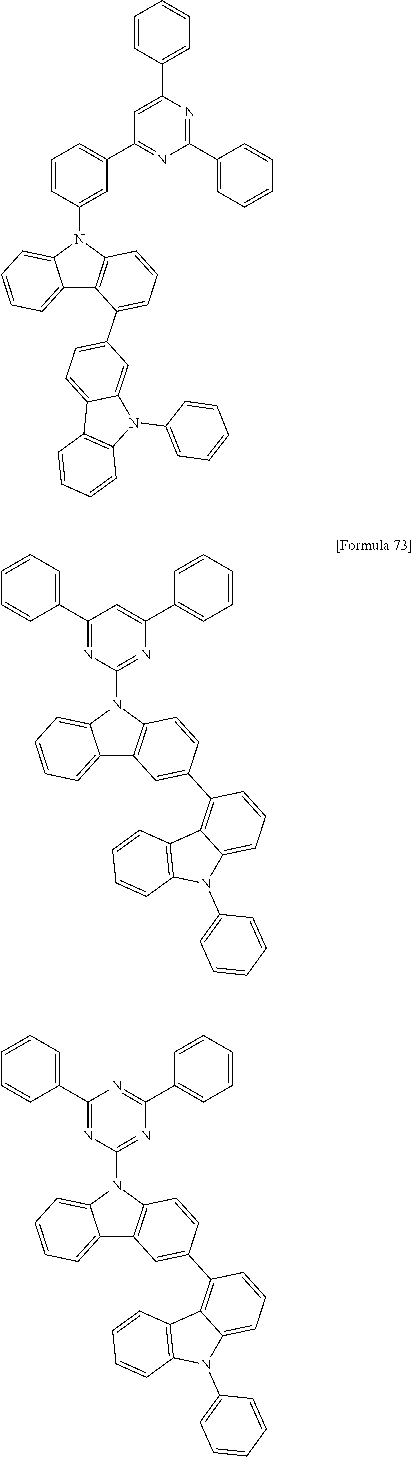 [SMILES: c1ccc(-c2cc(-c3cccc(-n4c5ccccc5c5c(-c6ccc7c8ccccc8n(-c8ccccc8)c7c6)cccc54)c3)nc(-c3ccccc3)n2)cc1 ; c1ccc(-c2cc(-c3ccccc3)nc(-n3c4ccccc4c4cc(-c5cccc6c5c5ccccc5n6-c5ccccc5)ccc43)n2)cc1 ; c1ccc(-c2nc(-c3ccccc3)nc(-n3c4ccccc4c4cc(-c5cccc6c5c5ccccc5n6-c5ccccc5)ccc43)n2)cc1]

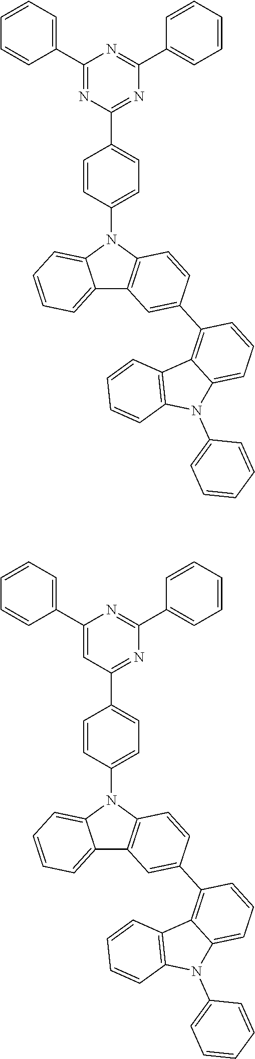 [SMILES: c1ccc(-c2nc(-c3ccccc3)nc(-c3ccc(-n4c5ccccc5c5cc(-c6cccc7c6c6ccccc6n7-c6ccccc6)ccc54)cc3)n2)cc1 ; c1ccc(-c2cc(-c3ccc(-n4c5ccccc5c5cc(-c6cccc7c6c6ccccc6n7-c6ccccc6)ccc54)cc3)nc(-c3ccccc3)n2)cc1]

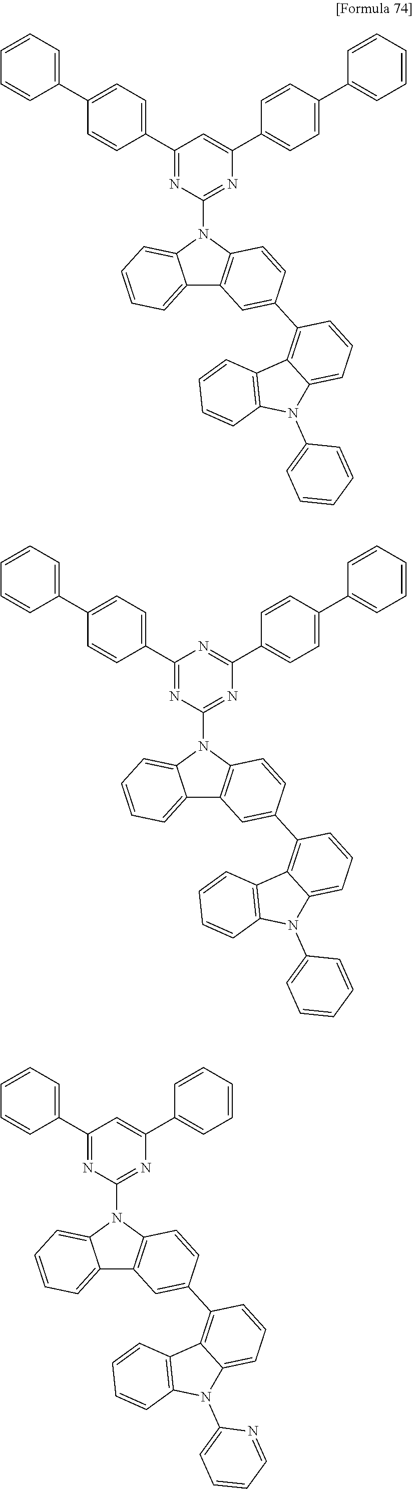 [SMILES: c1ccc(-c2ccc(-c3cc(-c4ccc(-c5ccccc5)cc4)nc(-n4c5ccccc5c5cc(-c6cccc7c6c6ccccc6n7-c6ccccc6)ccc54)n3)cc2)cc1 ; c1ccc(-c2ccc(-c3nc(-c4ccc(-c5ccccc5)cc4)nc(-n4c5ccccc5c5cc(-c6cccc7c6c6ccccc6n7-c6ccccc6)ccc54)n3)cc2)cc1 ; c1ccc(-c2cc(-c3ccccc3)nc(-n3c4ccccc4c4cc(-c5cccc6c5c5ccccc5n6-c5ccccn5)ccc43)n2)cc1]

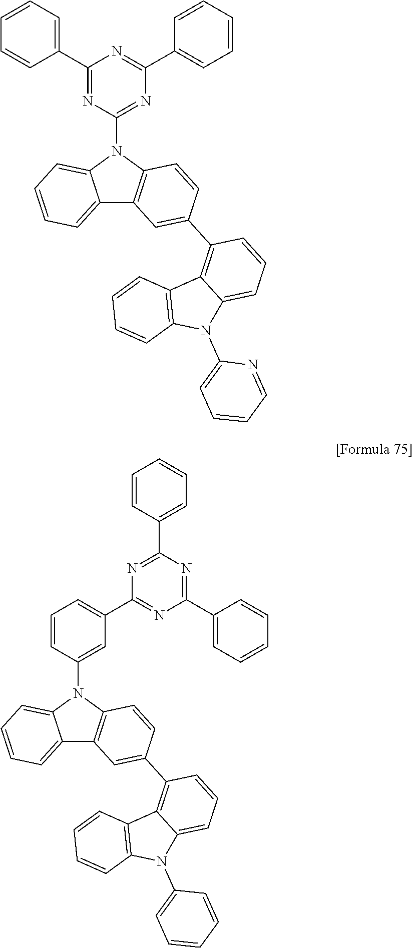 [SMILES: c1ccc(-c2nc(-c3ccccc3)nc(-n3c4ccccc4c4cc(-c5cccc6c5c5ccccc5n6-c5ccccn5)ccc43)n2)cc1 ; c1ccc(-c2nc(-c3ccccc3)nc(-c3cccc(-n4c5ccccc5c5cc(-c6cccc7c6c6ccccc6n7-c6ccccc6)ccc54)c3)n2)cc1]

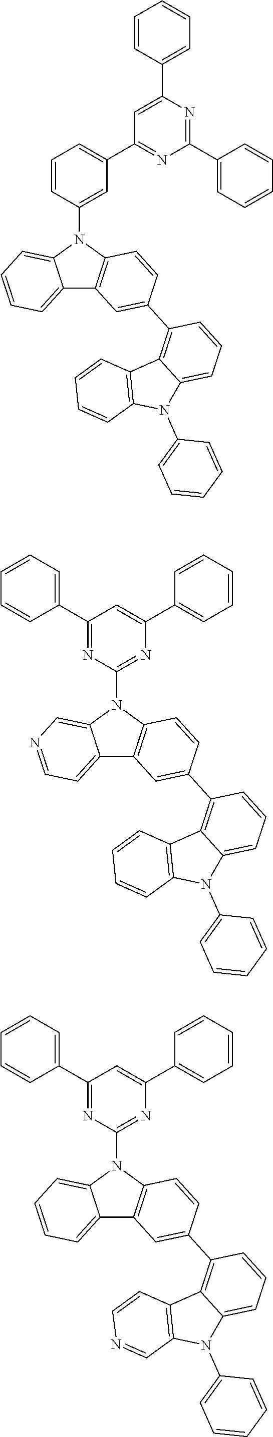

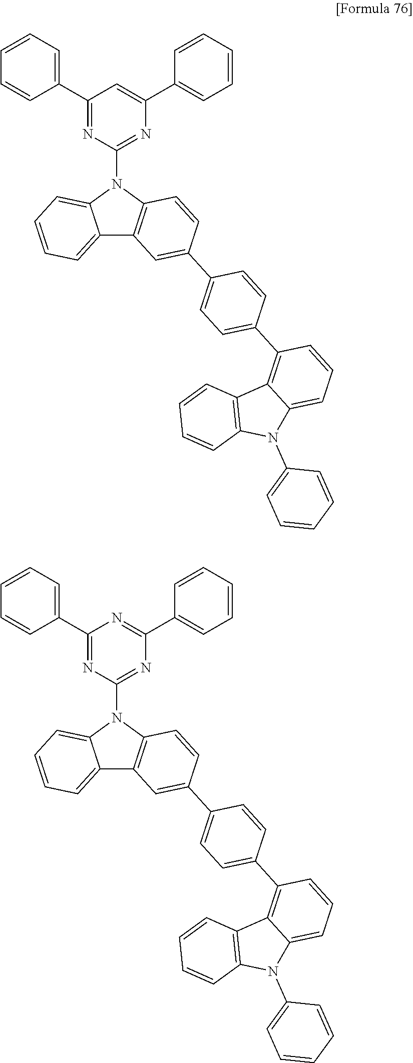 [SMILES: c1ccc(-c2cc(-c3ccccc3)nc(-n3c4ccccc4c4cc(-c5ccc(-c6cccc7c6c6ccccc6n7-c6ccccc6)cc5)ccc43)n2)cc1 ; c1ccc(-c2nc(-c3ccccc3)nc(-n3c4ccccc4c4cc(-c5ccc(-c6cccc7c6c6ccccc6n7-c6ccccc6)cc5)ccc43)n2)cc1]

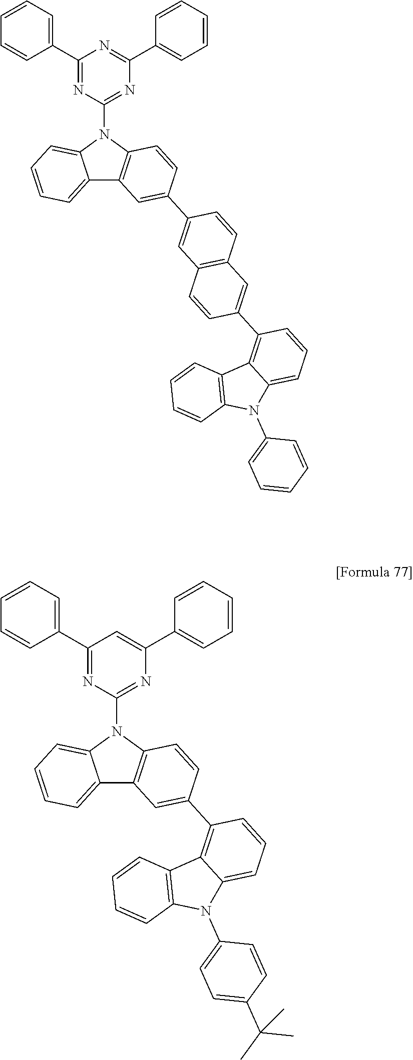 [SMILES: c1ccc(-c2nc(-c3ccccc3)nc(-n3c4ccccc4c4cc(-c5ccc6cc(-c7cccc8c7c7ccccc7n8-c7ccccc7)ccc6c5)ccc43)n2)cc1 ; CC(C)(C)c1ccc(-n2c3ccccc3c3c(-c4ccc5c(c4)c4ccccc4n5-c4nc(-c5ccccc5)cc(-c5ccccc5)n4)cccc32)cc1]

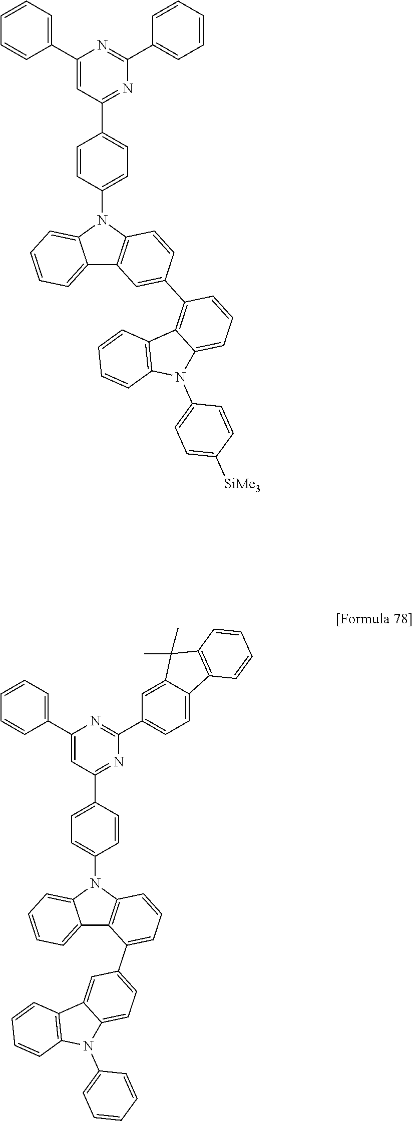 [SMILES: C[Si](C)(C)c1ccc(-n2c3ccccc3c3c(-c4ccc5c(c4)c4ccccc4n5-c4ccc(-c5cc(-c6ccccc6)nc(-c6ccccc6)n5)cc4)cccc32)cc1 ; CC1(C)c2ccccc2-c2ccc(-c3nc(-c4ccccc4)cc(-c4ccc(-n5c6ccccc6c6c(-c7ccc8c(c7)c7ccccc7n8-c7ccccc7)cccc65)cc4)n3)cc21]

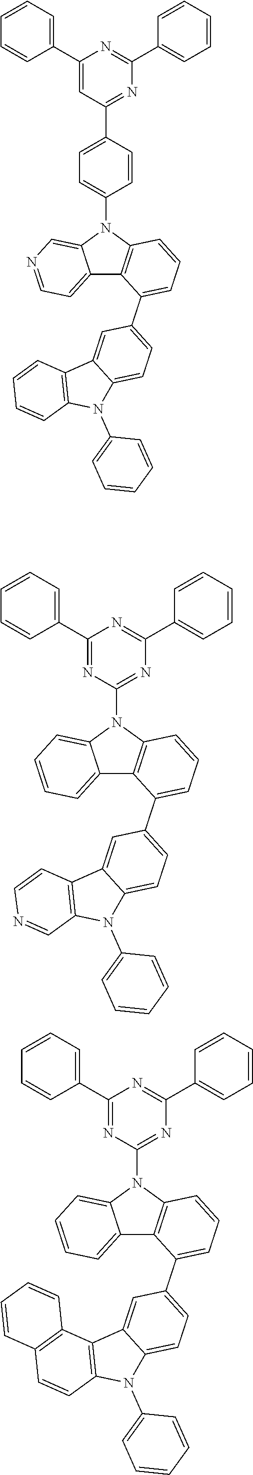 [SMILES: c1ccc(-c2cc(-c3ccc(-n4c5cnccc5c5c(-c6ccc7c(c6)c6ccccc6n7-c6ccccc6)cccc54)cc3)nc(-c3ccccc3)n2)cc1 ; c1ccc(-c2nc(-c3ccccc3)nc(-n3c4ccccc4c4c(-c5ccc6c(c5)c5ccncc5n6-c5ccccc5)cccc43)n2)cc1 ; c1ccc(-c2nc(-c3ccccc3)nc(-n3c4ccccc4c4c(-c5ccc6c(c5)c5c7ccccc7ccc5n6-c5ccccc5)cccc43)n2)cc1]

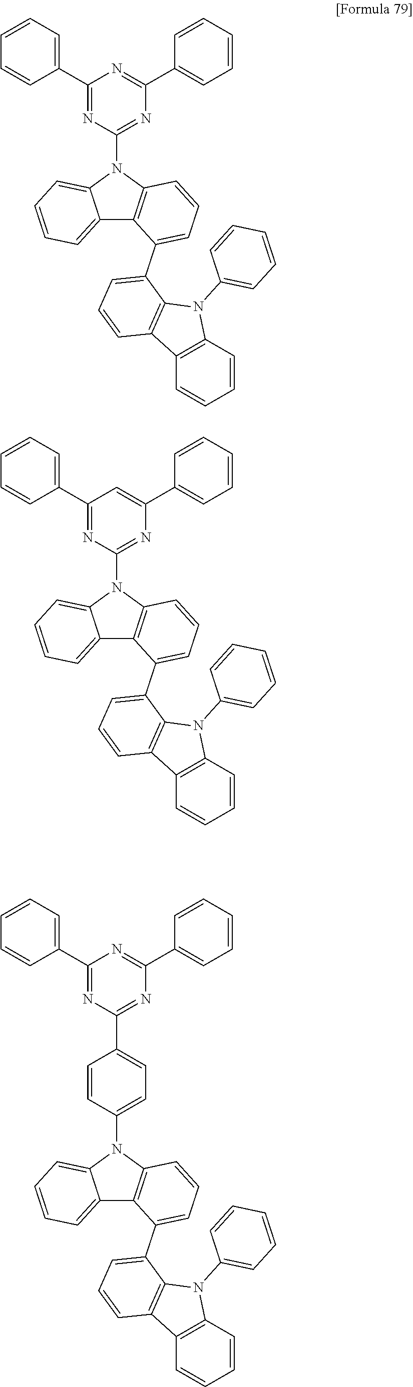

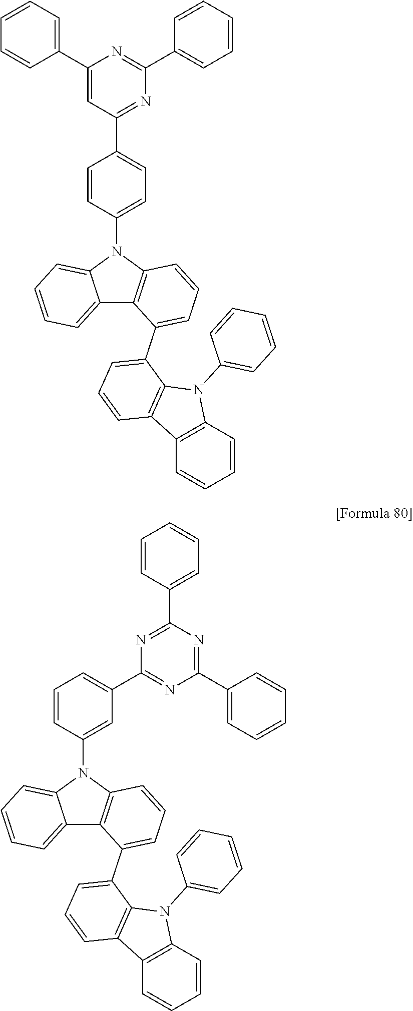 [SMILES: c1ccc(-c2cc(-c3ccc(-n4c5ccccc5c5c(-c6cccc7c8ccccc8n(-c8ccccc8)c67)cccc54)cc3)nc(-c3ccccc3)n2)cc1 ; c1ccc(-c2nc(-c3ccccc3)nc(-c3cccc(-n4c5ccccc5c5c(-c6cccc7c8ccccc8n(-c8ccccc8)c67)cccc54)c3)n2)cc1]

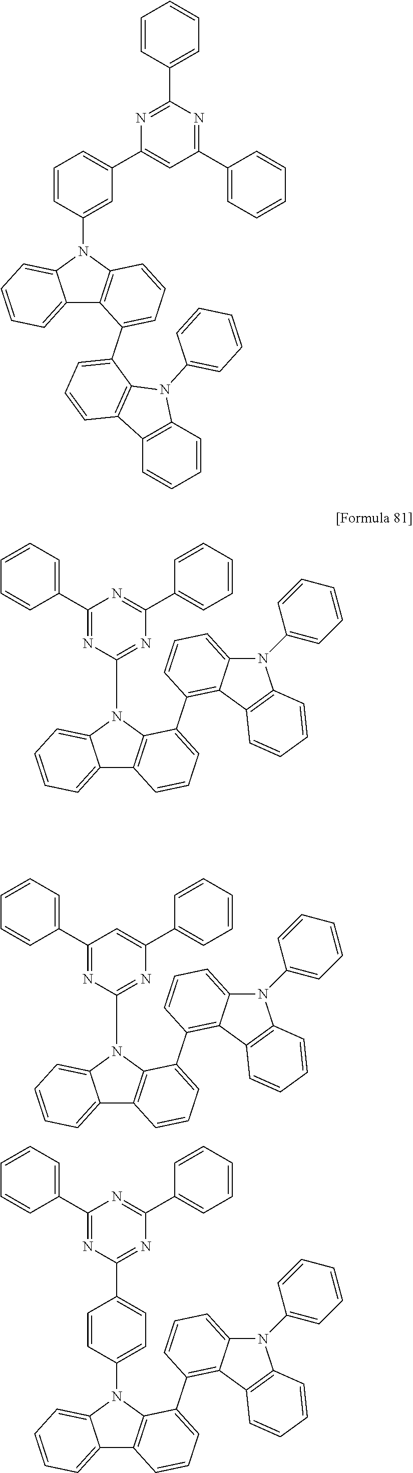

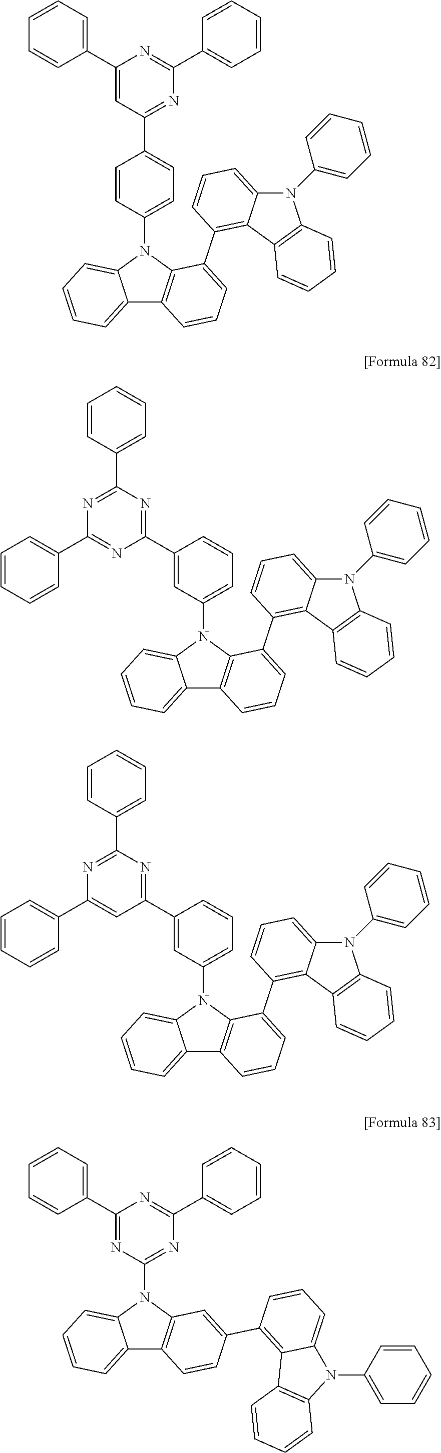 [SMILES: c1ccc(-c2cc(-c3ccc(-n4c5ccccc5c5cccc(-c6cccc7c6c6ccccc6n7-c6ccccc6)c54)cc3)nc(-c3ccccc3)n2)cc1 ; c1ccc(-c2nc(-c3ccccc3)nc(-c3cccc(-n4c5ccccc5c5cccc(-c6cccc7c6c6ccccc6n7-c6ccccc6)c54)c3)n2)cc1 ; c1ccc(-c2cc(-c3cccc(-n4c5ccccc5c5cccc(-c6cccc7c6c6ccccc6n7-c6ccccc6)c54)c3)nc(-c3ccccc3)n2)cc1 ; c1ccc(-c2nc(-c3ccccc3)nc(-n3c4ccccc4c4ccc(-c5cccc6c5c5ccccc5n6-c5ccccc5)cc43)n2)cc1]

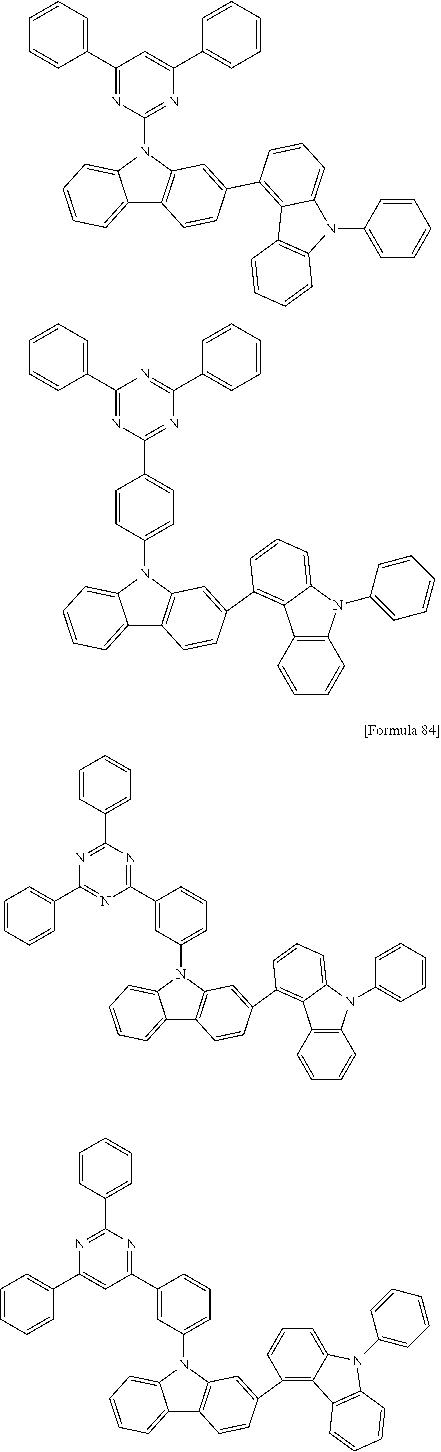

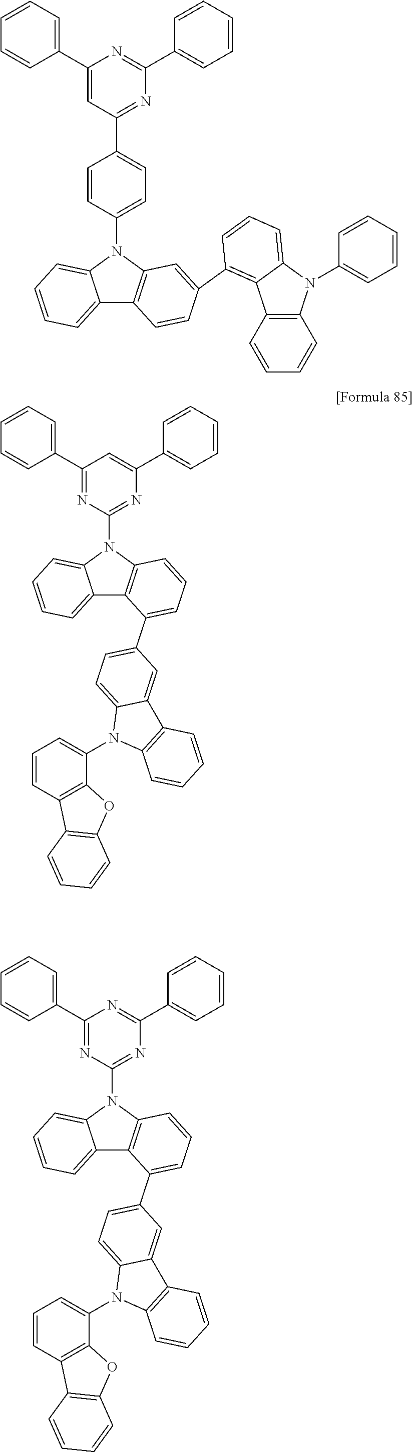 [SMILES: c1ccc(-c2cc(-c3ccc(-n4c5ccccc5c5ccc(-c6cccc7c6c6ccccc6n7-c6ccccc6)cc54)cc3)nc(-c3ccccc3)n2)cc1 ; c1ccc(-c2cc(-c3ccccc3)nc(-n3c4ccccc4c4c(-c5ccc6c(c5)c5ccccc5n6-c5cccc6c5oc5ccccc56)cccc43)n2)cc1 ; c1ccc(-c2nc(-c3ccccc3)nc(-n3c4ccccc4c4c(-c5ccc6c(c5)c5ccccc5n6-c5cccc6c5oc5ccccc56)cccc43)n2)cc1]

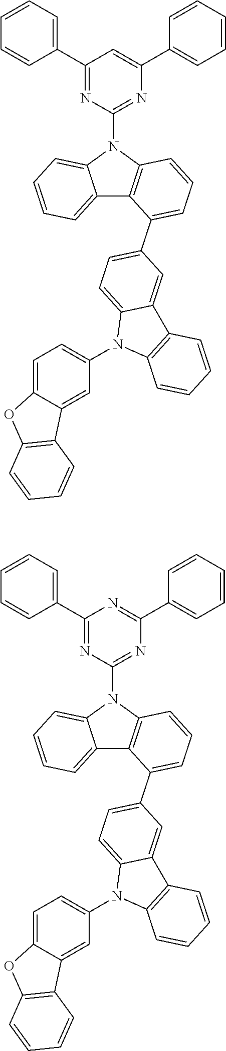 [SMILES: c1ccc(-c2cc(-c3ccccc3)nc(-n3c4ccccc4c4c(-c5ccc6c(c5)c5ccccc5n6-c5ccc6oc7ccccc7c6c5)cccc43)n2)cc1 ; c1ccc(-c2nc(-c3ccccc3)nc(-n3c4ccccc4c4c(-c5ccc6c(c5)c5ccccc5n6-c5ccc6oc7ccccc7c6c5)cccc43)n2)cc1]

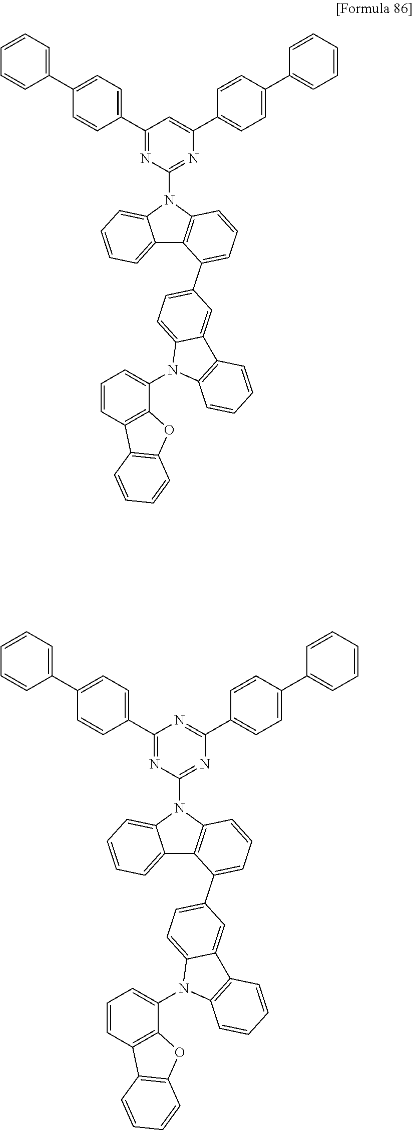 [SMILES: c1ccc(-c2ccc(-c3cc(-c4ccc(-c5ccccc5)cc4)nc(-n4c5ccccc5c5c(-c6ccc7c(c6)c6ccccc6n7-c6cccc7c6oc6ccccc67)cccc54)n3)cc2)cc1 ; c1ccc(-c2ccc(-c3nc(-c4ccc(-c5ccccc5)cc4)nc(-n4c5ccccc5c5c(-c6ccc7c(c6)c6ccccc6n7-c6cccc7c6oc6ccccc67)cccc54)n3)cc2)cc1]

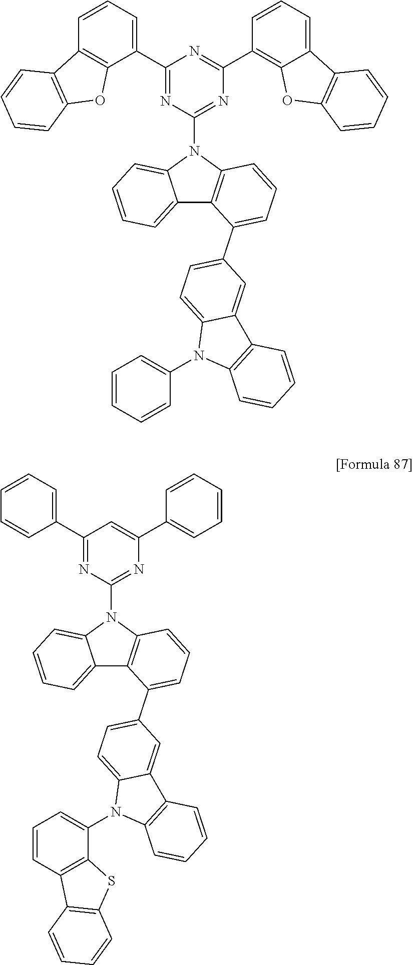 [SMILES: c1ccc(-n2c3ccccc3c3cc(-c4cccc5c4c4ccccc4n5-c4nc(-c5cccc6c5oc5ccccc56)nc(-c5cccc6c5oc5ccccc56)n4)ccc32)cc1 ; c1ccc(-c2cc(-c3ccccc3)nc(-n3c4ccccc4c4c(-c5ccc6c(c5)c5ccccc5n6-c5cccc6c5sc5ccccc56)cccc43)n2)cc1]

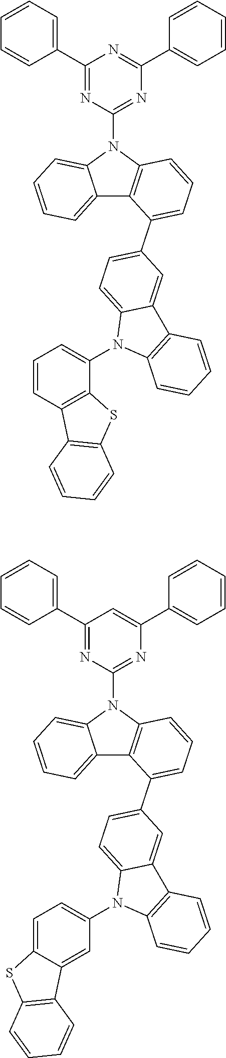 [SMILES: c1ccc(-c2nc(-c3ccccc3)nc(-n3c4ccccc4c4c(-c5ccc6c(c5)c5ccccc5n6-c5cccc6c5sc5ccccc56)cccc43)n2)cc1 ; c1ccc(-c2cc(-c3ccccc3)nc(-n3c4ccccc4c4c(-c5ccc6c(c5)c5ccccc5n6-c5ccc6sc7ccccc7c6c5)cccc43)n2)cc1]

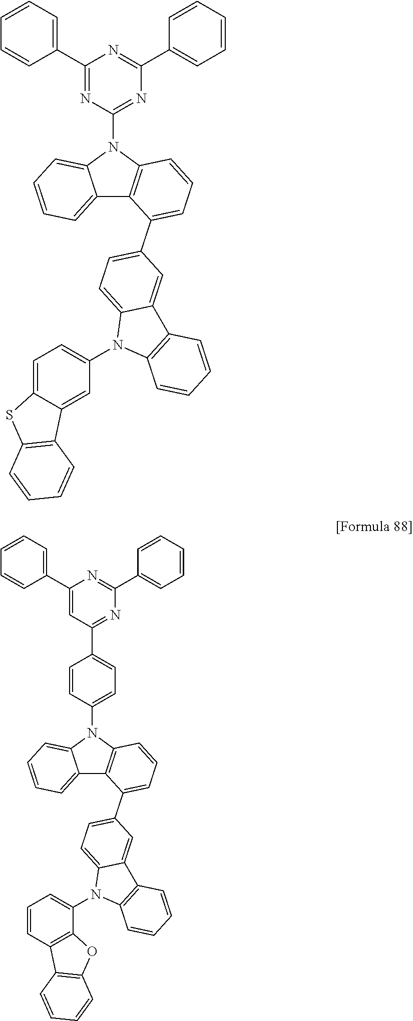

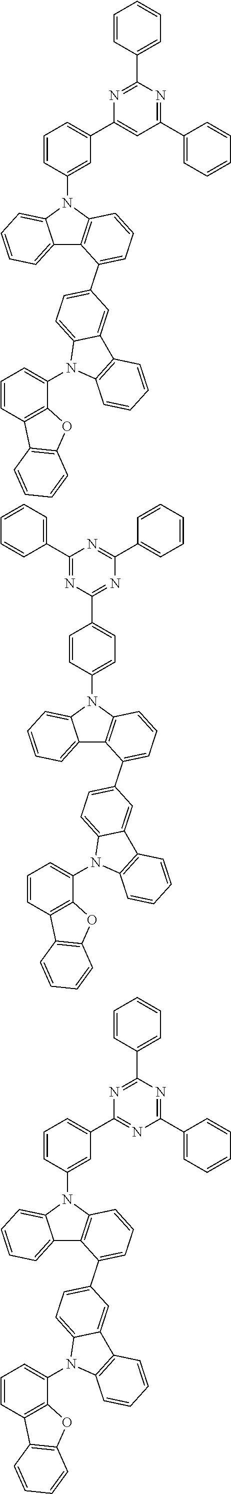

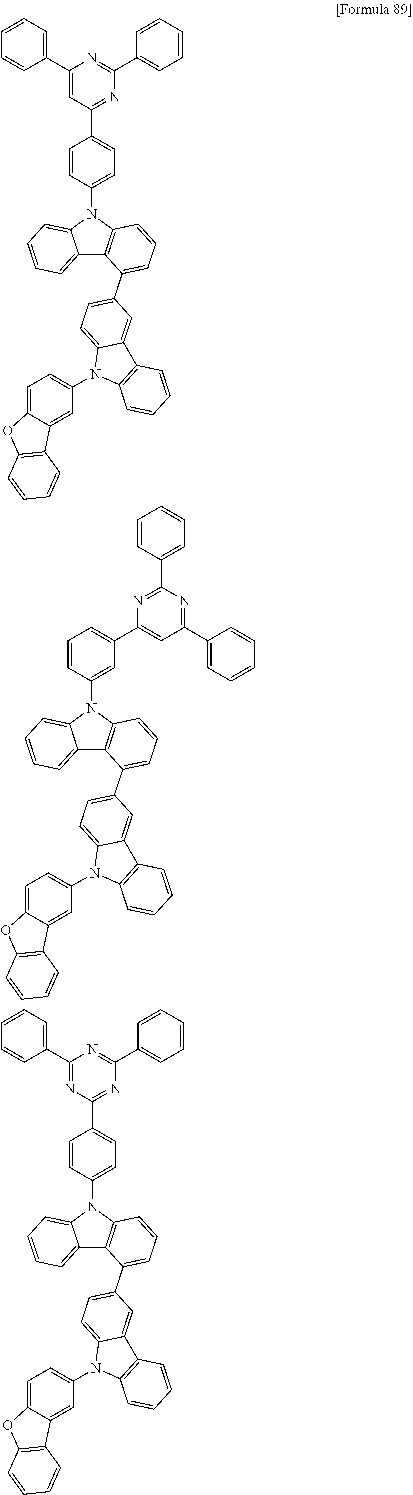

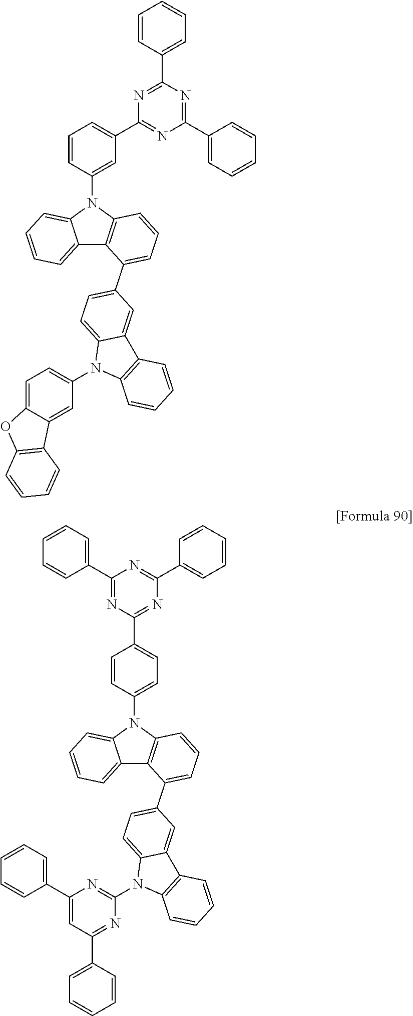

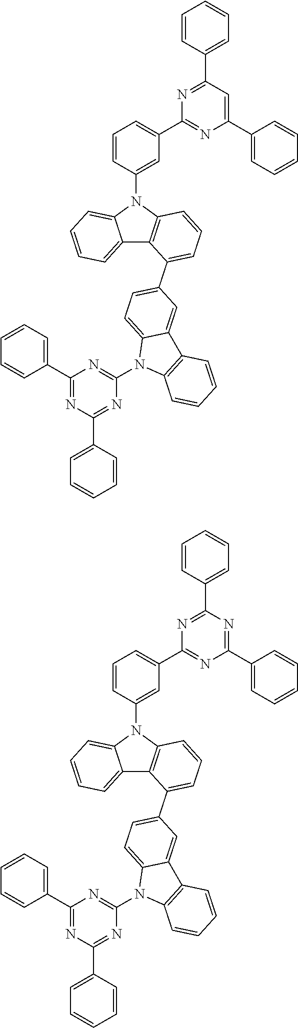 [SMILES: c1ccc(-c2cc(-c3ccccc3)nc(-c3cccc(-n4c5ccccc5c5c(-c6ccc7c(c6)c6ccccc6n7-c6nc(-c7ccccc7)nc(-c7ccccc7)n6)cccc54)c3)n2)cc1 ; c1ccc(-c2nc(-c3ccccc3)nc(-c3cccc(-n4c5ccccc5c5c(-c6ccc7c(c6)c6ccccc6n7-c6nc(-c7ccccc7)nc(-c7ccccc7)n6)cccc54)c3)n2)cc1]

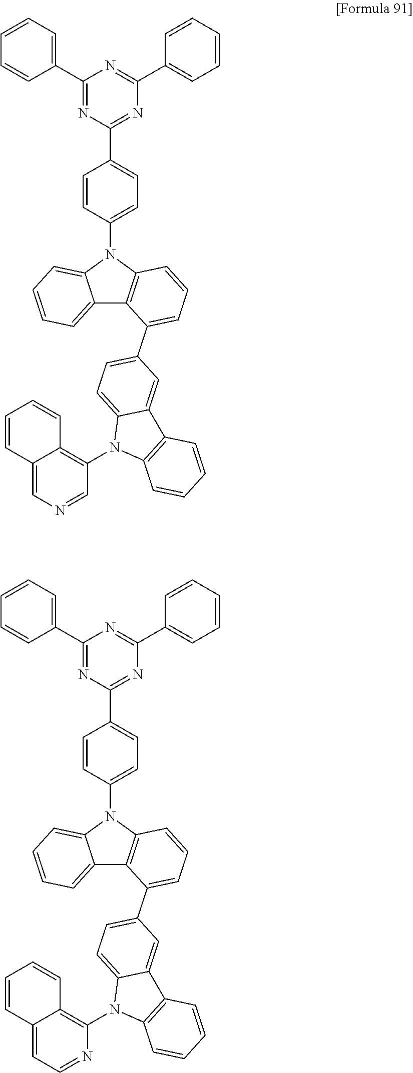 [SMILES: c1ccc(-c2nc(-c3ccccc3)nc(-c3ccc(-n4c5ccccc5c5c(-c6ccc7c(c6)c6ccccc6n7-c6cncc7ccccc67)cccc54)cc3)n2)cc1 ; c1ccc(-c2nc(-c3ccccc3)nc(-c3ccc(-n4c5ccccc5c5c(-c6ccc7c(c6)c6ccccc6n7-c6nccc7ccccc67)cccc54)cc3)n2)cc1]

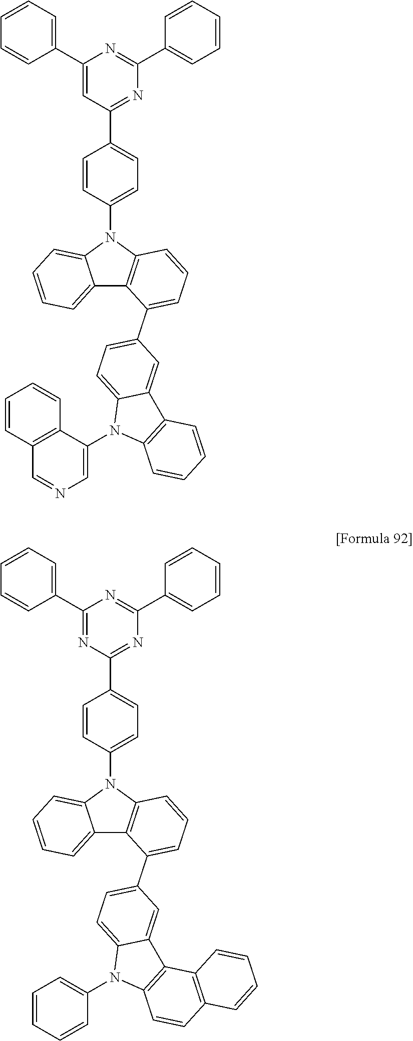 [SMILES: c1ccc(-c2cc(-c3ccc(-n4c5ccccc5c5c(-c6ccc7c(c6)c6ccccc6n7-c6cncc7ccccc67)cccc54)cc3)nc(-c3ccccc3)n2)cc1 ; c1ccc(-c2nc(-c3ccccc3)nc(-c3ccc(-n4c5ccccc5c5c(-c6ccc7c(c6)c6c8ccccc8ccc6n7-c6ccccc6)cccc54)cc3)n2)cc1]

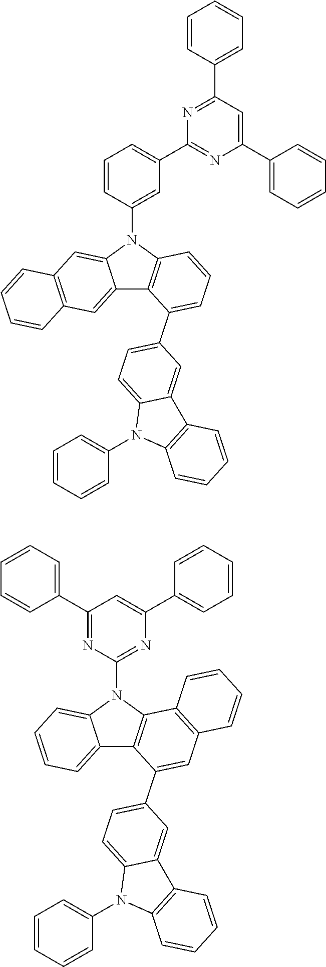 [SMILES: c1ccc(-c2cc(-c3ccccc3)nc(-c3cccc(-n4c5cc6ccccc6cc5c5c(-c6ccc7c(c6)c6ccccc6n7-c6ccccc6)cccc54)c3)n2)cc1 ; c1ccc(-c2cc(-c3ccccc3)nc(-n3c4ccccc4c4c(-c5ccc6c(c5)c5ccccc5n6-c5ccccc5)cc5ccccc5c43)n2)cc1]

### Second Host Material

The second host material used in the organic EL device according to the exemplary embodiment may be a compound represented by the following formula (2).

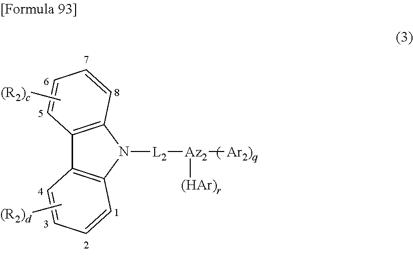

In the formula (3), R₂ are each independently a hydrogen atom, a halogen atom, a cyano group, a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted alkenyl group having 2 to 30 carbon atoms, a substituted or unsubstituted alkynyl group having 2 to 30 carbon atoms, a substituted or unsubstituted alkylsilyl group having 3 to 30 carbon atoms, a substituted or unsubstituted arylsilyl group having 6 to 30 ring carbon atoms, a substituted or unsubstituted alkoxy group having 1 to 30 carbon atoms, a substituted or unsubstituted aralkyl group having 6 to 30 ring carbon atoms, or a substituted or unsubstituted aryloxy group having 6 to 30 ring carbon atoms.

In the formula (3), c and d each independently an integer of 0 to 4 and plural R₂ are mutually the same or different.

In the formula (3), R₂ represents the same as R₁ in the formula (1).

In the formula (3), q is an integer of from 1 to 4.

In the formula (3), r is 0 or 1.

In the formula (3), 1≦q+r≦4.

In the formula (3), L₂ is a single bond or a linking group, the linking group being a substituted or unsubstituted aryl group having 6 to 30 ring carbon atoms, a substituted or unsubstituted heterocyclic group having 5 to 30 ring atoms, a cyclic hydrocarbon group having 5 to 30 ring carbon atoms, or a group provided by bonding the aryl group and the heterocyclic group.

L₂ as the linking group is the same as L₁ in the formula (1) as the linking group.

In the formula (3), Ar₂ is a substituted or unsubstituted aryl group having 6 to 30 ring carbon atoms, a substituted or unsubstituted heterocyclic group having 5 to 30 ring carbon atoms, or a group provided by bonding the aryl group and the heterocyclic group.

Ar₂ represents the same as Ar₁ in the formula (1).

In the formula (3), Az₂ is a group represented by the following formula (4).

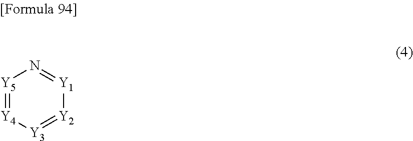

In the formula (4), any one of Y₁ to Y₅ is bonded to L₂.

In the formula (4), q of the other four of Y₁ to Y₅ that are not bonded to L₂ are each a carbon atom bonded to Ar₂, r of the other four of Y₁ to Y₅ are each a carbon atom bonded to HAr, and (4-q-r) of the other four of Y₁ to Y₅ are each independently CR₃ or a nitrogen atom. CR₃ is a carbon atom (C) bonded with R₃.

In the formula (4), R₃ represents the same as R₂ in the formula (3).

In the formula (4), HAr is represented by any one of the following formulae (5) to (7).

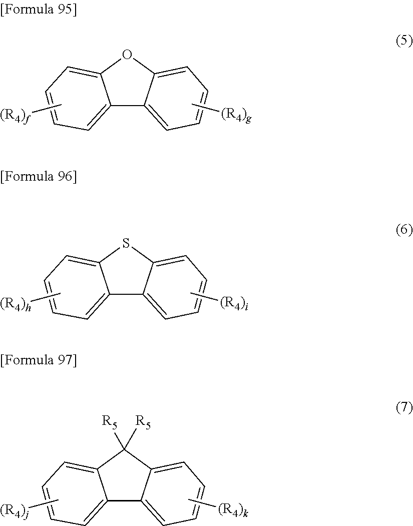

In the formula (5), each of f and g is 4.

In the formula (6), each of h and i is 4.

In the formula (7), each of j and k is 4.

Plural R₄ in each of the formulae (5), (6) and (7) are mutually the same or different and at least one of the plural R₄ is a single bond to Az₂. R₄ in each of the formulae (5), (6) and (7) represents the same as R₂ in the formula (3).

Two R₅ in the formula (7) are mutually the same or different and each represent the same as R₂ in the formula (3).

R₂ is bonded to a carbazole ring in the formula (3), the carbazole ring being bonded to a moiety represented by the following formula (8).

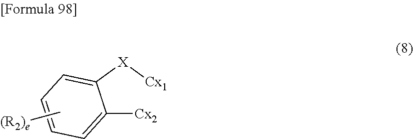

In the moiety represented by the formula (8), Cx₁ and Cx₂ are any adjacent two of carbon atoms in 1- to 8-positions of the carbazole ring to which R₂ is bonded in the formula (3), the moiety represented by the formula (8) being bonded to the carbazole ring in the adjacent two of carbon atoms.

Specific description is made below on such an arrangement that the moiety represented by the formula (8) is bonded to the carbazole ring to which R₂ is bonded in the formula (3).

When Cx₁ is a carbon atom in the 1-position of the carbazole ring, Cx₂ is a carbon atom in the 2-position of the carbazole ring and the structure of the formula (3) is represented by the following formula (3-1).

When Cx₁ is a carbon atom in the 2-position of the carbazole ring, Cx₂ is a carbon atom in the 1-position or a carbon atom in the 3-position of the carbazole ring. While the structure of the formula (3) is represented by the following formula (3-2) in the former case, the structure is represented by the following formula (3-3) in the latter case.

When Cx₁ is a carbon atom in the 3-position of the carbazole ring, Cx₂ is a carbon atom in the 2-position or a carbon atom in the 4-position of the carbazole ring. While the structure of the formula (3) is represented by the following formula (3-4) in the former case, the structure is represented by the following formula (3-5) in the latter case.

When Cx₁ is a carbon atom in the 4-position of the carbazole ring, Cx₂ is a carbon atom in the 3-position of the carbazole ring and the structure of the formula (3) is represented by the following formula (3-6).

When Cx₁ is a carbon atom in the 5-position of the carbazole ring, Cx₂ is a carbon atom in the 6-position of the carbazole ring and the structure of the formula (3) is similar to a structure represented by the following formula (3-6).

When Cx₁ is a carbon atom in the 6-position of the carbazole ring, Cx₂ is a carbon atom in the 5-position or a carbon atom in the 7-position of the carbazole ring. The structure of the formula (3) is similar to a structure represented by the following formula (3-5) in the former case and is similar to a structure represented by the following formula (3-4) in the latter case.

When Cx₁ is a carbon atom in the 7-position of the carbazole ring, Cx₂ is a carbon atom in the 6-position or a carbon atom in the 8-position of the carbazole ring. The structure of the formula (3) is similar to a structure represented by the following formula (3-3) in the former case and is similar to a structure represented by the following formula (3-2) in the latter case.

When Cx₁ is a carbon atom in the 8-position of the carbazole ring, Cx₂ is a carbon atom in the 7-position of the carbazole ring and the structure of the formula (3) is similar to a structure represented by the following formula (3-1).

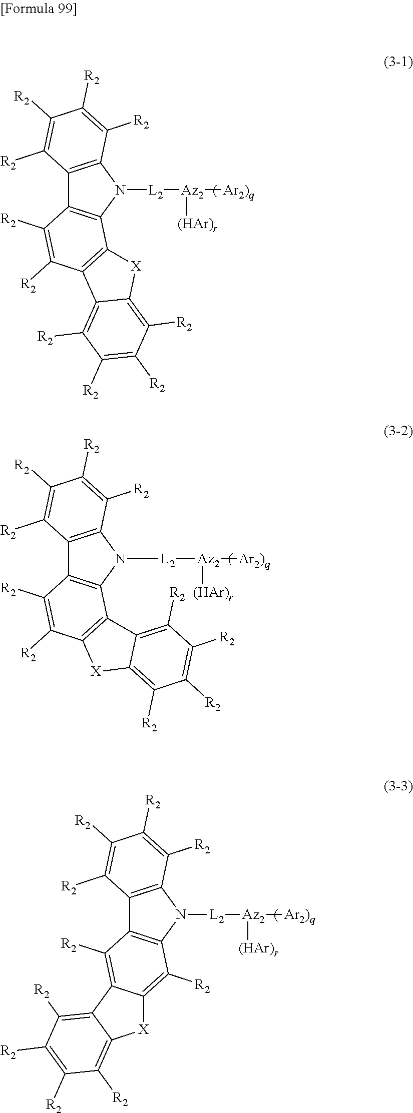

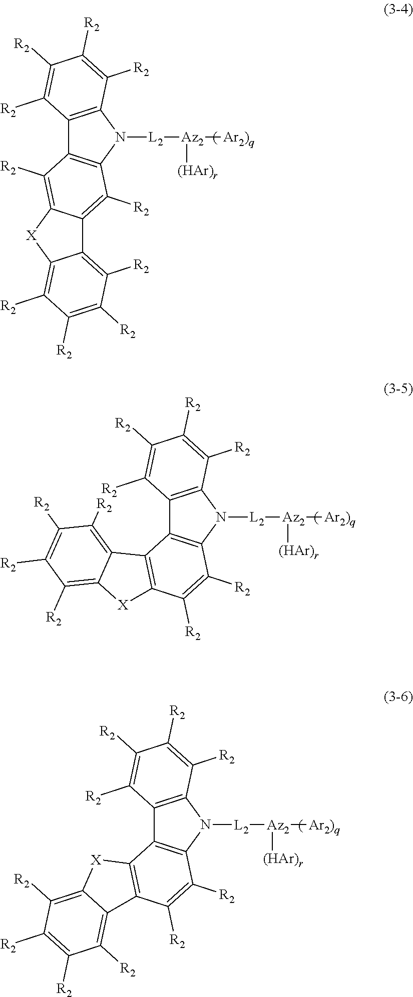

In the formula (8), X is an oxygen atom, a sulfur atom, NR₂ or C(R₂)₂. NR₂ is a nitrogen atom (N) bonded with one R₂ and C(R₂)₂ is a carbon atom (C) bonded with two R₂.

In the formula (8), e is 4.

In the formula (8), R₂ represents the same as R₂ in the formula (3).

Examples of the compound represented by the formula (3) are shown below. It should be noted that these exemplary compound structures are not intended to limit the scope of the invention.

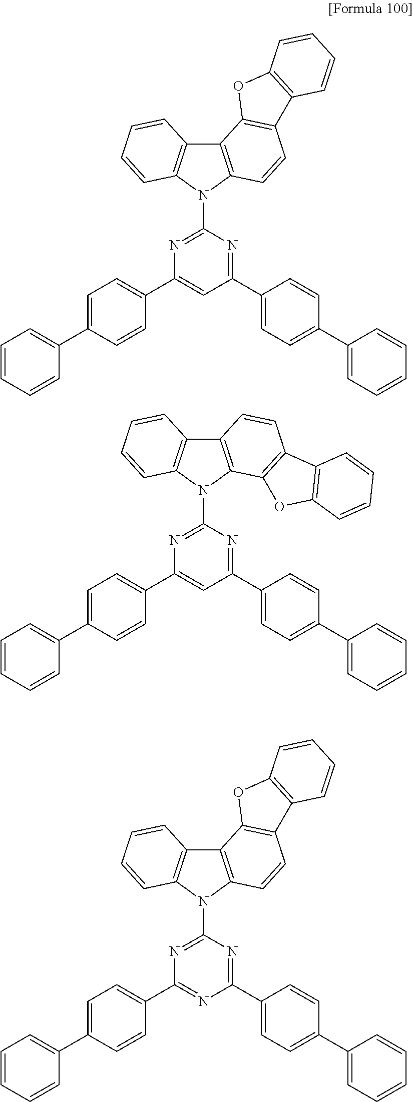 [SMILES: c1ccc(-c2ccc(-c3cc(-c4ccc(-c5ccccc5)cc4)nc(-n4c5ccccc5c5c6oc7ccccc7c6ccc54)n3)cc2)cc1 ; c1ccc(-c2ccc(-c3cc(-c4ccc(-c5ccccc5)cc4)nc(-n4c5ccccc5c5ccc6c7ccccc7oc6c54)n3)cc2)cc1 ; c1ccc(-c2ccc(-c3nc(-c4ccc(-c5ccccc5)cc4)nc(-n4c5ccccc5c5c6oc7ccccc7c6ccc54)n3)cc2)cc1]

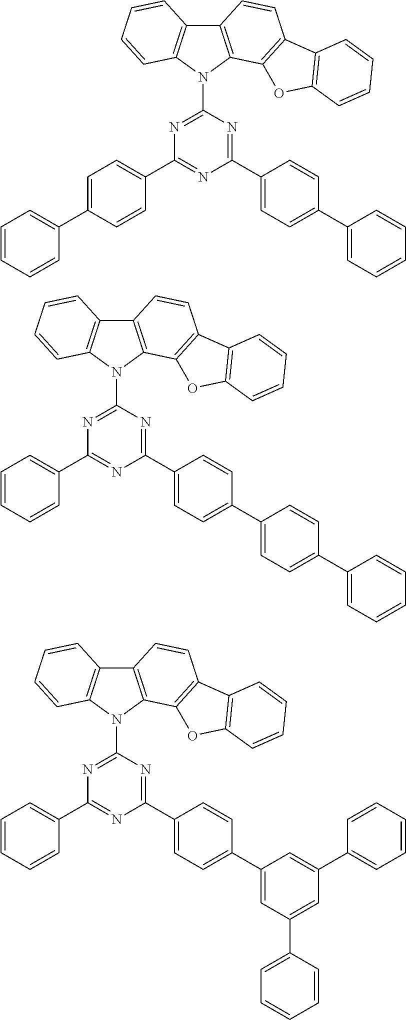

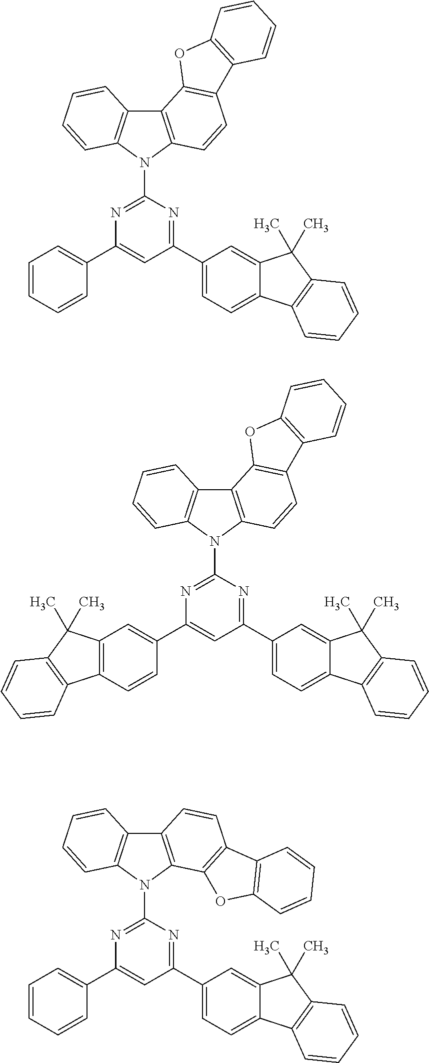

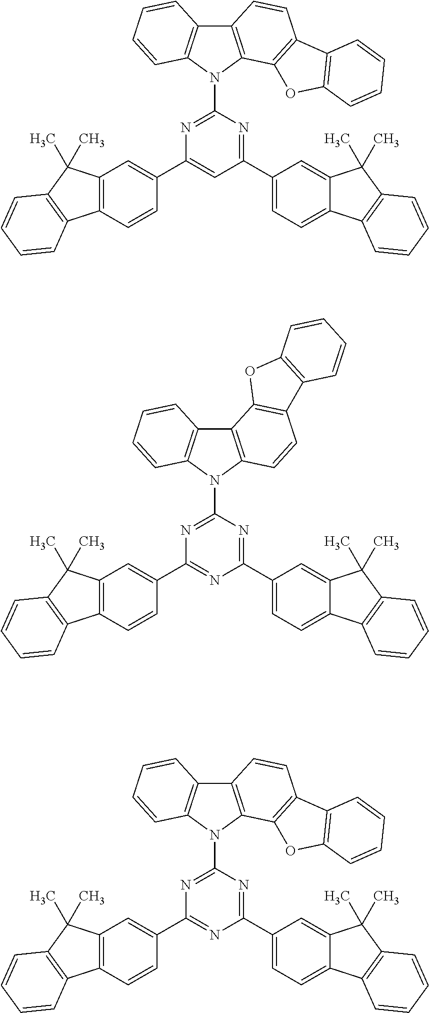 [SMILES: CC1(C)c2ccccc2-c2ccc(-c3cc(-c4ccc5c(c4)C(C)(C)c4ccccc4-5)nc(-n4c5ccccc5c5ccc6c7ccccc7oc6c54)n3)cc21 ; CC1(C)c2ccccc2-c2ccc(-c3nc(-c4ccc5c(c4)C(C)(C)c4ccccc4-5)nc(-n4c5ccccc5c5c6oc7ccccc7c6ccc54)n3)cc21 ; CC1(C)c2ccccc2-c2ccc(-c3nc(-c4ccc5c(c4)C(C)(C)c4ccccc4-5)nc(-n4c5ccccc5c5ccc6c7ccccc7oc6c54)n3)cc21]

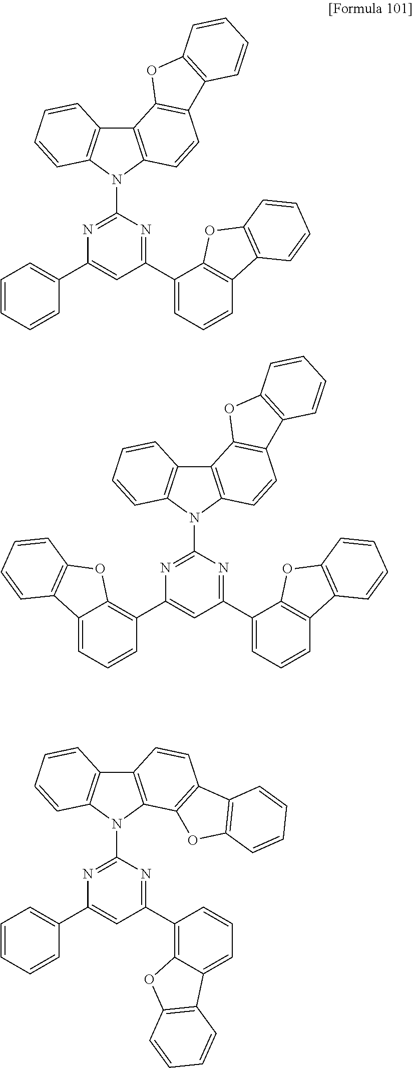 [SMILES: c1ccc(-c2cc(-c3cccc4c3oc3ccccc34)nc(-n3c4ccccc4c4c5oc6ccccc6c5ccc43)n2)cc1 ; c1ccc2c(c1)oc1c(-c3cc(-c4cccc5c4oc4ccccc45)nc(-n4c5ccccc5c5c6oc7ccccc7c6ccc54)n3)cccc12 ; c1ccc(-c2cc(-c3cccc4c3oc3ccccc34)nc(-n3c4ccccc4c4ccc5c6ccccc6oc5c43)n2)cc1]

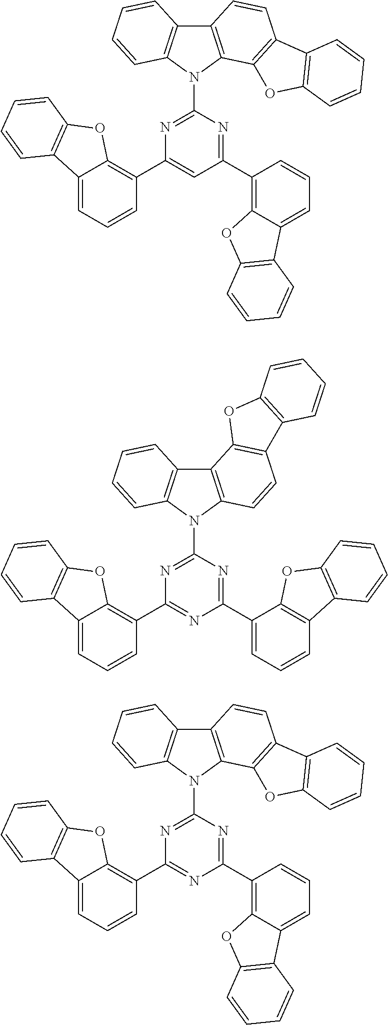

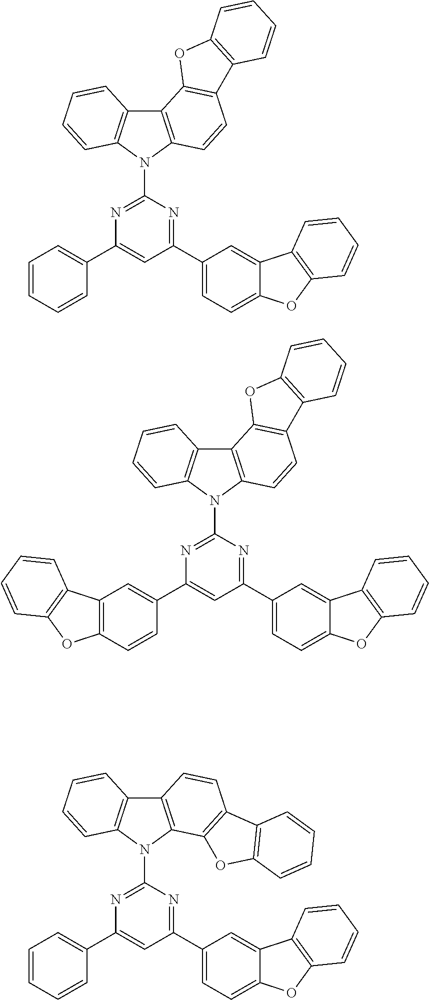

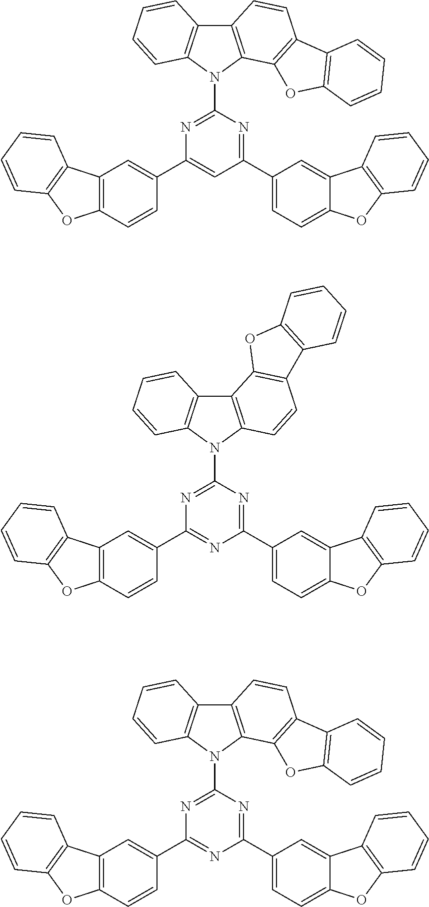 [SMILES: c1ccc2c(c1)oc1ccc(-c3cc(-c4ccc5oc6ccccc6c5c4)nc(-n4c5ccccc5c5ccc6c7ccccc7oc6c54)n3)cc12 ; c1ccc2c(c1)oc1ccc(-c3nc(-c4ccc5oc6ccccc6c5c4)nc(-n4c5ccccc5c5c6oc7ccccc7c6ccc54)n3)cc12 ; c1ccc2c(c1)oc1ccc(-c3nc(-c4ccc5oc6ccccc6c5c4)nc(-n4c5ccccc5c5ccc6c7ccccc7oc6c54)n3)cc12]

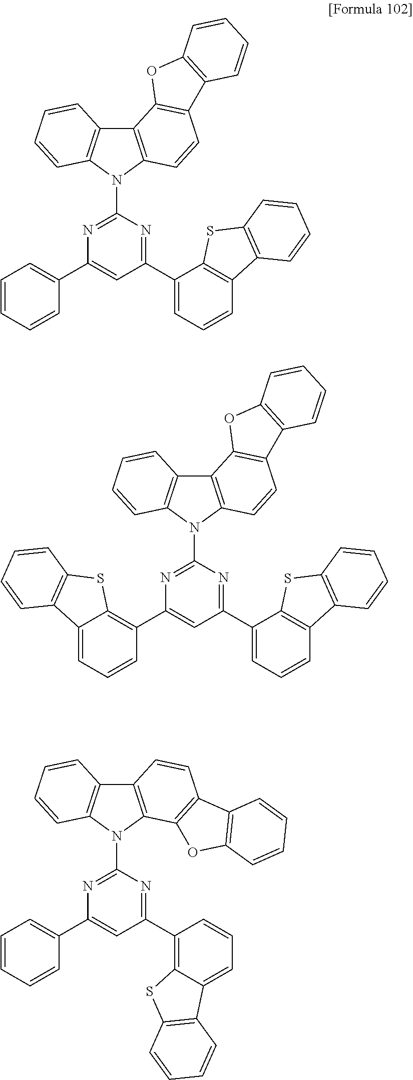 [SMILES: c1ccc(-c2cc(-c3cccc4c3sc3ccccc34)nc(-n3c4ccccc4c4c5oc6ccccc6c5ccc43)n2)cc1 ; c1ccc2c(c1)oc1c2ccc2c1c1ccccc1n2-c1nc(-c2cccc3c2sc2ccccc23)cc(-c2cccc3c2sc2ccccc23)n1 ; c1ccc(-c2cc(-c3cccc4c3sc3ccccc34)nc(-n3c4ccccc4c4ccc5c6ccccc6oc5c43)n2)cc1]

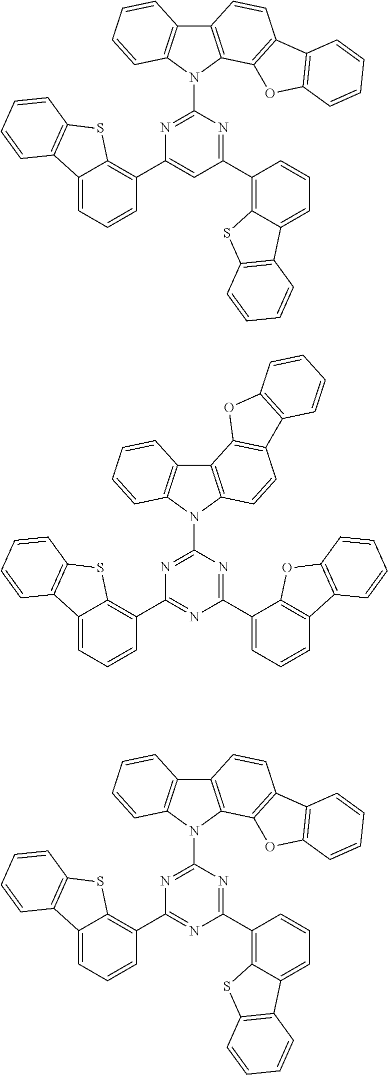

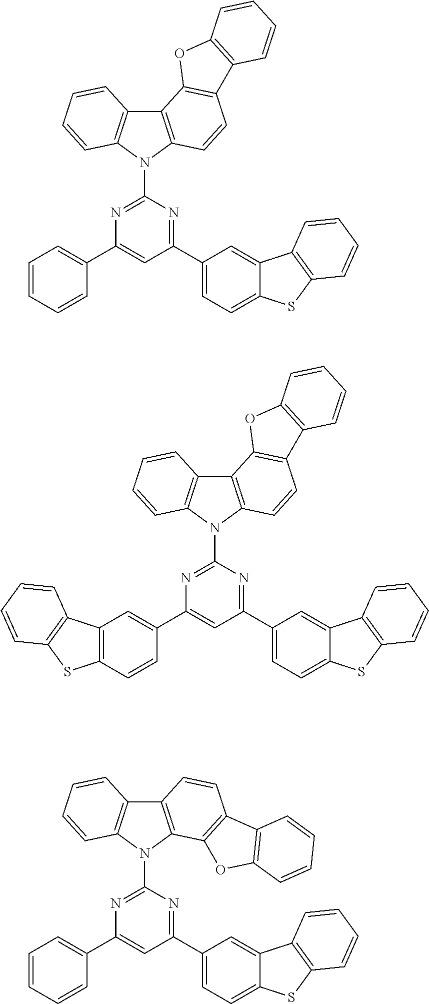 [SMILES: c1ccc(-c2cc(-c3ccc4sc5ccccc5c4c3)nc(-n3c4ccccc4c4c5oc6ccccc6c5ccc43)n2)cc1 ; c1ccc2c(c1)oc1c2ccc2c1c1ccccc1n2-c1nc(-c2ccc3sc4ccccc4c3c2)cc(-c2ccc3sc4ccccc4c3c2)n1 ; c1ccc(-c2cc(-c3ccc4sc5ccccc5c4c3)nc(-n3c4ccccc4c4ccc5c6ccccc6oc5c43)n2)cc1]

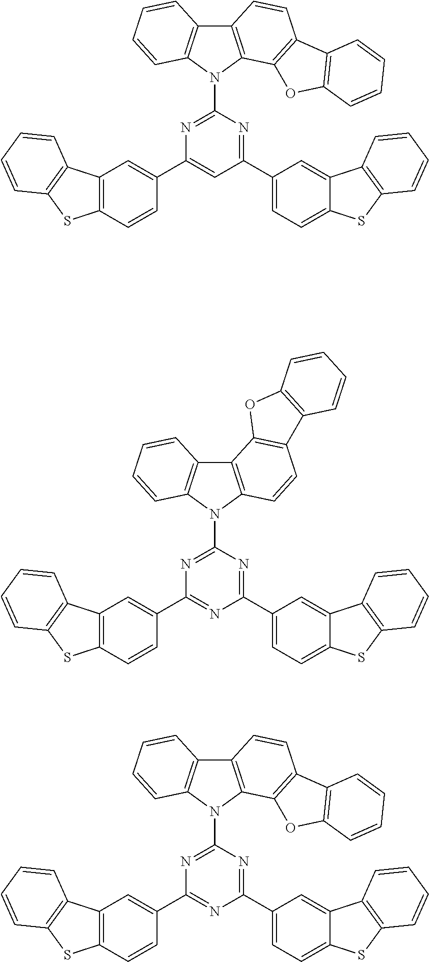 [SMILES: c1ccc2c(c1)oc1c2ccc2c3ccccc3n(-c3nc(-c4ccc5sc6ccccc6c5c4)cc(-c4ccc5sc6ccccc6c5c4)n3)c21 ; c1ccc2c(c1)oc1c2ccc2c1c1ccccc1n2-c1nc(-c2ccc3sc4ccccc4c3c2)nc(-c2ccc3sc4ccccc4c3c2)n1 ; c1ccc2c(c1)oc1c2ccc2c3ccccc3n(-c3nc(-c4ccc5sc6ccccc6c5c4)nc(-c4ccc5sc6ccccc6c5c4)n3)c21]

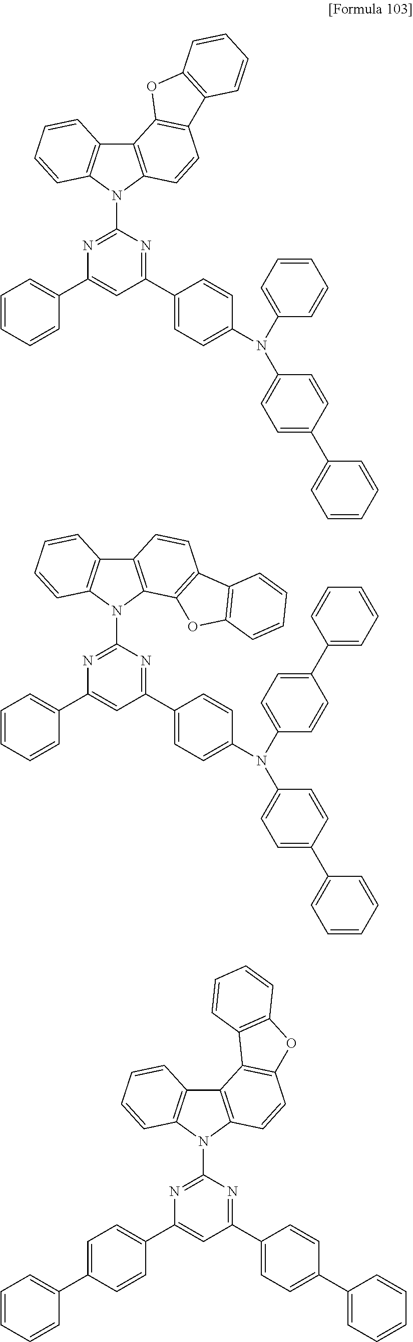 [SMILES: c1ccc(-c2ccc(N(c3ccccc3)c3ccc(-c4cc(-c5ccccc5)nc(-n5c6ccccc6c6c7oc8ccccc8c7ccc65)n4)cc3)cc2)cc1 ; c1ccc(-c2ccc(N(c3ccc(-c4ccccc4)cc3)c3ccc(-c4cc(-c5ccccc5)nc(-n5c6ccccc6c6ccc7c8ccccc8oc7c65)n4)cc3)cc2)cc1 ; c1ccc(-c2ccc(-c3cc(-c4ccc(-c5ccccc5)cc4)nc(-n4c5ccccc5c5c6c(ccc54)oc4ccccc46)n3)cc2)cc1]

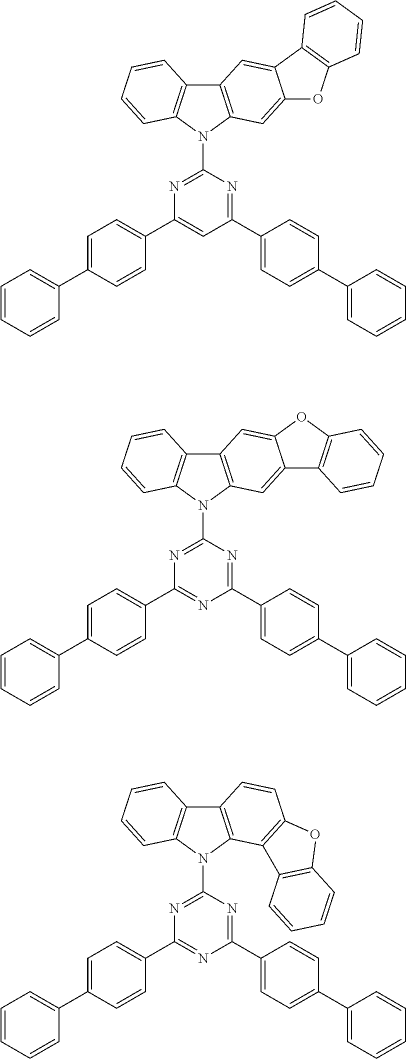 [SMILES: c1ccc(-c2ccc(-c3cc(-c4ccc(-c5ccccc5)cc4)nc(-n4c5ccccc5c5cc6c(cc54)oc4ccccc46)n3)cc2)cc1 ; c1ccc(-c2ccc(-c3nc(-c4ccc(-c5ccccc5)cc4)nc(-n4c5ccccc5c5cc6oc7ccccc7c6cc54)n3)cc2)cc1 ; c1ccc(-c2ccc(-c3nc(-c4ccc(-c5ccccc5)cc4)nc(-n4c5ccccc5c5ccc6oc7ccccc7c6c54)n3)cc2)cc1]

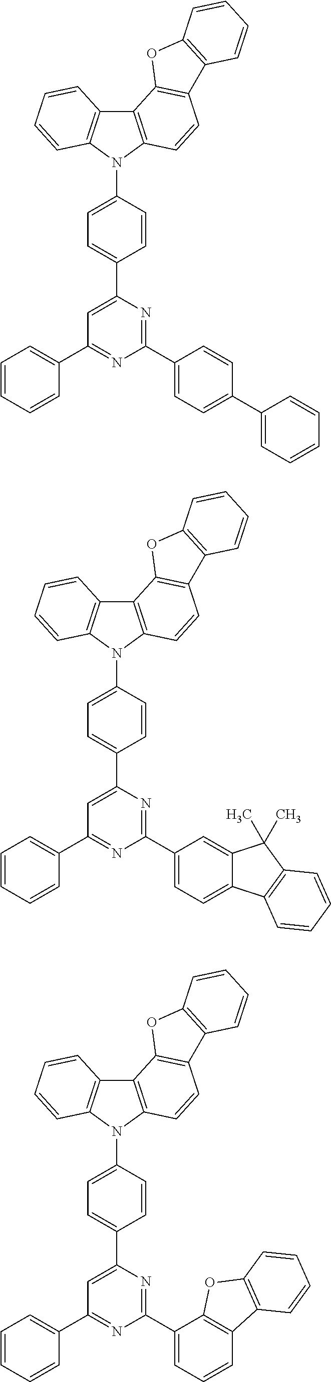 [SMILES: c1ccc(-c2ccc(-c3nc(-c4ccccc4)cc(-c4ccc(-n5c6ccccc6c6c7oc8ccccc8c7ccc65)cc4)n3)cc2)cc1 ; CC1(C)c2ccccc2-c2ccc(-c3nc(-c4ccccc4)cc(-c4ccc(-n5c6ccccc6c6c7oc8ccccc8c7ccc65)cc4)n3)cc21 ; c1ccc(-c2cc(-c3ccc(-n4c5ccccc5c5c6oc7ccccc7c6ccc54)cc3)nc(-c3cccc4c3oc3ccccc34)n2)cc1]

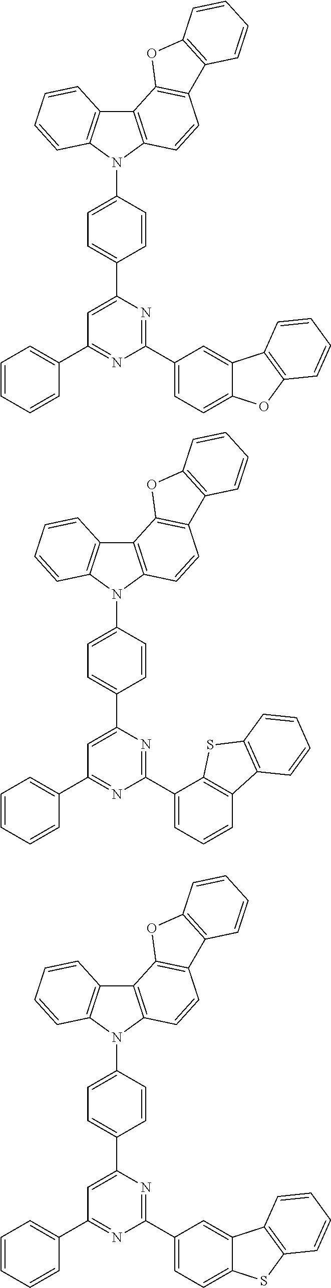

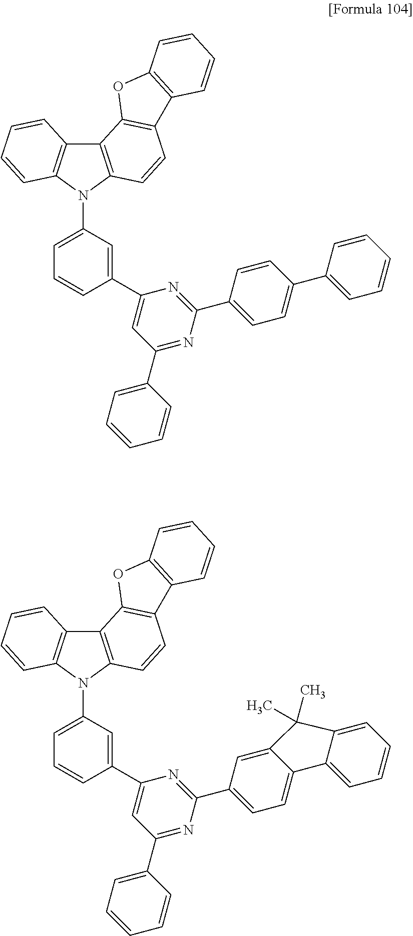 [SMILES: c1ccc(-c2ccc(-c3nc(-c4ccccc4)cc(-c4cccc(-n5c6ccccc6c6c7oc8ccccc8c7ccc65)c4)n3)cc2)cc1 ; CC1(C)c2ccccc2-c2ccc(-c3nc(-c4ccccc4)cc(-c4cccc(-n5c6ccccc6c6c7oc8ccccc8c7ccc65)c4)n3)cc21]

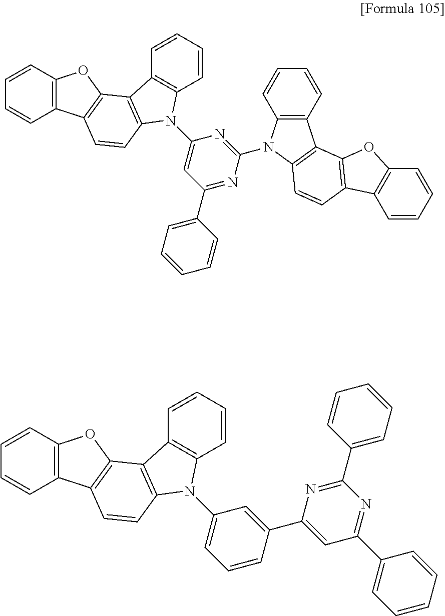 [SMILES: c1ccc(-c2cc(-n3c4ccccc4c4c5oc6ccccc6c5ccc43)nc(-n3c4ccccc4c4c5oc6ccccc6c5ccc43)n2)cc1 ; c1ccc(-c2cc(-c3cccc(-n4c5ccccc5c5c6oc7ccccc7c6ccc54)c3)nc(-c3ccccc3)n2)cc1]

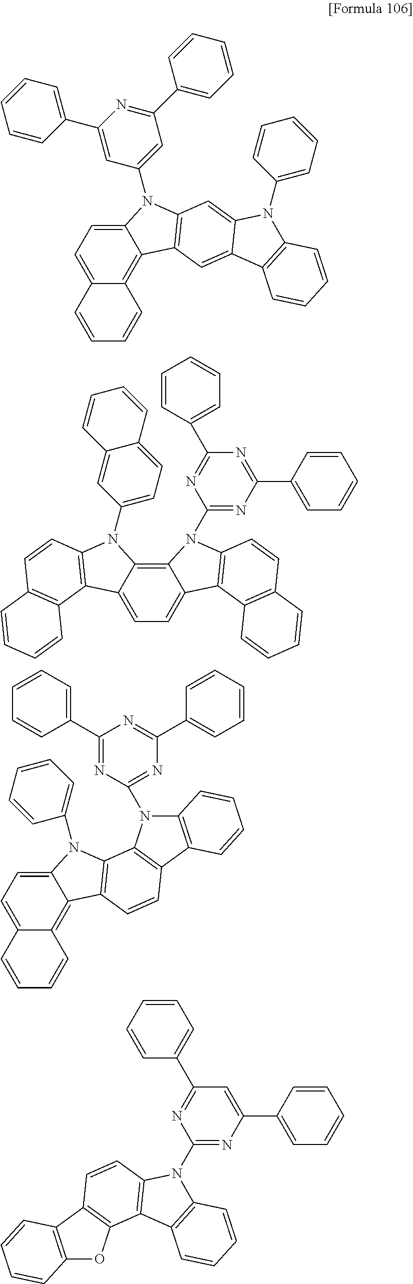

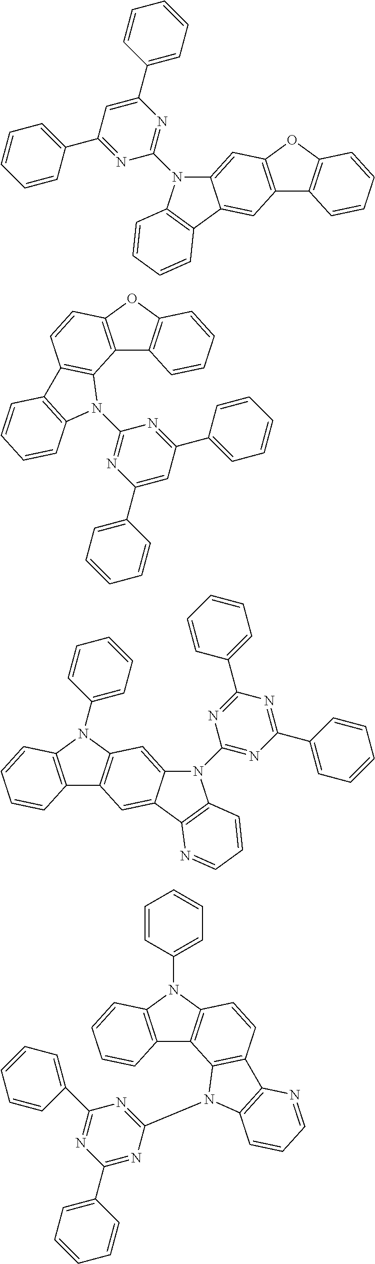

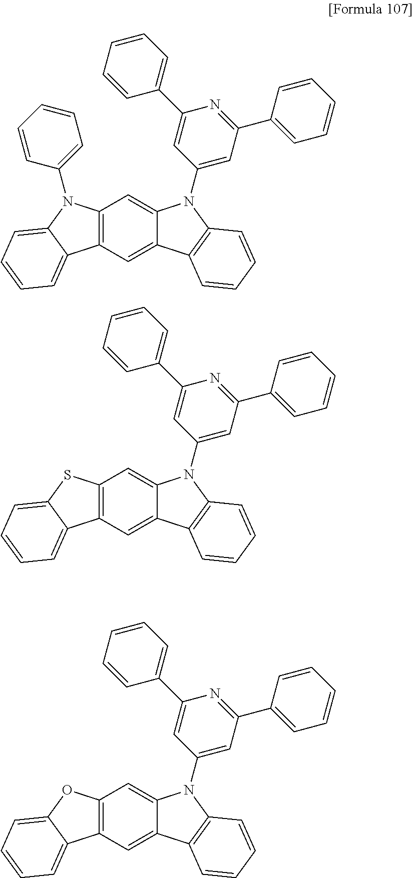 [SMILES: c1ccc(-c2cc(-n3c4ccccc4c4cc5c6ccccc6n(-c6ccccc6)c5cc43)cc(-c3ccccc3)n2)cc1 ; c1ccc(-c2cc(-n3c4ccccc4c4cc5c(cc43)sc3ccccc35)cc(-c3ccccc3)n2)cc1 ; c1ccc(-c2cc(-n3c4ccccc4c4cc5c(cc43)oc3ccccc35)cc(-c3ccccc3)n2)cc1]

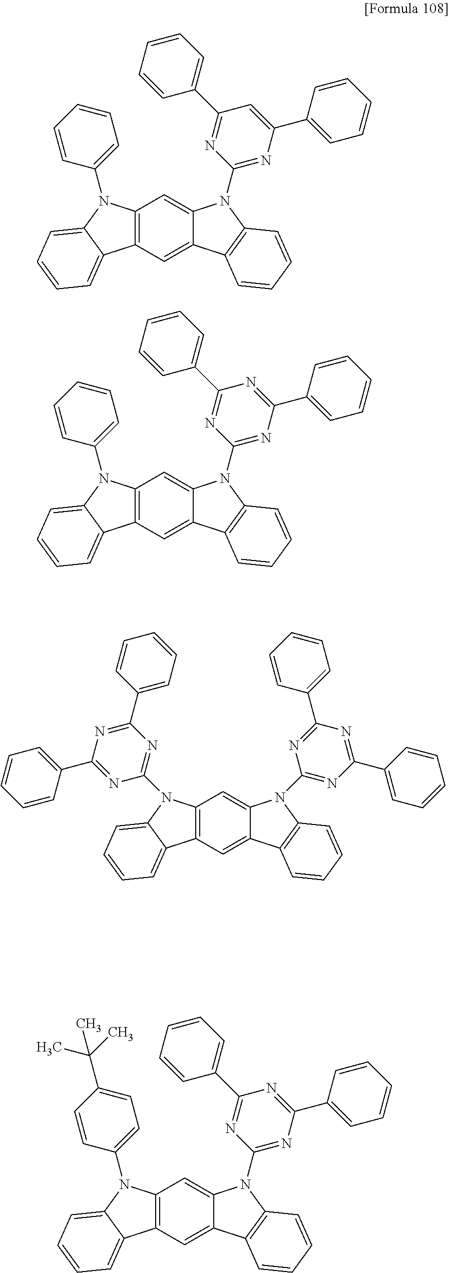 [SMILES: c1ccc(-c2cc(-c3ccccc3)nc(-n3c4ccccc4c4cc5c6ccccc6n(-c6ccccc6)c5cc43)n2)cc1 ; c1ccc(-c2nc(-c3ccccc3)nc(-n3c4ccccc4c4cc5c6ccccc6n(-c6ccccc6)c5cc43)n2)cc1 ; c1ccc(-c2nc(-c3ccccc3)nc(-n3c4ccccc4c4cc5c6ccccc6n(-c6nc(-c7ccccc7)nc(-c7ccccc7)n6)c5cc43)n2)cc1 ; CC(C)(C)c1ccc(-n2c3ccccc3c3cc4c5ccccc5n(-c5nc(-c6ccccc6)nc(-c6ccccc6)n5)c4cc32)cc1]

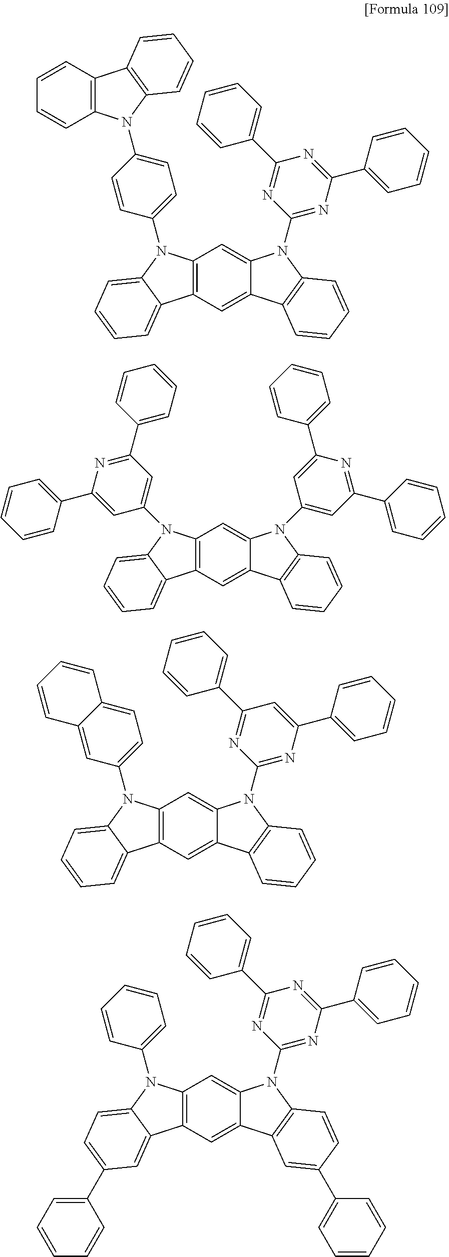

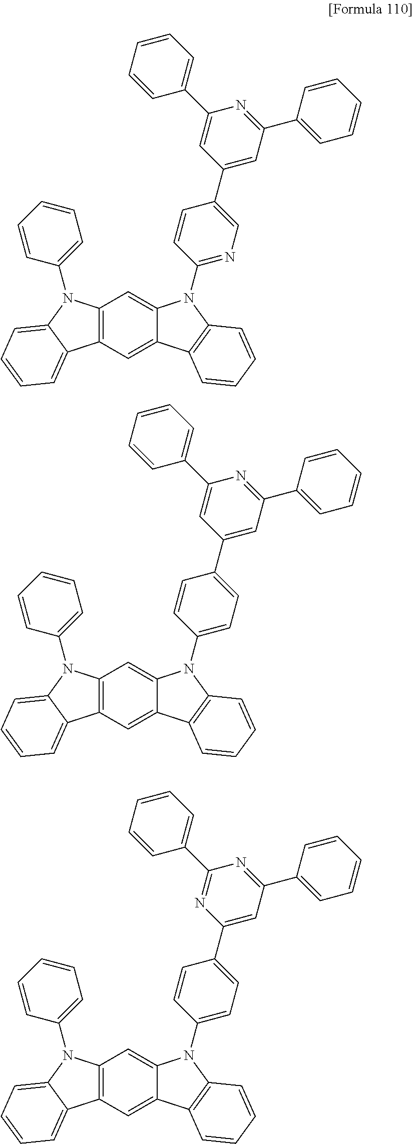

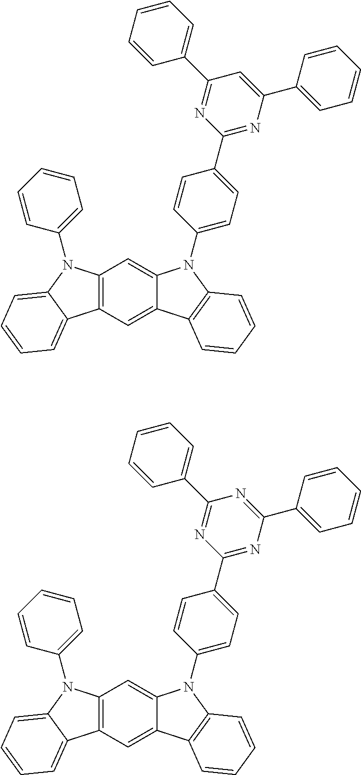 [SMILES: c1ccc(-c2cc(-c3ccccc3)nc(-c3ccc(-n4c5ccccc5c5cc6c7ccccc7n(-c7ccccc7)c6cc54)cc3)n2)cc1 ; c1ccc(-c2nc(-c3ccccc3)nc(-c3ccc(-n4c5ccccc5c5cc6c7ccccc7n(-c7ccccc7)c6cc54)cc3)n2)cc1]

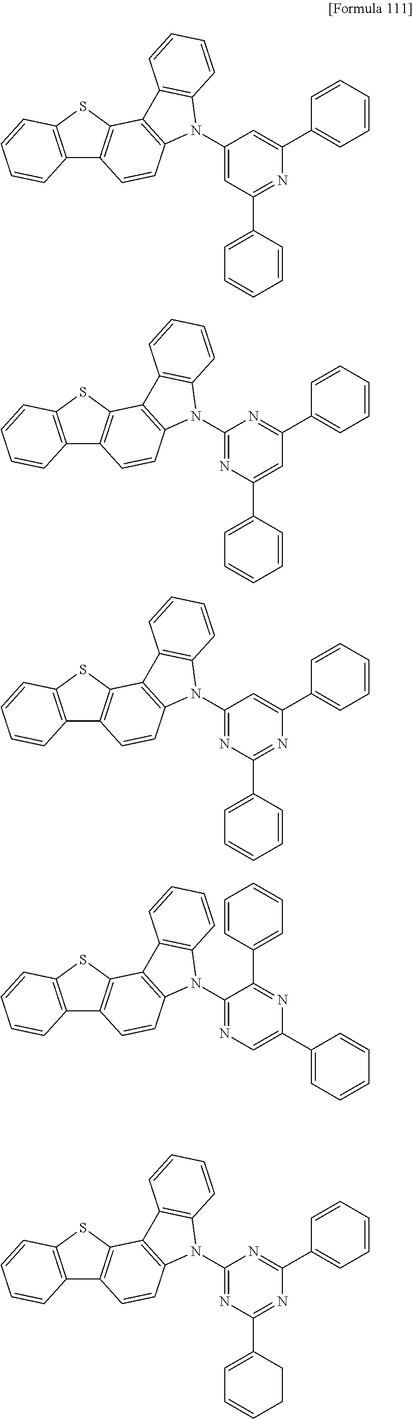

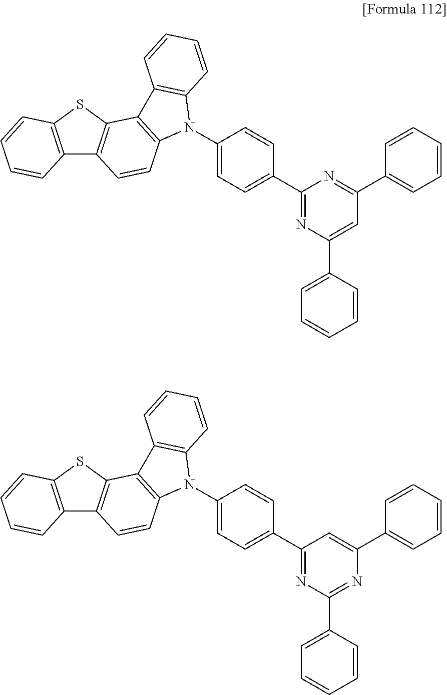 [SMILES: c1ccc(-c2cc(-c3ccccc3)nc(-c3ccc(-n4c5ccccc5c5c6sc7ccccc7c6ccc54)cc3)n2)cc1 ; c1ccc(-c2cc(-c3ccc(-n4c5ccccc5c5c6sc7ccccc7c6ccc54)cc3)nc(-c3ccccc3)n2)cc1]

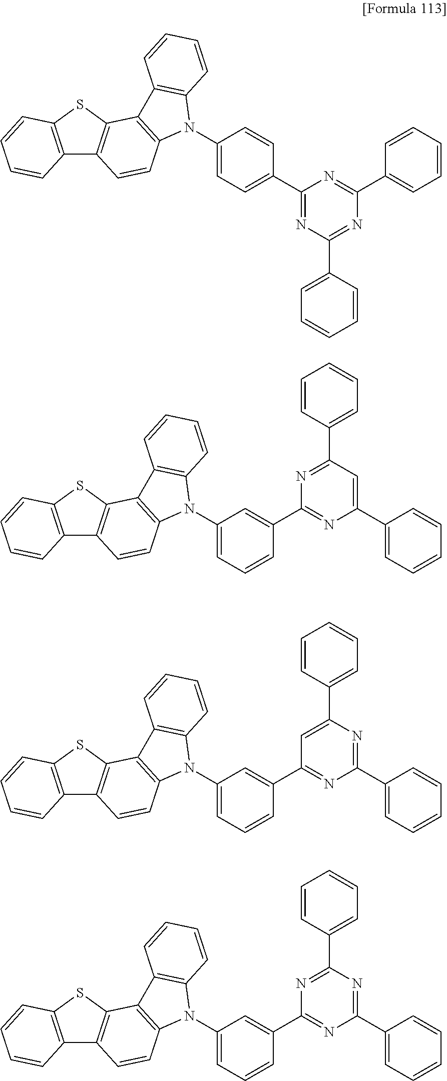

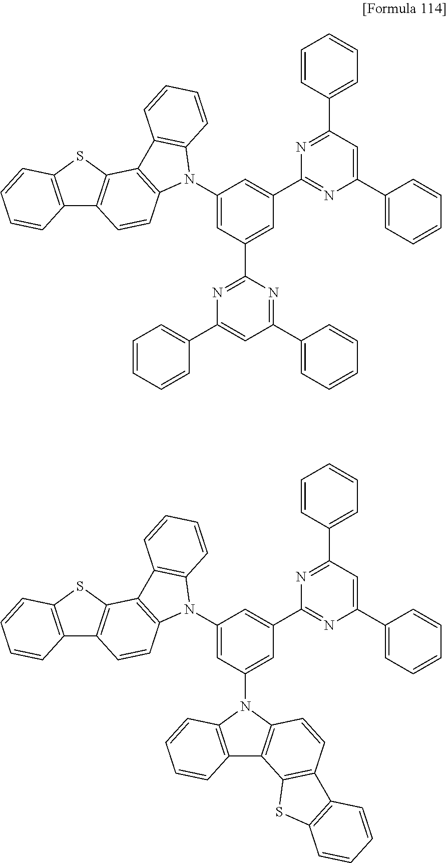 [SMILES: c1ccc(-c2cc(-c3ccccc3)nc(-c3cc(-c4nc(-c5ccccc5)cc(-c5ccccc5)n4)cc(-n4c5ccccc5c5c6sc7ccccc7c6ccc54)c3)n2)cc1 ; c1ccc(-c2cc(-c3ccccc3)nc(-c3cc(-n4c5ccccc5c5c6sc7ccccc7c6ccc54)cc(-n4c5ccccc5c5c6sc7ccccc7c6ccc54)c3)n2)cc1]

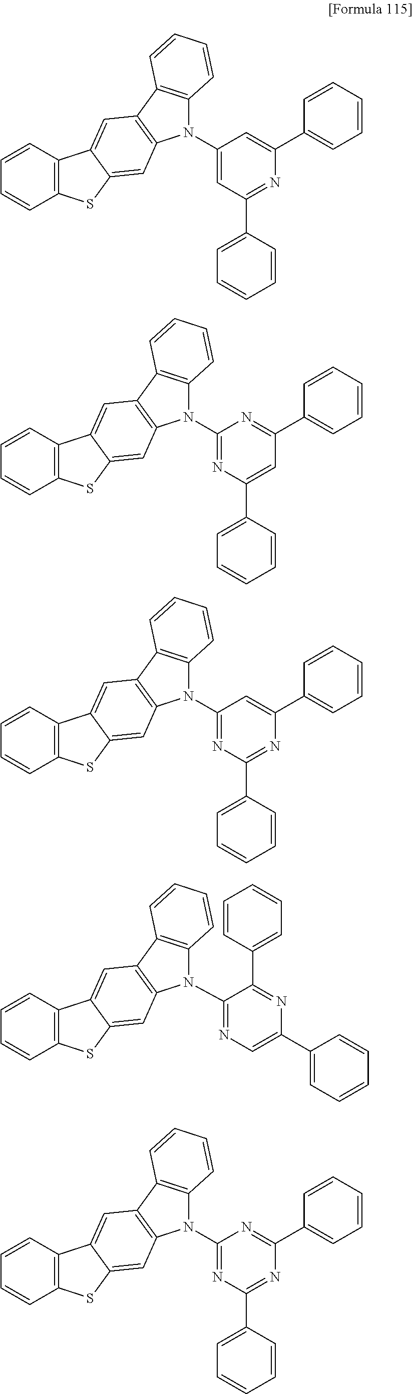

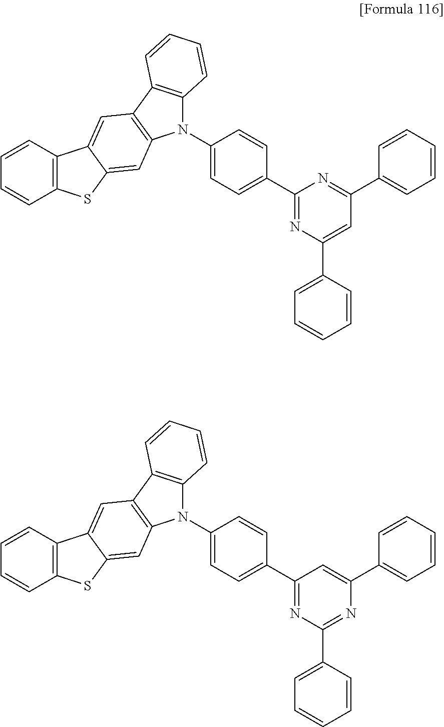 [SMILES: c1ccc(-c2cc(-c3ccccc3)nc(-c3ccc(-n4c5ccccc5c5cc6c(cc54)sc4ccccc46)cc3)n2)cc1 ; c1ccc(-c2cc(-c3ccc(-n4c5ccccc5c5cc6c(cc54)sc4ccccc46)cc3)nc(-c3ccccc3)n2)cc1]

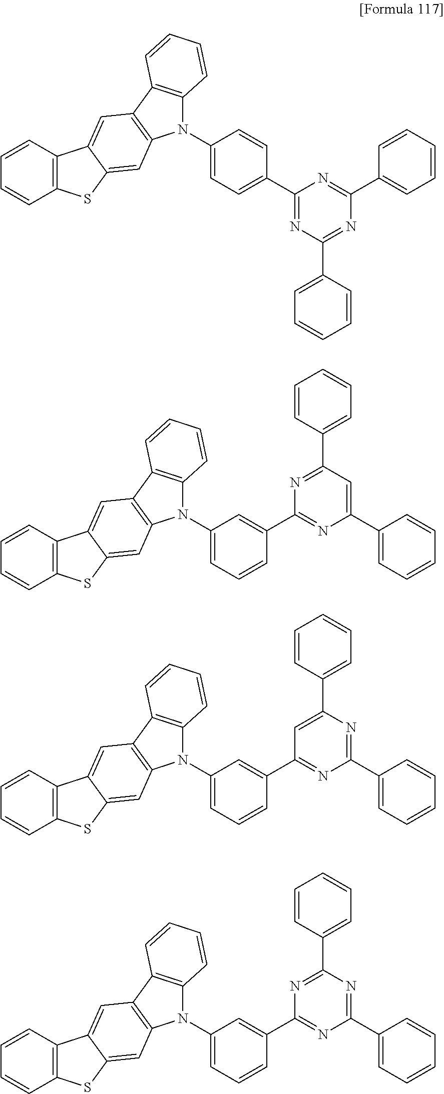

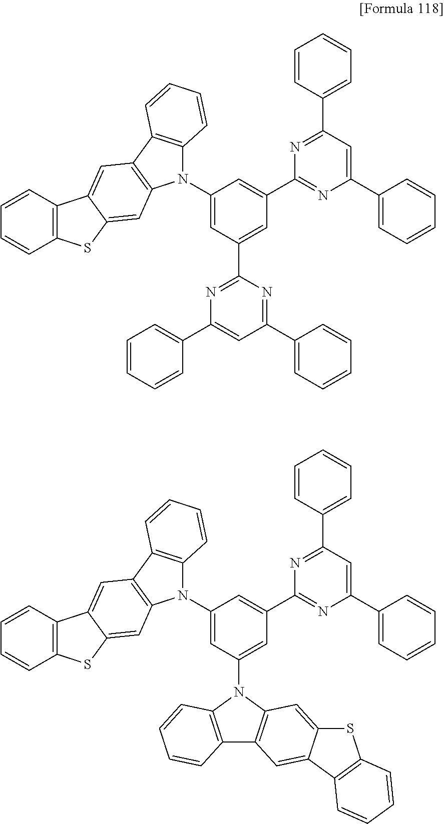 [SMILES: c1ccc(-c2cc(-c3ccccc3)nc(-c3cc(-c4nc(-c5ccccc5)cc(-c5ccccc5)n4)cc(-n4c5ccccc5c5cc6c(cc54)sc4ccccc46)c3)n2)cc1 ; c1ccc(-c2cc(-c3ccccc3)nc(-c3cc(-n4c5ccccc5c5cc6c(cc54)sc4ccccc46)cc(-n4c5ccccc5c5cc6c(cc54)sc4ccccc46)c3)n2)cc1]

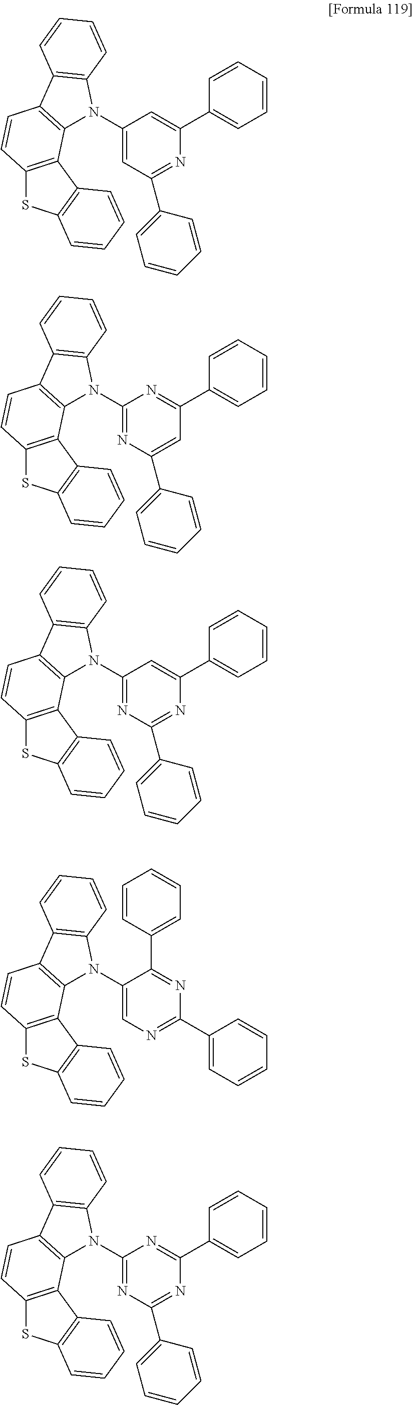

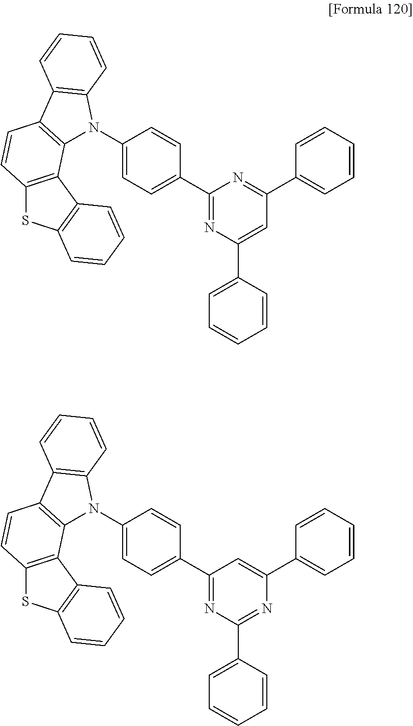 [SMILES: c1ccc(-c2cc(-c3ccccc3)nc(-c3ccc(-n4c5ccccc5c5ccc6sc7ccccc7c6c54)cc3)n2)cc1 ; c1ccc(-c2cc(-c3ccc(-n4c5ccccc5c5ccc6sc7ccccc7c6c54)cc3)nc(-c3ccccc3)n2)cc1]

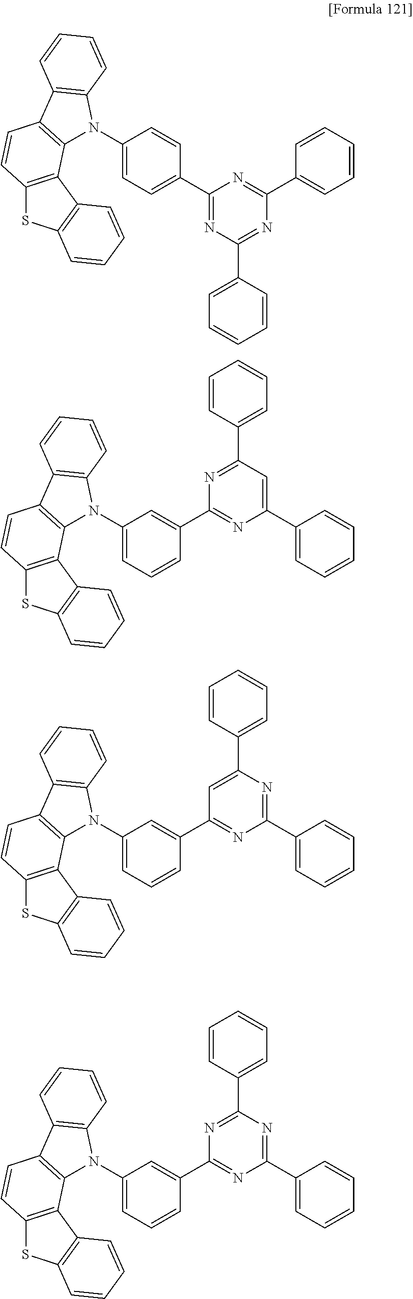

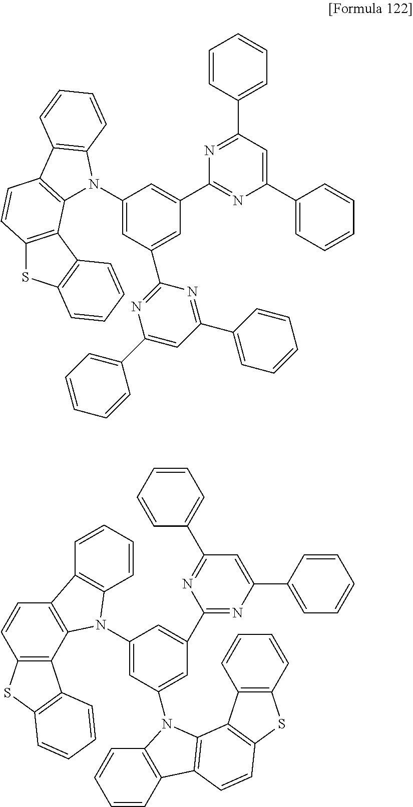 [SMILES: c1ccc(-c2cc(-c3ccccc3)nc(-c3cc(-c4nc(-c5ccccc5)cc(-c5ccccc5)n4)cc(-n4c5ccccc5c5ccc6sc7ccccc7c6c54)c3)n2)cc1 ; c1ccc(-c2cc(-c3ccccc3)nc(-c3cc(-n4c5ccccc5c5ccc6sc7ccccc7c6c54)cc(-n4c5ccccc5c5ccc6sc7ccccc7c6c54)c3)n2)cc1]

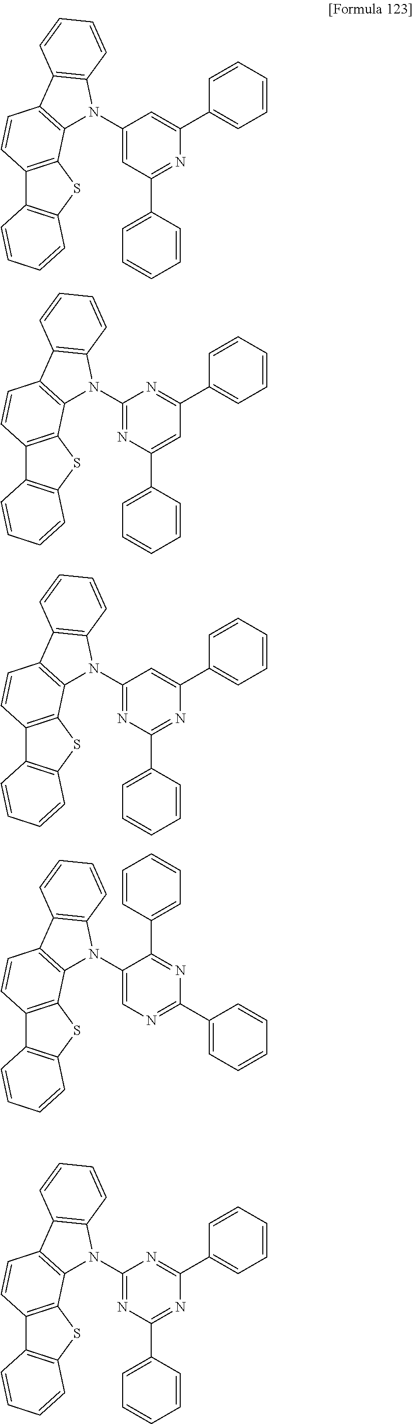

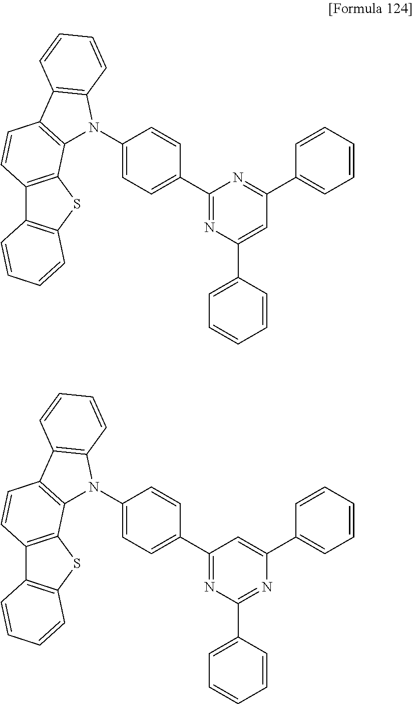 [SMILES: c1ccc(-c2cc(-c3ccccc3)nc(-c3ccc(-n4c5ccccc5c5ccc6c7ccccc7sc6c54)cc3)n2)cc1 ; c1ccc(-c2cc(-c3ccc(-n4c5ccccc5c5ccc6c7ccccc7sc6c54)cc3)nc(-c3ccccc3)n2)cc1]

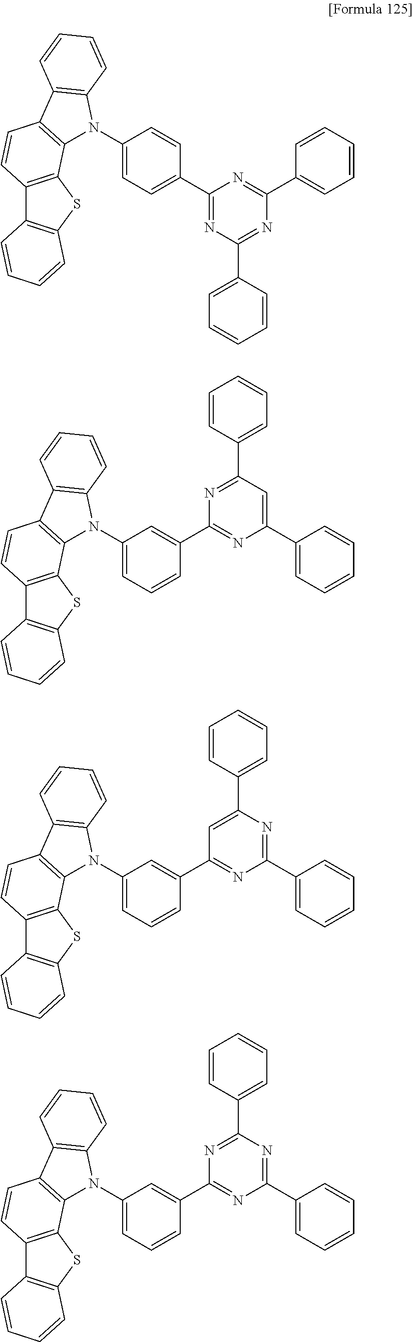

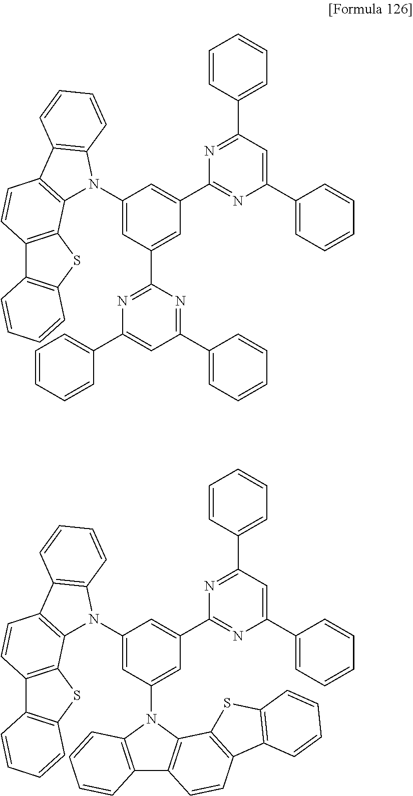 [SMILES: c1ccc(-c2cc(-c3ccccc3)nc(-c3cc(-c4nc(-c5ccccc5)cc(-c5ccccc5)n4)cc(-n4c5ccccc5c5ccc6c7ccccc7sc6c54)c3)n2)cc1 ; c1ccc(-c2cc(-c3ccccc3)nc(-c3cc(-n4c5ccccc5c5ccc6c7ccccc7sc6c54)cc(-n4c5ccccc5c5ccc6c7ccccc7sc6c54)c3)n2)cc1]

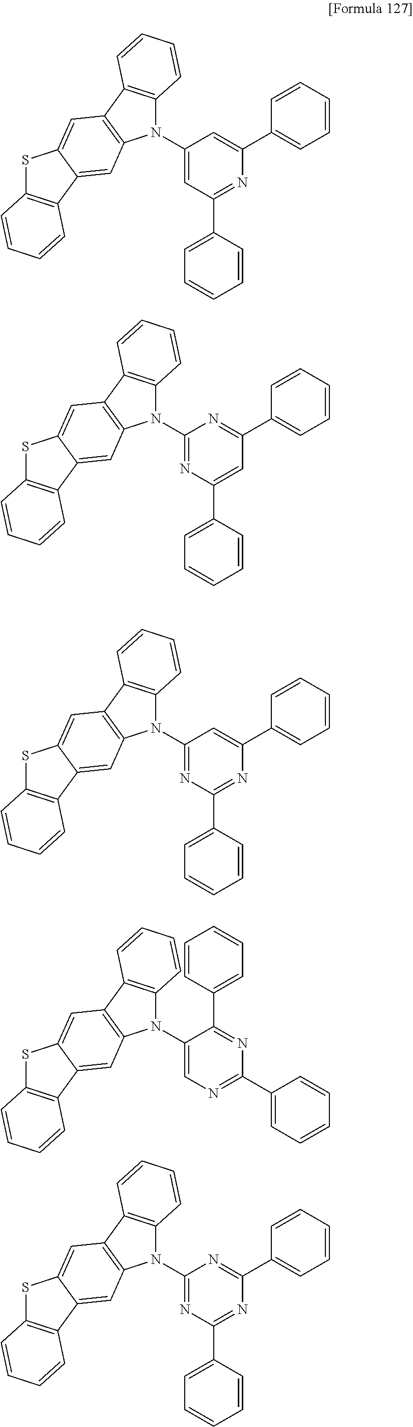

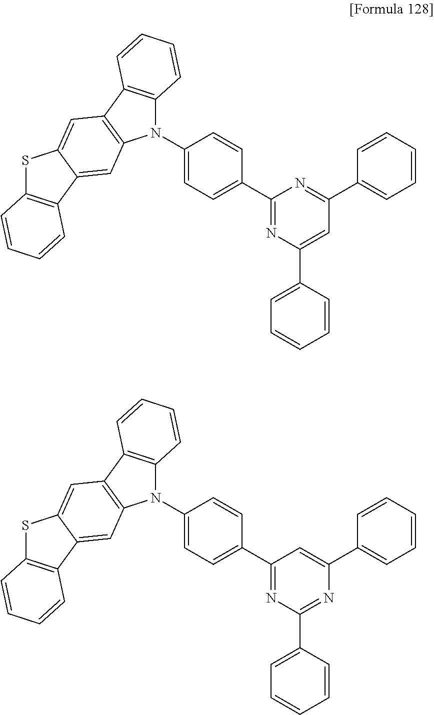 [SMILES: c1ccc(-c2cc(-c3ccccc3)nc(-c3ccc(-n4c5ccccc5c5cc6sc7ccccc7c6cc54)cc3)n2)cc1 ; c1ccc(-c2cc(-c3ccc(-n4c5ccccc5c5cc6sc7ccccc7c6cc54)cc3)nc(-c3ccccc3)n2)cc1]

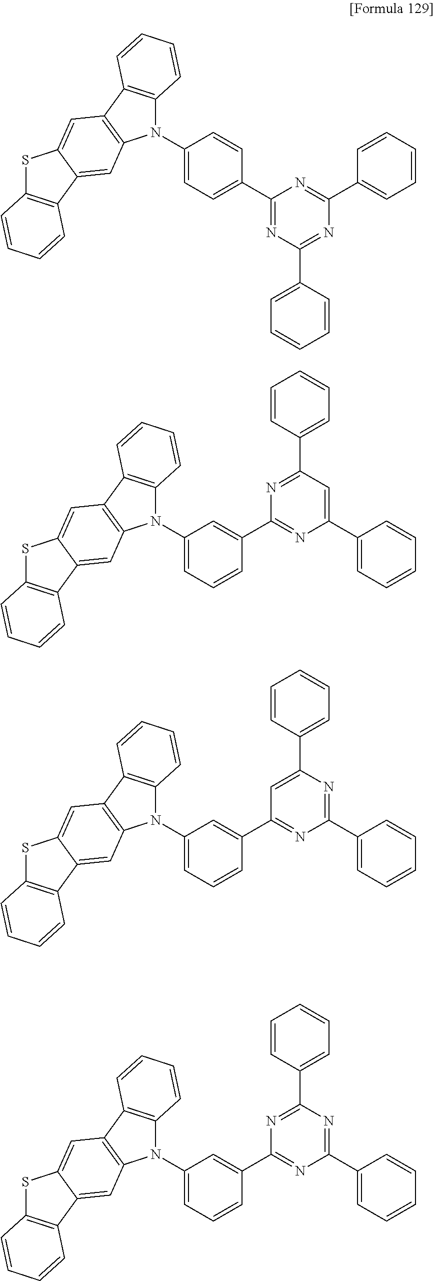

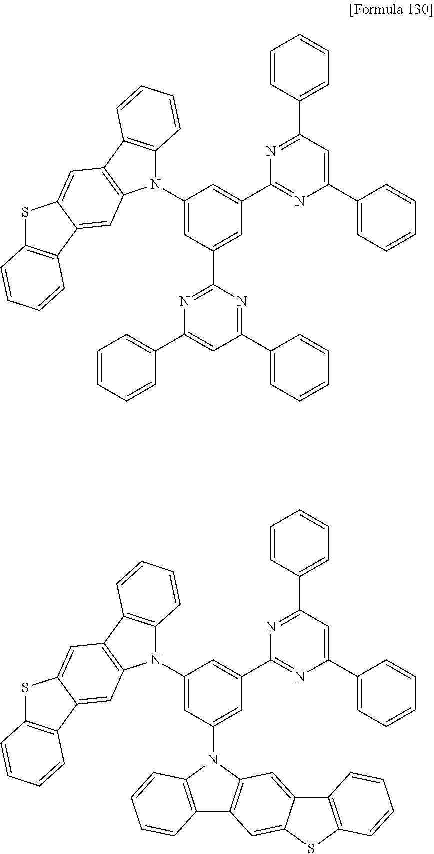 [SMILES: c1ccc(-c2cc(-c3ccccc3)nc(-c3cc(-c4nc(-c5ccccc5)cc(-c5ccccc5)n4)cc(-n4c5ccccc5c5cc6sc7ccccc7c6cc54)c3)n2)cc1 ; c1ccc(-c2cc(-c3ccccc3)nc(-c3cc(-n4c5ccccc5c5cc6sc7ccccc7c6cc54)cc(-n4c5ccccc5c5cc6sc7ccccc7c6cc54)c3)n2)cc1]

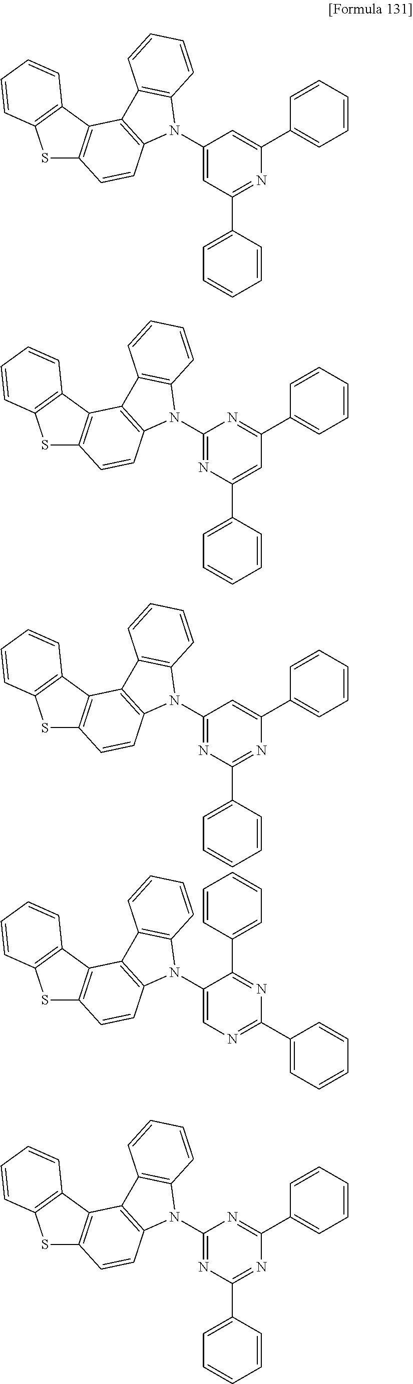

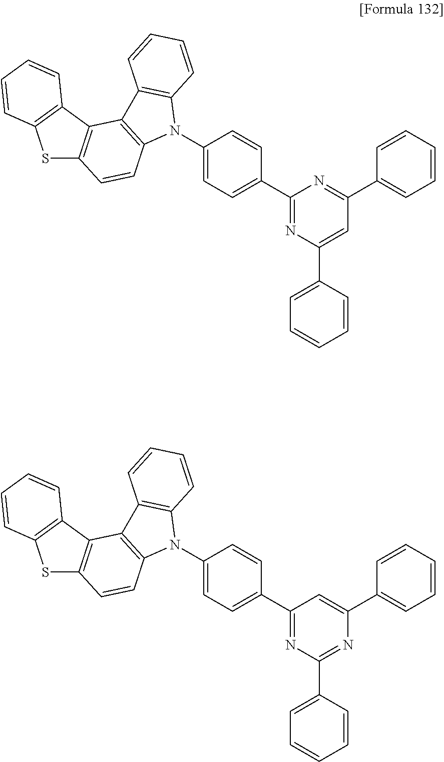 [SMILES: c1ccc(-c2cc(-c3ccccc3)nc(-c3ccc(-n4c5ccccc5c5c6c(ccc54)sc4ccccc46)cc3)n2)cc1 ; c1ccc(-c2cc(-c3ccc(-n4c5ccccc5c5c6c(ccc54)sc4ccccc46)cc3)nc(-c3ccccc3)n2)cc1]

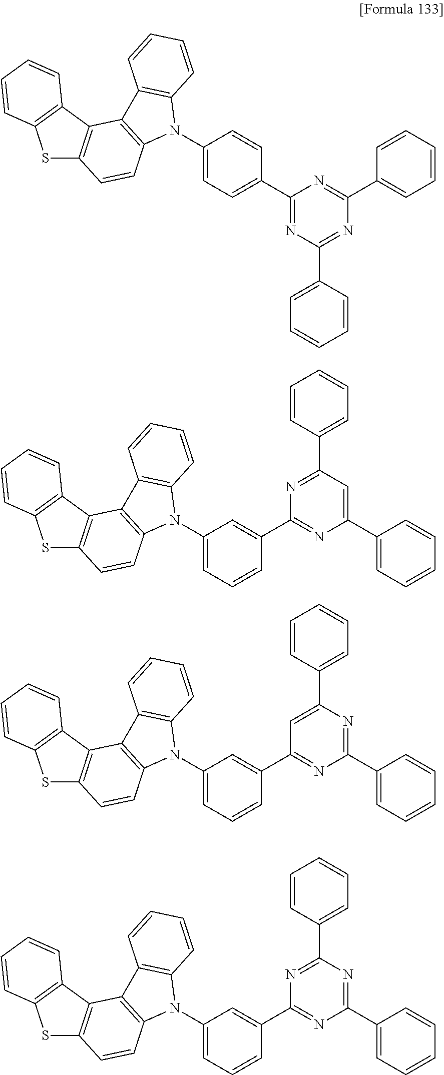

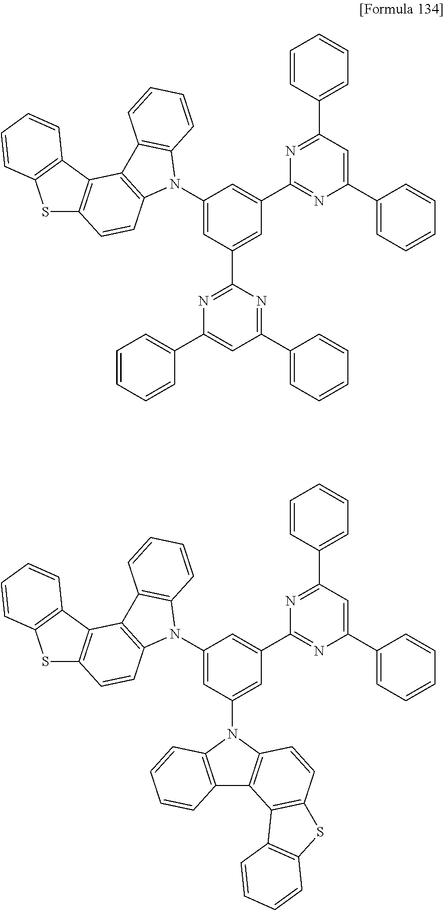 [SMILES: c1ccc(-c2cc(-c3ccccc3)nc(-c3cc(-c4nc(-c5ccccc5)cc(-c5ccccc5)n4)cc(-n4c5ccccc5c5c6c(ccc54)sc4ccccc46)c3)n2)cc1 ; c1ccc(-c2cc(-c3ccccc3)nc(-c3cc(-n4c5ccccc5c5c6c(ccc54)sc4ccccc46)cc(-n4c5ccccc5c5c6c(ccc54)sc4ccccc46)c3)n2)cc1]

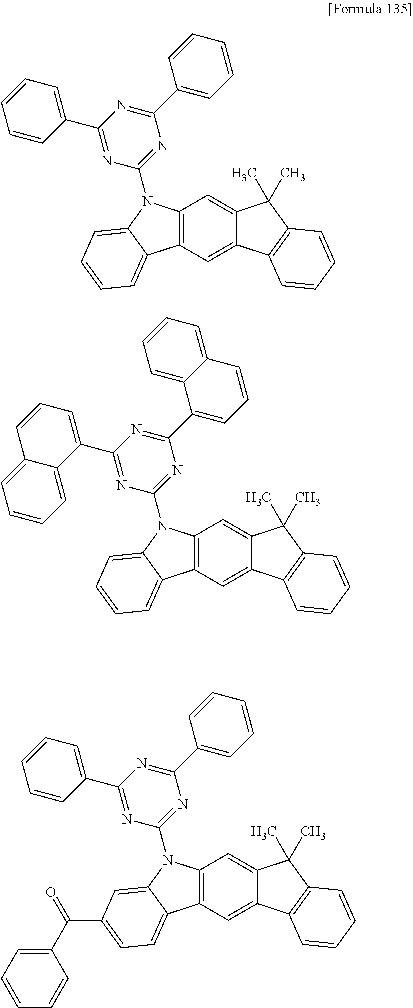

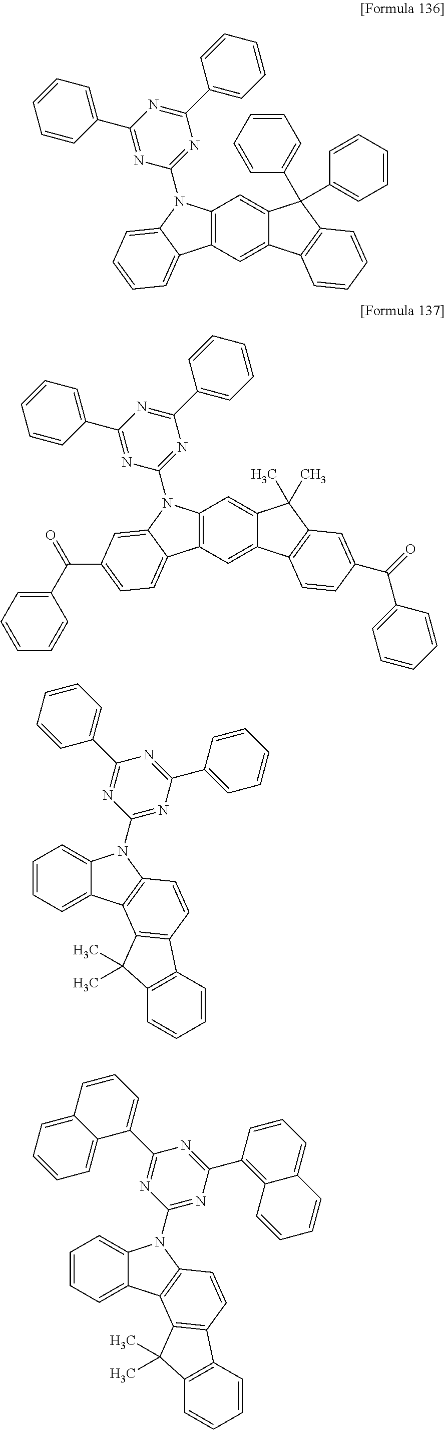

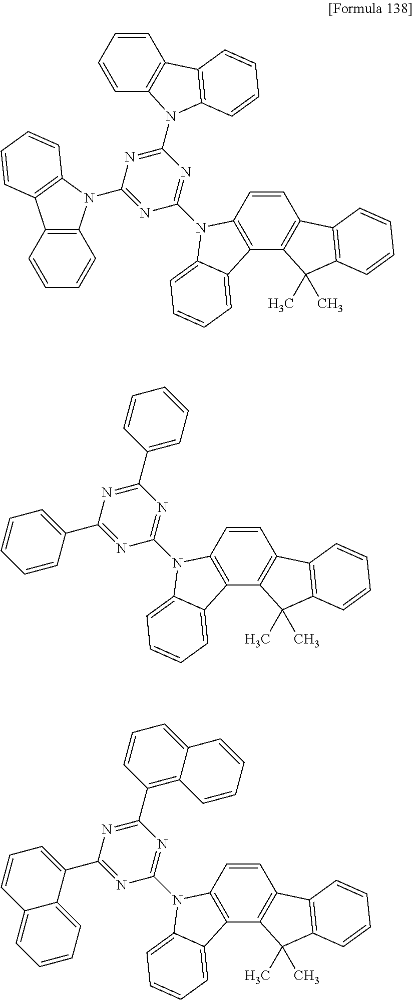 [SMILES: CC1(C)c2ccccc2-c2ccc3c(c21)c1ccccc1n3-c1nc(-n2c3ccccc3c3ccccc32)nc(-n2c3ccccc3c3ccccc32)n1 ; CC1(C)c2ccccc2-c2ccc3c(c21)c1ccccc1n3-c1nc(-c2ccccc2)nc(-c2ccccc2)n1 ; CC1(C)c2ccccc2-c2ccc3c(c21)c1ccccc1n3-c1nc(-c2cccc3ccccc23)nc(-c2cccc3ccccc23)n1]

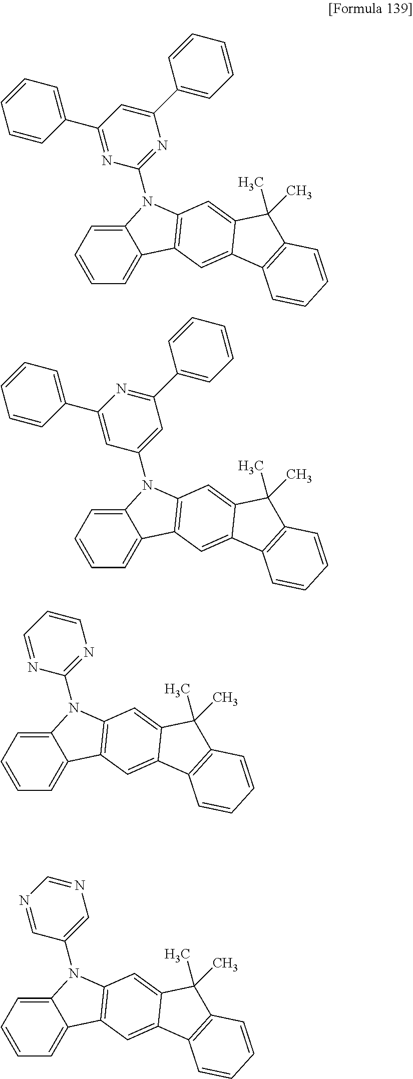 [SMILES: CC1(C)c2ccccc2-c2cc3c4ccccc4n(-c4nc(-c5ccccc5)cc(-c5ccccc5)n4)c3cc21 ; CC1(C)c2ccccc2-c2cc3c4ccccc4n(-c4cc(-c5ccccc5)nc(-c5ccccc5)c4)c3cc21 ; CC1(C)c2ccccc2-c2cc3c4ccccc4n(-c4ncccn4)c3cc21 ; CC1(C)c2ccccc2-c2cc3c4ccccc4n(-c4cncnc4)c3cc21]

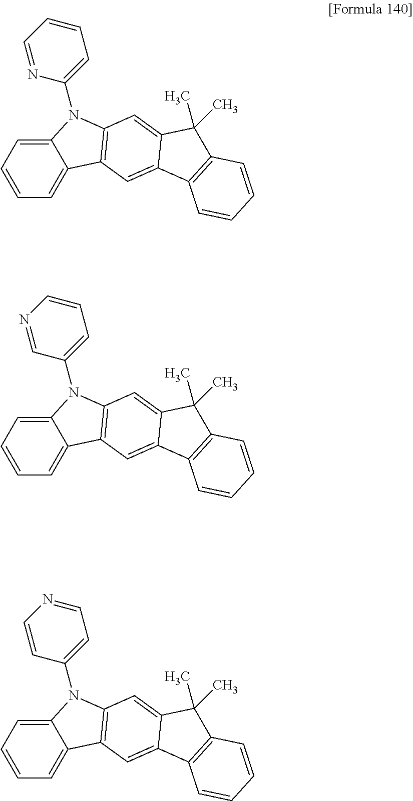 [SMILES: CC1(C)c2ccccc2-c2cc3c4ccccc4n(-c4ccccn4)c3cc21 ; CC1(C)c2ccccc2-c2cc3c4ccccc4n(-c4cccnc4)c3cc21 ; CC1(C)c2ccccc2-c2cc3c4ccccc4n(-c4ccncc4)c3cc21]

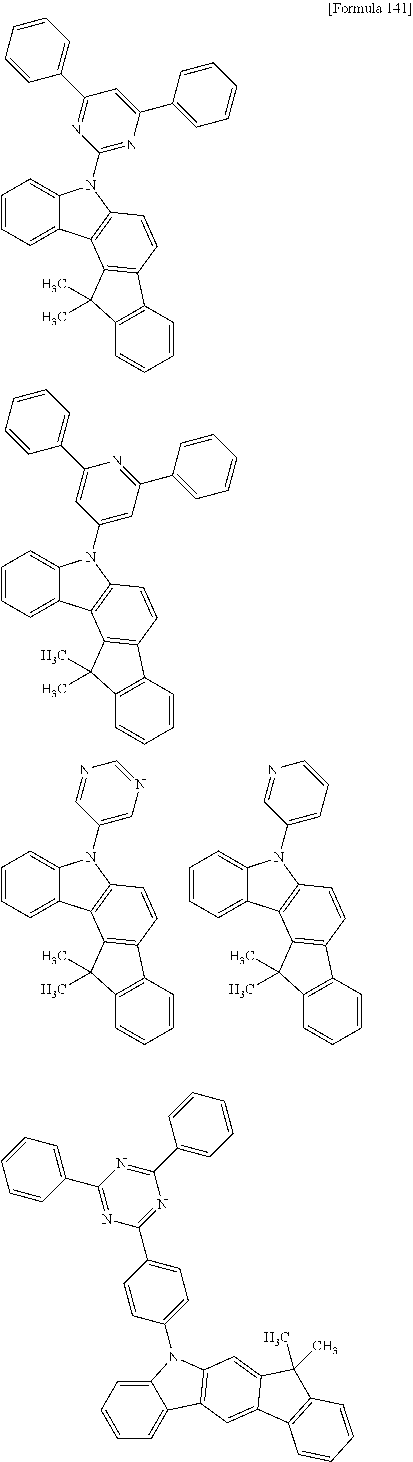

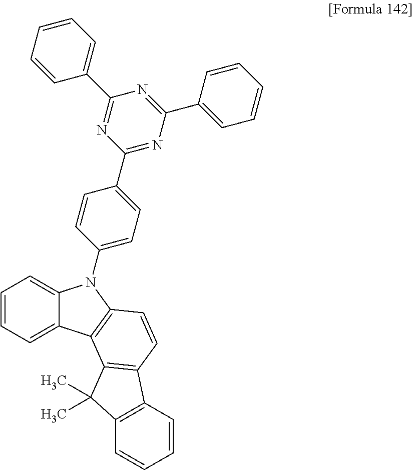 [SMILES: CC1(C)c2ccccc2-c2ccc3c(c21)c1ccccc1n3-c1ccc(-c2nc(-c3ccccc3)nc(-c3ccccc3)n2)cc1]

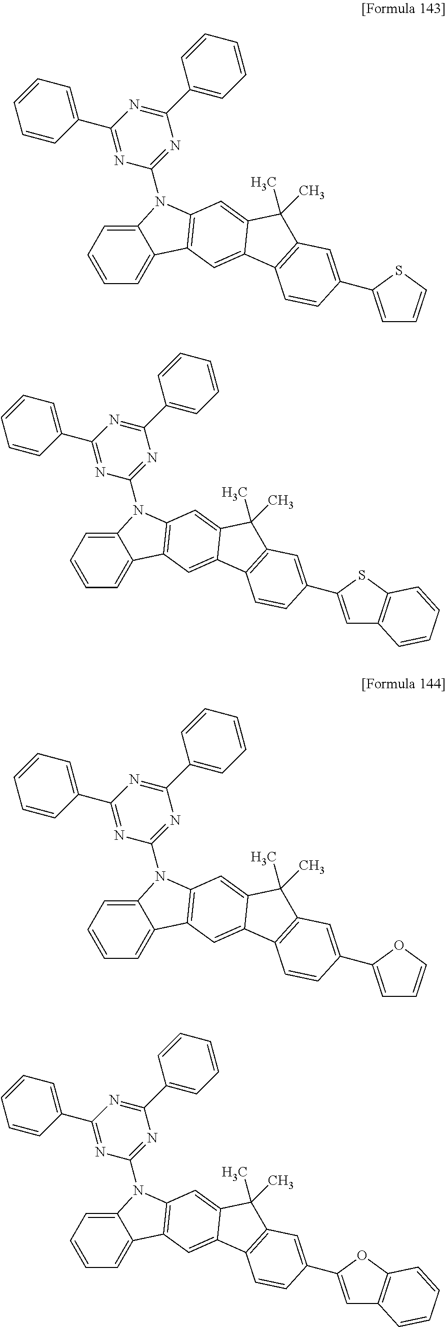 [SMILES: CC1(C)c2cc(-c3cccs3)ccc2-c2cc3c4ccccc4n(-c4nc(-c5ccccc5)nc(-c5ccccc5)n4)c3cc21 ; CC1(C)c2cc(-c3cc4ccccc4s3)ccc2-c2cc3c4ccccc4n(-c4nc(-c5ccccc5)nc(-c5ccccc5)n4)c3cc21 ; CC1(C)c2cc(-c3ccco3)ccc2-c2cc3c4ccccc4n(-c4nc(-c5ccccc5)nc(-c5ccccc5)n4)c3cc21 ; CC1(C)c2cc(-c3cc4ccccc4o3)ccc2-c2cc3c4ccccc4n(-c4nc(-c5ccccc5)nc(-c5ccccc5)n4)c3cc21]

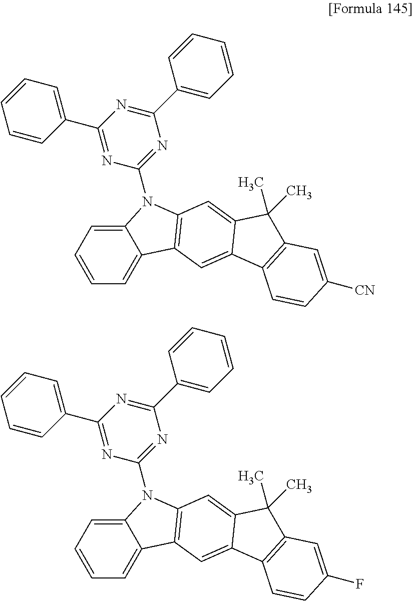 [SMILES: CC1(C)c2cc(C#N)ccc2-c2cc3c4ccccc4n(-c4nc(-c5ccccc5)nc(-c5ccccc5)n4)c3cc21 ; CC1(C)c2cc(F)ccc2-c2cc3c4ccccc4n(-c4nc(-c5ccccc5)nc(-c5ccccc5)n4)c3cc21]

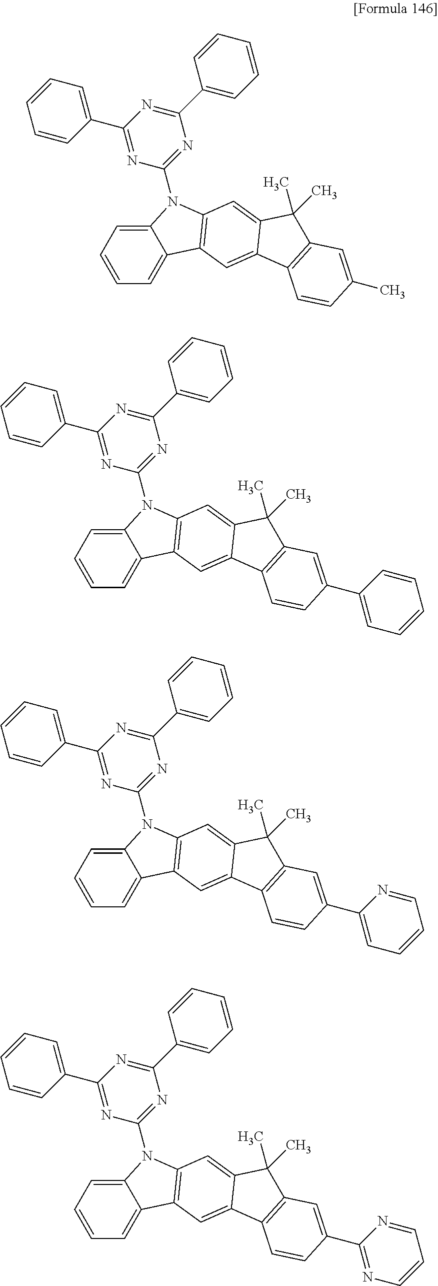 [SMILES: Cc1ccc2c(c1)C(C)(C)c1cc3c(cc1-2)c1ccccc1n3-c1nc(-c2ccccc2)nc(-c2ccccc2)n1 ; CC1(C)c2cc(-c3ccccc3)ccc2-c2cc3c4ccccc4n(-c4nc(-c5ccccc5)nc(-c5ccccc5)n4)c3cc21 ; CC1(C)c2cc(-c3ccccn3)ccc2-c2cc3c4ccccc4n(-c4nc(-c5ccccc5)nc(-c5ccccc5)n4)c3cc21 ; CC1(C)c2cc(-c3ncccn3)ccc2-c2cc3c4ccccc4n(-c4nc(-c5ccccc5)nc(-c5ccccc5)n4)c3cc21]

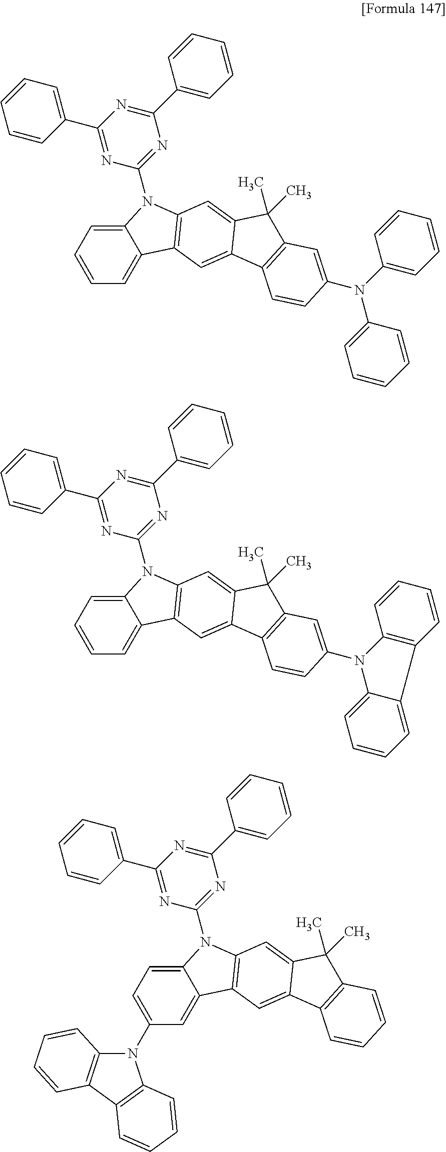 [SMILES: CC1(C)c2cc(N(c3ccccc3)c3ccccc3)ccc2-c2cc3c4ccccc4n(-c4nc(-c5ccccc5)nc(-c5ccccc5)n4)c3cc21 ; CC1(C)c2cc(-n3c4ccccc4c4ccccc43)ccc2-c2cc3c4ccccc4n(-c4nc(-c5ccccc5)nc(-c5ccccc5)n4)c3cc21 ; CC1(C)c2ccccc2-c2cc3c4cc(-n5c6ccccc6c6ccccc65)ccc4n(-c4nc(-c5ccccc5)nc(-c5ccccc5)n4)c3cc21]

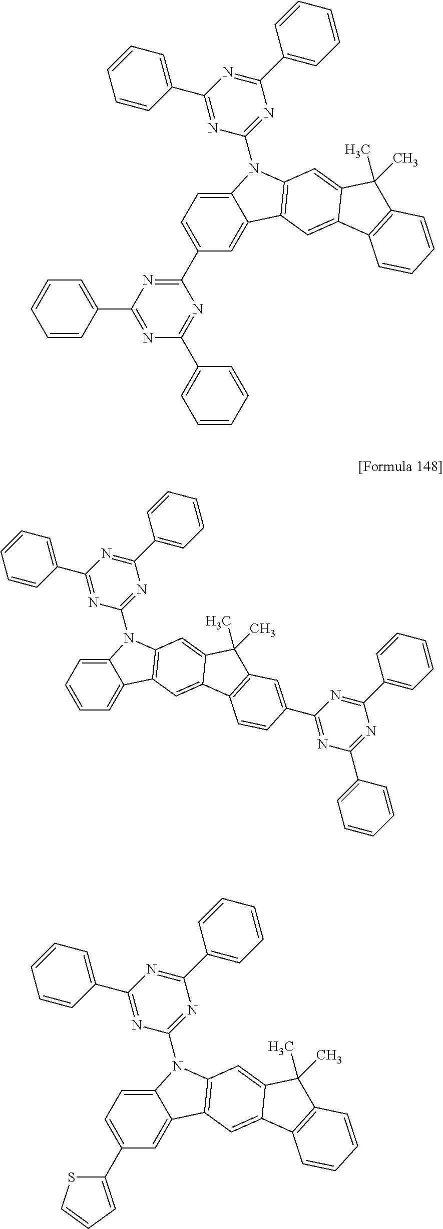 [SMILES: CC1(C)c2ccccc2-c2cc3c4cc(-c5nc(-c6ccccc6)nc(-c6ccccc6)n5)ccc4n(-c4nc(-c5ccccc5)nc(-c5ccccc5)n4)c3cc21 ; CC1(C)c2cc(-c3nc(-c4ccccc4)nc(-c4ccccc4)n3)ccc2-c2cc3c4ccccc4n(-c4nc(-c5ccccc5)nc(-c5ccccc5)n4)c3cc21 ; CC1(C)c2ccccc2-c2cc3c4cc(-c5cccs5)ccc4n(-c4nc(-c5ccccc5)nc(-c5ccccc5)n4)c3cc21]

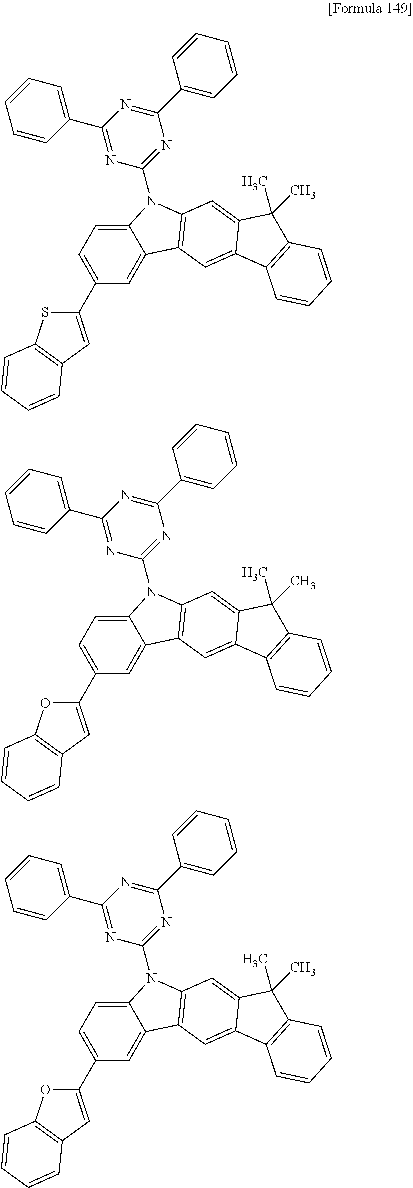 [SMILES: CC1(C)c2ccccc2-c2cc3c4cc(-c5cc6ccccc6s5)ccc4n(-c4nc(-c5ccccc5)nc(-c5ccccc5)n4)c3cc21 ; CC1(C)c2ccccc2-c2cc3c4cc(-c5cc6ccccc6o5)ccc4n(-c4nc(-c5ccccc5)nc(-c5ccccc5)n4)c3cc21 ; CC1(C)c2ccccc2-c2cc3c4cc(-c5cc6ccccc6o5)ccc4n(-c4nc(-c5ccccc5)nc(-c5ccccc5)n4)c3cc21]

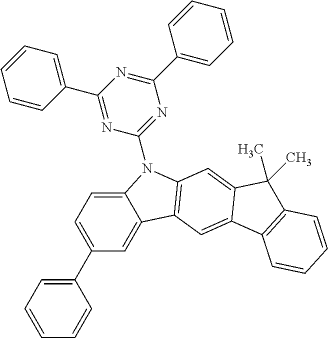 [SMILES: CC1(C)c2ccccc2-c2cc3c4cc(-c5ccccc5)ccc4n(-c4nc(-c5ccccc5)nc(-c5ccccc5)n4)c3cc21]

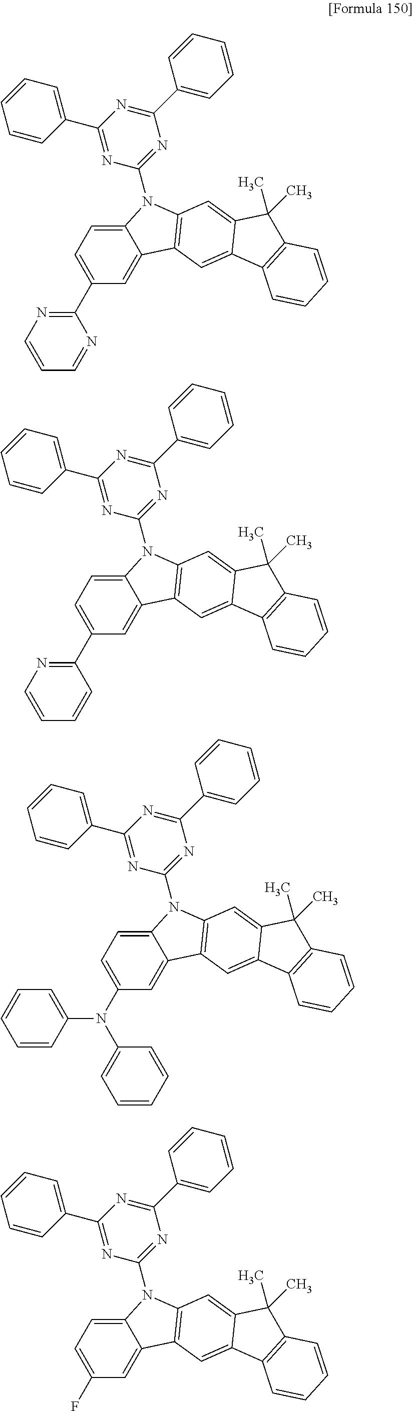 [SMILES: CC1(C)c2ccccc2-c2cc3c4cc(-c5ncccn5)ccc4n(-c4nc(-c5ccccc5)nc(-c5ccccc5)n4)c3cc21 ; CC1(C)c2ccccc2-c2cc3c4cc(-c5ccccn5)ccc4n(-c4nc(-c5ccccc5)nc(-c5ccccc5)n4)c3cc21 ; CC1(C)c2ccccc2-c2cc3c4cc(N(c5ccccc5)c5ccccc5)ccc4n(-c4nc(-c5ccccc5)nc(-c5ccccc5)n4)c3cc21 ; CC1(C)c2ccccc2-c2cc3c4cc(F)ccc4n(-c4nc(-c5ccccc5)nc(-c5ccccc5)n4)c3cc21]

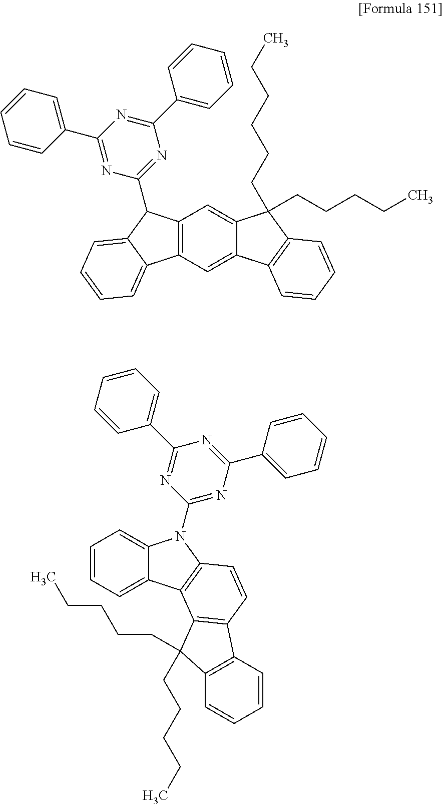

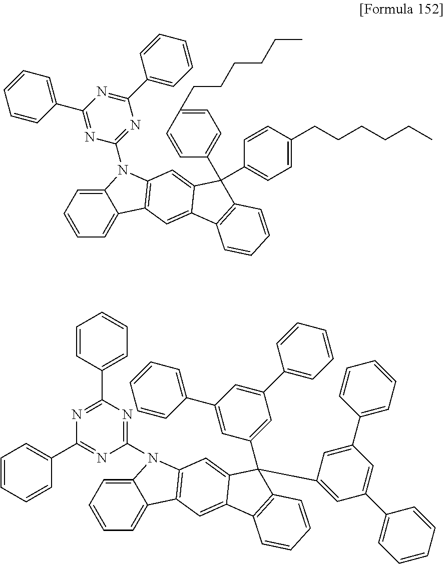 [SMILES: CCCCCCc1ccc(C2(c3ccc(CCCCCC)cc3)c3ccccc3-c3cc4c5ccccc5n(-c5nc(-c6ccccc6)nc(-c6ccccc6)n5)c4cc32)cc1 ; c1ccc(-c2cc(-c3ccccc3)cc(C3(c4cc(-c5ccccc5)cc(-c5ccccc5)c4)c4ccccc4-c4cc5c6ccccc6n(-c6nc(-c7ccccc7)nc(-c7ccccc7)n6)c5cc43)c2)cc1]

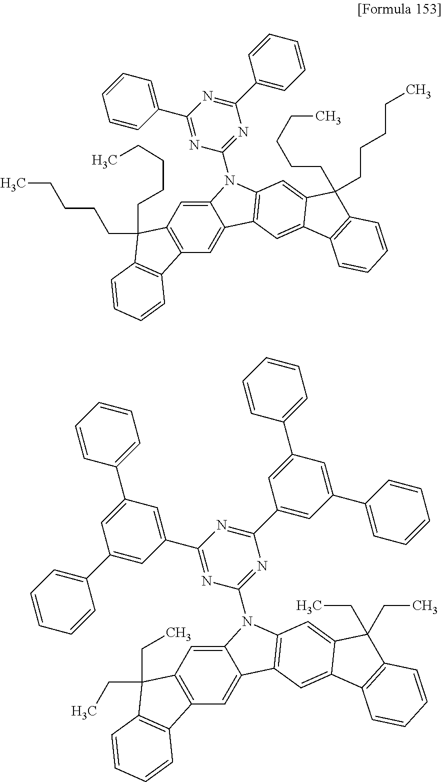 [SMILES: CCCCCC1(CCCCC)c2ccccc2-c2cc3c4cc5c(cc4n(-c4nc(-c6ccccc6)nc(-c6ccccc6)n4)c3cc21)C(CCCCC)(CCCCC)c1ccccc1-5 ; CCC1(CC)c2ccccc2-c2cc3c4cc5c(cc4n(-c4nc(-c6cc(-c7ccccc7)cc(-c7ccccc7)c6)nc(-c6cc(-c7ccccc7)cc(-c7ccccc7)c6)n4)c3cc21)C(CC)(CC)c1ccccc1-5]

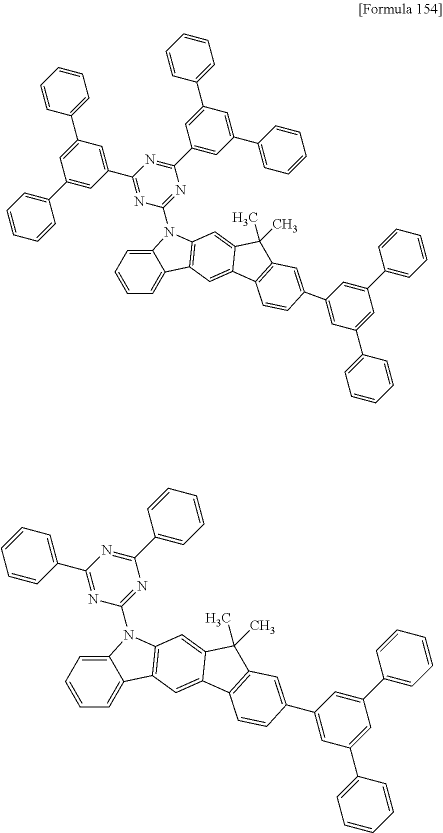 [SMILES: CC1(C)c2cc(-c3cc(-c4ccccc4)cc(-c4ccccc4)c3)ccc2-c2cc3c4ccccc4n(-c4nc(-c5cc(-c6ccccc6)cc(-c6ccccc6)c5)nc(-c5cc(-c6ccccc6)cc(-c6ccccc6)c5)n4)c3cc21 ; CC1(C)c2cc(-c3cc(-c4ccccc4)cc(-c4ccccc4)c3)ccc2-c2cc3c4ccccc4n(-c4nc(-c5ccccc5)nc(-c5ccccc5)n4)c3cc21]

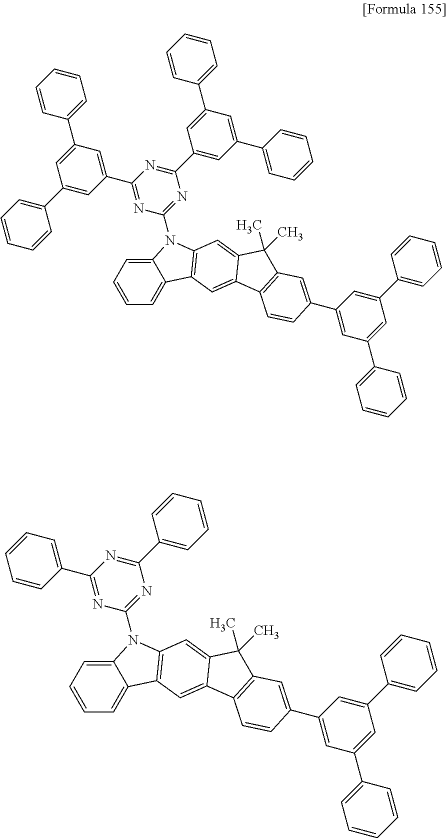 [SMILES: CC1(C)c2cc(-c3cc(-c4ccccc4)cc(-c4ccccc4)c3)ccc2-c2cc3c4ccccc4n(-c4nc(-c5cc(-c6ccccc6)cc(-c6ccccc6)c5)nc(-c5cc(-c6ccccc6)cc(-c6ccccc6)c5)n4)c3cc21 ; CC1(C)c2cc(-c3cc(-c4ccccc4)cc(-c4ccccc4)c3)ccc2-c2cc3c4ccccc4n(-c4nc(-c5ccccc5)nc(-c5ccccc5)n4)c3cc21]

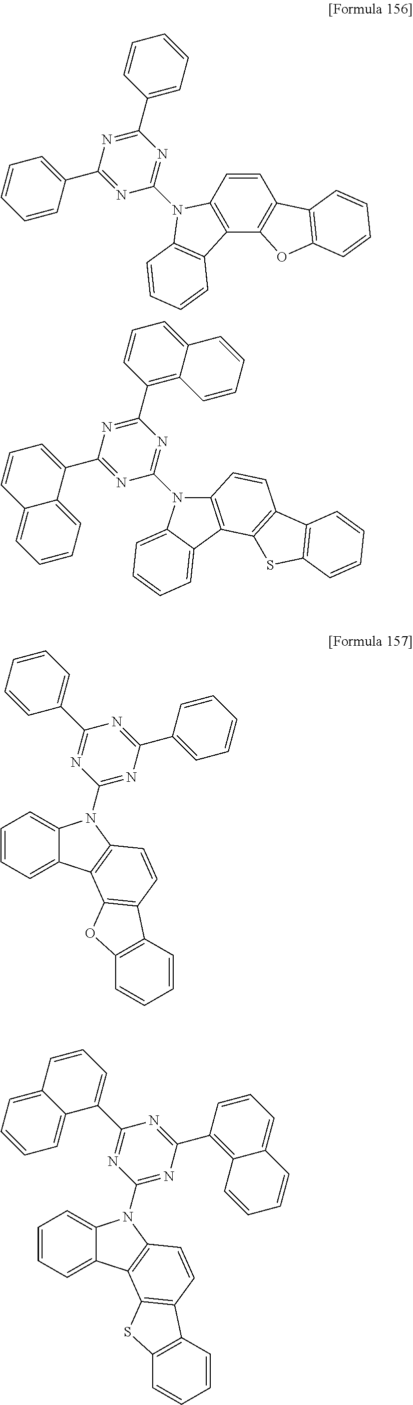

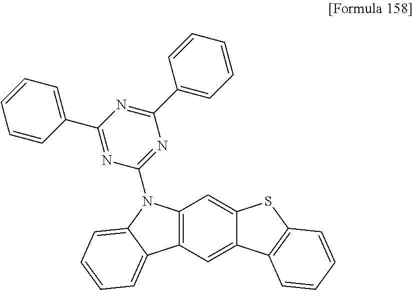 [SMILES: c1ccc(-c2nc(-c3ccccc3)nc(-n3c4ccccc4c4cc5c(cc43)sc3ccccc35)n2)cc1]

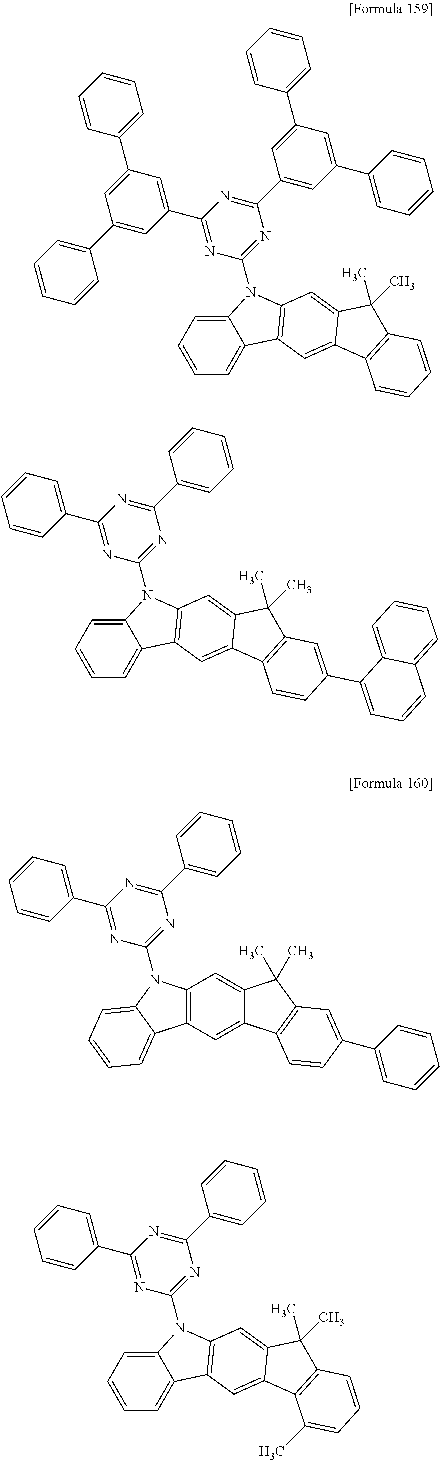 [SMILES: CC1(C)c2ccccc2-c2cc3c4ccccc4n(-c4nc(-c5cc(-c6ccccc6)cc(-c6ccccc6)c5)nc(-c5cc(-c6ccccc6)cc(-c6ccccc6)c5)n4)c3cc21 ; CC1(C)c2cc(-c3cccc4ccccc34)ccc2-c2cc3c4ccccc4n(-c4nc(-c5ccccc5)nc(-c5ccccc5)n4)c3cc21 ; CC1(C)c2cc(-c3ccccc3)ccc2-c2cc3c4ccccc4n(-c4nc(-c5ccccc5)nc(-c5ccccc5)n4)c3cc21 ; Cc1cccc2c1-c1cc3c4ccccc4n(-c4nc(-c5ccccc5)nc(-c5ccccc5)n4)c3cc1C2(C)C]

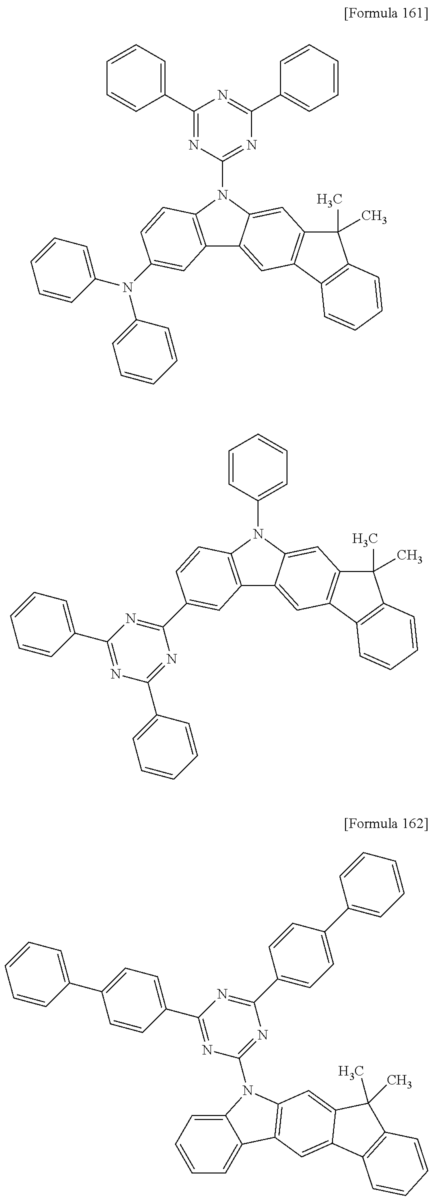 [SMILES: CC1(C)c2ccccc2-c2cc3c4cc(N(c5ccccc5)c5ccccc5)ccc4n(-c4nc(-c5ccccc5)nc(-c5ccccc5)n4)c3cc21 ; CC1(C)c2ccccc2-c2cc3c4cc(-c5nc(-c6ccccc6)nc(-c6ccccc6)n5)ccc4n(-c4ccccc4)c3cc21 ; CC1(C)c2ccccc2-c2cc3c4ccccc4n(-c4nc(-c5ccc(-c6ccccc6)cc5)nc(-c5ccc(-c6ccccc6)cc5)n4)c3cc21]

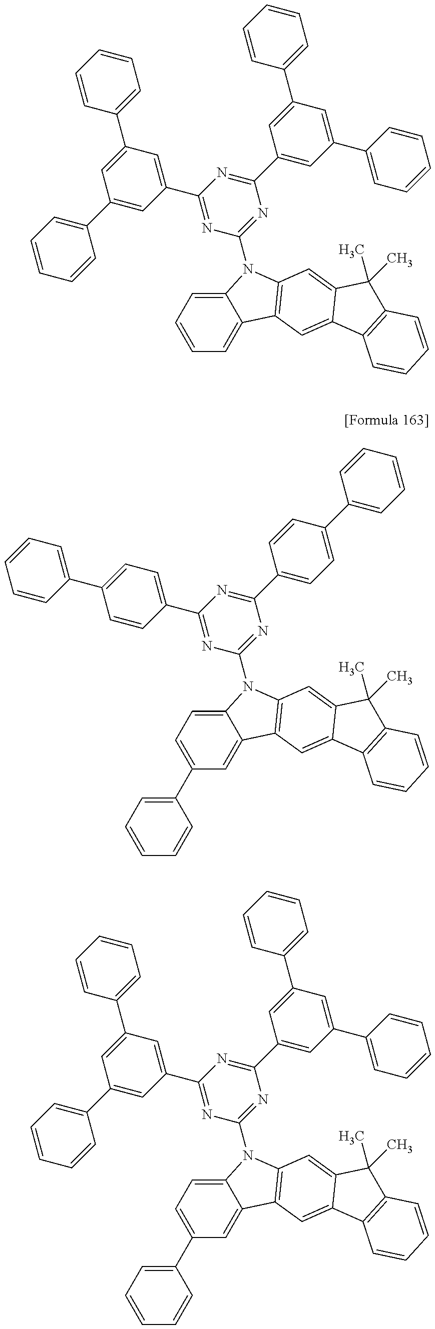 [SMILES: CC1(C)c2ccccc2-c2cc3c4ccccc4n(-c4nc(-c5cc(-c6ccccc6)cc(-c6ccccc6)c5)nc(-c5cc(-c6ccccc6)cc(-c6ccccc6)c5)n4)c3cc21 ; CC1(C)c2ccccc2-c2cc3c4cc(-c5ccccc5)ccc4n(-c4nc(-c5ccc(-c6ccccc6)cc5)nc(-c5ccc(-c6ccccc6)cc5)n4)c3cc21 ; CC1(C)c2ccccc2-c2cc3c4cc(-c5ccccc5)ccc4n(-c4nc(-c5cc(-c6ccccc6)cc(-c6ccccc6)c5)nc(-c5cc(-c6ccccc6)cc(-c6ccccc6)c5)n4)c3cc21]

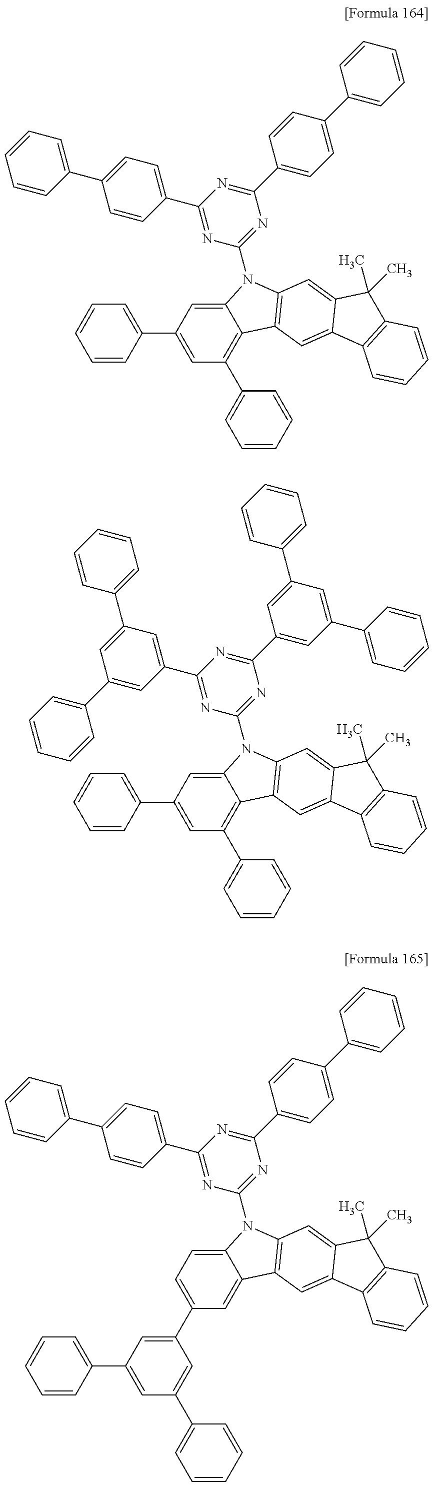

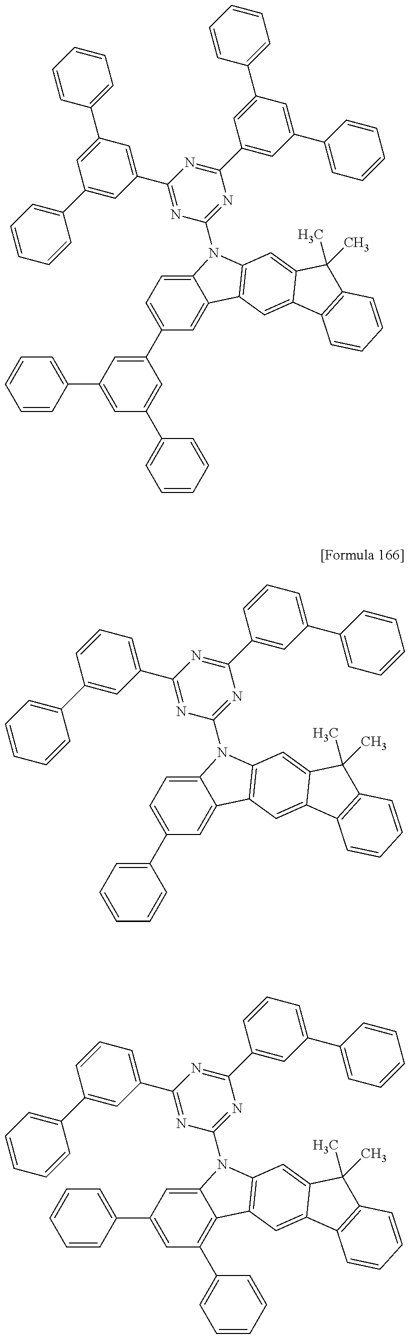 [SMILES: CC1(C)c2ccccc2-c2cc3c4cc(-c5cc(-c6ccccc6)cc(-c6ccccc6)c5)ccc4n(-c4nc(-c5cc(-c6ccccc6)cc(-c6ccccc6)c5)nc(-c5cc(-c6ccccc6)cc(-c6ccccc6)c5)n4)c3cc21 ; CC1(C)c2ccccc2-c2cc3c4cc(-c5ccccc5)ccc4n(-c4nc(-c5cccc(-c6ccccc6)c5)nc(-c5cccc(-c6ccccc6)c5)n4)c3cc21 ; CC1(C)c2ccccc2-c2cc3c4c(-c5ccccc5)cc(-c5ccccc5)cc4n(-c4nc(-c5cccc(-c6ccccc6)c5)nc(-c5cccc(-c6ccccc6)c5)n4)c3cc21]

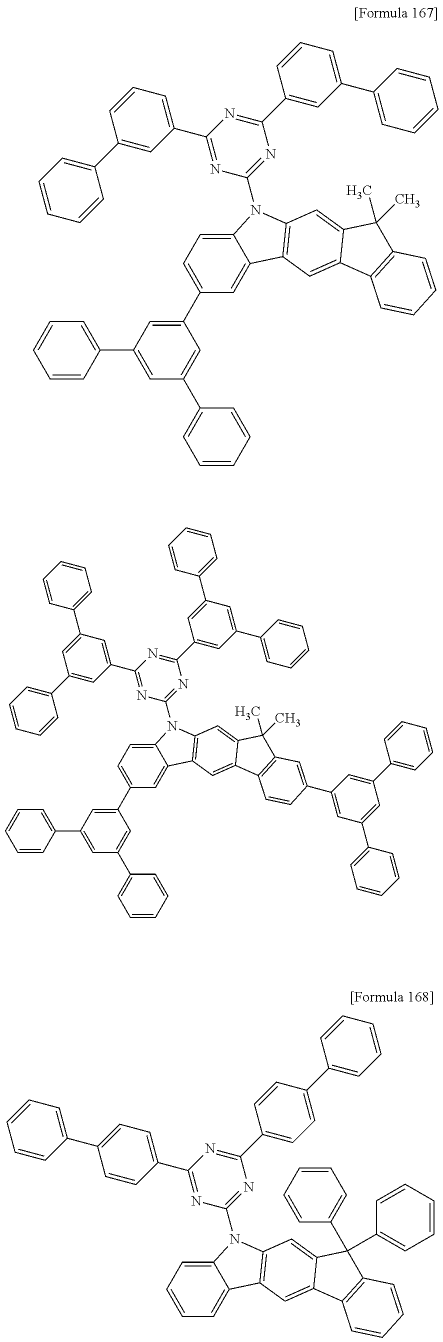 [SMILES: CC1(C)c2ccccc2-c2cc3c4cc(-c5cc(-c6ccccc6)cc(-c6ccccc6)c5)ccc4n(-c4nc(-c5cccc(-c6ccccc6)c5)nc(-c5cccc(-c6ccccc6)c5)n4)c3cc21 ; CC1(C)c2cc(-c3cc(-c4ccccc4)cc(-c4ccccc4)c3)ccc2-c2cc3c4cc(-c5cc(-c6ccccc6)cc(-c6ccccc6)c5)ccc4n(-c4nc(-c5cc(-c6ccccc6)cc(-c6ccccc6)c5)nc(-c5cc(-c6ccccc6)cc(-c6ccccc6)c5)n4)c3cc21 ; c1ccc(-c2ccc(-c3nc(-c4ccc(-c5ccccc5)cc4)nc(-n4c5ccccc5c5cc6c(cc54)C(c4ccccc4)(c4ccccc4)c4ccccc4-6)n3)cc2)cc1]

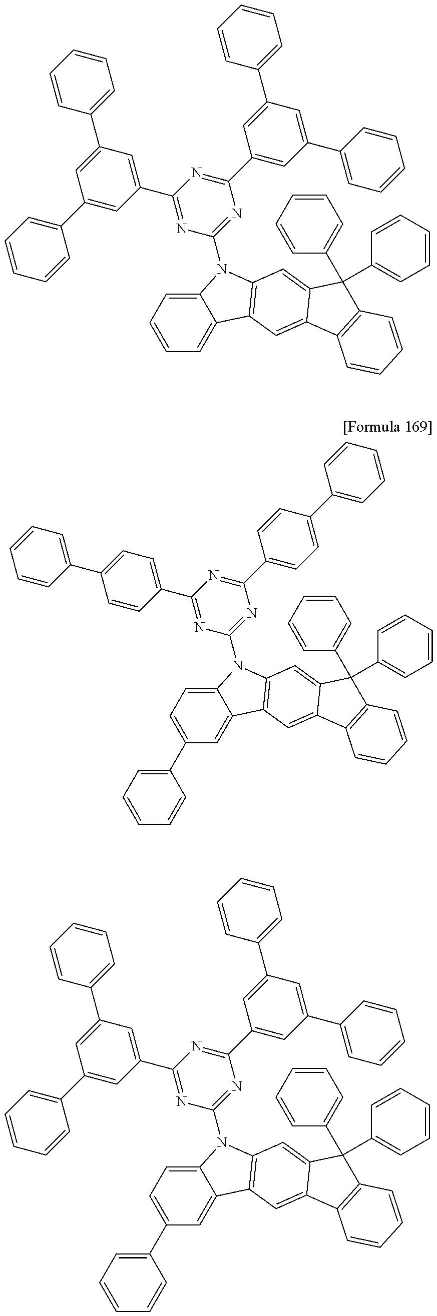 [SMILES: c1ccc(-c2cc(-c3ccccc3)cc(-c3nc(-c4cc(-c5ccccc5)cc(-c5ccccc5)c4)nc(-n4c5ccccc5c5cc6c(cc54)C(c4ccccc4)(c4ccccc4)c4ccccc4-6)n3)c2)cc1 ; c1ccc(-c2ccc(-c3nc(-c4ccc(-c5ccccc5)cc4)nc(-n4c5ccc(-c6ccccc6)cc5c5cc6c(cc54)C(c4ccccc4)(c4ccccc4)c4ccccc4-6)n3)cc2)cc1 ; c1ccc(-c2cc(-c3ccccc3)cc(-c3nc(-c4cc(-c5ccccc5)cc(-c5ccccc5)c4)nc(-n4c5ccc(-c6ccccc6)cc5c5cc6c(cc54)C(c4ccccc4)(c4ccccc4)c4ccccc4-6)n3)c2)cc1]

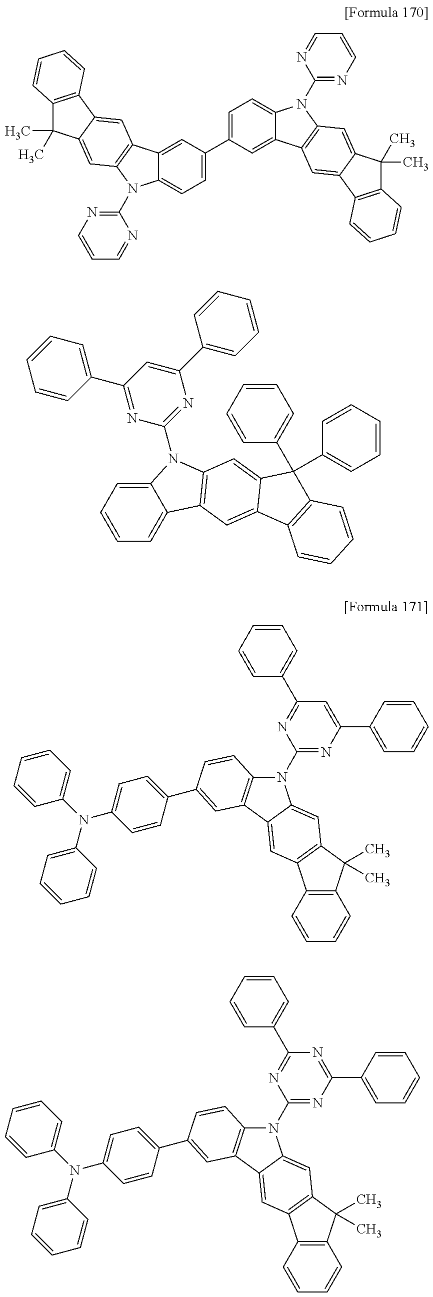

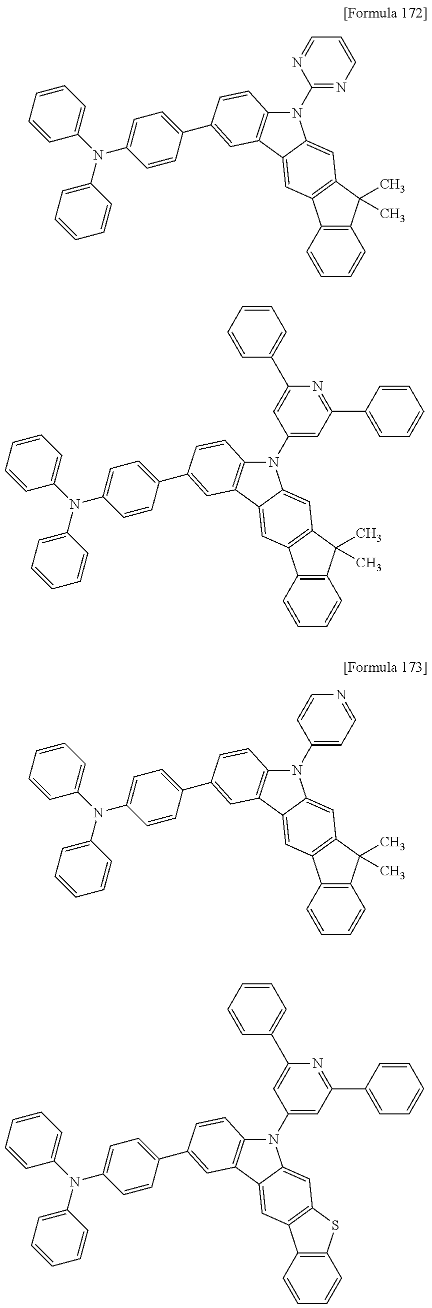 [SMILES: CC1(C)c2ccccc2-c2cc3c4cc(-c5ccc(N(c6ccccc6)c6ccccc6)cc5)ccc4n(-c4ncccn4)c3cc21 ; CC1(C)c2ccccc2-c2cc3c4cc(-c5ccc(N(c6ccccc6)c6ccccc6)cc5)ccc4n(-c4cc(-c5ccccc5)nc(-c5ccccc5)c4)c3cc21 ; CC1(C)c2ccccc2-c2cc3c4cc(-c5ccc(N(c6ccccc6)c6ccccc6)cc5)ccc4n(-c4ccncc4)c3cc21 ; c1ccc(-c2cc(-n3c4ccc(-c5ccc(N(c6ccccc6)c6ccccc6)cc5)cc4c4cc5c(cc43)sc3ccccc35)cc(-c3ccccc3)n2)cc1]

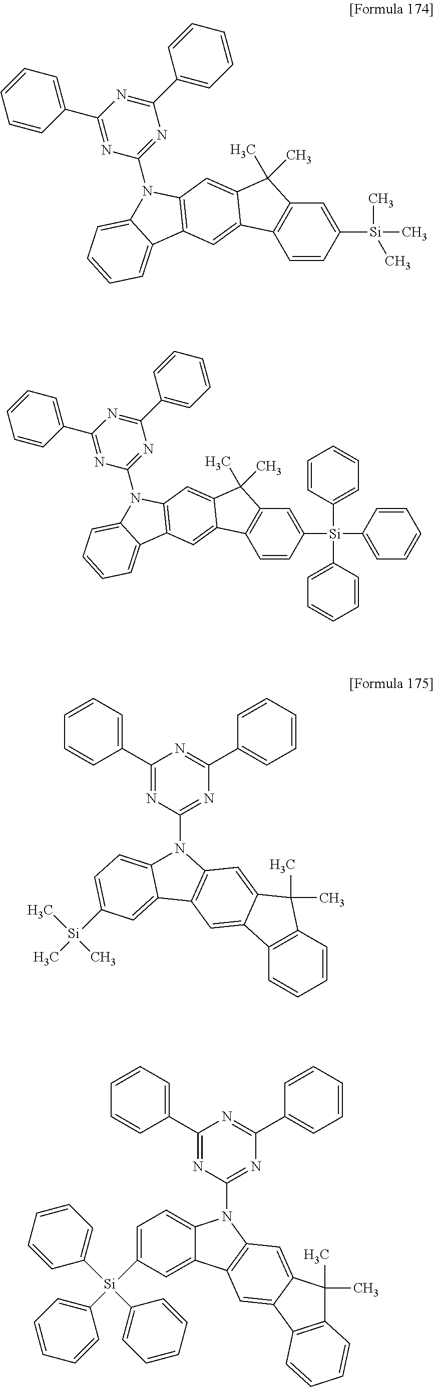

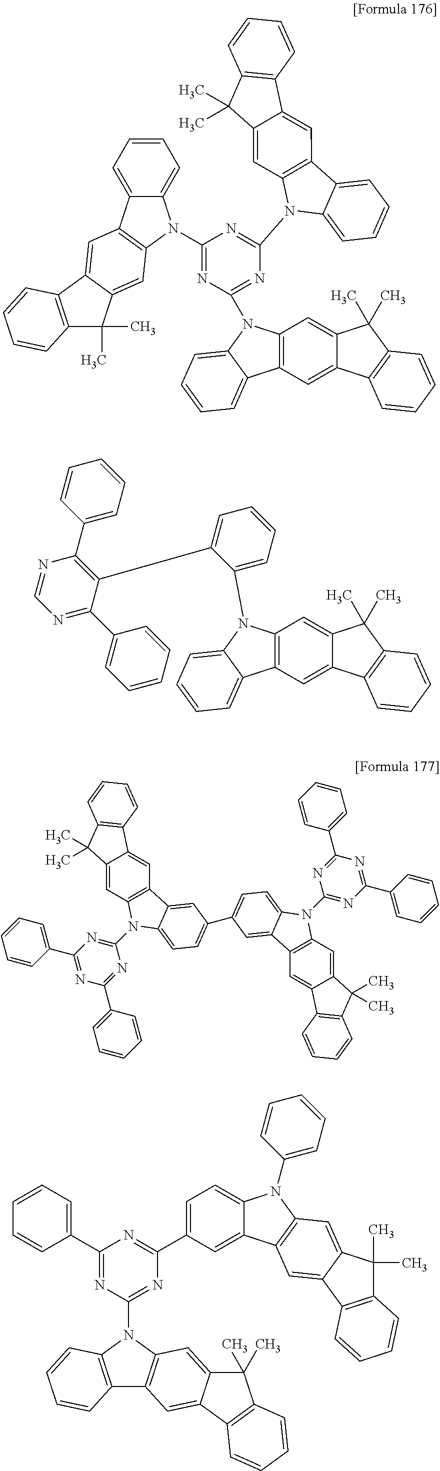

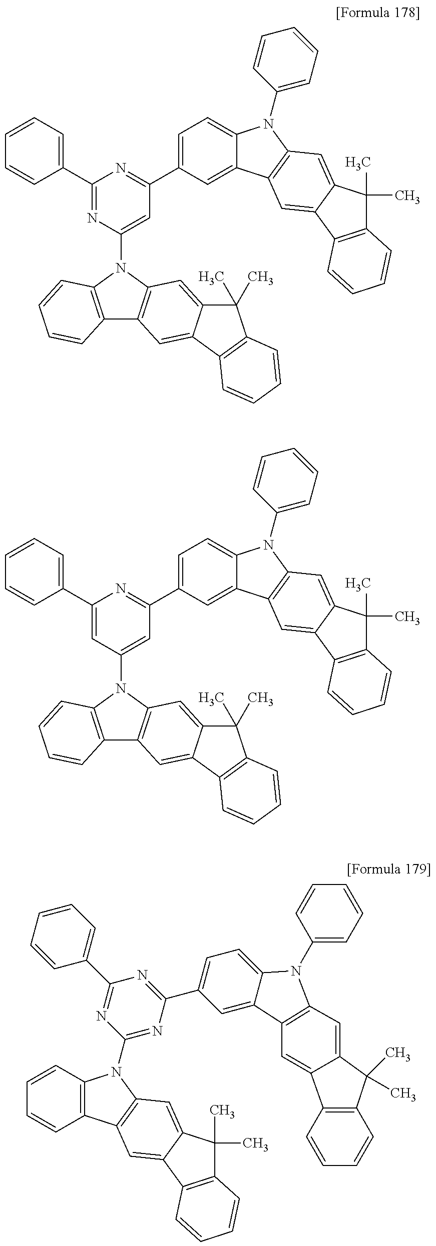 [SMILES: CC1(C)c2ccccc2-c2cc3c4cc(-c5cc(-n6c7ccccc7c7cc8c(cc76)C(C)(C)c6ccccc6-8)nc(-c6ccccc6)n5)ccc4n(-c4ccccc4)c3cc21 ; CC1(C)c2ccccc2-c2cc3c4ccccc4n(-c4cc(-c5ccccc5)nc(-c5ccc6c(c5)c5cc7c(cc5n6-c5ccccc5)C(C)(C)c5ccccc5-7)c4)c3cc21 ; CC1(C)c2ccccc2-c2cc3c4cc(-c5nc(-c6ccccc6)nc(-n6c7ccccc7c7cc8c(cc76)C(C)(C)c6ccccc6-8)n5)ccc4n(-c4ccccc4)c3cc21]

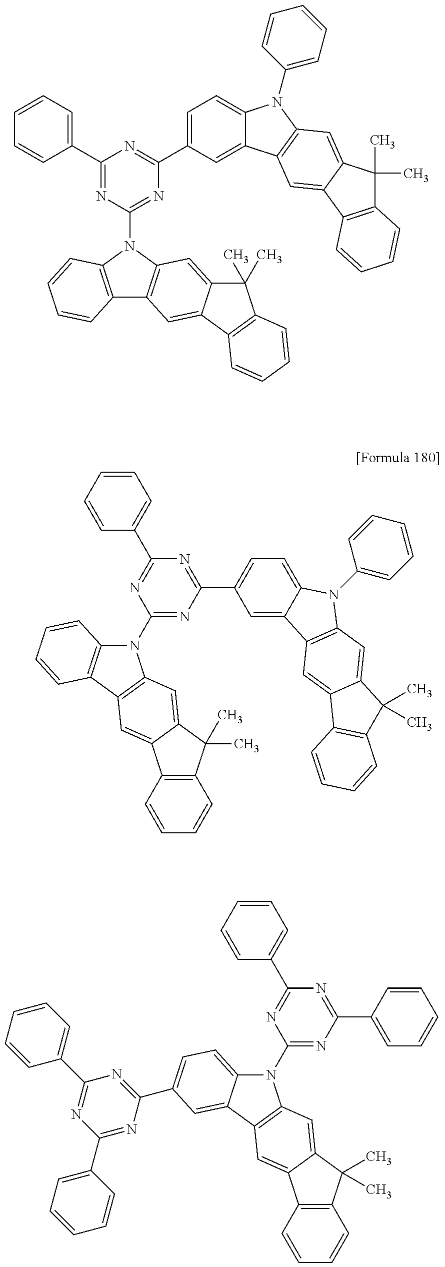 [SMILES: CC1(C)c2ccccc2-c2cc3c4cc(-c5nc(-c6ccccc6)nc(-n6c7ccccc7c7cc8c(cc76)C(C)(C)c6ccccc6-8)n5)ccc4n(-c4ccccc4)c3cc21 ; CC1(C)c2ccccc2-c2cc3c4cc(-c5nc(-c6ccccc6)nc(-n6c7ccccc7c7cc8c(cc76)C(C)(C)c6ccccc6-8)n5)ccc4n(-c4ccccc4)c3cc21 ; CC1(C)c2ccccc2-c2cc3c4cc(-c5nc(-c6ccccc6)nc(-c6ccccc6)n5)ccc4n(-c4nc(-c5ccccc5)nc(-c5ccccc5)n4)c3cc21]

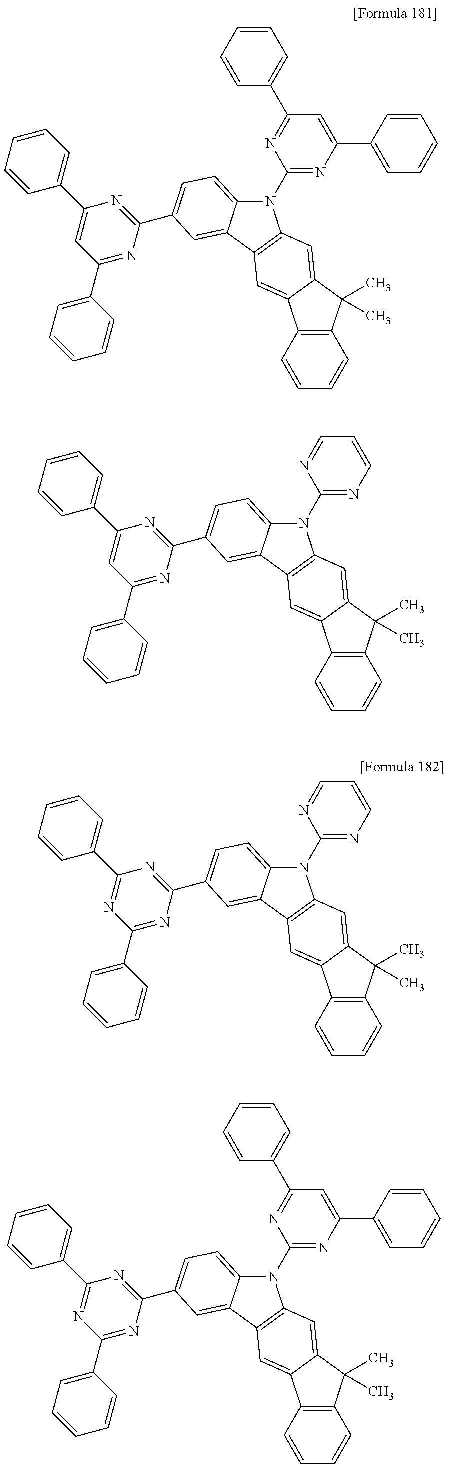 [SMILES: CC1(C)c2ccccc2-c2cc3c4cc(-c5nc(-c6ccccc6)cc(-c6ccccc6)n5)ccc4n(-c4nc(-c5ccccc5)cc(-c5ccccc5)n4)c3cc21 ; CC1(C)c2ccccc2-c2cc3c4cc(-c5nc(-c6ccccc6)cc(-c6ccccc6)n5)ccc4n(-c4ncccn4)c3cc21 ; CC1(C)c2ccccc2-c2cc3c4cc(-c5nc(-c6ccccc6)nc(-c6ccccc6)n5)ccc4n(-c4ncccn4)c3cc21 ; CC1(C)c2ccccc2-c2cc3c4cc(-c5nc(-c6ccccc6)nc(-c6ccccc6)n5)ccc4n(-c4nc(-c5ccccc5)cc(-c5ccccc5)n4)c3cc21]

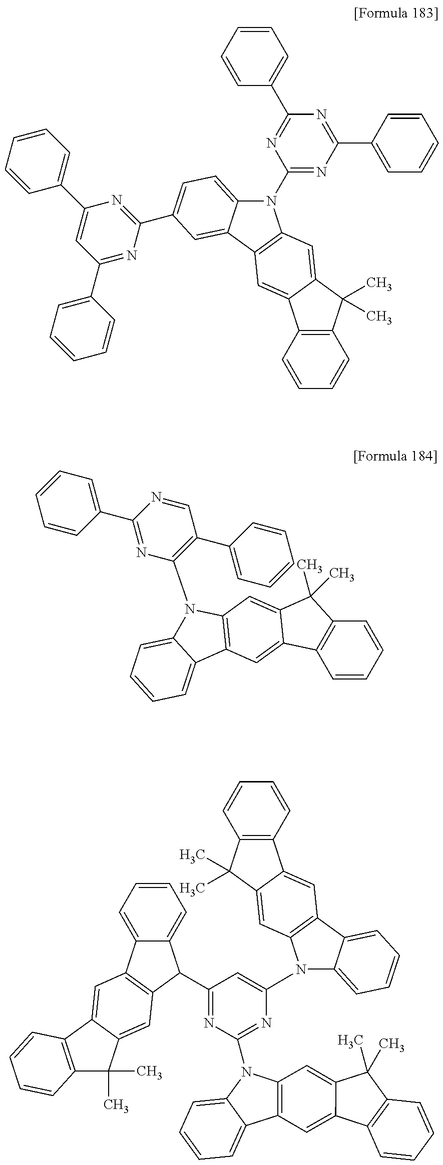 [SMILES: CC1(C)c2ccccc2-c2cc3c4cc(-c5nc(-c6ccccc6)cc(-c6ccccc6)n5)ccc4n(-c4nc(-c5ccccc5)nc(-c5ccccc5)n4)c3cc21 ; CC1(C)c2ccccc2-c2cc3c4ccccc4n(-c4nc(-c5ccccc5)ncc4-c4ccccc4)c3cc21 ; CC1(C)c2ccccc2-c2cc3c(cc21)C(c1cc(-n2c4ccccc4c4cc5c(cc42)C(C)(C)c2ccccc2-5)nc(-n2c4ccccc4c4cc5c(cc42)C(C)(C)c2ccccc2-5)n1)c1ccccc1-3]

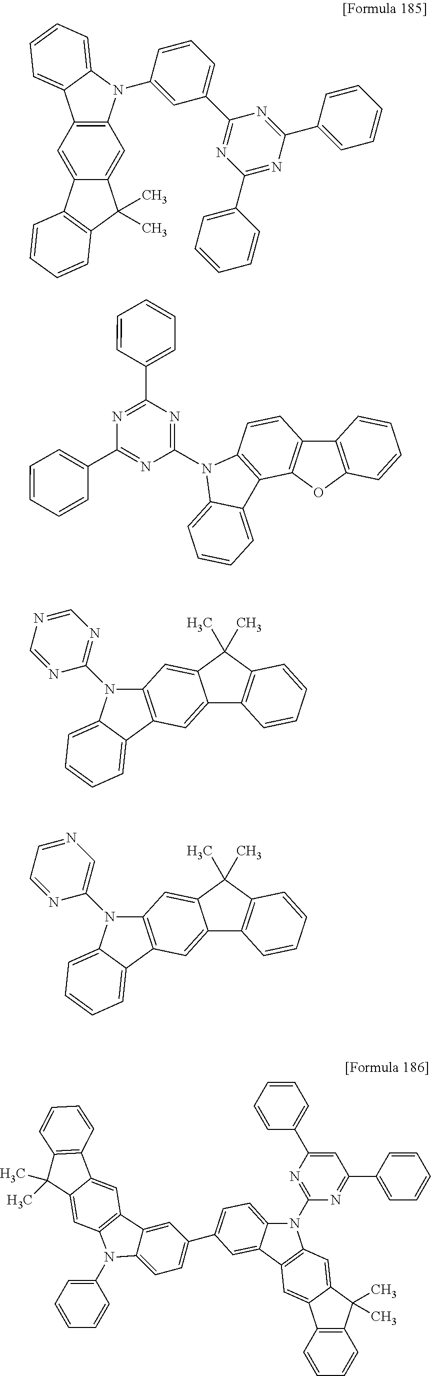 [SMILES: CC1(C)c2ccccc2-c2cc3c4ccccc4n(-c4cccc(-c5nc(-c6ccccc6)nc(-c6ccccc6)n5)c4)c3cc21 ; c1ccc(-c2nc(-c3ccccc3)nc(-n3c4ccccc4c4c5oc6ccccc6c5ccc43)n2)cc1 ; CC1(C)c2ccccc2-c2cc3c4ccccc4n(-c4ncncn4)c3cc21 ; CC1(C)c2ccccc2-c2cc3c4ccccc4n(-c4cnccn4)c3cc21 ; CC1(C)c2ccccc2-c2cc3c4cc(-c5ccc6c(c5)c5cc7c(cc5n6-c5nc(-c6ccccc6)cc(-c6ccccc6)n5)C(C)(C)c5ccccc5-7)ccc4n(-c4ccccc4)c3cc21]

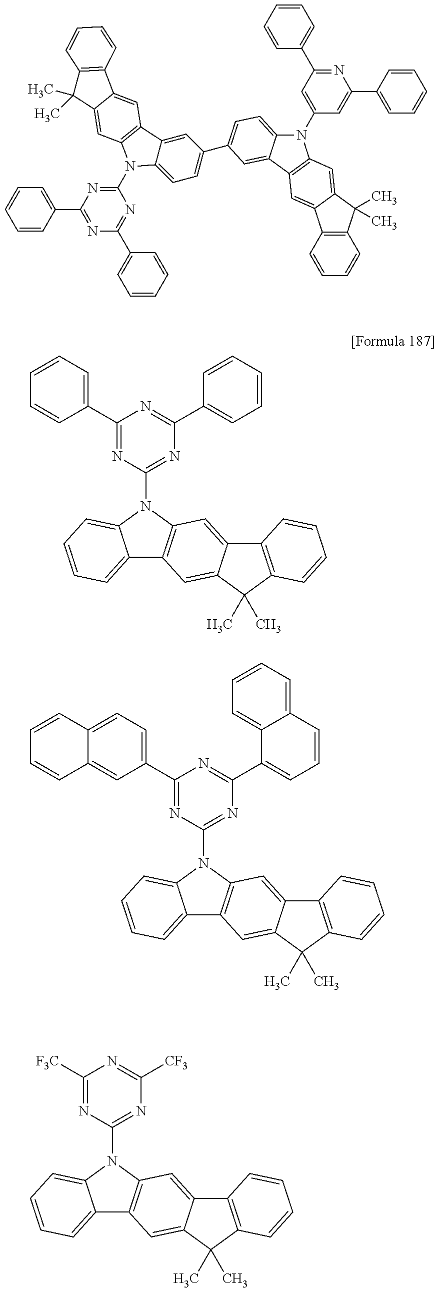

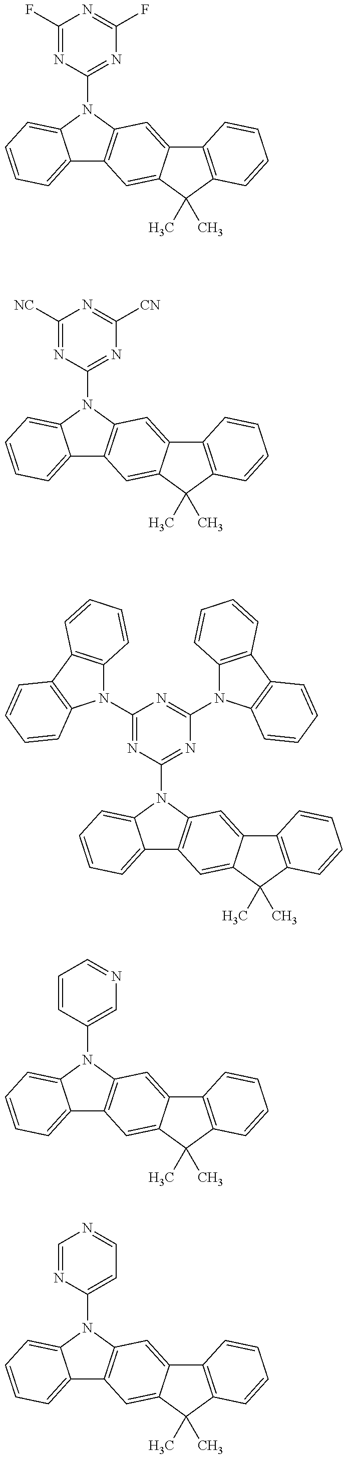 [SMILES: CC1(C)c2ccccc2-c2cc3c(cc21)c1ccccc1n3-c1nc(F)nc(F)n1 ; CC1(C)c2ccccc2-c2cc3c(cc21)c1ccccc1n3-c1nc(C#N)nc(C#N)n1 ; CC1(C)c2ccccc2-c2cc3c(cc21)c1ccccc1n3-c1nc(-n2c3ccccc3c3ccccc32)nc(-n2c3ccccc3c3ccccc32)n1 ; CC1(C)c2ccccc2-c2cc3c(cc21)c1ccccc1n3-c1cccnc1 ; CC1(C)c2ccccc2-c2cc3c(cc21)c1ccccc1n3-c1ccncn1]

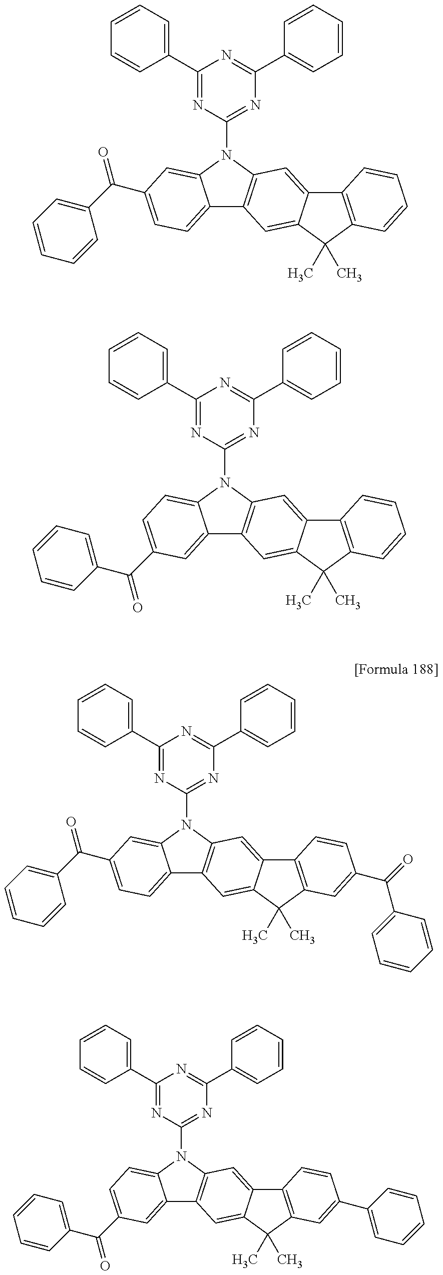 [SMILES: CC1(C)c2ccccc2-c2cc3c(cc21)c1ccc(C(=O)c2ccccc2)cc1n3-c1nc(-c2ccccc2)nc(-c2ccccc2)n1 ; CC1(C)c2ccccc2-c2cc3c(cc21)c1cc(C(=O)c2ccccc2)ccc1n3-c1nc(-c2ccccc2)nc(-c2ccccc2)n1 ; CC1(C)c2cc(C(=O)c3ccccc3)ccc2-c2cc3c(cc21)c1ccc(C(=O)c2ccccc2)cc1n3-c1nc(-c2ccccc2)nc(-c2ccccc2)n1 ; CC1(C)c2cc(-c3ccccc3)ccc2-c2cc3c(cc21)c1cc(C(=O)c2ccccc2)ccc1n3-c1nc(-c2ccccc2)nc(-c2ccccc2)n1]

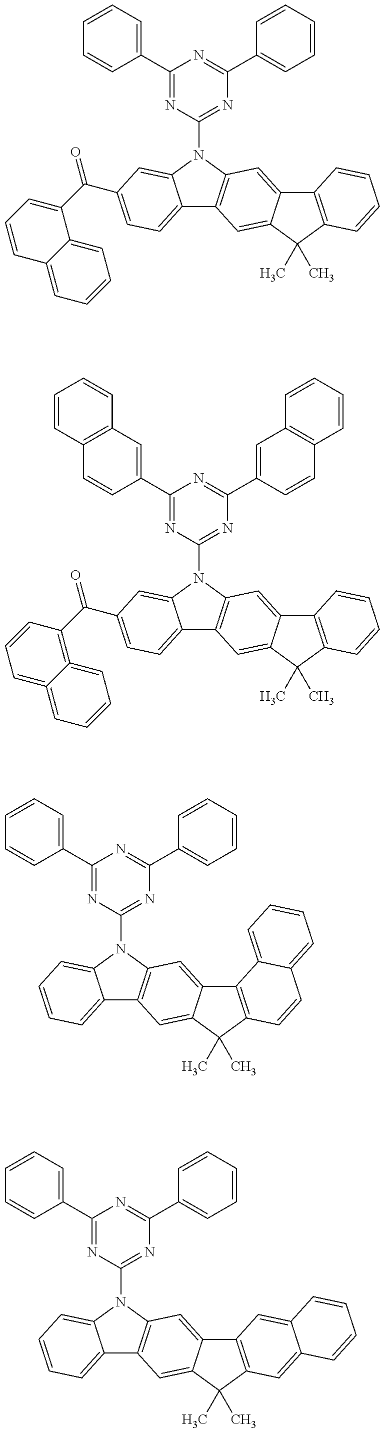

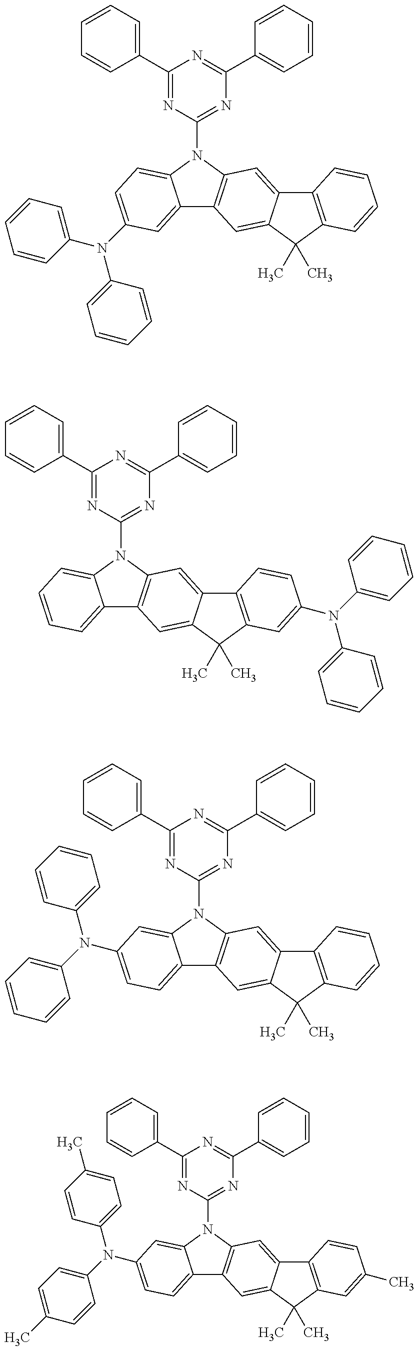

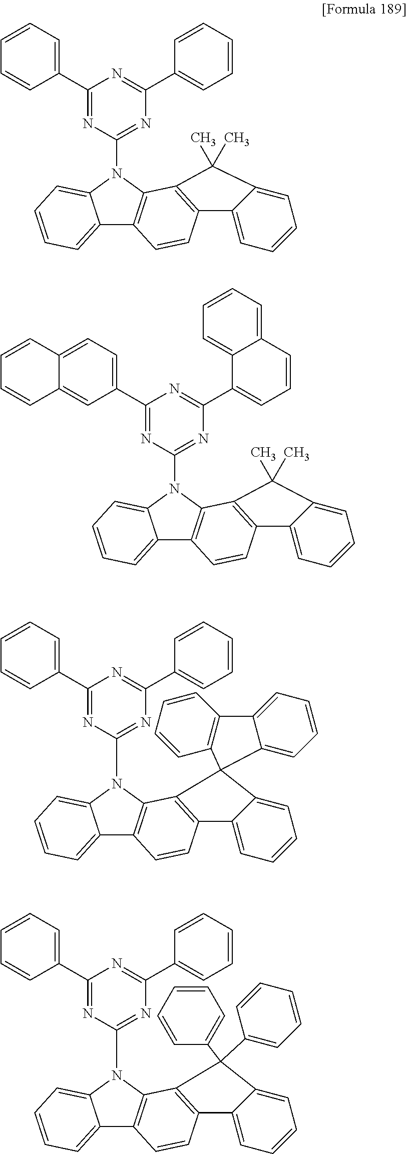

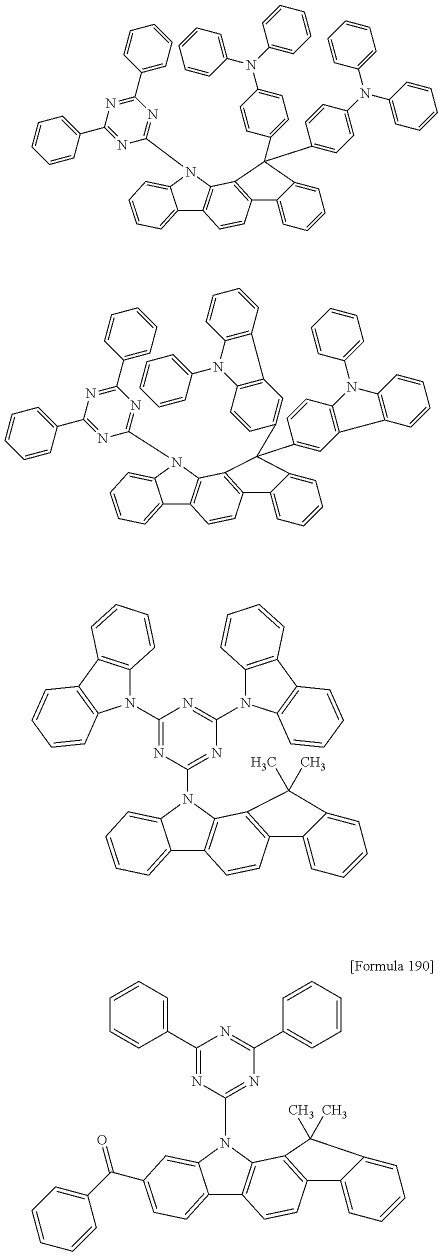 [SMILES: c1ccc(-c2nc(-c3ccccc3)nc(-n3c4ccccc4c4ccc5c(c43)C(c3ccc(N(c4ccccc4)c4ccccc4)cc3)(c3ccc(N(c4ccccc4)c4ccccc4)cc3)c3ccccc3-5)n2)cc1 ; c1ccc(-c2nc(-c3ccccc3)nc(-n3c4ccccc4c4ccc5c(c43)C(c3ccc4c(c3)c3ccccc3n4-c3ccccc3)(c3ccc4c(c3)c3ccccc3n4-c3ccccc3)c3ccccc3-5)n2)cc1 ; CC1(C)c2ccccc2-c2ccc3c4ccccc4n(-c4nc(-n5c6ccccc6c6ccccc65)nc(-n5c6ccccc6c6ccccc65)n4)c3c21 ; CC1(C)c2ccccc2-c2ccc3c4ccc(C(=O)c5ccccc5)cc4n(-c4nc(-c5ccccc5)nc(-c5ccccc5)n4)c3c21]

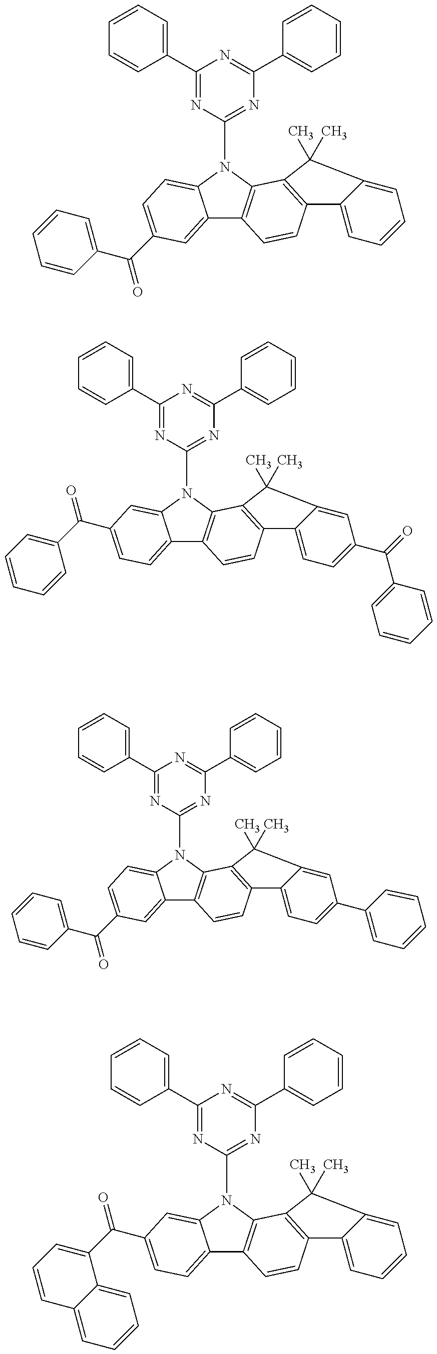 [SMILES: CC1(C)c2ccccc2-c2ccc3c4cc(C(=O)c5ccccc5)ccc4n(-c4nc(-c5ccccc5)nc(-c5ccccc5)n4)c3c21 ; CC1(C)c2cc(C(=O)c3ccccc3)ccc2-c2ccc3c4ccc(C(=O)c5ccccc5)cc4n(-c4nc(-c5ccccc5)nc(-c5ccccc5)n4)c3c21 ; CC1(C)c2cc(-c3ccccc3)ccc2-c2ccc3c4cc(C(=O)c5ccccc5)ccc4n(-c4nc(-c5ccccc5)nc(-c5ccccc5)n4)c3c21 ; CC1(C)c2ccccc2-c2ccc3c4ccc(C(=O)c5cccc6ccccc56)cc4n(-c4nc(-c5ccccc5)nc(-c5ccccc5)n4)c3c21]

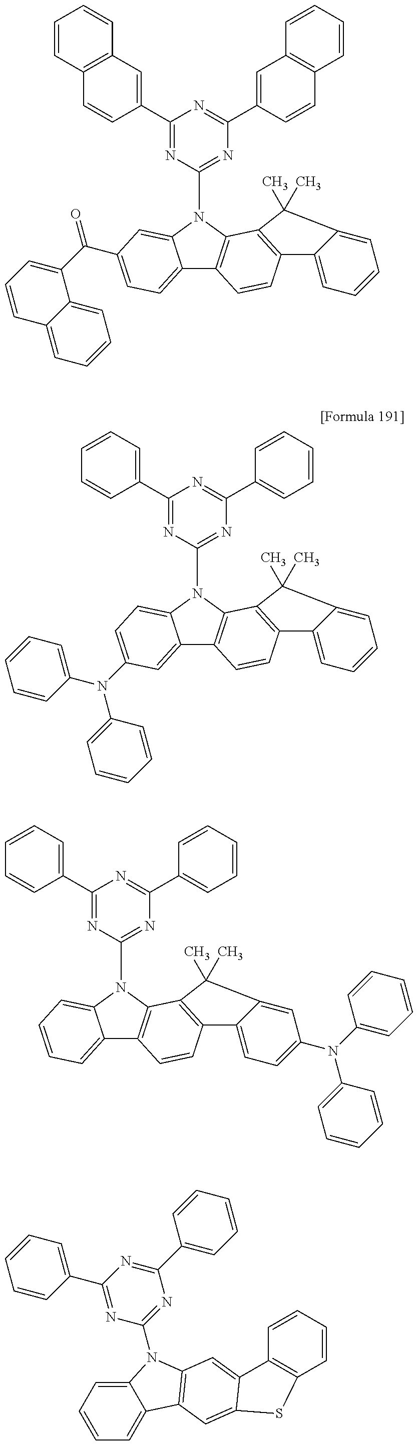 [SMILES: CC1(C)c2ccccc2-c2ccc3c4ccc(C(=O)c5cccc6ccccc56)cc4n(-c4nc(-c5ccc6ccccc6c5)nc(-c5ccc6ccccc6c5)n4)c3c21 ; CC1(C)c2ccccc2-c2ccc3c4cc(N(c5ccccc5)c5ccccc5)ccc4n(-c4nc(-c5ccccc5)nc(-c5ccccc5)n4)c3c21 ; CC1(C)c2cc(N(c3ccccc3)c3ccccc3)ccc2-c2ccc3c4ccccc4n(-c4nc(-c5ccccc5)nc(-c5ccccc5)n4)c3c21 ; c1ccc(-c2nc(-c3ccccc3)nc(-n3c4ccccc4c4cc5sc6ccccc6c5cc43)n2)cc1]

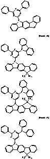

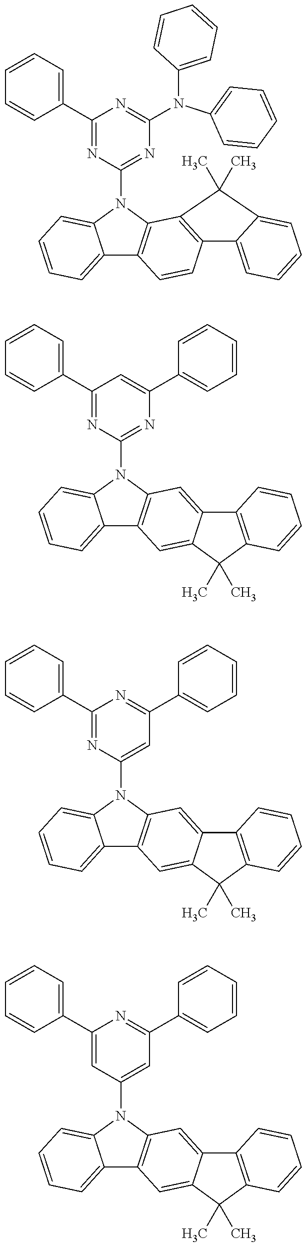 [SMILES: CC1(C)c2ccccc2-c2ccc3c4ccccc4n(-c4nc(-c5ccccc5)nc(N(c5ccccc5)c5ccccc5)n4)c3c21 ; CC1(C)c2ccccc2-c2cc3c(cc21)c1ccccc1n3-c1nc(-c2ccccc2)cc(-c2ccccc2)n1 ; CC1(C)c2ccccc2-c2cc3c(cc21)c1ccccc1n3-c1cc(-c2ccccc2)nc(-c2ccccc2)n1 ; CC1(C)c2ccccc2-c2cc3c(cc21)c1ccccc1n3-c1cc(-c2ccccc2)nc(-c2ccccc2)c1]

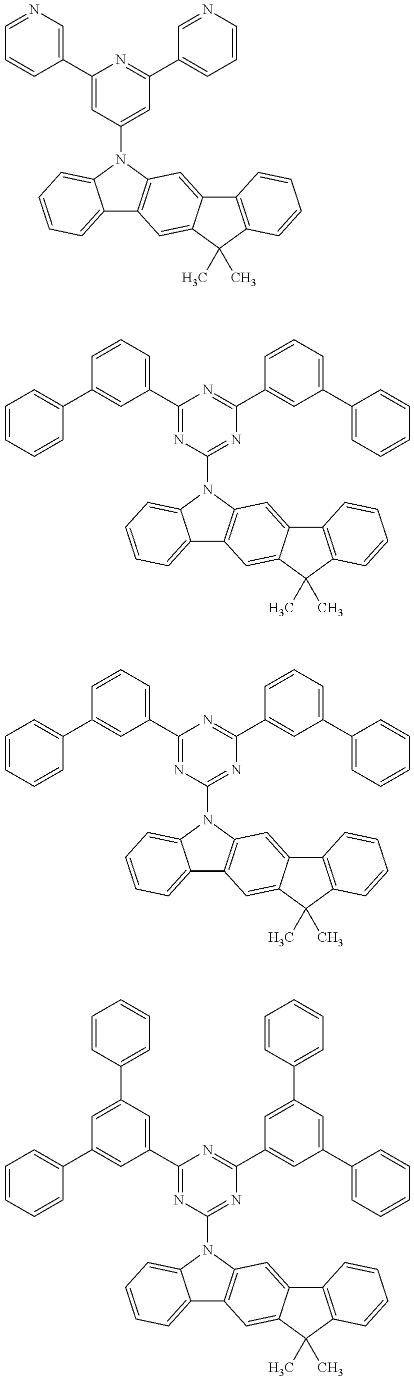 [SMILES: CC1(C)c2ccccc2-c2cc3c(cc21)c1ccccc1n3-c1cc(-c2cccnc2)nc(-c2cccnc2)c1 ; CC1(C)c2ccccc2-c2cc3c(cc21)c1ccccc1n3-c1nc(-c2cccc(-c3ccccc3)c2)nc(-c2cccc(-c3ccccc3)c2)n1 ; CC1(C)c2ccccc2-c2cc3c(cc21)c1ccccc1n3-c1nc(-c2cccc(-c3ccccc3)c2)nc(-c2cccc(-c3ccccc3)c2)n1 ; CC1(C)c2ccccc2-c2cc3c(cc21)c1ccccc1n3-c1nc(-c2cc(-c3ccccc3)cc(-c3ccccc3)c2)nc(-c2cc(-c3ccccc3)cc(-c3ccccc3)c2)n1]

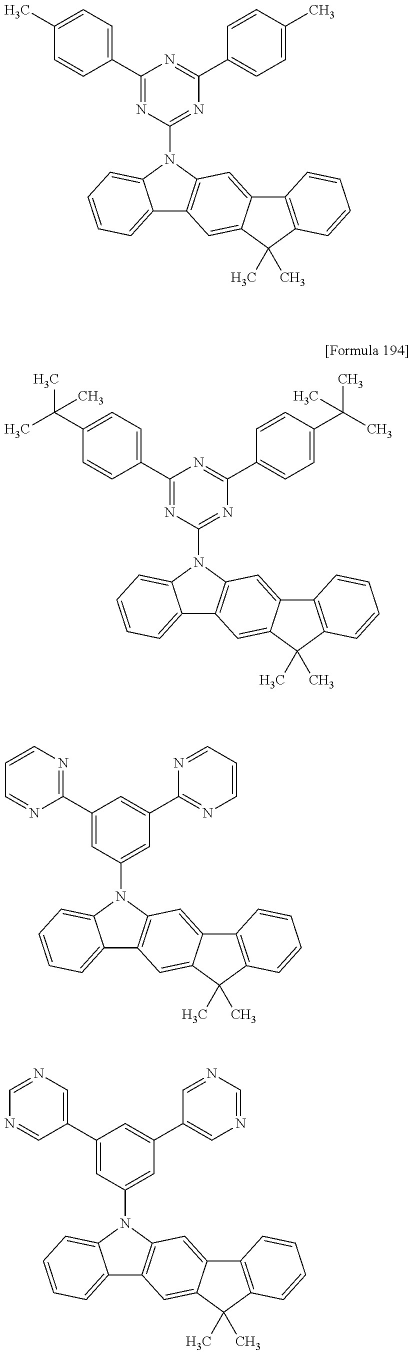 [SMILES: Cc1ccc(-c2nc(-c3ccc(C)cc3)nc(-n3c4ccccc4c4cc5c(cc43)-c3ccccc3C5(C)C)n2)cc1 ; CC(C)(C)c1ccc(-c2nc(-c3ccc(C(C)(C)C)cc3)nc(-n3c4ccccc4c4cc5c(cc43)-c3ccccc3C5(C)C)n2)cc1 ; CC1(C)c2ccccc2-c2cc3c(cc21)c1ccccc1n3-c1cc(-c2ncccn2)cc(-c2ncccn2)c1 ; CC1(C)c2ccccc2-c2cc3c(cc21)c1ccccc1n3-c1cc(-c2cncnc2)cc(-c2cncnc2)c1]

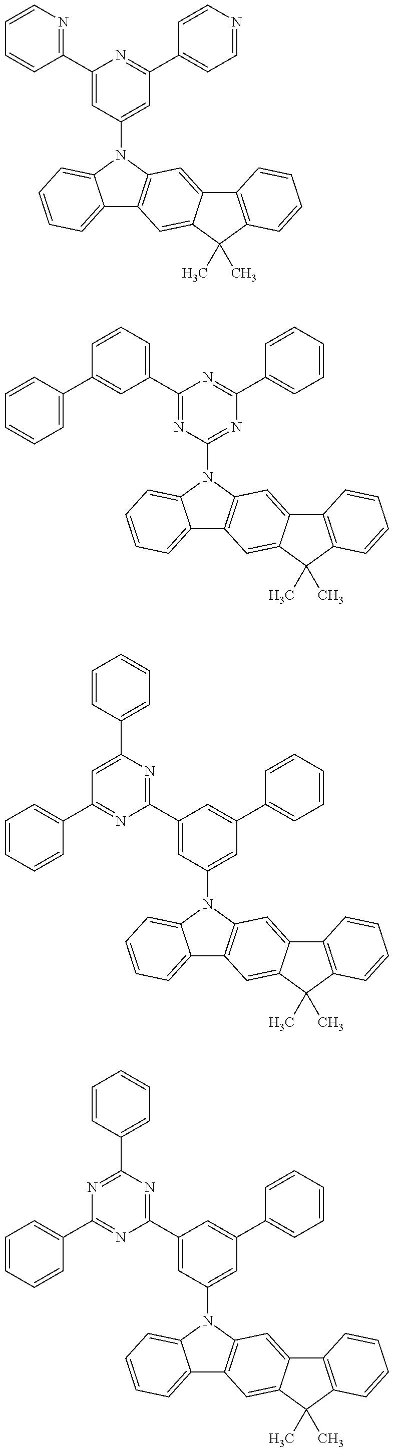 [SMILES: CC1(C)c2ccccc2-c2cc3c(cc21)c1ccccc1n3-c1cc(-c2ccncc2)nc(-c2ccccn2)c1 ; CC1(C)c2ccccc2-c2cc3c(cc21)c1ccccc1n3-c1nc(-c2ccccc2)nc(-c2cccc(-c3ccccc3)c2)n1 ; CC1(C)c2ccccc2-c2cc3c(cc21)c1ccccc1n3-c1cc(-c2ccccc2)cc(-c2nc(-c3ccccc3)cc(-c3ccccc3)n2)c1 ; CC1(C)c2ccccc2-c2cc3c(cc21)c1ccccc1n3-c1cc(-c2ccccc2)cc(-c2nc(-c3ccccc3)nc(-c3ccccc3)n2)c1]

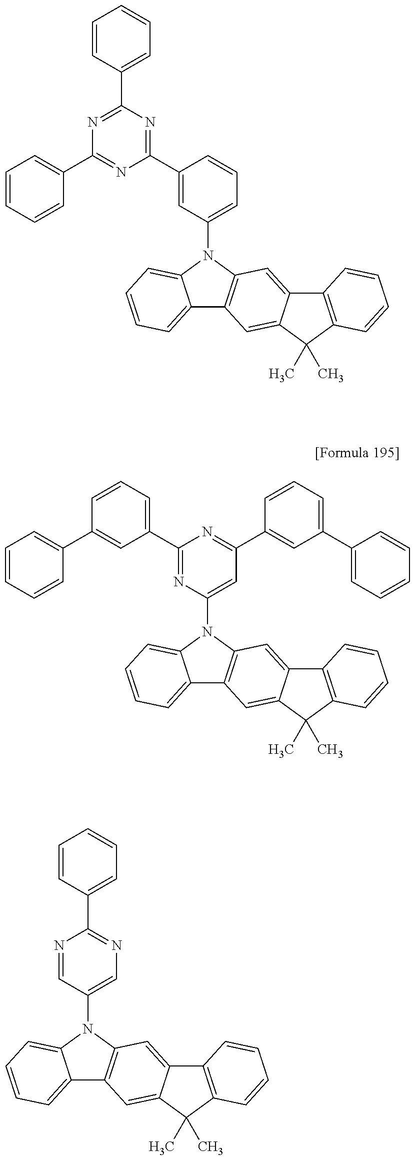 [SMILES: CC1(C)c2ccccc2-c2cc3c(cc21)c1ccccc1n3-c1cccc(-c2nc(-c3ccccc3)nc(-c3ccccc3)n2)c1 ; CC1(C)c2ccccc2-c2cc3c(cc21)c1ccccc1n3-c1cc(-c2cccc(-c3ccccc3)c2)nc(-c2cccc(-c3ccccc3)c2)n1 ; CC1(C)c2ccccc2-c2cc3c(cc21)c1ccccc1n3-c1cnc(-c2ccccc2)nc1]

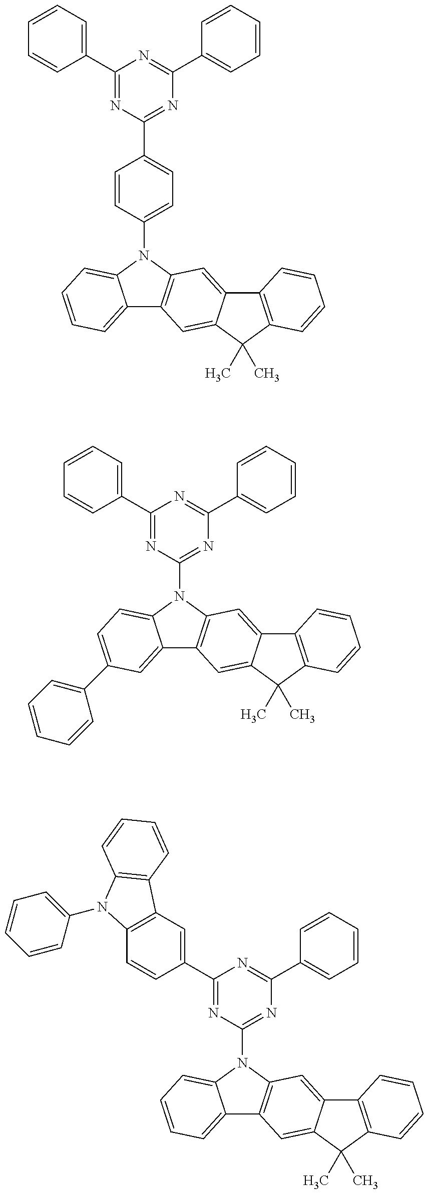 [SMILES: CC1(C)c2ccccc2-c2cc3c(cc21)c1ccccc1n3-c1ccc(-c2nc(-c3ccccc3)nc(-c3ccccc3)n2)cc1 ; CC1(C)c2ccccc2-c2cc3c(cc21)c1cc(-c2ccccc2)ccc1n3-c1nc(-c2ccccc2)nc(-c2ccccc2)n1 ; CC1(C)c2ccccc2-c2cc3c(cc21)c1ccccc1n3-c1nc(-c2ccccc2)nc(-c2ccc3c(c2)c2ccccc2n3-c2ccccc2)n1]

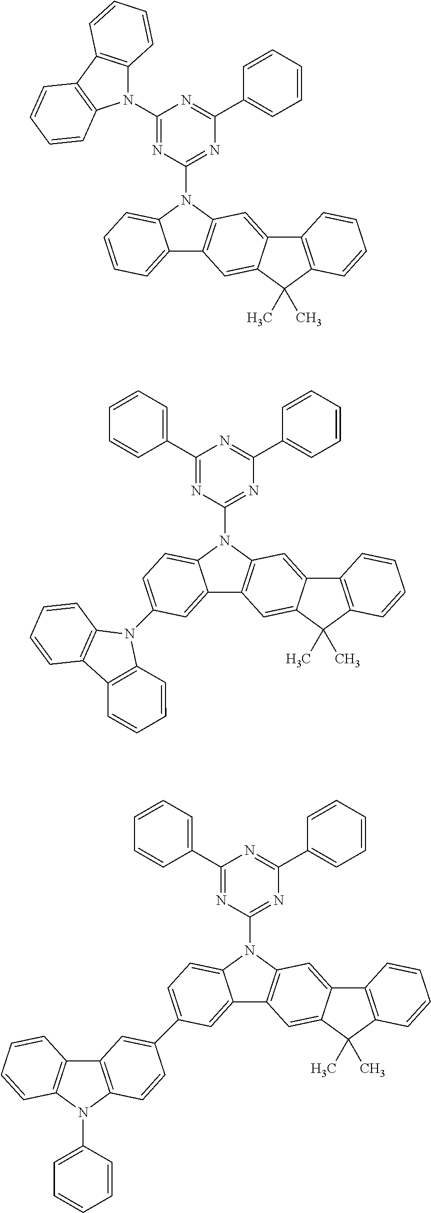 [SMILES: CC1(C)c2ccccc2-c2cc3c(cc21)c1ccccc1n3-c1nc(-c2ccccc2)nc(-n2c3ccccc3c3ccccc32)n1 ; CC1(C)c2ccccc2-c2cc3c(cc21)c1cc(-n2c4ccccc4c4ccccc42)ccc1n3-c1nc(-c2ccccc2)nc(-c2ccccc2)n1 ; CC1(C)c2ccccc2-c2cc3c(cc21)c1cc(-c2ccc4c(c2)c2ccccc2n4-c2ccccc2)ccc1n3-c1nc(-c2ccccc2)nc(-c2ccccc2)n1]

### Phosphorescent Dopant Material

The phosphorescent dopant material preferably contains a metal complex. The metal complex preferably has a metal atom selected from among Ir (iridium), Pt (platinum), Os (osmium), Au (gold), Cu (copper), Re (rhenium) and Ru (ruthenium) as well as a ligand. Particularly, the ligand preferably has an ortho-metal bond.

The phosphorescent dopant material is preferably a compound containing a metal atom selected from among Ir, Os, and Pt because such a compound, which exhibits a high phosphorescence quantum yield, can further enhance the external quantum efficiency of the organic EL device. More preferable examples of the phosphorescent dopant material are metal complexes such as an iridium complex, an osmium complex and a platinum complex, among which an iridium complex and a platinum complex are further more preferable and ortho metalation of an iridium complex is the most preferable. The organic metal complex formed of the ligand selected from the group consisting of phenyl quinoline, phenyl isoquinoline, phenyl pyridine, phenyl pyrimidine and phenyl imidazoles is preferable in terms of the luminous efficiency and the like.

Specific examples of such a preferable metal complex are shown below.

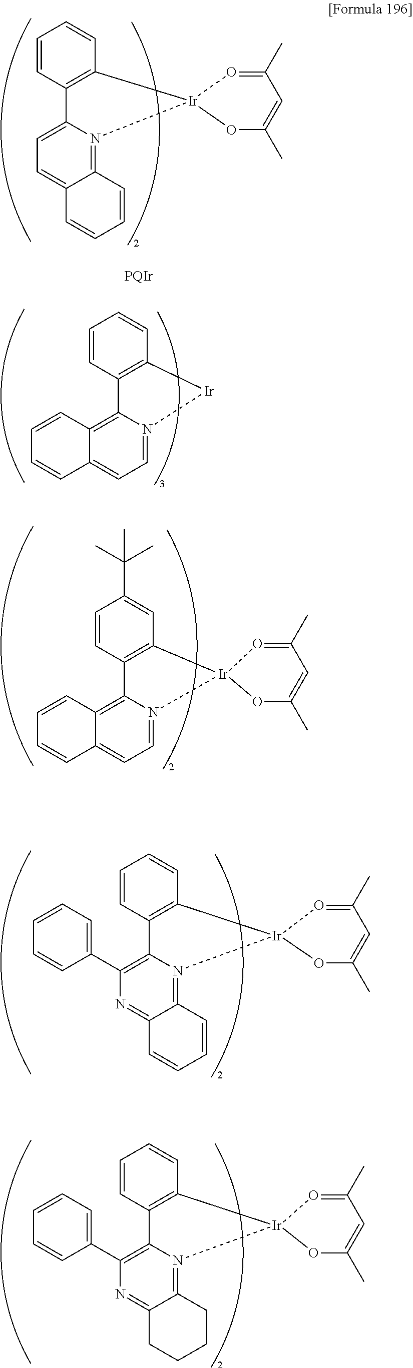

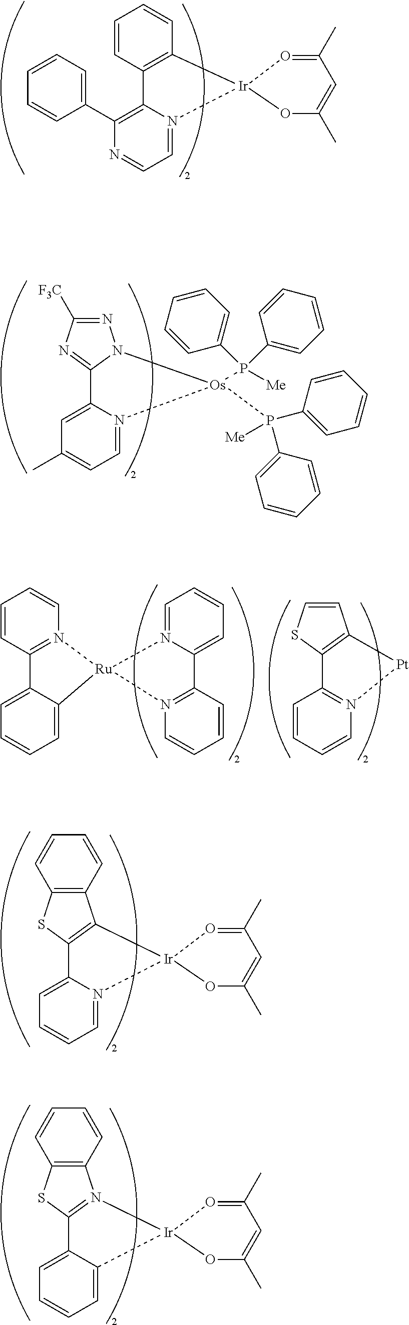

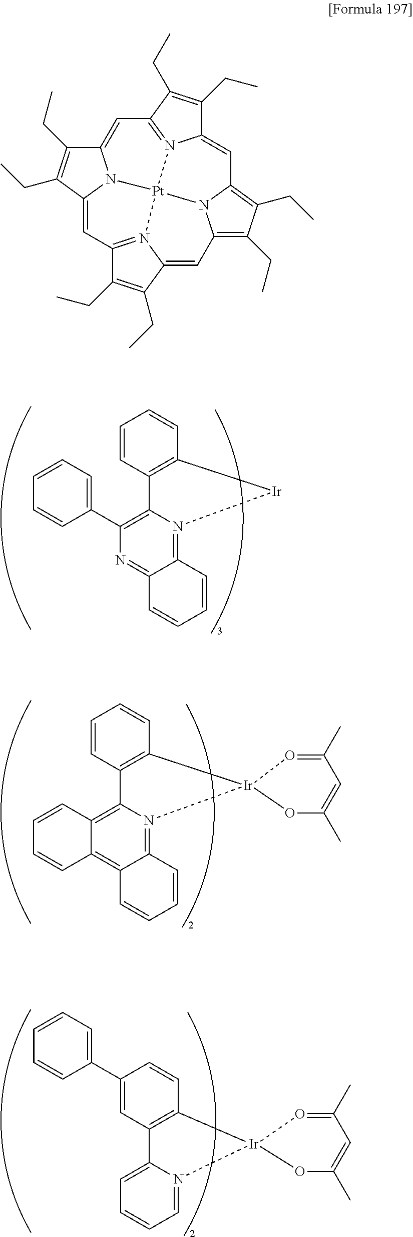

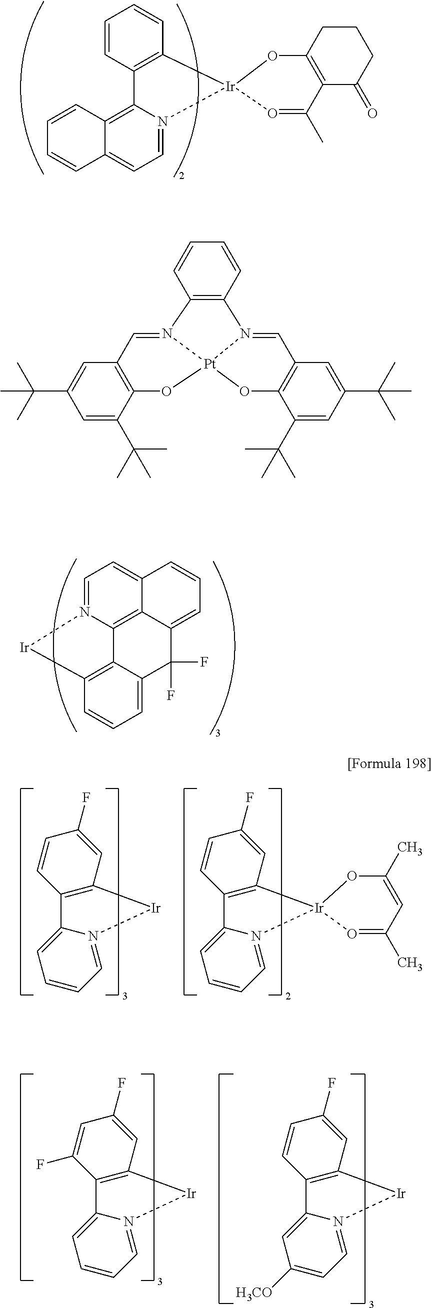

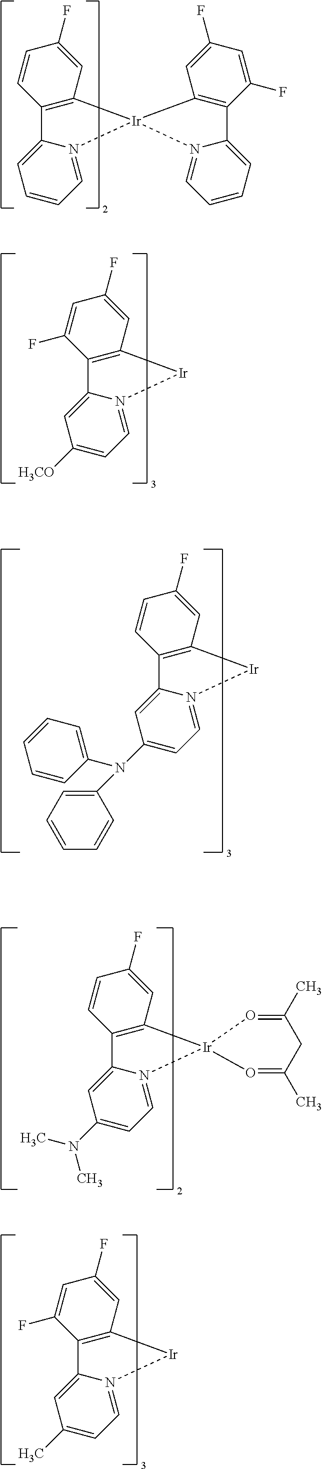

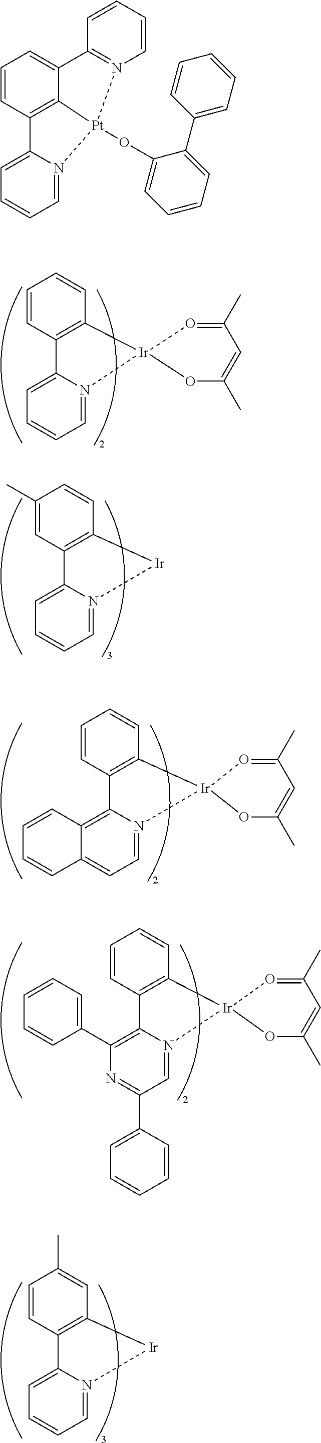

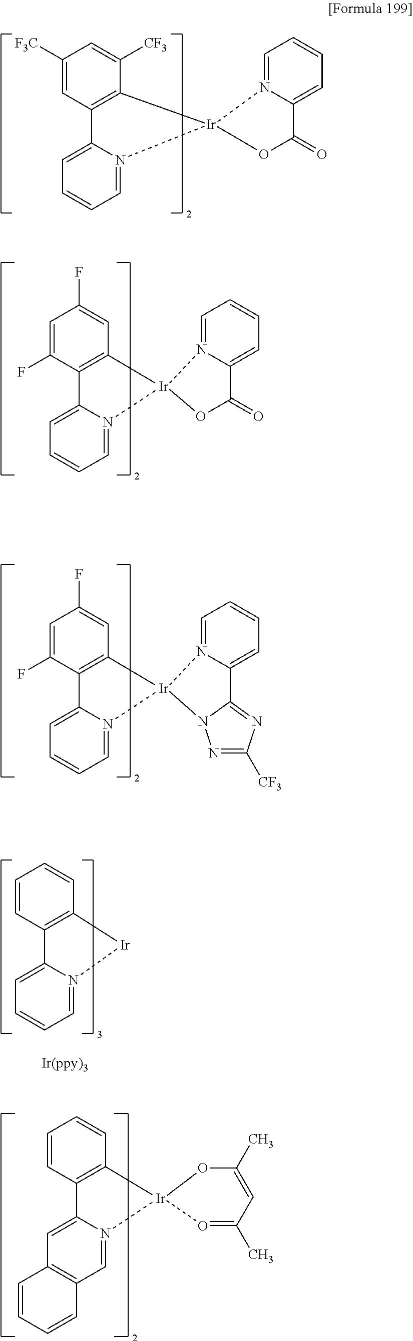

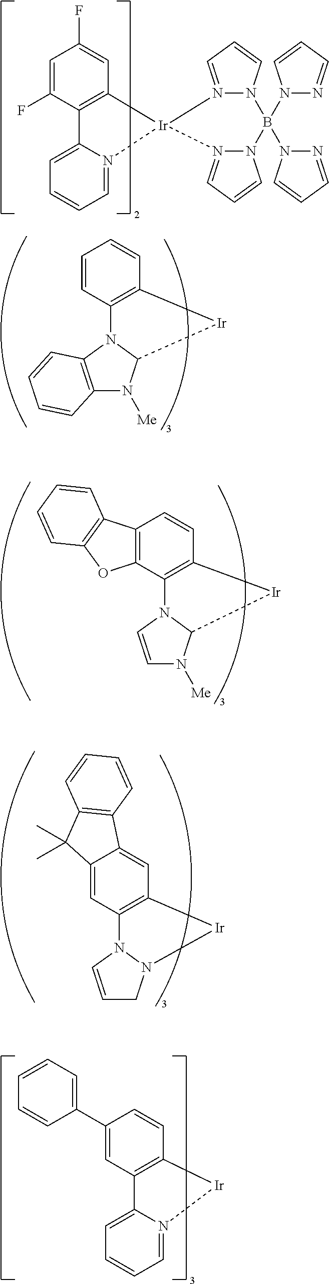

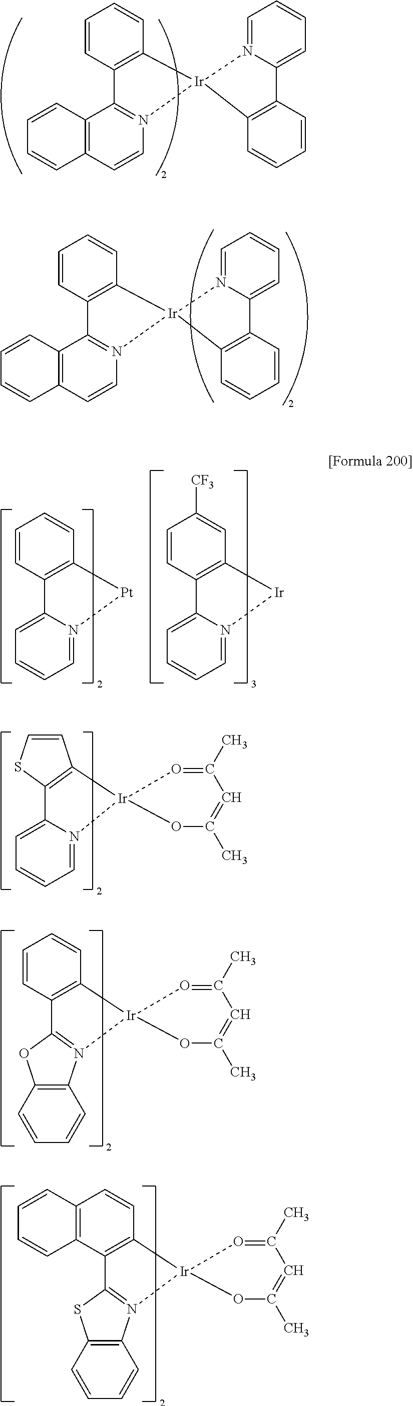

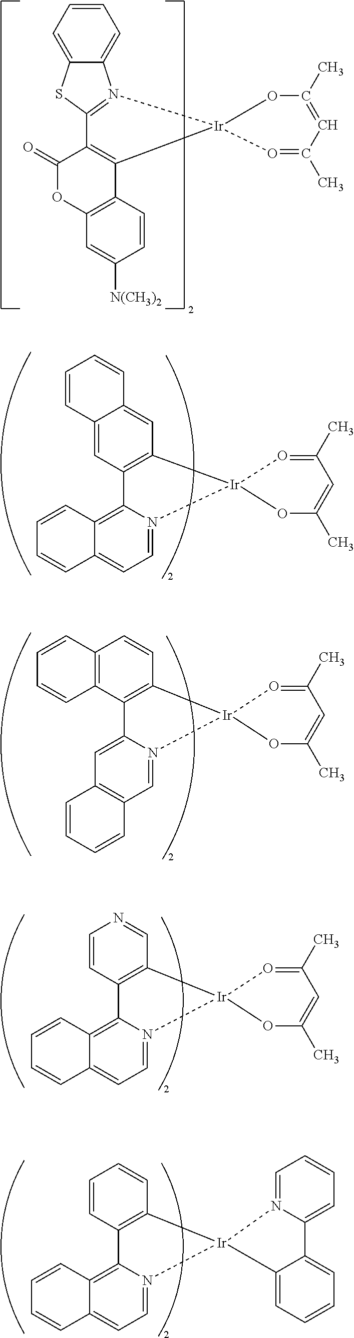

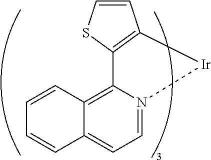

One of the phosphorescent dopant material may be used alone or, alternatively, two or more thereof may be used in combination.

At least one phosphorescent dopant material contained in the emitting layer 5 preferably has a peak emission wavelength of from 500 nm to 650 nm, more preferably of from 510 nm to 630 nm. In the exemplary embodiment, an emission color is preferably green. Although the peak emission wavelength for green emission is generally in a range from 495 nm to 570 nm, an emission wavelength of from 510 nm to 570 nm is particularly preferable in the exemplary embodiment.

By doping the phosphorescent dopant material having such an emission wavelength to the first material and second host material as specified above to form the emitting layer 5, the organic EL device can exhibit a high efficiency.

### Substrate

The organic EL device 1 is formed by laminating the anode 3, the emitting layer 5, the cathode 4 and the like on the light-transmissive substrate 2. The substrate 2, which supports the anode 3 and the like, is preferably a smoothly-shaped substrate that transmits 50% or more of light in a visible region of 400 nm to 700 nm.

The light-transmissive substrate 2 is exemplified by a glass plate and a polymer plate.

For the glass plate, materials such as soda-lime glass, barium/strontium-containing glass, lead glass, aluminosilicate glass, borosilicate glass, barium borosilicate glass and quartz can be used.

For the polymer plate, materials such as polycarbonate, acryl, polyethylene terephthalate, polyether sulfide and polysulfone can be used.

Incidentally, the substrate can be peeled off from the organic EL device by a peeling method.

### Anode and Cathode

The anode 3 of the organic EL device 1 is used for injecting holes into the hole injecting layer, the hole transporting layer 6 or the emitting layer 5. It is favorable that the anode 3 has a work function of 4.5 eV or more.

Specific examples of a material for the anode are alloys of indium-tin oxide (ITO), tin oxide (NESA), indium zinc oxide, gold, silver, platinum and copper.

The anode 3 can be manufactured by forming a thin film from these anode materials, for instance, on the substrate 2 by a method such as vapor deposition and sputtering.

When light from the emitting layer 5 is to be emitted through the anode 3, the anode 3 preferably transmits more than 10% of the light in the visible region. The sheet resistance of the anode 3 is preferably several hundreds Ω/square or lower. Although depending on the material of the anode 3, the thickness of the anode is typically in a range of 10 nm to 1 μm, preferably in a range of 10 nm to 200 nm.

The cathode is preferably formed of a material with smaller work function in order to inject electrons into the emitting layer.

Although a material for the cathode is subject to no specific limitation, examples of the material are indium, aluminum, magnesium, alloy of magnesium and indium, alloy of magnesium and aluminum, alloy of aluminum and lithium, alloy of aluminum, scandium and lithium, and alloy of magnesium and silver.

Like the anode 3, the cathode 4 may be made, for instance, on the electron transporting layer 7 by forming a thin film by a method such as vapor deposition and sputtering. In addition, the light from the emitting layer 5 may be extracted through the cathode 4. When light from the emitting layer 5 is extracted through the cathode 4, the cathode 4 preferably transmits more than 10% of the light in the visible region.

The sheet resistance of the cathode is preferably several hundreds Ω per square or lower.

Although depending on the material of the cathode, the thickness of the cathode is typically in a range from 10 nm to 1 μm, preferably in a range from 50 to 200 nm.

### Other Layers

In order to further increase a current efficiency (or luminous efficiency), the hole injecting layer, hole transporting layer, electron injecting layer and the like may be provided as needed. The organic EL device 1 is provided with the hole transporting layer 6 and the electron transporting layer 7.

### Hole Transporting Layer

The hole transporting layer 6 helps injection of holes into the emitting layer and transports the holes to an emitting region. The hole transporting layer 6 has a large hole mobility and a small ionization potential.

A material for forming the hole transporting layer 6 is preferably a material capable of transporting the holes to the emitting layer 5 at a lower electric field intensity. The second host material represented by the formula (2) according to the invention is usable. Additionally, for instance, an aromatic amine derivative represented by the following formula (A1) is favorably usable.

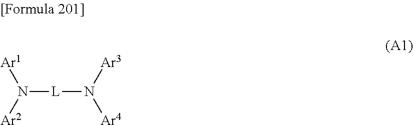

In the formula (A1), Ar¹ to Ar⁴ are each independently an aryl group having 6 to 30 ring carbon atoms, a heterocyclic group having 5 to 30 ring atoms, a group provided by bonding the aryl group and the heterocyclic group, or a group provided by bonding the aryl group and the heterocyclic group.

Incidentally, the aryl group and the heterocyclic group may be substituted.

In the formula (A1), L is a linking group and represents a divalent aryl group having 6 to 30 ring carbon atoms, a divalent heterocyclic group having 5 to 30 ring atoms, or a divalent group provided by bonding two or more aryl groups or heterocyclic groups via a single bond, an ether bond, a thioether bond, an alkylene group having 1 to 20 carbon atoms, an alkenylene group having 2 to 20 carbon atoms, or an amino group. Incidentally, the divalent aryl group and the divalent heterocyclic group may be substituted.

Non-exhaustive specific examples of the compound represented by the formula (A1) are shown below.

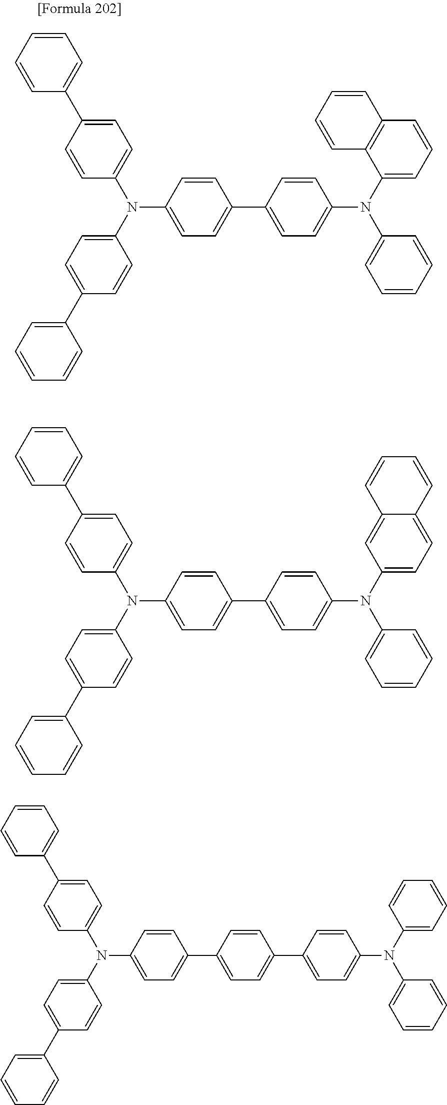

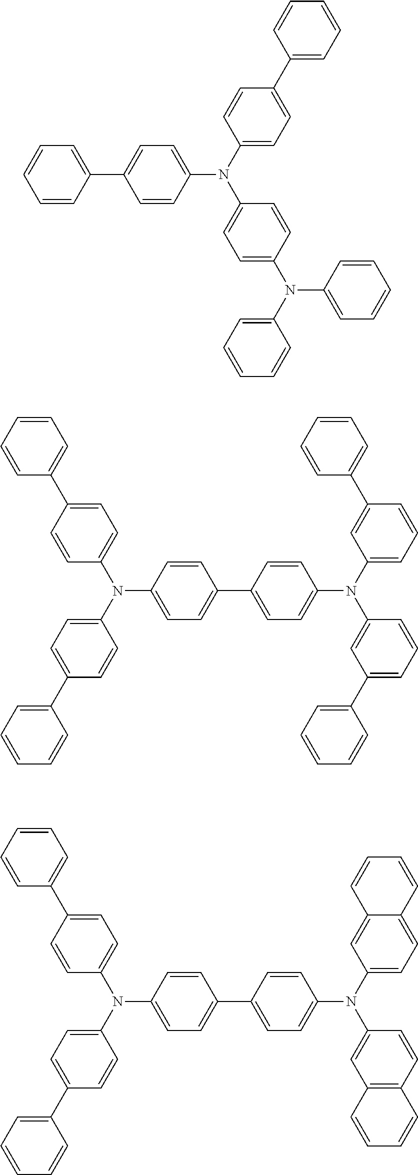 [SMILES: c1ccc(-c2ccc(N(c3ccc(-c4ccccc4)cc3)c3ccc(N(c4ccccc4)c4ccccc4)cc3)cc2)cc1 ; c1ccc(-c2ccc(N(c3ccc(-c4ccccc4)cc3)c3ccc(-c4ccc(N(c5cccc(-c6ccccc6)c5)c5cccc(-c6ccccc6)c5)cc4)cc3)cc2)cc1 ; c1ccc(-c2ccc(N(c3ccc(-c4ccccc4)cc3)c3ccc(-c4ccc(N(c5ccc6ccccc6c5)c5ccc6ccccc6c5)cc4)cc3)cc2)cc1]

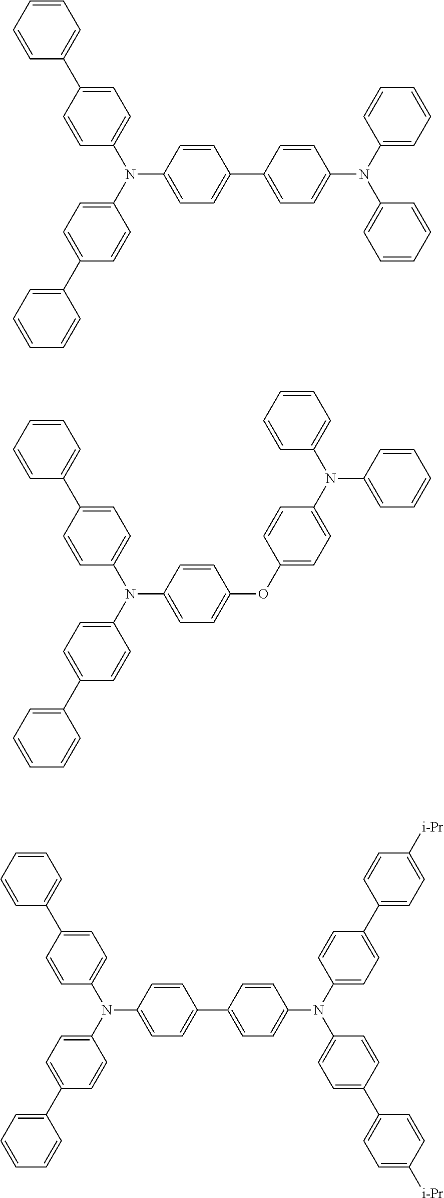 [SMILES: c1ccc(-c2ccc(N(c3ccc(-c4ccccc4)cc3)c3ccc(-c4ccc(N(c5ccccc5)c5ccccc5)cc4)cc3)cc2)cc1 ; c1ccc(-c2ccc(N(c3ccc(Oc4ccc(N(c5ccccc5)c5ccccc5)cc4)cc3)c3ccc(-c4ccccc4)cc3)cc2)cc1 ; CC(C)c1ccc(-c2ccc(N(c3ccc(-c4ccc(C(C)C)cc4)cc3)c3ccc(-c4ccc(N(c5ccc(-c6ccccc6)cc5)c5ccc(-c6ccccc6)cc5)cc4)cc3)cc2)cc1]

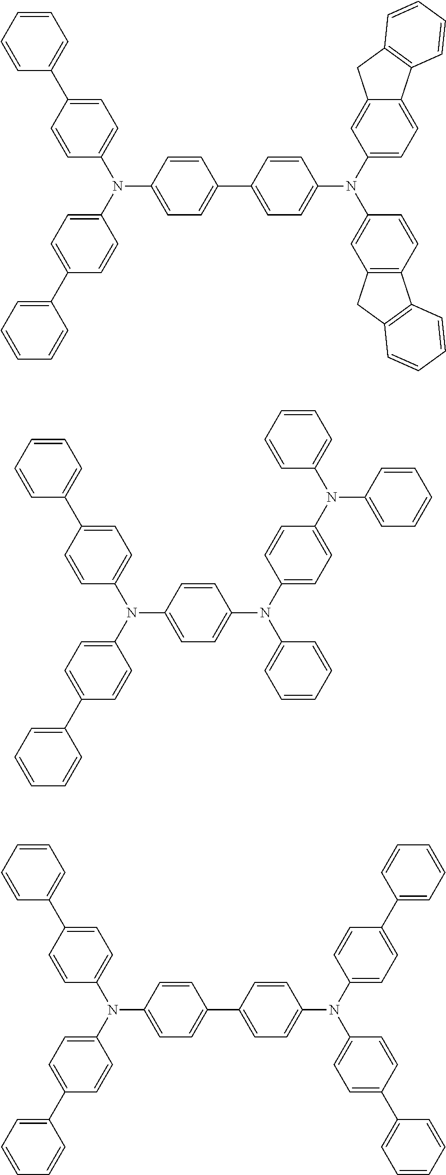 [SMILES: c1ccc(-c2ccc(N(c3ccc(-c4ccccc4)cc3)c3ccc(-c4ccc(N(c5ccc6c(c5)Cc5ccccc5-6)c5ccc6c(c5)Cc5ccccc5-6)cc4)cc3)cc2)cc1 ; c1ccc(-c2ccc(N(c3ccc(-c4ccccc4)cc3)c3ccc(N(c4ccccc4)c4ccc(N(c5ccccc5)c5ccccc5)cc4)cc3)cc2)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1]

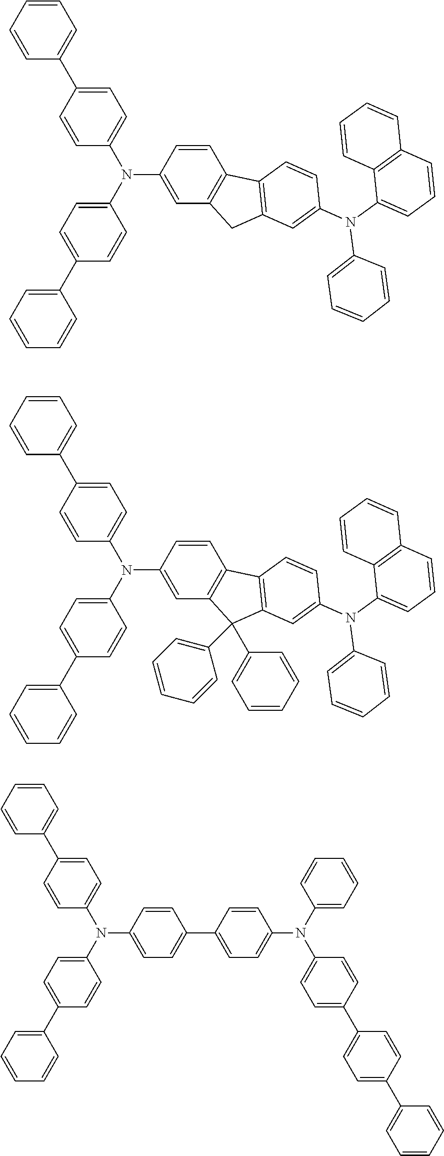

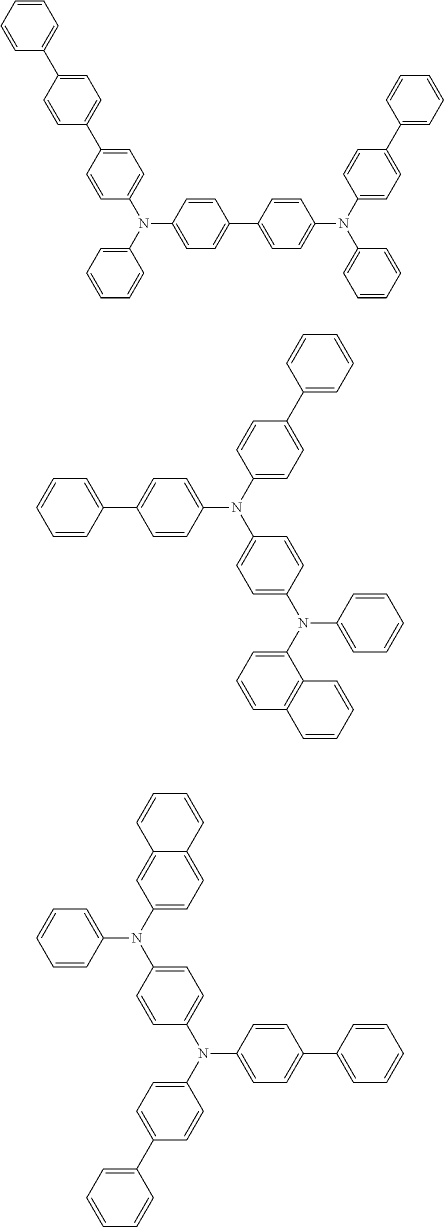

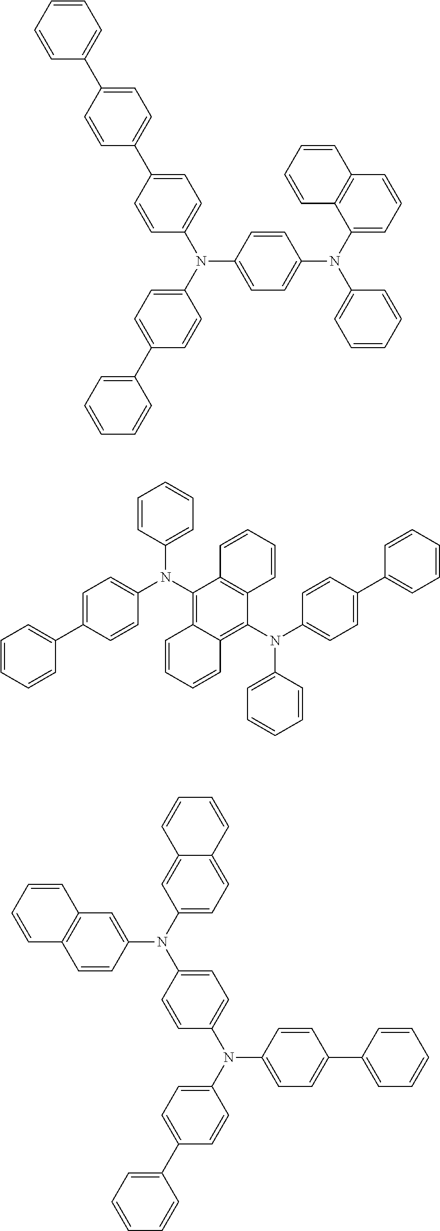 [SMILES: c1ccc(-c2ccc(-c3ccc(N(c4ccc(-c5ccccc5)cc4)c4ccc(N(c5ccccc5)c5cccc6ccccc56)cc4)cc3)cc2)cc1 ; c1ccc(-c2ccc(N(c3ccccc3)c3c4ccccc4c(N(c4ccccc4)c4ccc(-c5ccccc5)cc4)c4ccccc34)cc2)cc1 ; c1ccc(-c2ccc(N(c3ccc(-c4ccccc4)cc3)c3ccc(N(c4ccc5ccccc5c4)c4ccc5ccccc5c4)cc3)cc2)cc1]

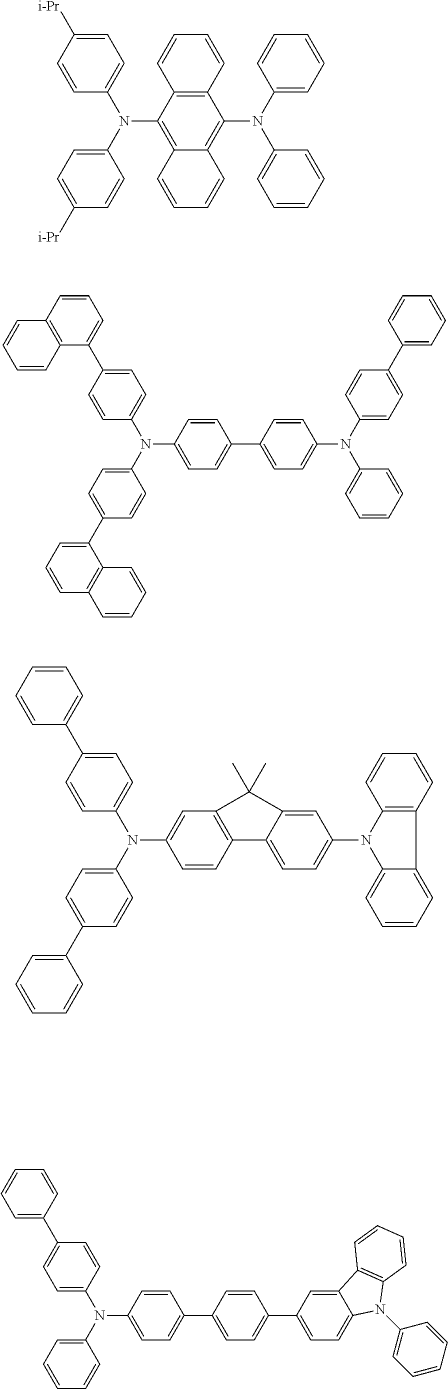 [SMILES: CC(C)c1ccc(N(c2ccc(C(C)C)cc2)c2c3ccccc3c(N(c3ccccc3)c3ccccc3)c3ccccc23)cc1 ; c1ccc(-c2ccc(N(c3ccccc3)c3ccc(-c4ccc(N(c5ccc(-c6cccc7ccccc67)cc5)c5ccc(-c6cccc7ccccc67)cc5)cc4)cc3)cc2)cc1 ; CC1(C)c2cc(N(c3ccc(-c4ccccc4)cc3)c3ccc(-c4ccccc4)cc3)ccc2-c2ccc(-n3c4ccccc4c4ccccc43)cc21 ; c1ccc(-c2ccc(N(c3ccccc3)c3ccc(-c4ccc(-c5ccc6c(c5)c5ccccc5n6-c5ccccc5)cc4)cc3)cc2)cc1]

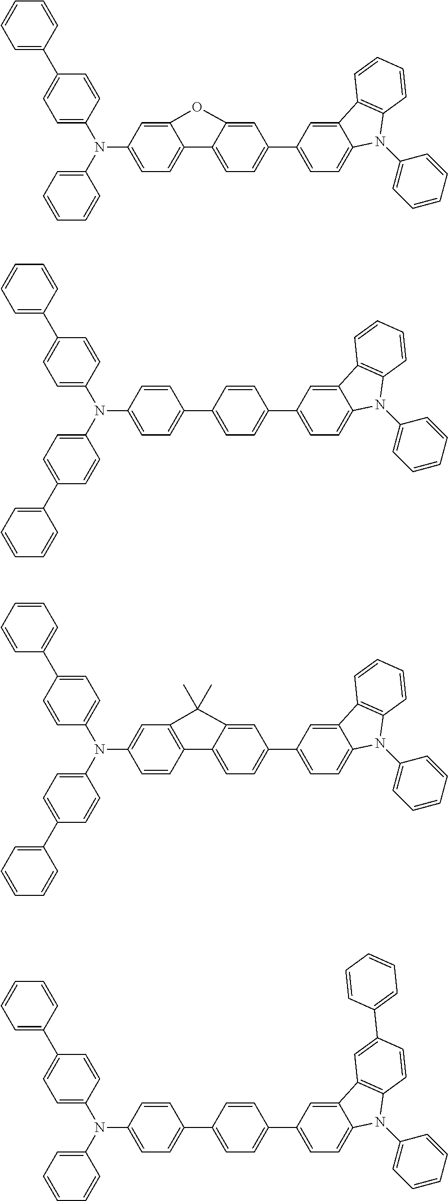 [SMILES: c1ccc(-c2ccc(N(c3ccccc3)c3ccc4c(c3)oc3cc(-c5ccc6c(c5)c5ccccc5n6-c5ccccc5)ccc34)cc2)cc1 ; c1ccc(-c2ccc(N(c3ccc(-c4ccccc4)cc3)c3ccc(-c4ccc(-c5ccc6c(c5)c5ccccc5n6-c5ccccc5)cc4)cc3)cc2)cc1 ; CC1(C)c2cc(-c3ccc4c(c3)c3ccccc3n4-c3ccccc3)ccc2-c2ccc(N(c3ccc(-c4ccccc4)cc3)c3ccc(-c4ccccc4)cc3)cc21 ; c1ccc(-c2ccc(N(c3ccccc3)c3ccc(-c4ccc(-c5ccc6c(c5)c5cc(-c7ccccc7)ccc5n6-c5ccccc5)cc4)cc3)cc2)cc1]

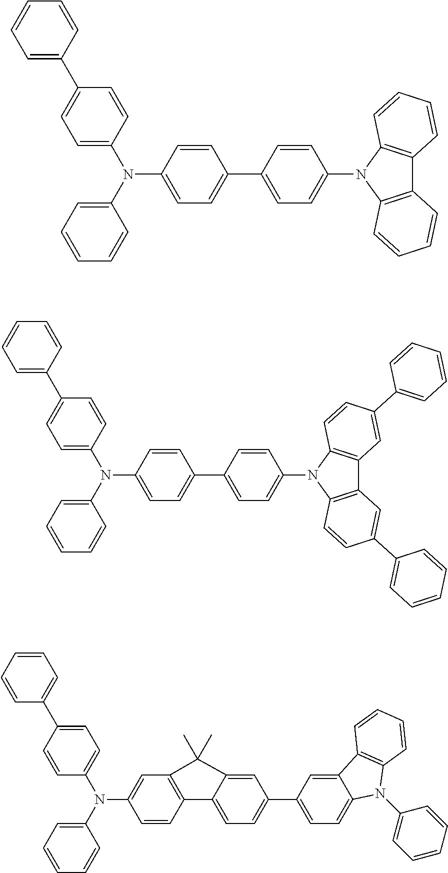 [SMILES: c1ccc(-c2ccc(N(c3ccccc3)c3ccc(-c4ccc(-n5c6ccccc6c6ccccc65)cc4)cc3)cc2)cc1 ; c1ccc(-c2ccc(N(c3ccccc3)c3ccc(-c4ccc(-n5c6ccc(-c7ccccc7)cc6c6cc(-c7ccccc7)ccc65)cc4)cc3)cc2)cc1 ; CC1(C)c2cc(-c3ccc4c(c3)c3ccccc3n4-c3ccccc3)ccc2-c2ccc(N(c3ccccc3)c3ccc(-c4ccccc4)cc3)cc21]

An aromatic amine represented by the following formula (A2) is also favorably usable to form the hole transporting layer.

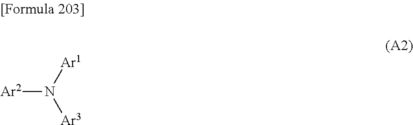

In the above formula (A2), Ar¹ to Ar³ each represent the same as Ar¹ to Ar⁴ in the formula (A1). Non-exhaustive specific examples of the compound represented by the formula (A2) are shown below.

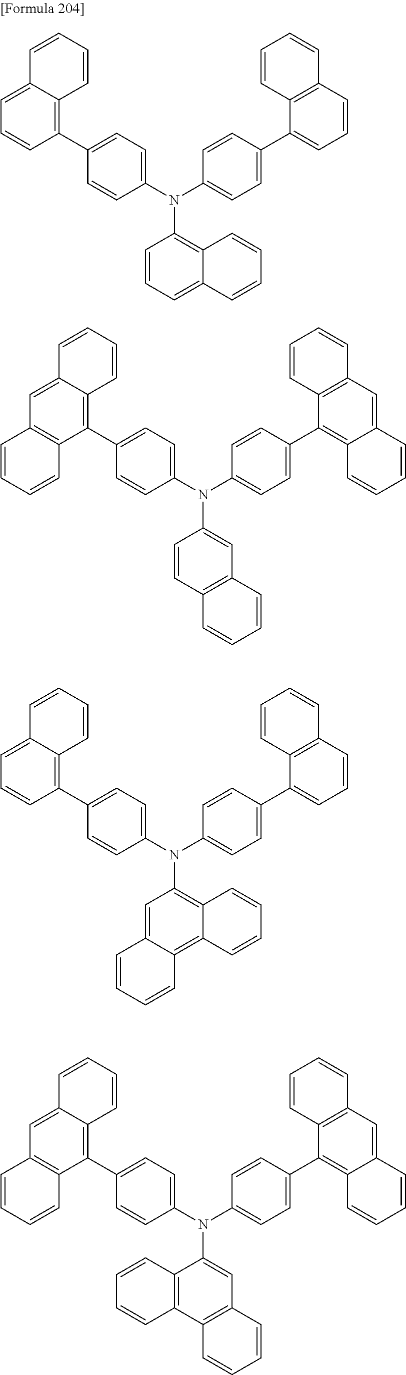 [SMILES: c1ccc2c(-c3ccc(N(c4ccc(-c5cccc6ccccc56)cc4)c4cccc5ccccc45)cc3)cccc2c1 ; c1ccc2cc(N(c3ccc(-c4c5ccccc5cc5ccccc45)cc3)c3ccc(-c4c5ccccc5cc5ccccc45)cc3)ccc2c1 ; c1ccc2c(-c3ccc(N(c4ccc(-c5cccc6ccccc56)cc4)c4cc5ccccc5c5ccccc45)cc3)cccc2c1 ; c1ccc2c(-c3ccc(N(c4ccc(-c5c6ccccc6cc6ccccc56)cc4)c4cc5ccccc5c5ccccc45)cc3)c3ccccc3cc2c1]

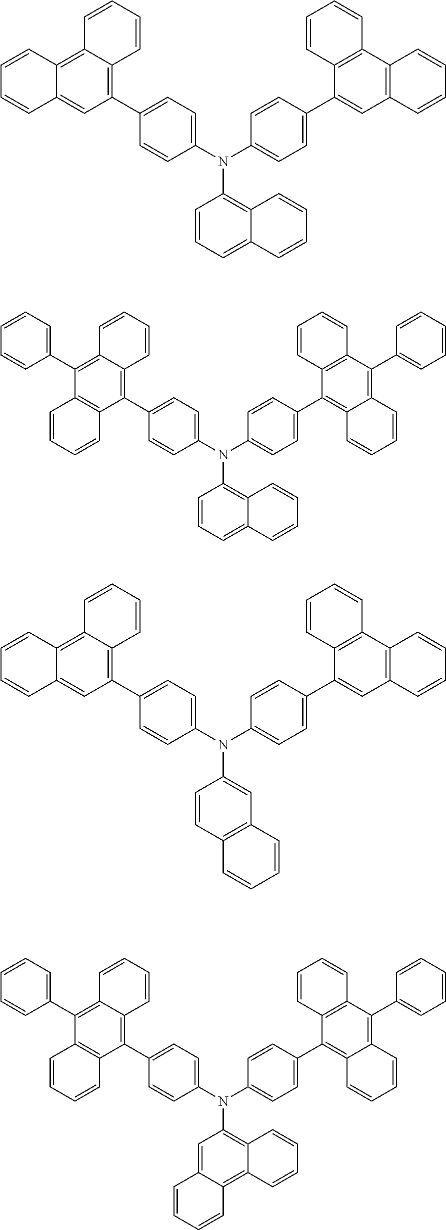 [SMILES: c1ccc2c(N(c3ccc(-c4cc5ccccc5c5ccccc45)cc3)c3ccc(-c4cc5ccccc5c5ccccc45)cc3)cccc2c1 ; c1ccc(-c2c3ccccc3c(-c3ccc(N(c4ccc(-c5c6ccccc6c(-c6ccccc6)c6ccccc56)cc4)c4cccc5ccccc45)cc3)c3ccccc23)cc1 ; c1ccc2cc(N(c3ccc(-c4cc5ccccc5c5ccccc45)cc3)c3ccc(-c4cc5ccccc5c5ccccc45)cc3)ccc2c1 ; c1ccc(-c2c3ccccc3c(-c3ccc(N(c4ccc(-c5c6ccccc6c(-c6ccccc6)c6ccccc56)cc4)c4cc5ccccc5c5ccccc45)cc3)c3ccccc23)cc1]

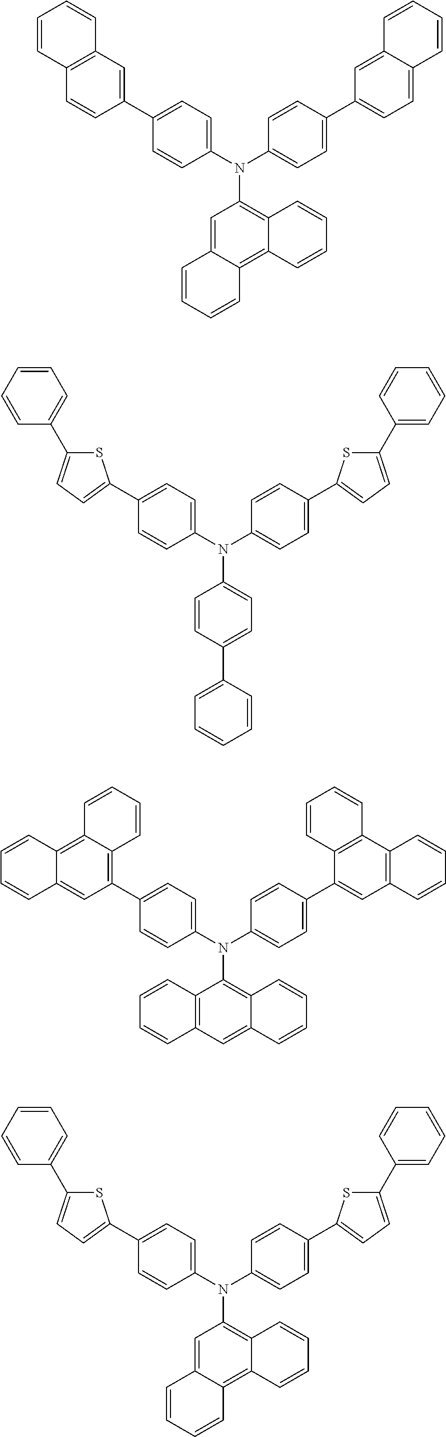 [SMILES: c1ccc2cc(-c3ccc(N(c4ccc(-c5ccc6ccccc6c5)cc4)c4cc5ccccc5c5ccccc45)cc3)ccc2c1 ; c1ccc(-c2ccc(N(c3ccc(-c4ccc(-c5ccccc5)s4)cc3)c3ccc(-c4ccc(-c5ccccc5)s4)cc3)cc2)cc1 ; c1ccc2c(N(c3ccc(-c4cc5ccccc5c5ccccc45)cc3)c3ccc(-c4cc5ccccc5c5ccccc45)cc3)c3ccccc3cc2c1 ; c1ccc(-c2ccc(-c3ccc(N(c4ccc(-c5ccc(-c6ccccc6)s5)cc4)c4cc5ccccc5c5ccccc45)cc3)s2)cc1]

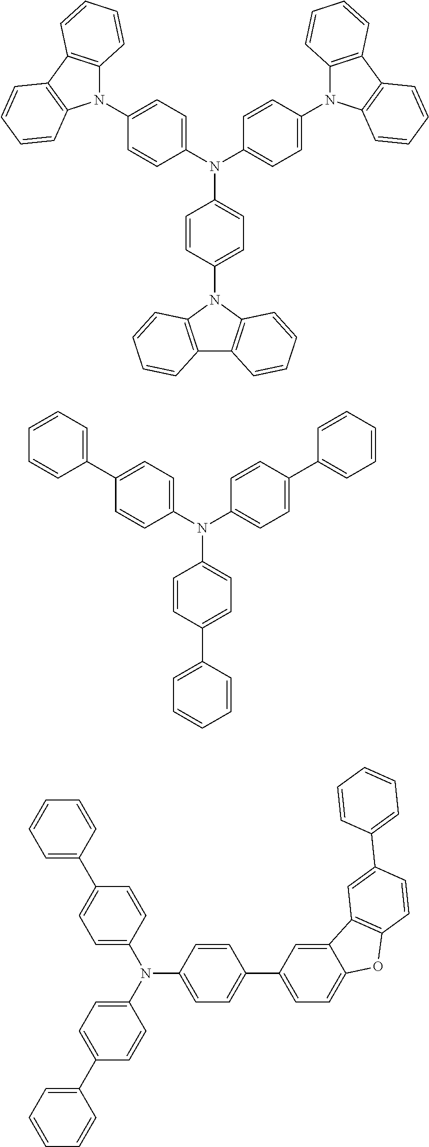 [SMILES: c1ccc2c(c1)c1ccccc1n2-c1ccc(N(c2ccc(-n3c4ccccc4c4ccccc43)cc2)c2ccc(-n3c4ccccc4c4ccccc43)cc2)cc1 ; c1ccc(-c2ccc(N(c3ccc(-c4ccccc4)cc3)c3ccc(-c4ccccc4)cc3)cc2)cc1 ; c1ccc(-c2ccc(N(c3ccc(-c4ccccc4)cc3)c3ccc(-c4ccc5oc6ccc(-c7ccccc7)cc6c5c4)cc3)cc2)cc1]

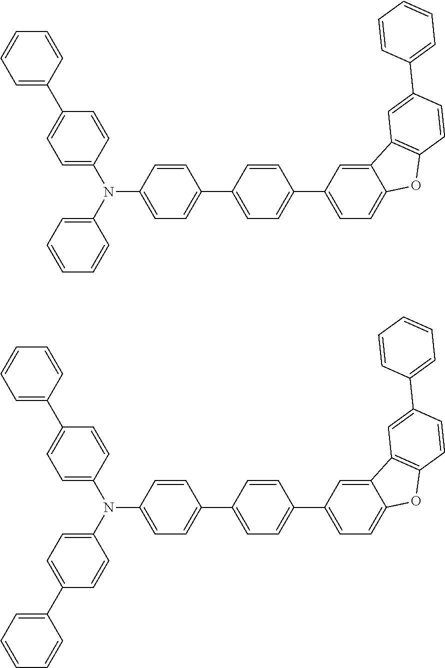 [SMILES: c1ccc(-c2ccc(N(c3ccccc3)c3ccc(-c4ccc(-c5ccc6oc7ccc(-c8ccccc8)cc7c6c5)cc4)cc3)cc2)cc1 ; c1ccc(-c2ccc(N(c3ccc(-c4ccccc4)cc3)c3ccc(-c4ccc(-c5ccc6oc7ccc(-c8ccccc8)cc7c6c5)cc4)cc3)cc2)cc1]

### Electron Transporting Layer

The electron transporting layer 7, which helps injection of electrons into the emitting layer 5, has a large electron mobility.

In the exemplary embodiment, the electron transporting layer 7 is provided between the emitting layer 5 and the cathode. The electron transporting layer 7 preferably contains a nitrogen-containing cyclic derivative as a main component. The electron injecting layer may serve as an electron transporting layer.

Incidentally, “as a main component” means that the nitrogen-containing cyclic derivative is contained in the electron transporting layer 7 at a content of 50 mass % or more.

A preferable example of an electron transporting material for forming the electron transporting layer 7 is an aromatic heterocyclic compound having in the molecule at least one heteroatom. Particularly, a nitrogen-containing cyclic derivative is preferable. The nitrogen-containing cyclic derivative is preferably an aromatic ring having a nitrogen-containing six-membered or five-membered ring skeleton, or a fused aromatic cyclic compound having a nitrogen-containing six-membered or five-membered ring skeleton.

A preferable example of the nitrogen-containing cyclic derivative is a nitrogen-containing cyclic metal chelate complex represented by the following formula (B1).

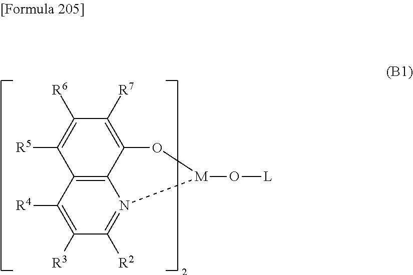

In the formula (B1), R² to R⁷ are each independently any one of

a hydrogen atom, a halogen atom, an oxy group, an amino group, a hydrocarbon group having 1 to 40 carbon atoms, an alkoxyl group, an aryloxy group, an alkoxycarbonyl group, and a heterocyclic group, which may be substituted.

Examples of the halogen atom are fluorine, chlorine, bromine and iodine. In addition, examples of the substituted or unsubstituted amino group include an alkylamino group, an arylamino group and an aralkylamino group.

The alkoxycarbonyl group in the formula (B1) is represented by —COOY′. Examples of Y′ are the same as those of the alkyl group. The alkylamino group and the aralkylamino group are represented by —NQ¹Q². Q¹ and Q² are each independently exemplified as described above in relation to the above alkyl group and the above aralkyl group (i.e., a group provided by substituting a hydrogen atom of the alkyl group with an aryl group), and preferable examples thereof are also the same as those of the above alkyl group and the above aralkyl group. Either Q¹ or Q² may be a hydrogen atom. Incidentally, the aralkyl group is a group provided by substituting a hydrogen atom of the alkyl group with an aryl group.

In the formula (B1), the arylamino group is represented by —NAr¹Ar². Ar¹ and Ar² are each independently exemplified in the same manner as described above for the aryl group. Either Ar¹ or Ar² may be a hydrogen atom.

M in the formula (B1) represents any one of aluminum (Al), gallium (Ga) and indium (In), among which In is preferable.

L in the formula (B1) represents a group represented by the following formula (B2) or (B3).

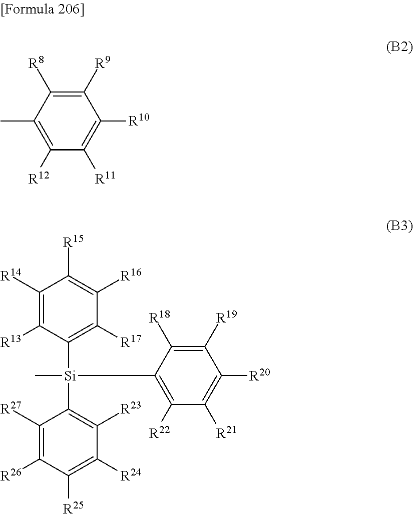

In the formula (B2), R⁸ to R¹² are each independently a hydrogen atom or a hydrocarbon group having 1 to 40 carbon atoms. Adjacent groups may form a cyclic structure. The hydrocarbon group may be substituted.

In the formula (B3), R¹³ to R²⁷ each independently represent a hydrogen atom or a hydrocarbon group having 1 to 40 carbon atoms.

Adjacent groups may form a cyclic structure. The hydrocarbon group may be substituted.

Examples of the hydrocarbon group having 1 to 40 carbon atoms represented by each of R⁸ to R¹² and R¹³ to R²⁷ in the formulae (B2) and (B3) are the same as those of R² to R⁷ in the formula (B1).

Examples of the divalent group formed when adjacent ones of groups R⁸ to R¹² and R¹³ to R²⁷ form a cyclic structure are a tetramethylene group, a pentamethylene group, a hexamethylene group, a diphenylmethane-2,2′-diyl group, a diphenylethane-3,3′-diyl group and a diphenylpropane-4,4′-diyl group.

The electron transporting layer preferably contains at least one of nitrogen-containing heterocycle derivatives represented by the following formulae (B4) to (B6).

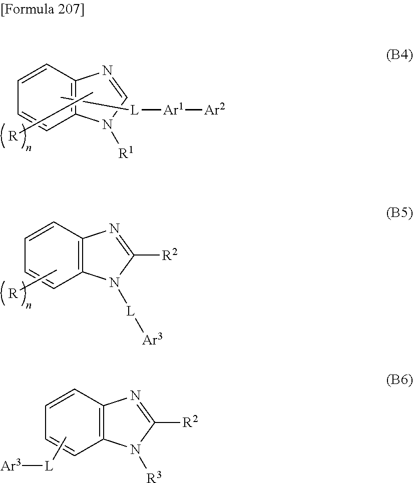

In the formulae (B4) to (B6), R is a hydrogen atom, an aryl group having 6 to 30 ring carbon atoms, a pyridyl group, a quinolyl group, an alkyl group having 1 to 20 carbon atoms, or an alkoxy group having 1 to 20 carbon atoms.

n is an integer of from 0 to 4.

In the formulae (B4) to (B6), R¹ is an aryl group having 6 to 30 ring carbon atoms, a pyridyl group, a quinolyl group, an alkyl group having 1 to 20 carbon atoms, or an alkoxy group having 1 to 20 carbon atoms.

In the formulae (B4) to (B6), R² and R³ are independently a hydrogen atom, an aryl group having 6 to 30 ring carbon atoms, a pyridyl group, a quinolyl group, an alkyl group having 1 to 20 carbon atoms, or an alkoxy group having 1 to 20 carbon atoms.

In the formulae (B4) to (B6), L is an aryl group having 6 to 30 ring carbon atoms, a pyridinylene group, a quinolinylene group, or a fluorenylene group.

In the formulae (B4) to (B6), Ar¹ is an aryl group having 6 to 30 ring carbon atoms, a pyridinylene group, or a quinolinylene group.

In the formulae (B4) to (B6), Ar² is an aryl group having 6 to 30 ring carbon atoms, a pyridyl group, a quinolyl group, an alkyl group having 1 to 20 carbon atoms, or an alkoxy group having 1 to 20 carbon atoms.

In the formulae (B4) to (B6), Ar³ is an aryl group having 6 to 60 ring carbon atoms, a pyridyl group, a quinolyl group, an alkyl group having 1 to 20 carbon atoms, an alkoxy group having 1 to 20 carbon atoms, or a group represented by —Ar¹—Ar² (in which Ar¹ and Ar² are the same as described above).

The aryl group, pyridyl group, quinolyl group, alkyl group, alkoxy group, pyridinylene group, quinolinylene group and fluorenylene group described in relation to R, R¹, R², R³, L, Ar¹, Ar² and Ar³ in the formulae (B4) to (B6) may be substituted.

As an electron transporting compound for the electron injecting layer or the electron transporting layer, 8-hydroxyquinoline or a metal complex of its derivative, an oxadiazole derivative and a nitrogen-containing heterocyclic derivative are preferable. An example of the 8-hydroxyquinoline or the metal complex of its derivative is a metal chelate oxinoid compound containing a chelate of oxine (typically 8-quinolinol or 8-hydroxyquinoline). For instance, tris(8-quinolinol)aluminum is usable. Examples of the oxadiazole derivative are shown below.

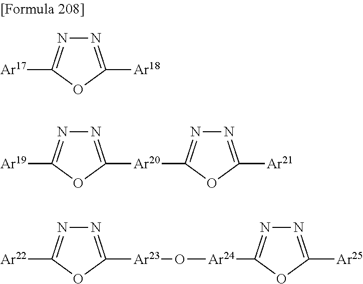

In the formulae representing the examples of the oxadiazole derivative, each of Ar¹⁷, Ar¹⁸, Ar¹⁹, Ar²¹, Ar²² and Ar²⁵ is an aryl group having 6 to 30 ring carbon atoms.

Incidentally, the aryl group may be substituted. Ar¹⁷ and Ar¹⁸, Ar¹⁹ and Ar²¹, and Ar²² and Ar²⁵ may be mutually the same or different.

Examples of the aryl group are a phenyl group, naphthyl group, biphenyl group, anthranil group, perylenyl group and pyrenyl group. Examples of a substituent for these groups are an alkyl group having 1 to 10 carbon atoms, alkoxy group having 1 to 10 carbon atoms and cyano group.

In the formulae representing the examples of the oxadiazole derivative, each of Ar²⁰, Ar²³ and Ar²⁴ is a divalent aryl group having 6 to 30 ring carbon atoms.

Incidentally, the aryl group may be substituted.

Ar²³ and Ar²⁴ may be mutually the same or different.

Examples of the divalent aryl group are a phenylene group, naphthylene group, biphenylene group, anthranylene group, perylenylene group and pyrenylene group. Examples of a substituent for these groups are an alkyl group having 1 to 10 carbon atoms, alkoxy group having 1 to 10 carbon atoms and cyano group.

The electron transporting compound preferably has an excellent thin-film formability. Examples of the electron transporting compound are shown below.

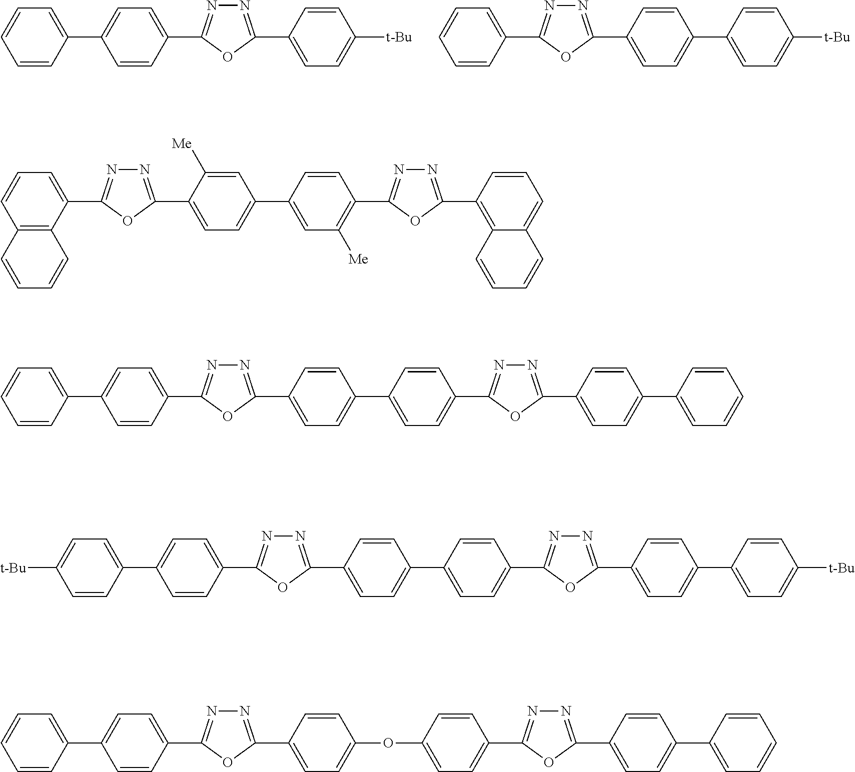 [SMILES: CC(C)(C)c1ccc(-c2nnc(-c3ccc(-c4ccccc4)cc3)o2)cc1 ; CC(C)(C)c1ccc(-c2ccc(-c3nnc(-c4ccccc4)o3)cc2)cc1 ; Cc1cc(-c2ccc(-c3nnc(-c4cccc5ccccc45)o3)c(C)c2)ccc1-c1nnc(-c2cccc3ccccc23)o1 ; c1ccc(-c2ccc(-c3nnc(-c4ccc(-c5ccc(-c6nnc(-c7ccc(-c8ccccc8)cc7)o6)cc5)cc4)o3)cc2)cc1 ; CC(C)(C)c1ccc(-c2ccc(-c3nnc(-c4ccc(-c5ccc(-c6nnc(-c7ccc(-c8ccc(C(C)(C)C)cc8)cc7)o6)cc5)cc4)o3)cc2)cc1 ; c1ccc(-c2ccc(-c3nnc(-c4ccc(Oc5ccc(-c6nnc(-c7ccc(-c8ccccc8)cc7)o6)cc5)cc4)o3)cc2)cc1]

An example of the nitrogen-containing heterocyclic derivative as the electron transporting compound is a nitrogen-containing compound that is not a metal complex, the derivative being formed of an organic compound represented by one of the following formulae. Examples of the nitrogen-containing heterocyclic derivative are five-membered ring or six-membered ring derivative having a skeleton represented by the following formula (B7) and a derivative having a structure represented by the following formula (B8).

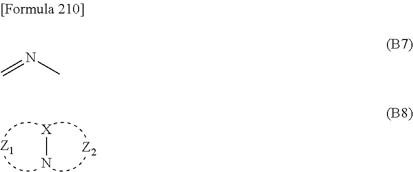

In the formula (B8), X is a carbon atom or a nitrogen atom. Z₁ and Z₂ are each independently a group of atoms capable of forming a nitrogen-containing heterocycle.

Preferably, the nitrogen-containing heterocyclic derivative is an organic compound having a nitrogen-containing aromatic polycyclic group having a five-membered ring or six-membered ring. Further, when the nitrogen-containing heterocyclic derivative is such a nitrogen-containing aromatic polycyclic group that contains plural nitrogen atoms, the nitrogen-containing heterocyclic derivative is preferably a nitrogen-containing aromatic polycyclic organic compound having a skeleton formed by a combination of the skeletons represented by the formulae (B7) and (B8) or by a combination of the skeletons represented by the formulae (B7) and (B9).

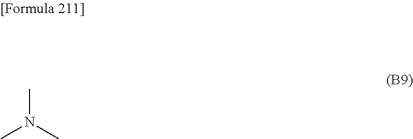

A nitrogen-containing group of the nitrogen-containing aromatic polycyclic organic compound is selected from nitrogen-containing heterocyclic groups represented by the following formulae.

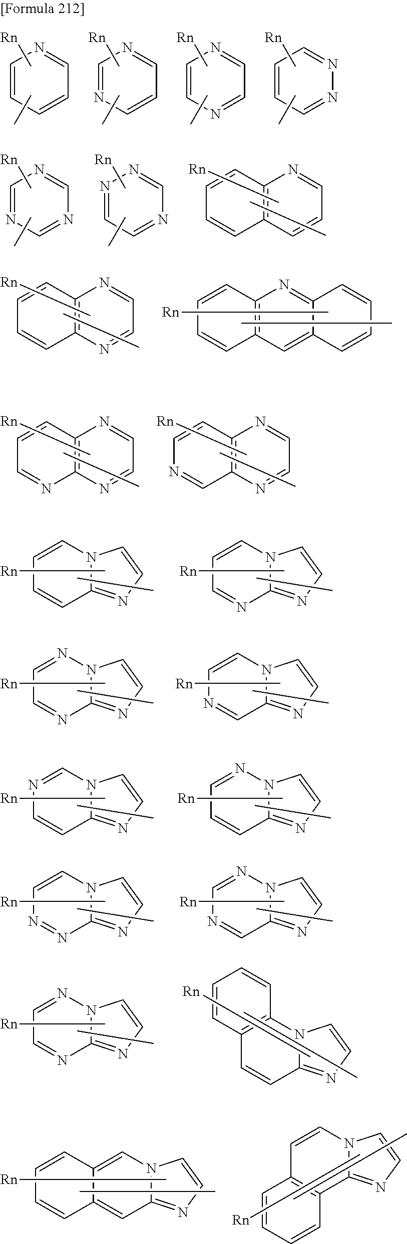

In each of the formulae representing the nitrogen-containing heterocyclic groups, R is an aryl group having 6 to 30 ring carbon atoms, a heterocyclic group having 5 to 30 ring atoms, an alkyl group having 1 to 20 carbon atoms, or an alkoxy group having 1 to 20 carbon atoms.

In each of the formulae representing the nitrogen-containing heterocyclic groups, n is an integer of from 0 to 5. When n is integer of 2 or more, plural R may be mutually the same or different.

A preferable specific compound is a nitrogen-containing heterocyclic derivative represented by the following formula (B10).

HAr-L¹-Ar¹—Ar² (B10)

In the formula (B10), HAr is a nitrogen-containing heterocyclic group having 1 to 40 ring carbon atoms.

In the formula (B10), L¹ is a single bond, an aryl group having 6 to 30 ring carbon atoms, or a heterocyclic group having 2 to 40 ring carbon atoms.

In the formula (B10), Ar¹ is a divalent aryl group having 6 to 40 ring carbon atoms.

In the formula (B10), Ar² is an aryl group having 6 to 40 ring carbon atoms, or a heterocyclic group having 2 to 40 ring carbon atoms.

The nitrogen-containing heterocyclic group, aryl group and heterocyclic group described in relation to HAr, L¹, Ar¹ and Ar² in the formula (B10) may be substituted.

HAr in the formula (B10) is selected from, for instance, the following group.

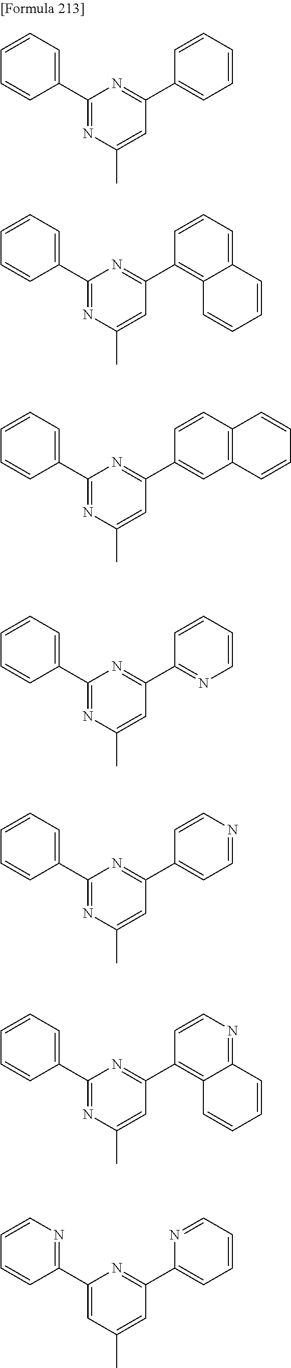

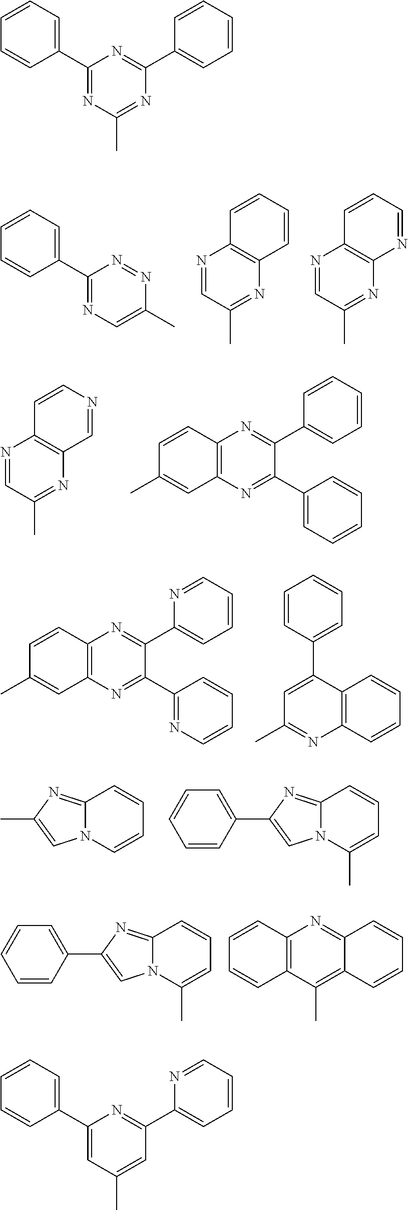

L¹ in the formula (B10) is selected from, for instance, the following group.

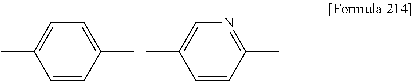

Ar¹ in the formula (B10) is selected from, for instance, arylanthranil groups shown below.

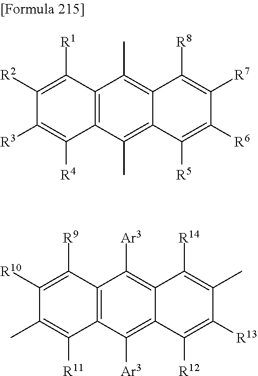

In the formulae representing the arylanthranil groups, R¹ to R¹⁴ are each independently a hydrogen atom, a halogen atom, an alkyl group having 1 to 20 carbon atoms, an alkoxy group having 1 to 20 carbon atoms, an aryloxy group having 6 to 30 ring carbon atoms, an aryl group having 6 to 30 ring carbon atoms, or a heterocyclic group having 5 to 30 ring atoms.

In the formulae of the arylanthranil groups, Ar³ is an aryl group having 6 to 30 ring carbon atoms, or a heterocyclic group having 5 to 30 ring atoms.

Incidentally, the aryl group and the heterocyclic group described in relation to R¹ to R¹⁴ and Ar³ in the formulae of the arylanthranil groups may be substituted.

All of R¹ to R⁸ of the nitrogen-containing heterocyclic derivative may be hydrogen atoms.

In the formulae of the arylanthranil groups, Ar² is selected from, for instance, the following group.

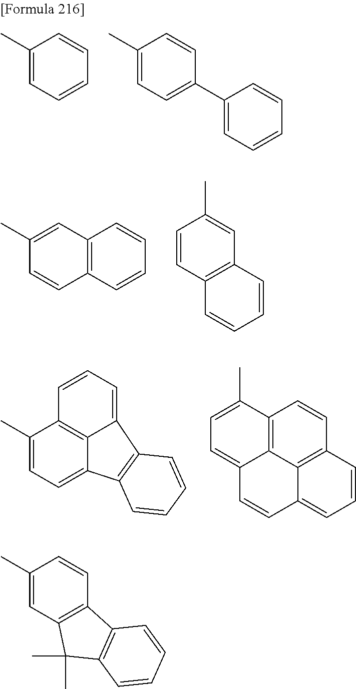

In addition to the above, the following compound (see JP-A-9-3448) is also favorably usable as the nitrogen-containing aromatic polycyclic organic compound (i.e., the electron transporting compound).

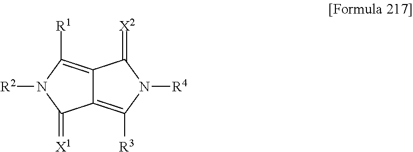

In the formula of the nitrogen-containing aromatic polycyclic organic compound, R¹ to R⁴ are each independently a hydrogen atom, an aliphatic group, an alicyclic group, a carbocyclic aromatic cyclic group, or a heterocyclic group.

Incidentally, the aliphatic group, alicyclic group, carbocyclic aromatic cyclic group and heterocyclic group may be substituted.

In the formula of the nitrogen-containing aromatic polycyclic organic compound, X¹ and X² are each independently an oxygen atom, a sulfur atom or a dicyanomethylene group.

The following compound (see JP-A-2000-173774) can also be favorably used for the electron transporting compound.

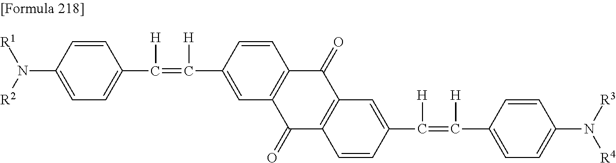

In the formula, R¹, R², R³ and R⁴, which may be mutually the same or different, each represent an aryl group or a fused aryl group represented by the following formula.

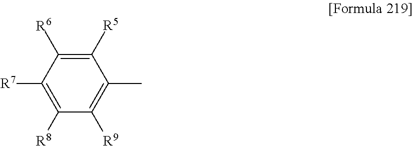

In the formula, R⁵, R⁶, R⁷, R⁸ and R⁹, which may be mutually the same or different, each represent a hydrogen atom, saturated or unsaturated alkoxy group, alkyl group, amino group or alkylamino group. At least one of R⁵, R⁶, R⁷, R⁸ and R⁹ represents a saturated or unsaturated alkoxy group, alkyl group, amino group or alkylamino group.

A polymer compound containing the nitrogen-containing heterocyclic group or a nitrogen-containing heterocyclic derivative may be used as the electron transporting compound.

The electron injecting layer preferably contains an inorganic compound such as an insulator or a semiconductor in addition to the nitrogen-containing cyclic derivative. Such an insulator or a semiconductor, when contained in the electron injecting layer, can effectively prevent a current leak, thereby enhancing electron capability of the electron injecting layer.

### Electron-donating Dopant and Organic Metal Complex

In the organic EL device according to the exemplary embodiment, at least one of an electron-donating dopant and an organic metal complex may be preferably contained in an interfacial region between the cathode and an organic thin-film layer.

With this arrangement, the organic EL device can emit light with enhanced luminance intensity and have a longer lifetime.

The electron-donating dopant is exemplified by at least one selected from among alkali metal, alkali metal compound, alkaline earth metal, alkaline earth metal compound, rare earth metal and rare earth metal compound.

The organic metal complex is exemplified by at least one selected from among an organic metal complex containing an alkali metal, an organic metal complex containing an alkaline earth metal, and an organic metal complex containing a rare earth metal.

Examples of the alkali metal are lithium (L₁) (work function: 2.93 eV), sodium (Na) (work function: 2.36 eV), potassium (K) (work function: 2.28 eV), rubidium (Rb) (work function: 2.16 eV) and cesium (Cs) (work function: 1.95 eV), among which a substance having a work function of 2.9 eV or less is particularly preferable. Among the above, the reductive dopant is preferably K, Rb or Cs, more preferably Rb or Cs, the most preferably Cs.

Examples of the alkaline earth metal are calcium (Ca) (work function: 2.9 eV), strontium (Sr) (work function: no less than 2.0 eV and no more than 2.5 eV) and barium (Ba) (work function: 2.52 eV), among which a substance having a work function of 2.9 eV or less is particularly preferable.

Examples of the rare earth metal are scandium (Sc), yttrium (Y), cerium (Ce), terbium (Tb) and ytterbium (Yb), among which a substance having a work function of 2.9 eV or less is particularly preferable.

Since the above preferred metals have particularly high reducibility, addition of a relatively small amount of the metals to an electron injecting zone can enhance luminance intensity and lifetime of the organic EL device.

Examples of the alkali metal compound are alkali oxides such as lithium oxide (Li₂O), cesium oxide (Cs₂O) and potassium oxide (K₂O) and alkali halogenides such as lithium fluoride (LiF), sodium fluoride (NaF), cesium fluoride (CsF) and potassium fluoride (KF), among which lithium fluoride (LiF), lithium oxide (Li₂O) and sodium fluoride (NaF) are preferable.

Examples of the alkaline earth metal compound are barium oxide (BaO), strontium oxide (SrO) and calcium oxide (CaO) and mixtures thereof such as strontium acid barium (BaₓSr₁₋ₓO) (0<x<1) and calcium acid barium (BaₓCa₁₋ₓO) (0<x<¹), among which BaO, SrO and CaO are preferable.

Examples of the rare earth metal compound are ytterbium fluoride (YbF₃), scandium fluoride (ScF₃), scandium oxide (ScO₃), yttrium oxide (Y₂O₃), cerium oxide (Ce₂O₃), gadolinium fluoride (GdF₃) and terbium fluoride (TbF₃), among which YbF₃, ScF₃ and TbF₃ are preferable.

The organic metal complex is not subject to a particular limitation as long as the organic metal complex contains at least one of alkali metal ion, alkaline earth metal ion and rare earth metal ion as a metal ion as described above. Preferable examples of a ligand are quinolinol, benzoquinolinol, acridinol, phenanthridinol, hydroxyphenyl oxazole, hydroxyphenyl thiazole, hydroxydiaryl oxadiazole, hydroxydiaryl thiadiazole, hydroxyphenyl pyridine, hydroxyphenyl benzoimidazole, hydroxybenzo triazole, hydroxy fluborane, bipyridyl, phenanthroline, phthalocyanine, porphyrin, cyclopentadiene, β-diketones, azomethines and derivatives thereof, which are not exhaustive.

The added electron-donating dopant and organic metal complex preferably form a layer or an island pattern in the interfacial region. The layer or the island pattern is preferably formed by depositing at least one of the electron-donating dopant and the organic metal complex by resistance heating deposition while an organic substance that forms the interfacial region (i.e., a luminescent material or an electron injecting material) is simultaneously deposited, thereby dispersing the at least one of the electron-donating dopant and the organic metal complex in the organic substance. Dispersion concentration is 100:1 to 1:100 (organic substance:electron-donating dopant/organic metal complex) in a mole ratio, preferably 5:1 to 1:5.

When at least one of the electron-donating dopant and the organic metal complex forms the layer, the luminescent material or the electron injecting material that forms the organic layer of the interfacial region is first laminated and then the at least one of the electron-donating dopant and the organic metal complex is deposited singularly thereon by resistance heating deposition to form a layer of preferably 0.1-nm thickness to 15-nm thickness.

When at least one of the electron-donating dopant and the organic metal complex forms the island pattern, the luminescent material or the electron injecting material that forms the organic layer of the interfacial region is first laminated and then the at least one of the electron-donating dopant and the organic metal complex is deposited singularly thereon by resistance heating deposition to form an island pattern of preferably 0.05-nm thickness to 1-nm thickness.

A ratio of the main component to at least one of the electron-donating dopant and the organic metal complex in the organic EL device according to the exemplary embodiment is preferably 5:1 to 1:5 (main component:electron-donating dopant/organic metal complex) in a mole ratio, more preferably 2:1 to 1:2.

### Film Thickness

In the organic EL device according to the exemplary embodiment, the thickness of each of the layers between the anode and the cathode is not subject to a particularly limitation except for the thicknesses as particularly specified above. However, the thickness is typically preferably in a range from several nanometers to 1 μm because an excessively thinned film is likely to entail defects such as a pin hole while an excessively thickened film requires application of high voltage and deteriorates efficiency.

### Manufacturing Method of Organic EL Device

A manufacturing method of the organic EL device according to the exemplary embodiment is not subject to a particular limitation. Any conventional manufacturing method of an organic EL device is usable. Specifically, each layer on the substrate is formable by vacuum deposition, a casting method, a coating method and a spin coating method. Moreover, in place of using the casting method, the coating method and the spin coating by which a solution containing a dispersed organic material for each layer is applied on a transparent polymer such as polycarbonate, polyurethane, polystyrene, polyarylate and polyester, each layer can be formed by co-deposition of the organic material and the transparent polymer.

### Second Exemplary Embodiment

Next, a second exemplary embodiment is described below.

In the description of the second exemplary embodiment, the same components as those in the first exemplary embodiment are denoted by the same reference signs and names to simplify or omit an explanation of the components. In the second exemplary embodiment, the same materials and compounds as described in the first exemplary embodiment are usable.

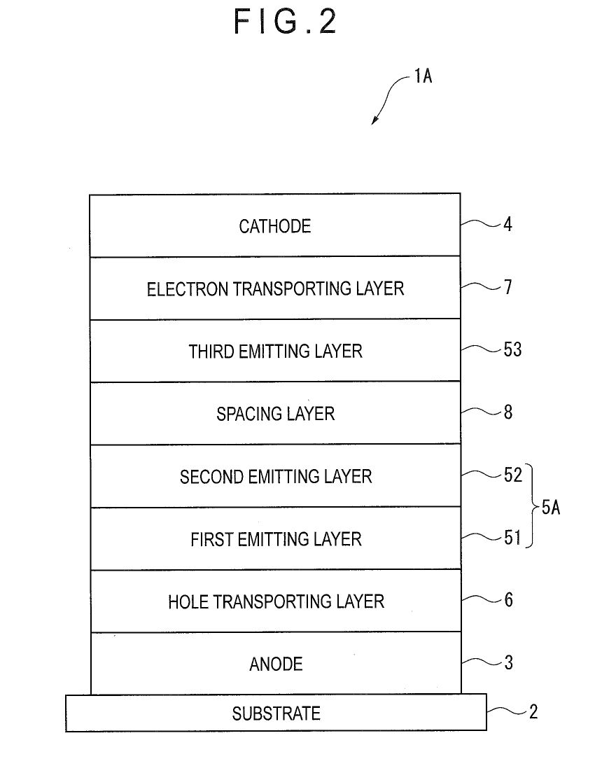

An organic EL device 1A according to the second exemplary embodiment is different from the organic EL device according to the first exemplary embodiment in including an emitting unit 5A, a third emitting layer 53, and a spacing layer 8 interposed between the emitting unit 5A and the third emitting layer 53. As shown in FIG. 2, the anode 3, the hole transporting layer 6, the emitting unit 5A, the spacing layer 8, the third emitting layer 53, the electron transporting layer 7 and cathode 4 are laminated on the substrate 2 in this sequence.

The emitting unit 5A includes: a first emitting layer 51 formed continuous to the hole transporting layer 6; and a second emitting layer 52 formed between the first emitting layer 51 and the spacing layer 8 to be continuous thereto.

The first emitting layer 51 contains a host material for the first emitting layer and a luminescent material for the first emitting layer. Preferable examples of the host material for the first emitting layer are amine derivatives such as a monoamine compound, diamine compound, triamine compound, tetramine compound and amine compound substituted by a carbazole group. Alternatively, the host material for the first emitting layer may be the same as the first host material represented by the formula (1) and the second host material represented by the formula (2). The luminescent material for the first emitting layer is preferably a material with an emission peak of 570 nm or more. An emission color with the emission peak of 570 nm or more is, for instance, red.

The second emitting layer 52 serves as an emitting layer according to the invention. In other words, the second emitting layer 52 is the same as the emitting layer 5 in the first exemplary embodiment.

The spacing layer 8 serves to provide energy barriers at HOMO level and LUMO level against the second emitting layer 52 and the third emitting layer 53, which are adjacent to the spacing layer 8, thereby adjusting injection of charges (holes or electrons) into the second emitting layer 52 and the third emitting layer 53 and thus adjusting balance of the charges injected into the second emitting layer 52 and the third emitting layer 53. Moreover, the spacing layer 8 also serves to provide a triplet energy barrier, thereby preventing the triplet energy generated in the second emitting layer 52 from dispersing into the third emitting layer 53 for efficient light emission in the second emitting layer 52.

The third emitting layer 53 is designed to, for instance, emit blue fluorescent light and has a peak wavelength of 450 nm to 500 nm. The third emitting layer 53 contains a host material for the third emitting layer and a luminescent material for the third emitting layer.

The third host material is exemplified by a compound having an anthracene central skeleton and having a structure represented by the following formula (41).

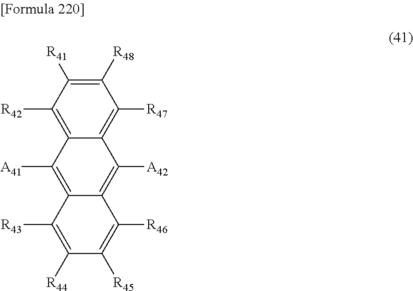

In the formula (41), A₄₁ and A₄₂ each represent a group derived from a substituted or unsubstituted aromatic ring having 6 to 30 ring carbon atoms.

R₄₁ to R₄₈ each independently represent a hydrogen atom, substituted or unsubstituted aryl group having 6 to 30 ring carbon atoms, substituted or unsubstituted heterocyclic group having 5 to 30 ring atoms, substituted or unsubstituted alkyl group having 1 to 50 carbon atoms, substituted or unsubstituted cycloalkyl group having 3 to 50 carbon atoms, substituted or unsubstituted alkoxy group having 1 to 50 carbon atoms, substituted or unsubstituted aralkyl group having 6 to 50 carbon atoms, substituted or unsubstituted aryloxy group having 5 to 50 ring atoms, substituted or unsubstituted arylthio group having 5 to 50 ring atoms, substituted or unsubstituted alkoxycarbonyl group having 1 to 50 carbon atoms, substituted or unsubstituted silyl group, carboxyl group, halogen atom, cyano group, nitro group or hydroxy group.

Examples of substituents with which the aromatic rings for A₄₁ and A₄₂ are substituted are a substituted or unsubstituted aryl group having 6 to 30 ring carbon atoms, substituted or unsubstituted alkyl group having 1 to 50 carbon atoms, substituted or unsubstituted cycloalkyl group having 3 to 50 carbon atoms, substituted or unsubstituted alkoxy group having 1 to 50 carbon atoms, substituted or unsubstituted aralkyl group having 6 to 50 carbon atoms, substituted or unsubstituted aryloxy group having 5 to 50 ring atoms, substituted or unsubstituted arylthio group having 5 to 50 ring atoms, substituted or unsubstituted alkoxycarbonyl group having 1 to 50 carbon atoms, substituted or unsubstituted silyl group, carboxyl group, halogen atom, cyano group, nitro group or hydroxy group.

Examples of the luminescent material for the third emitting layer are an arylamine compound, a styrylamine compound, anthracene, naphthalene, phenanthrene, pyrene, tetracene, coronene, chrysene, fluorescein, perylene, phthaloperylene, naphthaloperylene, perynone, phthaloperynone, naphthaloperynone, diphenylbutadiene, tetraphenylbutadiene, coumaline, oxadiazole, aldazine, bisbenzoxazoline, bisstyryl, pyrazine, cyclopentadiene, a metal complex of quinoline, a metal complex of aminoquinoline, a metal complex of benzoquinoline, imine, dipehnylethylene, vinylanthracene, diaminocarbazole, pyrane, thiopyrane, polymethine, merocyanine, an imidazole chelated oxinoid compound, quinacridone, rubrene and fluorescent pigment.

The third emitting layer 53 is designed to, for instance, emit blue fluorescent light and has a peak wavelength of 450 nm to 500 nm.

Since the organic EL device 1A includes the red-emitting first emitting layer 51, the green-emitting second emitting layer 52 and the blue-emitting third emitting layer 53, the device can emit white light as a whole.

Therefore, the organic EL device 1A is suitably usable as planar light sources such as an illuminator and a backlight.

### Third Exemplary Embodiment

Next, a third exemplary embodiment is described below.

In the description of the third exemplary embodiment, the same components as those in the first exemplary embodiment are denoted by the same reference signs and names to simplify or omit an explanation of the components. In the third exemplary embodiment, the same materials and compounds as described in the first exemplary embodiment are usable.

An organic EL device according to the third exemplary embodiment is a so-called tandem-type device including a charge generating layer and at least two emitting units. In addition to charges injected from a pair of electrodes, charges supplied from the charge generating layer are injected into the emitting units. Therefore, by providing the charge generating layer, luminous efficiency (current efficiency) relative to injected current is improved.

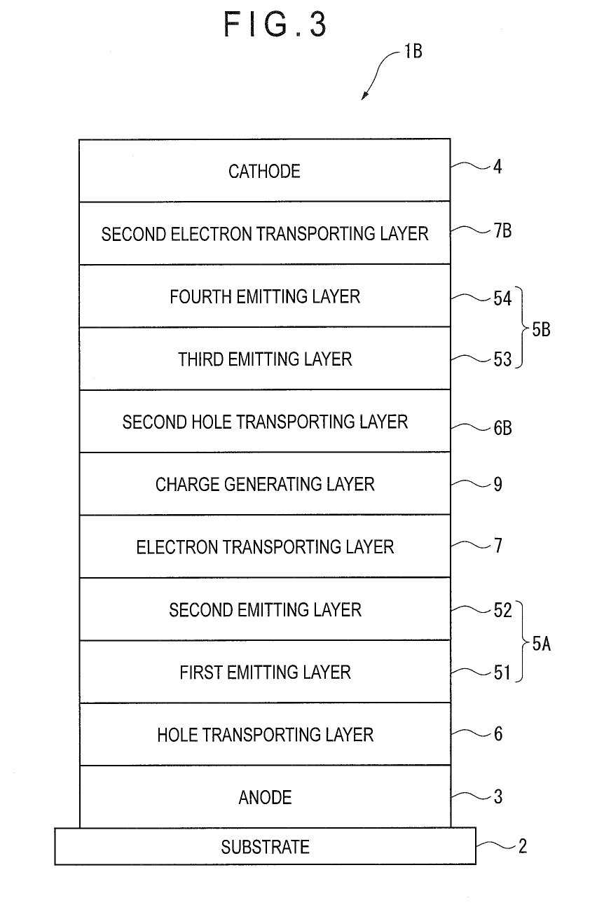

As shown in FIG. 3, an organic EL device 1B according to the third exemplary embodiment is provided by laminating the anode 3, the hole transporting layer 6, the first emitting unit 5A, the electron transporting layer 7, a charge generating layer 9, a second hole transporting layer 6B, a second emitting unit 5B, a second transporting layer 7B and the cathode 4 on the substrate 2 in this sequence.

The first emitting unit 5A is the same as the first emitting unit in the second exemplary embodiment. The second emitting layer 52 serving as the first emitting unit 5A is an emitting layer according to the invention. In other words, the second emitting layer 52 is the same as the emitting layer 5 of the first exemplary embodiment and the second emitting layer of the second exemplary embodiment.

The second emitting unit 5B includes: the third emitting layer 53 formed continuous to the second hole transporting layer 6B; and a fourth emitting layer 54 formed between the third emitting layer 53 and the second electron transporting layer 7B to be continuous thereto.

The third emitting layer 53 is the same as the third emitting layer of the second exemplary embodiment.

The fourth emitting layer 54B is designed to, for instance, emit green fluorescent light and has a peak wavelength of 500 nm to 570 nm. The fourth emitting layer 54 contains a fourth host material and a fourth luminescent material.

The charge generating layer 9 generates charges when an electric field is applied to the organic EL device 1B and injects electrons into the electron transporting layer 7 while injecting holes into the second hole transporting layer 6B.

As a material for the charge generating layer 9, a known material such as a material described in U.S. Pat. No. 7,358,661 is usable. Specific examples of the material include oxides, nitrides, iodides and borides of metals such as In, Sn, Zn, Ti, Zr, Hf, V, Mo, Cu, Ga, Sr, La and Ru. In order that the third emitting layer 53 easily receives the electrons from the charge generation layer 9, a donor, which is typically exemplified by an alkali metal, is preferably doped in the vicinity of an interface of the charge generation layer in the electron transporting layer 7. As the donor, at least one of a donor metal, donor metal compound and donor metal complex can be selected. Specific examples of compounds usable for the donor metal, donor metal compound and donor metal complex include ones disclosed in WO 2010/134352.

The second hole transporting layer 6B and the second electron transporting layer 7B are the same as the hole transporting layer and the electron transporting layer according to the first exemplary embodiment, respectively.

Since the organic EL device 1B is a so-called tandem-type device, the drive voltage can be reduced and durability can also be improved.

### Fourth Exemplary Embodiment

Next, a fourth exemplary embodiment is described below.

In the fourth exemplary embodiment, description is made on an organic-EL-device material used to manufacture the organic EL devices of the above exemplary embodiments.

The organic-EL-device material contains the compound represented by the formula (1) and the compound represented by the formula (3). Incidentally, the organic-EL-device material may further contain any other materials.

For the organic-EL-device material, the compound represented by the formula (1) is preferably the compound represented by the formula (9).

Alternatively, for the organic-EL-device material, the compound represented by the formula (1) is preferably the compound represented by the formula (10).

Preferably, the organic-EL-device material contains the first host material in an amount of from 10 mass % to 90 mass % and the second host material in an amount of from 10 mass % to 90 mass % with the provision that the sum of the mass percentages of the materials is 100 mass %. Further preferably, the first host material is contained in an amount of from 40 mass % to 60 mass % and the second host material is contained in an amount of from 40 mass % to 60 mass %.

The organic-EL-device material according to the fourth exemplary embodiment contains the compound represented by the formula (1) (i.e., the first host material) and the compound represented by the formula (3) (i.e., the second host material) and is thus suitably usable to form the emitting layer of the organic EL device according to any one of the above exemplary embodiments. Incidentally, the organic-EL-device material is also usable for any other portions of the organic EL device than the emitting layer.

When being used for the emitting layer, the organic-EL material may contain a phosphorescent dopant material in addition to the compound represented by the formula (1) and the compound represented by the formula (3).

When the organic-EL-device material according to the fourth exemplary embodiment is used to manufacture an organic EL device, a manufacturing process can be simplified because the material is blended with the compound represented by the formula (1) and the compound represented by the formula (3) in advance and thus it is not necessary to blend these compounds while adjusting a mass ration therebetween during the manufacturing process. Further, for instance, when the emitting layer is formed from the organic-EL-device material by vacuum deposition, it is not necessary to prepare a deposition boat for each of the first host material and the second host material as long as the respective deposition temperatures of the first host material and the second host material are similar to each other and thus a manufacturing machine can be simplified.

### Modifications of Embodiment(s)

It should be noted that the invention is not limited to the above description but may include any modification as long as such modification stays within a scope and a spirit of the invention.

Although the hole transporting layer is formed continuous to the anode in the first and second exemplary embodiments, a hole injecting layer may be further formed between the anode and the hole transporting layer.

A material for the hole injecting layer is preferably a porphyrin compound, an aromatic tertiary amine compound or a styryl amine compound, particularly preferably an aromatic tertiary amine compound such as hexacyanohexaazatriphenylene (HAT).

Although the electron transporting layer is formed continuous to the cathode in the first to third exemplary embodiments, an electron injecting layer may be further formed between the cathode and the electron transporting layer. Although two emitting units are formed in the third exemplary embodiment, three or more emitting units may be formed.

### EXAMPLES

Exemplary embodiments of the invention are described in detail below with reference to Examples and Comparative Examples. Incidentally, the details and the like of Examples are not intended to limit the scope of the invention.

Compounds used in Examples are shown below.

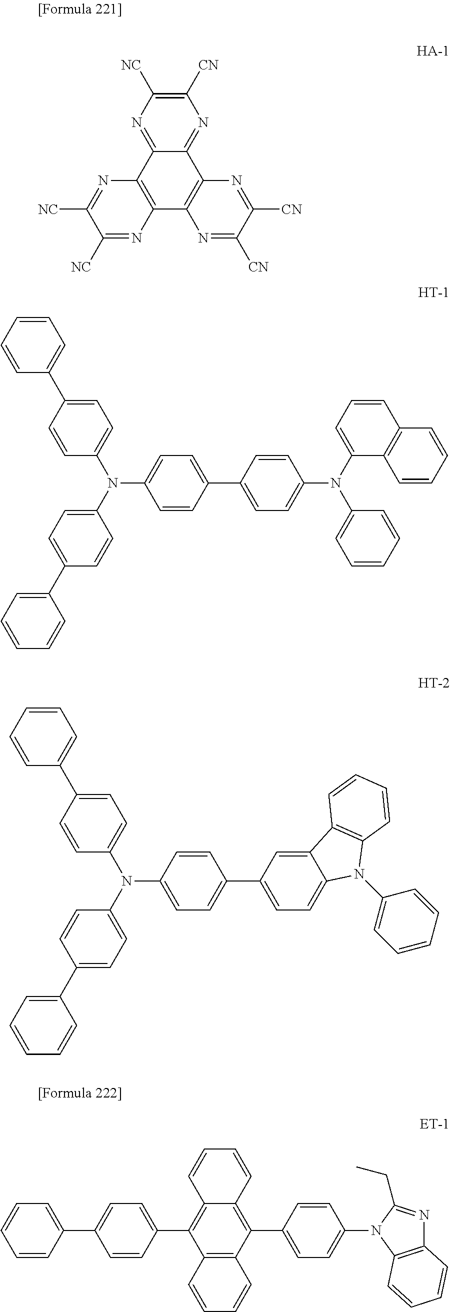 [SMILES: N#Cc1nc2c3nc(C#N)c(C#N)nc3c3nc(C#N)c(C#N)nc3c2nc1C#N ; c1ccc(-c2ccc(N(c3ccc(-c4ccccc4)cc3)c3ccc(-c4ccc(N(c5ccccc5)c5cccc6ccccc56)cc4)cc3)cc2)cc1 ; c1ccc(-c2ccc(N(c3ccc(-c4ccccc4)cc3)c3ccc(-c4ccc5c(c4)c4ccccc4n5-c4ccccc4)cc3)cc2)cc1 ; CCc1nc2ccccc2n1-c1ccc(-c2c3ccccc3c(-c3ccc(-c4ccccc4)cc3)c3ccccc23)cc1]

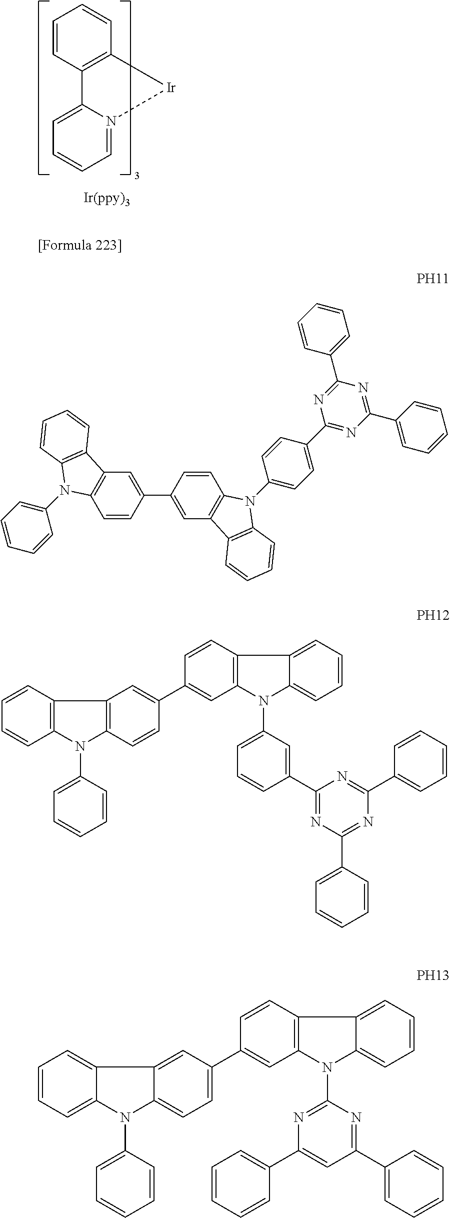

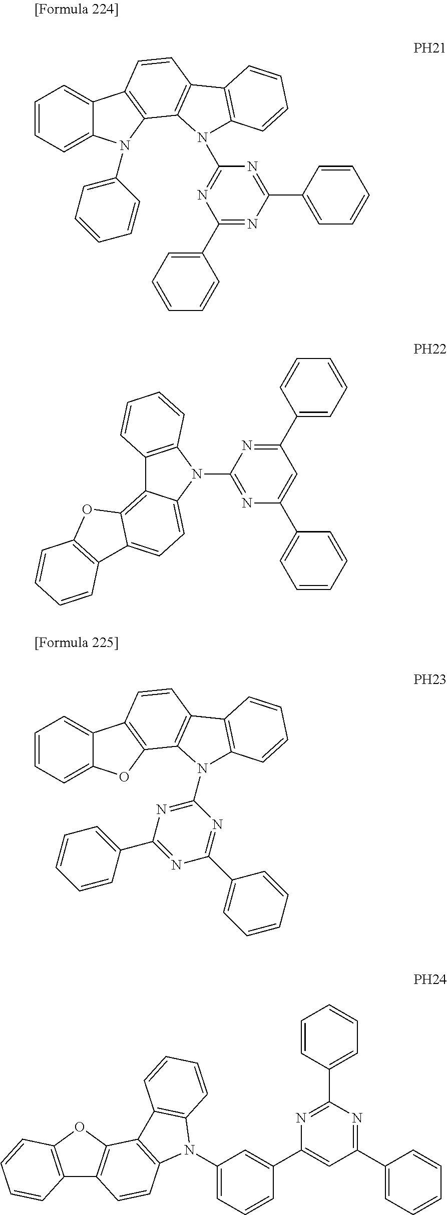 [SMILES: c1ccc(-c2nc(-c3ccccc3)nc(-n3c4ccccc4c4ccc5c6ccccc6n(-c6ccccc6)c5c43)n2)cc1 ; c1ccc(-c2cc(-c3ccccc3)nc(-n3c4ccccc4c4c5oc6ccccc6c5ccc43)n2)cc1 ; c1ccc(-c2nc(-c3ccccc3)nc(-n3c4ccccc4c4ccc5c6ccccc6oc5c43)n2)cc1 ; c1ccc(-c2cc(-c3cccc(-n4c5ccccc5c5c6oc7ccccc7c6ccc54)c3)nc(-c3ccccc3)n2)cc1]

### Manufacturing of Organic EL Devices

### Example 1

An organic EL device according to Example 1 was manufactured as follows.

A glass substrate (size: 25 mm×75 mm×1.1 mm thick, manufactured by Geomatec Co., Ltd.) having an ITO transparent electrode (anode) was ultrasonic-cleaned in isopropyl alcohol for five minutes and then UV/ozone-cleaned for 30 minutes. The thickness of ITO was 70 nm

After the glass substrate having the transparent electrode line was cleaned, the glass substrate was mounted on a substrate holder of a vacuum deposition apparatus and a compound HA-1 was deposited to form a 5-nm-thick HA-1 film on a surface of the glass substrate where the transparent electrode line was provided so as to cover the transparent electrode. The HA-1 film serves as the hole injecting layer.

On the hole injecting layer, a compound HT-1 was deposited to form a 65-nm-thick HT-1 film. The HT-1 film serves as the first hole transporting layer.

On the first hole transporting layer, a compound HT-2 was deposited to form a 10-nm-thick HT-2 film. The HT-2 film serves as the second hole transporting layer.

On the second hole transporting layer, a compound PH11 (the first host material), a compound PH21 (the second host material) and Ir(ppy)₃ (the phosphorescent dopant material) were co-deposited. Thus, a 25-nm-thick emitting layer for green emission was formed. In the emitting layer, the concentrations of the first host material, the second host material and the phosphorescent dopant material were set at 40 mass %, 50 mass % and 10 mass %, respectively.

On the emitting layer, a compound ET-1 was deposited to form a 35-nm-thick ET-1 film. The ET-1 film serves as the electron transporting layer.

On the electron transporting layer, LiF was deposited at a rate of 1 Å/min to form a 1-nm-thick electron injecting cathode.

On the electron injecting cathode, a metal Al was deposited to form an 80-nm-thick cathode.

Thus, the organic EL device of Example 1 was manufactured.

### Examples 2 to 5

Organic EL devices according to Examples 2 to 5 were manufactured in the same manner as the organic EL device according to Example 1 except that the first host material and the second host material for the emitting layer were replaced with materials shown in Table 2.

### Comparative Example 1

An organic EL device according to Comparative Example was manufactured in the same manner as the organic EL device according to Example 1 except that the second host material was not used but only the first host material was used as shown in Table 1.

TABLE 1

| | First Host Material | Second Host Material |
|---|---|---|
| Ex. 1 | PH11 | PH21 |
| Ex. 2 | PH12 | PH22 |
| Ex. 3 | PH12 | PH23 |
| Ex. 4 | PH12 | PH24 |
| Ex. 5 | PH13 | PH22 |
| Comp. 1 | PH11 | — |

### Evaluation of Organic EL Devices

The manufactured organic EL devices were evaluated in terms of drive voltage and external quantum efficiency (EQE). Evaluation was conducted in terms of each evaluation item with a current density being 10.00 mA/cm². The evaluation results are shown in Table 3.

### Drive Voltage

Electric current was applied between ITO and Al with a current density becoming 10.00 mA/cm² and a value (V) of the voltage at that time was measured.

### External Quantum Efficiency (EQE)

Voltage was applied to each of the organic EL devices with a current density becoming 10.00 mA/cm² and an EL emission spectrum at that time was measured by a spectroradiometer (CS-1000 manufactured by Konica Minolta Holdings, Inc.). The external quantum efficiency EQE (unit: %) was calculated based on the obtained spectral-radiance spectrum, assuming that the spectrum was provided under Lambertian radiation.

TABLE 2

| | Drive Voltage | EQE |
|---|---|---|
| | (V) | (%) |
| Ex. 1 | 4.55 | 21.9 |
| Ex. 2 | 3.28 | 20.7 |
| Ex. 3 | 3.05 | 19.1 |
| Ex. 4 | 3.27 | 20.3 |
| Ex. 5 | 3.37 | 19.6 |
| Comp. 1 | 3.02 | 16.3 |

As shown in Table 2, as compared with the organic EL device of Comparative Example, each of the organic EL devices of Examples 1 to 5 using the first host material and the second host material according to the invention exhibited a greater external quantum efficiency though the drive voltage of which was slightly increased. In view of the above, it has been proven that an organic EL device according to the invention exhibits a sufficient luminous efficiency.

### INDUSTRIAL APPLICABILITY

An organic EL device according to the invention is usable for a display and an illuminator.

### EXPLANATION OF CODES

1, 1A, 1B organic EL device (organic electroluminescence device)
2 substrate
3 anode
4 cathode
5 emitting layer
6 hole transporting layer
7 electron transporting layer

1. An organic electroluminescence device comprising:
an anode;
a cathode; and
an emitting layer being provided between the anode and the cathode, the emitting layer comprising a first host material, a second host material and a phosphorescent dopant material, the first host material comprising a compound represented by a formula (1) below, the second host material comprising a compound represented by a formula (3) below, 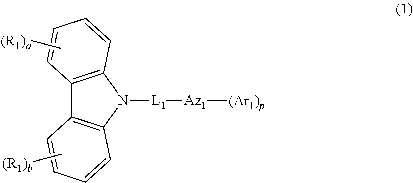
where:
R₁ are each independently a hydrogen atom, a halogen atom, a cyano group, a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted alkenyl group having 2 to 30 carbon atoms, a substituted or unsubstituted alkynyl group having 2 to 30 carbon atoms, a substituted or unsubstituted alkylsilyl group having 3 to 30 carbon atoms, a substituted or unsubstituted arylsilyl group having 6 to 30 ring carbon atoms, a substituted or unsubstituted alkoxy group having 1 to 30 carbon atoms, a substituted or unsubstituted aralkyl group having 6 to 30 ring carbon atoms, or a substituted or unsubstituted aryloxy group having 6 to 30 ring carbon atoms;
each of a and b is 4 and plural R₁ are mutually the same or different;
p is an integer of from 0 to 4;
L₁ is a single bond or a linking group, the linking group being a substituted or unsubstituted aryl group having 6 to 30 ring carbon atoms, a substituted or unsubstituted heterocyclic group having 5 to 30 ring atoms, a cyclic hydrocarbon group having 5 to 30 ring carbon atoms, or a group provided by bonding the aryl group, the heterocyclic group and/or the cyclic hydrocarbon group; and
Az₁ is a group represented by a formula (2) below, 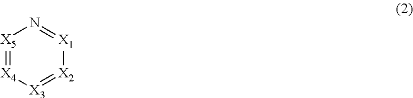
where:
any one of X₁ to X₅ is a carbon atom bonded to L₁;
the other four of X₁ to X₅ that are not bonded to L₁ are each independently CR₁ or a nitrogen atom when p is 0;
when p is 1 to 4, p of X₁ to X₅ are each a carbon atom bonded to Ar₁ in the formula (1) and (4-p) of X₁ to X₅ are each independently CR₁ or a nitrogen atom; and R₁ represents the same as R₁ in the formula (1), Ar₁ being a substituted or unsubstituted aryl group having 6 to 30 ring carbon atoms, a substituted or unsubstituted heterocyclic group having 5 to 30 ring carbon atoms, or a group provided by bonding the aryl group and the heterocyclic group, 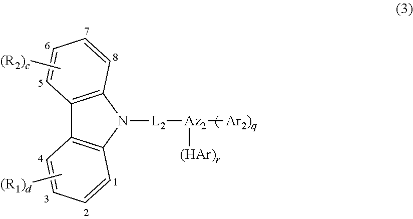
where:
R₂ are each independently a hydrogen atom, a halogen atom, a cyano group, a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted alkenyl group having 2 to 30 carbon atoms, a substituted or unsubstituted alkynyl group having 2 to 30 carbon atoms, a substituted or unsubstituted alkylsilyl group having 3 to 30 carbon atoms, a substituted or unsubstituted arylsilyl group having 6 to 30 ring carbon atoms, a substituted or unsubstituted alkoxy group having 1 to 30 carbon atoms, a substituted or unsubstituted aralkyl group having 6 to 30 ring carbon atoms, or a substituted or unsubstituted aryloxy group having 6 to 30 ring carbon atoms;
c and d each independently an integer of 0 to 4 and plural R₂ are mutually the same or different;
q is an integer of from 1 to 4;
r is 0 or 1;
1≦q+r≦4;
L₂ is a single bond or a linking group, the linking group being a substituted or unsubstituted aryl group having 6 to 30 ring carbon atoms, a substituted or unsubstituted heterocyclic group having 5 to 30 ring atoms, a cyclic hydrocarbon group having 5 to 30 ring carbon atoms, or a group provided by bonding the aromatic hydrocarbon group, the aromatic heterocyclic group and/or the cyclic hydrocarbon group;
Ar₂ is a substituted or unsubstituted aryl group having 6 to 30 ring carbon atoms, a substituted or unsubstituted heterocyclic group having 5 to 30 ring carbon atoms, or a group provided by bonding the aryl group and the heterocyclic group;
Az₂ is a group represented by a formula (4) below, 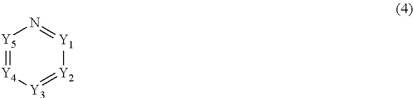
where:
any one of Y₁ to Y₅ is bonded to L₂;
q of the other four of Y₁ to Y₅ that are not bonded to L₂ are each a carbon atom bonded to Ar₂, r of the other four of Y₁ to Y₅ are each a carbon atom bonded to HAr, and (4-q-r) of the other four of Y₁ to Y₅ are each independently CR₃ or a nitrogen atom; and
R₃ represents the same as R₂ in the formula (3); and
HAr in the formula (3) is represented by any one of formulae (5) to (7) below, 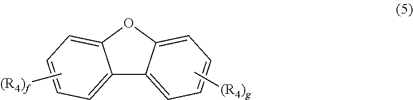 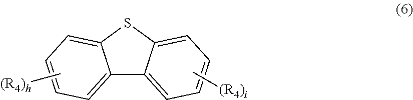 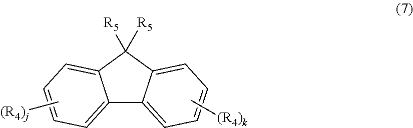
where:
each of f and g in the formula (5) is 4;
each of h and i in the formula (6) is 4;
each of j and k in the formula (7) is 4;
plural R₄ in each of the formulae (5), (6) and (7) are mutually the same or different and at least one of the plural R₄ is a single bond to Az₂;
R₄ in each of the formulae (5), (6) and (7) represents the same as R₂ in the formula (3); and
two R₅ in the formula (7) are mutually the same or different and each represent the same as R₂ in the formula (3), R₂ being bonded to a carbazole ring in the formula (3), the carbazole ring being bonded to a moiety represented by a formula (8) below, 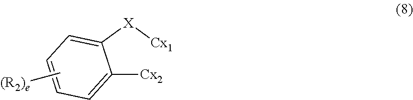
where:
Cx₁ and Cx₂ are any adjacent two of carbon atoms in 1- to 8-positions of the carbazole ring to which R₂ is bonded in the formula (3);
X is an oxygen atom, a sulfur atom, NR₂ or C(R₂)₂;
e is 4; and
R₂ represents the same as R₂ in the formula (3).

2. The organic electroluminescence device according to claim 1, wherein the compound represented by the formula (1) as the first host material comprises a compound represented by a formula (9) below, 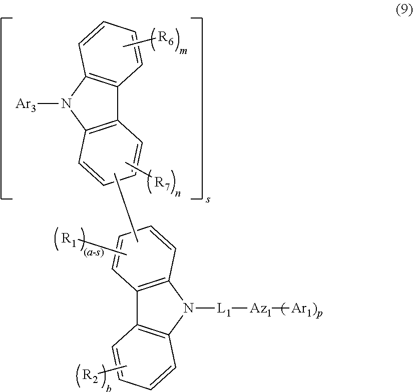
where:
s is an integer of from 1 to 4;
R₆ and R₇ each represent the same as R₁ in the formula (1);
m is 4 and plural R₆ are mutually the same or different;
n is 3 and plural R₇ are mutually the same or different; and
Ar₃ represents the same as Ar₁ in the formula (1).

3. The organic electroluminescence device according to claim 1, wherein the compound represented by the formula (1) as the first host material comprises a compound represented by a formula (10) below, 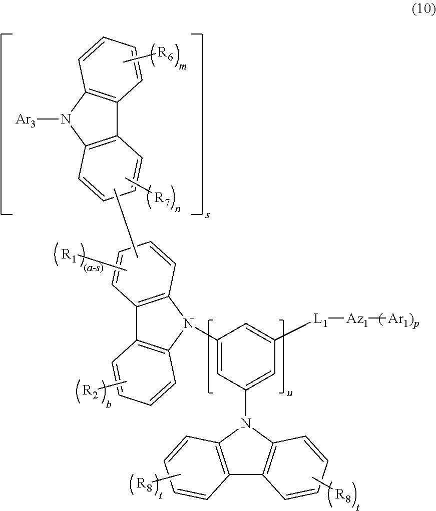
where:
R₆ and R₇ each represent the same as R₁ in the formula (1);
m is 4 and plural R₆ are mutually the same or different;
n is 3 and plural R₇ are mutually the same or different;
Ar₃ represents the same as Ar₁ in the formula (1);
s is 0 or 1, u is 0 or 1 and s and u satisfy a relation of s+u=1;
R₈ represents the same as R₁ in the formula (1); and
t is 4 and plural R₈ are mutually the same or different.

4. An organic-electroluminescence-device material comprising a compound represented by a formula (1) below and a compound represented by a formula (3) below, 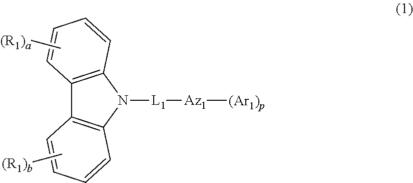
where:
R₁ are each independently a hydrogen atom, a halogen atom, a cyano group, a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted alkenyl group having 2 to 30 carbon atoms, a substituted or unsubstituted alkynyl group having 2 to 30 carbon atoms, a substituted or unsubstituted alkylsilyl group having 3 to 30 carbon atoms, a substituted or unsubstituted arylsilyl group having 6 to 30 ring carbon atoms, a substituted or unsubstituted alkoxy group having 1 to 30 carbon atoms, a substituted or unsubstituted aralkyl group having 6 to 30 ring carbon atoms, or a substituted or unsubstituted aryloxy group having 6 to 30 ring carbon atoms;
a and b each represent 4 and plural R₁ are mutually the same or different;
p is an integer of from 0 to 4;
L₁ is a single bond or a linking group, the linking group being a substituted or unsubstituted aryl group having 6 to 30 ring carbon atoms, a substituted or unsubstituted heterocyclic group having 5 to 30 ring atoms, a cyclic hydrocarbon group having 5 to 30 ring carbon atoms, or a group provided by bonding the aryl group, the heterocyclic group and/or the cyclic hydrocarbon group; and
Az₁ is a group represented by a formula (2) below, 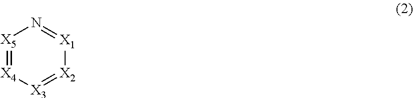
where:
any one of X₁ to X₅ is a carbon atom bonded to L₁;
the other four of X₁ to X₅ that are not bonded to L₁ are each independently CR₁ or a nitrogen atom when p is 0;
when p is 1 to 4, p of X₁ to X₅ are each a carbon atom bonded to Ar₁ in the formula (1) and (4-p) of X₁ to X₅ are each independently CR₁ or a nitrogen atom; and R₁ represents the same as R₁ in the formula (1), Ar₁ being a substituted or unsubstituted aryl group having 6 to 30 ring carbon atoms, a substituted or unsubstituted heterocyclic group having 5 to 30 ring carbon atoms, or a group provided by bonding the aryl group and the heterocyclic group, 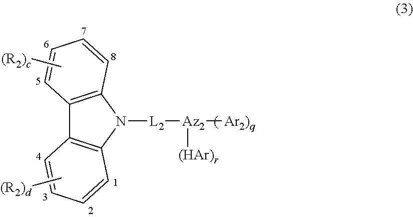
where:
R₂ are each independently a hydrogen atom, a halogen atom, a cyano group, a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted alkenyl group having 2 to 30 carbon atoms, a substituted or unsubstituted alkynyl group having 2 to 30 carbon atoms, a substituted or unsubstituted alkylsilyl group having 3 to 30 carbon atoms, a substituted or unsubstituted arylsilyl group having 6 to 30 ring carbon atoms, a substituted or unsubstituted alkoxy group having 1 to 30 carbon atoms, a substituted or unsubstituted aralkyl group having 6 to 30 ring carbon atoms, or a substituted or unsubstituted aryloxy group having 6 to 30 ring carbon atoms;
c and d each independently an integer of 0 to 4 and plural R₂ are mutually the same or different;
q is an integer of from 1 to 4;
r is 0 or 1;
1≦q+r≦4;
L₂ is a single bond or a linking group, the linking group being a substituted or unsubstituted aryl group having 6 to 30 ring carbon atoms, a substituted or unsubstituted heterocyclic group having 5 to 30 ring atoms, a cyclic hydrocarbon group having 5 to 30 ring carbon atoms, or a group provided by bonding the aryl group and the heterocyclic group;
Ar₂ is a substituted or unsubstituted aryl group having 6 to 30 ring carbon atoms, a substituted or unsubstituted heterocyclic group having 5 to 30 ring carbon atoms, or a group provided by bonding the aryl group and the heterocyclic group; and
Az₂ is a group represented by a formula (4) below, 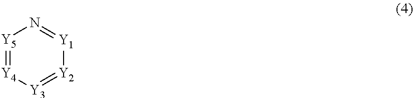
where:
any one of Y₁ to Y₅ is bonded to L₂;
q of the other four of Y₁ to Y₅ that are not bonded to L₂ are each a carbon atom bonded to Ar₂, r of the other four of Y₁ to Y₅ are each a carbon atom bonded to HAr, and (4-q-r) of the other four of Y₁ to Y₅ are each independently CR₃ or a nitrogen atom; and
R₃ represents the same as R₂ in the formula (3); and
HAr in the formula (3) is represented by any one of formulae (5) to (7) below, 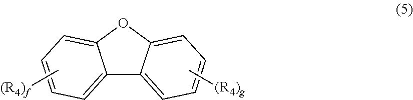 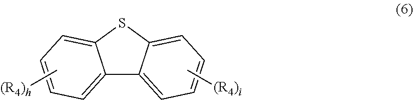 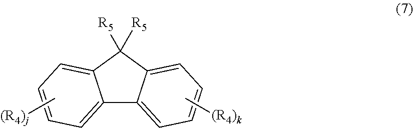
where:
each of f and g in the formula (5) is 4;
each of h and i in the formula (6) is 4;
each of j and k in the formula (7) is 4;
plural R₄ in each of the formulae (5), (6) and (7) are mutually the same or different and at least one of the plural R₄ is a single bond to Az₂;
R₄ in each of the formulae (5), (6) and (7) represents the same as R₂ in the formula (3); and
two R₅ in the formula (7) are mutually the same or different and each represent the same as R₂ in the formula (3), R₂ being bonded to a carbazole ring in the formula (3), the carbazole ring being bonded to a moiety represented by a formula (8) below, 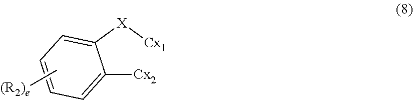
where:
Cx₁ and Cx₂ are any adjacent two of carbon atoms in 1- to 8-positions of the carbazole ring to which R₂ is bonded in the formula (3);
X is an oxygen atom, a sulfur atom, NR₂ or C(R₂)₂;
e is 4; and
R₂ represents the same as R₂ in the formula (3).

5. The organic-electroluminescence-device material according to claim 4, wherein the compound represented by the formula (1) comprises a compound represented by a formula (9) below, 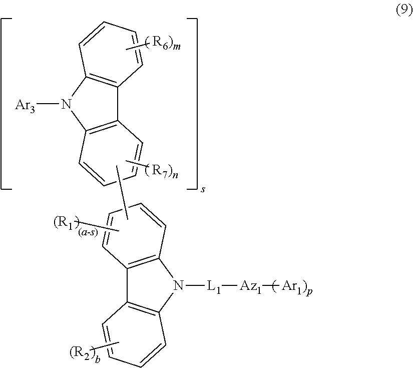
where:
s is an integer of from 1 to 4;
R₆ and R₇ each represent the same as R₁ in the formula (1);
m is 4 and plural R₆ are mutually the same or different;
n is 3 and plural R₇ are mutually the same or different; and
Ar₃ represents the same as Ar₁ in the formula (1).

6. The organic-electroluminescence-device material according to claim 4, wherein the compound represented by the formula (1) comprises a compound represented by a formula (10) below, 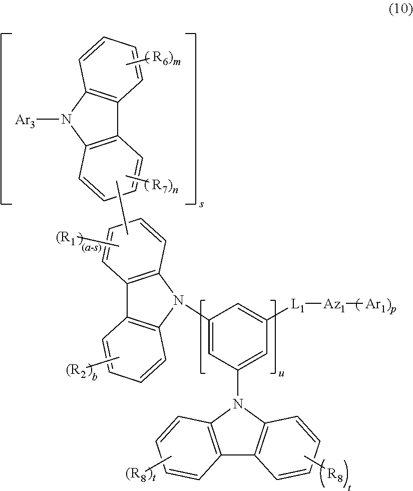
where:
R₆ and R₇ each represent the same as R₁ in the formula (1);
m is 4 and plural R₆ are mutually the same or different;
n is 3 and plural R₇ are mutually the same or different;
Ar₃ represents the same as Ar₁ in the formula (1);
s is 0 or 1, u is 0 or 1 and s and u satisfy a relation of s+u=1;
R₈ represents the same as R₁ in the formula (1); and
t is 4 and plural R₈ are mutually the same or different.

7. The organic electroluminescence device according to claim 1, wherein the emitting layer comprises the first host material in an amount of 10 mass % to 90 mass %, the second host material in an amount of from 10 mass % to 90 mass % and the phosphorescent dopant material in an amount of from 0.1 mass % to 30 mass % with a proviso that a sum of mass percentages of the materials in the emitting layer is 100 mass %.

8. The organic electroluminescence device according to claim 1, wherein the emitting layer comprises the first host material in an amount of 40 mass % to 60 mass %, the second host material in an amount of from 40 mass % to 60 mass % and the phosphorescent dopant material in an amount of from 0.1 mass % to 30 mass % with a proviso that a sum of mass percentages of the materials in the emitting layer is 100 mass %.

9. The organic electroluminescence device according to claim 1, wherein L₁ in the formula (1) is a single bond or a substituted or unsubstituted aryl group having 6 to 30 ring carbon atoms.

10. The organic electroluminescence device according to claim 1, wherein L₁ in the formula (1) is a substituted or unsubstituted p-phenylene group.

11. The organic electroluminescence device according to claim 2, wherein L₁ is a single bond or a substituted or unsubstituted aryl group having 6 to 30 ring carbon atoms.

12. The organic electroluminescence device according to claim 1, wherein at least one of X₁ to X₅ is a nitrogen atom.

13. The organic electroluminescence device according to claim 2, wherein
Ar₃ is a substituted or unsubstituted aryl group having 6 to 30 ring carbon atoms, and when Ar₃ is substituted, a substituent for Ar₃ is selected from the group consisting of an unsubstituted aryl group having 6 to 30 ring carbon atoms, an unsubstituted alkyl group having 1 to 30 carbon atoms, a halogen atom, a cyano group, an unsubstituted alkylsilyl group having 3 to 30 carbon atoms and an unsubstituted arylsilyl group having 6 to 30 ring carbon atoms.

14. The organic electroluminescence device according to claim 2, wherein s in the formula (9) is 1.

15. The organic electroluminescence device according to claim 1, wherein
X in the formula (8) is an oxygen atom or NR₂, and
R₂ in the formula (8) represents the same as R₂ in the formula (3).

16. The organic electroluminescence device according to claim 1, wherein X in the formula (8) is an oxygen atom.

17. The organic electroluminescence device according to claim 1, wherein L₂ is a substituted or unsubstituted aryl group having 6 to 30 ring carbon atoms, a substituted or unsubstituted heterocyclic group having 5 to 30 ring atoms, a cyclic hydrocarbon group having 5 to 30 ring carbon atoms, or a group provided by bonding the aryl group, the heterocyclic group and/or the cyclic hydrocarbon group.

18. An organic electroluminescence-device material consisting of:
a first host material in an amount of 10 mass % to 90 mass %, the first host material is a compound represented by formula (1) below; and
a second host material in an amount of 10 mass % to 90 mass %, the second host material comprising a compound represented by formula (3) below; 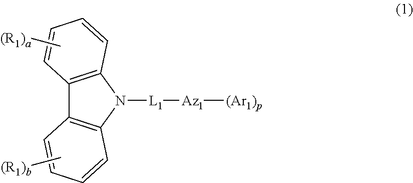
where:
R₁ are each independently a hydrogen atom, a halogen atom, a cyano group, a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted alkenyl group having 2 to 30 carbon atoms, a substituted or unsubstituted alkynyl group having 2 to 30 carbon atoms, a substituted or unsubstituted alkylsilyl group having 3 to 30 carbon atoms, a substituted or unsubstituted arylsilyl group having 6 to 30 ring carbon atoms, a substituted or unsubstituted alkoxy group having 1 to 30 carbon atoms, a substituted or unsubstituted aralkyl group having 6 to 30 ring carbon atoms, or a substituted or unsubstituted aryloxy group having 6 to 30 ring carbon atoms;
each of a and b is 4 and plural R₁ are mutually the same or different;
p is an integer of from 0 to 4;
L₁ is a single bond or a linking group, the linking group being a substituted or unsubstituted aryl group having 6 to 30 ring carbon atoms, a substituted or unsubstituted heterocyclic group having 5 to 30 ring atoms, a cyclic hydrocarbon group having 5 to 30 ring carbon atoms, or a group provided by bonding the aryl group, the heterocyclic group and/or the cyclic hydrocarbon group; and
Az₁ is a group represented by a formula (2) below, 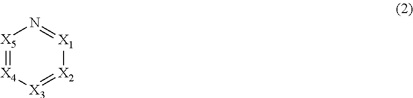
where:
any one of X₁ to X₅ is a carbon atom bonded to L₁;
the other four of X₁ to X₅ that are not bonded to L₁ are each independently CR₁ or a nitrogen atom when p is 0;
when p is 1 to 4, p of X₁ to X₅ are each a carbon atom bonded to Ar₁ in the formula (1) and (4-p) of X₁ to X₅ are each independently CR₁ or a nitrogen atom; and R₁ represents the same as R₁ in the formula (1), Ar₁ being a substituted or unsubstituted aryl group having 6 to 30 ring carbon atoms, a substituted or unsubstituted heterocyclic group having 5 to 30 ring carbon atoms, or a group provided by bonding the aryl group and the heterocyclic group, 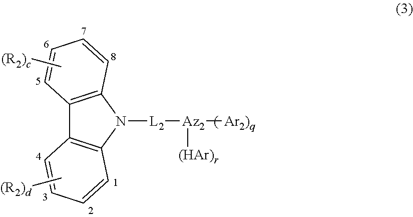
where:
R₂ are each independently a hydrogen atom, a halogen atom, a cyano group, a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted alkenyl group having 2 to 30 carbon atoms, a substituted or unsubstituted alkynyl group having 2 to 30 carbon atoms, a substituted or unsubstituted alkylsilyl group having 3 to 30 carbon atoms, a substituted or unsubstituted arylsilyl group having 6 to 30 ring carbon atoms, a substituted or unsubstituted alkoxy group having 1 to 30 carbon atoms, a substituted or unsubstituted aralkyl group having 6 to 30 ring carbon atoms, or a substituted or unsubstituted aryloxy group having 6 to 30 ring carbon atoms;
c and d each independently an integer of 0 to 4 and plural R₂ are mutually the same or different;
q is an integer of from 1 to 4;
r is 0 or 1;
1≦q+r≦4;
L₂ is a single bond or a linking group, the linking group being a substituted or unsubstituted aryl group having 6 to 30 ring carbon atoms, a substituted or unsubstituted heterocyclic group having 5 to 30 ring atoms, a cyclic hydrocarbon group having 5 to 30 ring carbon atoms, or a group provided by bonding the aromatic hydrocarbon group, the aromatic heterocyclic group and/or the cyclic hydrocarbon group;
Ar₂ is a substituted or unsubstituted aryl group having 6 to 30 ring carbon atoms, a substituted or unsubstituted heterocyclic group having 5 to 30 ring carbon atoms, or a group provided by bonding the aryl group and the heterocyclic group;
Az₂ is a group represented by a formula (4) below, 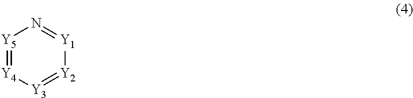
where:
any one of Y₁ to Y₅ is bonded to L₂;
q of the other four of Y₁ to Y₅ that are not bonded to L₂ are each a carbon atom bonded to Ar₂, r of the other four of Y₁ to Y₅ are each a carbon atom bonded to HAr, and (4-q-r) of the other four of Y₁ to Y₅ are each independently CR₃ or a nitrogen atom; and
R₃ represents the same as R₂ in the formula (3); and
HAr in the formula (3) is represented by any one of formulae (5) to (7) below, 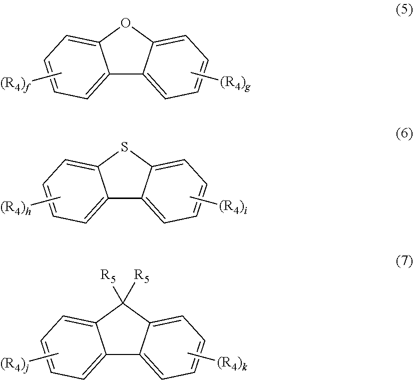
where:
each of f and g in the formula (5) is 4;
each of h and i in the formula (6) is 4;
each of j and k in the formula (7) is 4;
plural R₄ in each of the formulae (5), (6) and (7) are mutually the same or different and at least one of the plural R₄ is a single bond to Az₂;
R₄ in each of the formulae (5), (6) and (7) represents the same as R₂ in the formula (3); and
two R₅ in the formula (7) are mutually the same or different and each represent the same as R₂ in the formula (3), R₂ being bonded to a carbazole ring in the formula (3), the carbazole ring being bonded to a moiety represented by a formula (8) below, 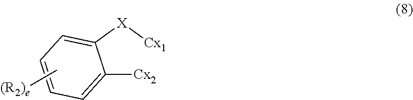
where:
Cx₁ and Cx₂ are any adjacent two of carbon atoms in 1- to 8-positions of the carbazole ring to which R₂ is bonded in the formula (3);
X is an oxygen atom, a sulfur atom, NR₂ or C(R₂)₂;
e is 4; and
R₂ represents the same as R₂ in the formula (3).
